(19) United States
(12) Patent Application Publication
(10) Pub. No.: US 2026/0282642 A1
(43) Pub. Date: Sep. 17, 2026

(54) ORGANIC COMPOUNDS AND ORGANIC LIGHT-EMITTING DEVICE COMPRISING SAME

(71) Applicant: SFC CO., LTD., Cheongju-si (KR)

(72) Inventors: Kyeong-hyeon KIM, Cheongju-si (KR); Do-yeong CHOI, Cheongju-si (KR); Kyeong-wan KIM, Cheongju-si (KR); Seo-youn PARK, Cheongju-si (KR); Jae-gyeong JEONG, Cheongju-si (KR); Yu-jin SEONG, Cheongju-si (KR); Se-jin LEE, Cheongju-si (KR)

(73) Assignee: SFC CO., LTD., Cheongju-si (KR)

(21) Appl. No.: 19/556,471

(22) Filed: Mar. 4, 2026

(30) Foreign Application Priority Data
Mar. 5, 2025 (KR) 10-2025-0028072
Jun. 4, 2025 (KR) 10-2025-0072698
Feb. 12, 2026 (KR) 10-2026-0028236

(51) Int. Cl. H10K 50/11; C07B 59/00; C07F 7/08; H10K 85/40; H10K 85/60

(52) U.S. Cl. CPC H10K 50/11; C07B 59/002; C07F 7/0805; C07F 7/0812; H10K 85/40; H10K 85/626; H10K 85/633; H10K 85/654; H10K 85/6572; H10K 85/6574; H10K 85/658; C07B 2200/05

(57) ABSTRACT

The present invention relates to an organic compound represented by the following [Chemical Formula 1] including the following [Structural Formula 1], and a high-efficiency and long-lifespan organic light-emitting device having significantly improved low-voltage driving, and excellent light-emitting efficiency, long lifespan and the like by employing the same as a host material of a light-emitting layer in the device.

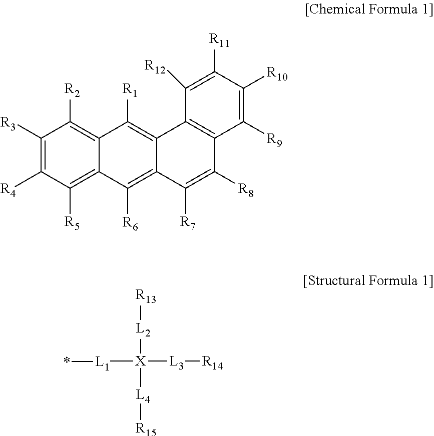

### CROSS-REFERENCE TO RELATED APPLICATION

This application claims the benefit under 35 USC 119 (a) of Korean Patent Application No. 10-2025-0028072 filed on Mar. 5, 2025, Korean Patent Application No. 10-2025-0072698 filed on Jun. 4, 2025, and Korean Patent Application No. 10-2026-0028236 filed on Feb. 12, 2026, in the Korean Intellectual Property Office, the disclosures of which are incorporated herein by reference in its entirety.

### TECHNICAL FIELD

The present invention relates to an organic compound employed in an organic layer in an organic light-emitting device, and an organic light-emitting device including the same.

### BACKGROUND ART

Organic light-emitting devices are self-luminous devices in which electrons injected from an electron injecting electrode (cathode) combine with holes injected from a hole injecting electrode (anode) in a light-emitting layer to form excitons, which emit light while releasing energy. Such organic light-emitting devices have advantages of low driving voltage, high luminance, wide viewing angle and short response time, and being applicable to full-color light-emitting flat-panel displays. Due to these advantages, organic light-emitting devices have received attention as next-generation light sources.

The above characteristics of organic light-emitting devices are achieved by structural optimization of organic layers of the devices and are supported by stable and efficient materials for the organic layers, such as hole injecting materials, hole transport materials, hole blocking materials, light-emitting materials, electron transport materials, electron injecting materials, and electron blocking materials. However, more research still needs to be done to develop structurally optimized structures of organic layers for organic light-emitting devices and stable and efficient materials for organic layers of organic light-emitting devices.

Particularly, to obtain maximum efficiency in a light-emitting layer, an appropriate combination of energy band gaps of a host and a dopant is required so that holes and electrons each migrate to the dopant through stable electrochemical paths to form excitons.

### DETAILED DESCRIPTION OF THE INVENTION

### Problems to be Solved by the Invention

Accordingly, the present invention is directed to providing a light-emitting layer host material having a characteristic structure, and a high-efficiency and long-lifespan organic light-emitting device having significantly improved low-voltage driving, light-emitting efficiency and lifespan by including the same.

### Means for Solving the Problems

In order to solve the above-described problems, one aspect of the present invention provides an organic compound represented by the following [Chemical Formula 1] including the following [Structural Formula 1], and an organic light-emitting device including the same as a light-emitting layer host in the device.

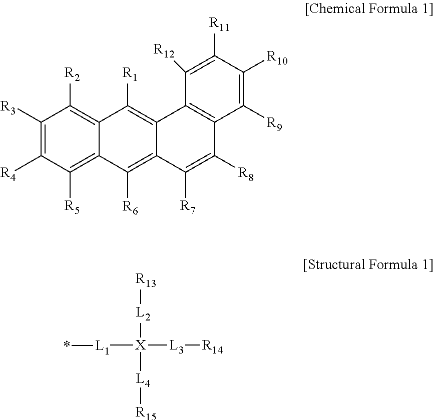

Specific structures of [Chemical Formula 1] and [Structural Formula 1], specific compounds according to the present invention obtained therefrom, and a definition of each substituent will be described below.

### Effects of the Invention

The present invention relates to an organic compound in which a characteristic moiety is introduced to a skeleton having a characteristic fused structure, and to an organic light-emitting device employing the same as a host of a light-emitting layer, and the organic light-emitting device having improved low voltage driving, high efficiency and long lifespan can be achieved. Accordingly, the organic light-emitting device can be effectively utilized not only in lighting devices, but also in various display devices such as flat-panel, flexible, stretchable and wearable displays, and displays for vehicles or aviation, and virtual or augmented reality.

### BEST MODE FOR CARRYING OUT THE INVENTION

Hereinafter, the present invention will be described in more detail.

One aspect of the present invention relates to a compound represented by the following [Chemical Formula 1] including the following [Structural Formula 1].

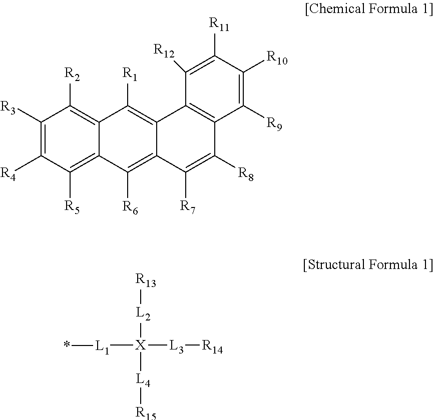

In [Chemical Formula 1],
one of R₁ to R₁₂ is linked to L₁ in [Structural Formula 1] via a single bond, and ‘*’ represents a linking site.

The remainders of R₁ to R₁₂ excluding the one linked to L₁ via a single bond are the same as or different from each other, and each independently selected from hydrogen, deuterium, tritium, a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted or unsubstituted C₂-C₃₀ alkenyl group, a substituted or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group.

X is Si or Ge.

L₁ to L₄ are the same as or different from each other, and each independently a single bond, or selected from a substituted or unsubstituted C₆-C₃₀ arylene group, a substituted or unsubstituted C₂-C₃₀ heteroarylene group, and a substituted or unsubstituted arylene group fused with a C₈-C₃₀ aliphatic hydrocarbon ring.

R₁₃ is selected from a substituted or unsubstituted C₆-C₅₀ aryl group, a substituted or unsubstituted C₂-C₅₀ heteroaryl group, a substituted or unsubstituted C₃-C₅₀ cycloalkyl group, a substituted or unsubstituted C₂-C₅₀ heterocycloalkyl group, and a substituted or unsubstituted cyclic group in which a C₃-C₃₀ aliphatic ring and a C₅-C₃₀ aromatic ring are fused.

R₁₄ and R₁₅ are the same as or different from each other, and each independently selected from a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted or unsubstituted C₂-C₃₀ alkenyl group, a substituted or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group.

In addition, the ‘substituted’ in the ‘substituted or unsubstituted’ in [Chemical Formula 1] and [Structural Formula 1] means being substituted with one or more substituents selected from the group consisting of deuterium, tritium, a C₁-C₂₄ alkyl group, a C₁-C₂₄ halogenated alkyl group, a C₂-C₂₄ alkenyl group, a C₂-C₂₄ alkynyl group, a C₃-C₃₀ cycloalkyl group, a C₁-C₂₄ heteroalkyl group, a C₆-C₃₀ aryl group, a C₇-C₃₀ arylalkyl group, a C₇-C₃₀ alkylaryl group, a C₂-C₃₀ heteroaryl group, a C₂-C₃₀ heteroarylalkyl group, a cyclic group in which a C₃-C₂₄ aliphatic ring and a C₅-C₂₄ aromatic ring are fused, a C₁-C₃₀ amine group, a C₁-C₃₀ silyl group, a C₁-C₃₀ germanium group, a C₁-C₃₀ oxy group, a C₁-C₃₀ thioxy group, a C₁-C₃₀ thionyl group, a cyano group, a halogen group, a thiol group, a hydroxyl group and a nitro group, and when there are two or more substituents, they are the same as or different from each other, and at least one hydrogen atom in the compound formed from [Chemical Formula 1] may be substituted with deuterium or tritium.

According to one embodiment of the present invention, R₆ in [Chemical Formula 1] may be linked to L₁ in [Structural Formula 1] via a single bond.

According to one embodiment of the present invention, Re in [Chemical Formula 1] may be linked to L₁ in [Structural Formula 1] via a single bond.

According to one embodiment of the present invention, L₁ may be a single bond, or a substituted or unsubstituted C₆-C₂₀ arylene group.

According to one embodiment of the present invention, R₁₃ may be a substituted or unsubstituted C₆-C₂₀ aryl group.

According to one embodiment of the present invention, R₁₄ and R₁₅ are the same as or different from each other, and may be each independently selected from a substituted or unsubstituted C₁-C₁₀ alkyl group, a substituted or unsubstituted C₆-C₂₀ aryl group, a substituted or unsubstituted C₂-C₂₀ heteroaryl group, and a substituted or unsubstituted cyclic group in which a C₃-C₂₀ aliphatic ring and a C₅-C₂₀ aromatic ring are fused.

According to one embodiment of the present invention, the remainders of R₁ to R₁₂ excluding the one linked to L₁ in [Structural Formula 1] via a single bond may each be hydrogen or deuterium.

Meanwhile, the range of the number of carbon atoms in the alkyl group or aryl group in the ‘substituted or unsubstituted C₁-C₃₀ alkyl group’, ‘substituted or unsubstituted C₆-C₅₀ aryl group’ and the like refers to the total number of carbon atoms forming the alkyl or aryl moiety when unsubstituted without considering the moiety substituted with the substituents. For example, it means that a phenyl group substituted with a butyl group at a para position corresponds to a C₆ aryl group substituted with a C₄ butyl group.

In addition, in the present invention, being linked to each other or to adjacent groups to further form a ring may mean that adjacent substituents among the specified substituents may bond to each other or the specified substituent and another adjacent group may bond to each h other to form a substituted or unsubstituted alicyclic or aromatic ring, and the ‘adjacent group’ may refer to a substituent substituting on an atom directly linked to an atom substituted with the corresponding substituent, a substituent positioned sterically closest to the corresponding substituent, or another substituent substituting on an atom substituted with the corresponding substituent. For example, two substituents substituting at an ortho position of a benzene ring and two substituents substituting on the same carbon in an aliphatic ring may be interpreted as ‘adjacent groups’ to each other, and the carbon atoms of the formed alicyclic or aromatic monocyclic or polycyclic ring may be replaced by a heteroatom such as O, S, N, P, Si or Ge.

In the present invention, the alkyl group may be linear or branched. Specific examples thereof may include a methyl group, an ethyl group, a propyl group, an n-propyl group, an isopropyl group, a butyl group, an n-butyl group, an isobutyl group, a tert-butyl group, a sec-butyl group, a 1-methyl-butyl group, a 1-ethyl-butyl group, a pentyl group, an n-pentyl group, an isopentyl group, a neopentyl group, a tert-pentyl group, a hexyl group, an n-hexyl group, a 1-methylpentyl group, a 2-methylpentyl group, a a 3,3-dimethylbutyl group, a 2-4-methyl-2-pentyl group, ethylbutyl group, a heptyl group, an n-heptyl group, a 1-methylhexyl group, a cyclopentylmethyl group, a cyclohexylmethyl group, an octyl group, an n-octyl group, a tert-octyl group, a 1-methylheptyl group, a 2-ethylhexyl group, a 2-propylpentyl group, an n-nonyl group, a 2,2-dimethylheptyl group, a 1-ethyl-propyl group, a 1,1-dimethyl-propyl group, an isohexyl group, a 2-methylpentyl group, a 4-methylhexyl group, a 5-methylhexyl group and the like, but are not limited thereto.

In the present invention, specific examples of the arylalkyl group may include phenylmethyl (benzyl), phenylethyl, phenylpropyl, naphthylmethyl, naphthylethyl and the like, but are not limited thereto.

In the present invention, specific examples of the alkylaryl group may include tolyl, xylenyl, dimethylnaphthyl, t-butylphenyl, t-butylnaphthyl, t-butylphenanthryl and the like, but are not limited thereto.

In the present invention, the alkenyl group includes linear or branched forms, and may be further substituted with other substituents. Specific examples thereof may include a vinyl group, a 1-propenyl group, an isopropenyl group, a 1-butenyl group, a 2-butenyl group, a 3-butenyl group, a 1-pentenyl group, a 2-pentenyl group, a 3-pentenyl group, a 3-methyl-1-butenyl group, a 1,3-butadienyl group, an allyl group, a 1-phenylvinyl-1-yl group, a 2-phenylvinyl-1-yl group, a 2,2-diphenylvinyl-1-yl group, a 2-phenyl-2-(naphthyl-1-yl) vinyl-1-yl group, a 2,2-bis(diphenyl-1-yl) vinyl-1-yl group, a stilbenyl group, a styrenyl group and the like, but are not limited thereto.

In the present invention, the alkynyl group also includes linear or branched forms, and may be further substituted with other substituents. Examples thereof may include ethynyl, 2-propynyl and the like, but are not limited thereto.

In the present invention, the cycloalkenyl group is a non-aromatic cyclic unsaturated hydrocarbon group having one or more carbon double bonds. Examples thereof may include cyclopropenyl, cyclobutenyl, cyclopentenyl, cyclohexenyl, cycloheptenyl, 1,3-cyclohexadienyl, 1,4-cyclohexadienyl, 2,4-cycloheptadienyl, 1,5-cyclooctadienyl and the like, but are not limited thereto.

In the present invention, the aromatic hydrocarbon ring or the aryl group may be monocyclic or polycyclic. The term ‘polycyclic group’ refers to a group directly linked to or fused with other cyclic groups, and the other cyclic group may be an aromatic hydrocarbon ring, but may also be other types of cyclic groups such as an aliphatic heteroring, an aliphatic hydrocarbon ring and an aromatic heteroring. Examples of the monocyclic aryl group may include a phenyl group, a biphenyl group, a terphenyl group and the like, and examples of the polycyclic aryl group may include a naphthyl group, an anthracenyl group, a phenanthrenyl group, a pyrenyl group, a perylenyl group, a tetracenyl group, a chrysenyl group, a fluorenyl group, an acenaphathcenyl group, a triphenylene group, a fluoranthrene group and the like, however, the scope of the present invention is not limited to these examples.

In addition, in the present invention, the arylene group refers to a divalent or higher group derived from an aromatic hydrocarbon group such as benzene, naphthalene, biphenyl, anthracene, fluorene or phenanthrene. A preferred arylene group is a divalent or trivalent arylene group. Specific examples of the arylene group may include a phenylene group, a biphenylene group, a naphthylene group, a fluorenylene group and the like. More specifically, a 1,4-phenylene group, a 1,3-phenylene group, a 1,2-phenylene group, a 4,4′-biphenylene group, a 4,3′-biphenylene group, a 1,4-naphthalenylene group, a 1,5-naphthalenylene group, a 1,3,5-phenylene group and the like may be included, however, the arylene group is not limited thereto.

In the present invention, the aromatic heteroring or the heteroaryl group is an aromatic ring including one or more of heteroatoms. Examples thereof may include a thiophene group, a furan group, a pyrrole group, an imidazole group, a thiazole group, an oxazole group, an oxadiazole group, a triazole group, a pyridyl group, a bipyridyl group, a pyrimidyl group, a triazine group, a triazole group, an acridyl group, a pyridazine group, a pyrazinyl group, a quinolinyl group, a quinazoline group, a quinoxalinyl group, a phthalazinyl group, a pyridopyrimidinyl group, a pyridopyrazinyl group, a pyrazinopyrazinyl group, an isoquinoline group, an indole group, a carbazole group, an indolocarbazole group, a benzoxazole group, a benzimidazole group, benzothiazole group, a benzocarbazole group, a benzothiophene group, a dibenzothiophene group, a benzofuranyl group, a dibenzofuranyl group, a phenanthroline group, a thiazolyl group, an isoxazolyl group, an oxadiazolyl group, a thiadiazolyl group, a benzothiazolyl group, a phenothiazinyl and the like, but are not limited thereto.

In addition, in the present invention, the heteroarylene group refers to a divalent or higher group derived from an aromatic group having one or more atoms other than carbon in the ring, such as pyridine, quinoline, pyrimidine, pyrazine, triazine, quinoxaline, quinazoline, dibenzofuran or dibenzothiophene. A preferred heteroarylene group is a divalent or trivalent heteroarylene group. Specific examples of the heteroarylene group may include a 2,6-pyridylene group, a 2,5-pyridylene group, a 3,5-pyridylene group, a 2,4,6-pyridylene group, a 2,4-pyrimidinylene group, a 2,5-pyrimidinylene group, a 4,6-pyrimidinylene group, a 2,4,6-pyrimidinylene group, a 2,4,6-triazinylene group, a 4,6-dibenzofuranylene group, a 2,6-dibenzofuranylene group, a 3,7-dibenzofuranylene group, a 4,6-dibenzothiophenylene group and the like, but are not limited thereto.

In the present invention, the aliphatic hydrocarbon ring or the cycloalkyl group refers to a non-aromatic ring formed only with carbon and hydrogen atoms. Examples thereof may include monocyclic or polycyclic groups, and the aliphatic hydrocarbon ring or the cycloalkyl group may be further substituted with other substituents. The term ‘polycyclic group’ refers to a group directly linked to or fused with other cyclic groups, and the other cyclic group may be an aliphatic hydrocarbon ring, but may also be other types of cyclic groups such as an aliphatic heteroring, an aromatic hydrocarbon ring and an aromatic heteroring. Specific examples thereof may include a cycloalkyl group such as a cyclopropyl group, a cyclobutyl group, cyclopentyl group, an adamantyl group, a bicycloheptanyl group, a 3-methylcyclopentyl group, a 2,3-dimethylcyclopentyl group, a cyclohexyl group, a 3-methylcyclohexyl group, a 4-methylcyclohexyl group, a 2,3-dimethylcyclohexyl group, a 3,4,5-trimethylcyclohexyl group, a 4-tert-butylcyclohexyl group, a cycloheptyl group and a cyclooctyl group, a cycloalkane group such as a cyclohexane group and a cyclopentane group, and a cycloalkene group such as a cyclohexene group and a cyclobutene group, but are not limited thereto.

In the present invention, the aliphatic heteroring or the heterocycloalkyl group refers to an aliphatic ring including one or more of heteroatoms such as O, S, Se, N, Si or Ge, includes monocyclic or polycyclic groups as well, and may be further substituted with other substituents. The term ‘polycyclic group’ refers to a group in which heterocycloalkyl, heterocycloalkane or the like is directly linked to or fused with other cyclic groups, and the other cyclic group may be an aliphatic heteroring, but may also be other types of cyclic groups such as an aliphatic hydrocarbon ring, an aromatic hydrocarbon ring and an aromatic heteroring.

In the present invention, the ring (cyclic group) in which an aliphatic ring and an aromatic ring are fused is an aliphatic-aromatic mixed ring (cyclic group), and refers to a ring in which two or more rings are linked to and fused with each other, and an aliphatic ring and an aromatic ring are fused. More specifically, the ring (cyclic group) in which an aliphatic ring and an aromatic ring are fused may include an aromatic hydrocarbon ring (cyclic group) fused with an aliphatic hydrocarbon ring, an aromatic hydrocarbon ring (cyclic group) fused with an aliphatic heteroring, an aromatic heteroring (cyclic group) fused with an aliphatic hydrocarbon ring, an aromatic heteroring (cyclic group) fused with an aliphatic heteroring, an aliphatic hydrocarbon ring (cyclic group) fused with an aromatic hydrocarbon ring, an aliphatic hydrocarbon ring (cyclic group) fused with an aromatic heteroring, an aliphatic heteroring (cyclic group) fused with an aromatic hydrocarbon ring, an aliphatic heteroring (cyclic group) fused with an aromatic heteroring, and the like, and specific examples thereof may include a tetrahydronaphthyl group, a tetrahydrobenzocycloheptene group, a tetrahydrophenanthrene group, a tetrahydroanthracenyl group, an octahydrotriphenylene group, a tetrahydrobenzothiophene group, a tetrahydrobenzofuranyl group, a tetrahydrocarbazole group, a tetrahydroquinoline group and the like. In addition, carbon in the ring (cyclic group) in which an aliphatic ring and an aromatic ring are fused may be substituted with a heteroatom such as O, S, N, P, Si or Ge.

In addition, in the present invention, the amine group includes —NH₂, and is a functional group in which at least one of the two hydrogen atoms bonded to the nitrogen atom in the —NH₂ is substituted with any one selected from an alkyl group, a cycloalkyl group, an aryl group, an aryl group fused with an aliphatic hydrocarbon ring, an arylalkyl group, an alkylaryl group, a heteroaryl group, and a heteroaryl group fused with an aliphatic hydrocarbon ring. When both the two hydrogen atoms bonded to the nitrogen atom in the —NH₂ are each substituted with the above-mentioned substituents, these respective substituents may be the same as or different from each other, and at least one hydrogen atom in the alkyl group, the cycloalkyl group, the aryl group, the aryl group fused with an aliphatic hydrocarbon ring, the arylalkyl group, the alkylaryl group, the heteroaryl group, the heteroaryl group fused with an aliphatic hydrocarbon ring bonded to the nitrogen atom in the amine group may be substituted with the same substituents as in the case of the aryl group.

Herein, the aryl group in each of the aryl group, the arylheteroaryl group, the aryl group fused with an aliphatic hydrocarbon ring, the cycloalkylaryl group or the like bonded to the nitrogen atom in the amine group may be a monocyclic aryl group or a polycyclic aryl group, and the heteroaryl group in each of the heteroaryl group, the arylheteroaryl group or the like may be a monocyclic heteroaryl group or a polycyclic heteroaryl group.

Examples of the amine group may include an alkylamine group in which one or two identical or different alkyl groups bond to a nitrogen atom, an arylamine group in which one or two identical or different aryl groups bond to a nitrogen atom, an alkylarylamine group in which one alkyl group and one aryl group bond to a nitrogen atom, and the like, and in addition thereto, may include a heteroarylamine group, an arylheteroarylamine group, an alkyl (aryl fused with an aliphatic hydrocarbon ring)amine group, an aryl (aryl fused with an aliphatic hydrocarbon ring)amine group, a cycloalkyl (aryl fused with an aliphatic hydrocarbon ring)amine group, a cycloalkylarylamine group, a heteroaryl (aryl fused with an aliphatic hydrocarbon ring)amine group, and the like.

In the present invention, the silyl group includes —SiH₃, and is a functional group in which at least one of the three hydrogen atoms bonded to the silicon atom in the —SiH₃ is substituted with any one selected from an alkyl group, a cycloalkyl group, an aryl group, an aryl group fused with an aliphatic hydrocarbon ring, an arylalkyl group, an alkylaryl group, a heteroaryl group, and a heteroaryl group fused with an aliphatic hydrocarbon ring. When one, two or three hydrogen atoms bonded to the silicon atom in the —SiH₃ are each substituted with the above-mentioned substituents, these respective substituents may be the same as or different from each other, and at least one hydrogen atom in the alkyl group, the cycloalkyl group, the aryl group, the aryl group fused with an aliphatic hydrocarbon ring, the arylalkyl group, the alkylaryl group, the heteroaryl group, the heteroaryl group fused with an aliphatic hydrocarbon ring bonded to the silicon atom in the silyl group may be substituted with the same substituents as in the case of the aryl group.

Herein, the aryl group in each of the aryl group, the arylheteroaryl group, the aryl group fused with an aliphatic hydrocarbon ring, the cycloalkylaryl group or the like bonded to the silicon atom in the silyl group may be a monocyclic aryl group or a polycyclic aryl group, and the heteroaryl group in each of the heteroaryl group, the arylheteroaryl group or the like may be a monocyclic heteroaryl group or a polycyclic heteroaryl group.

Examples of the silyl group may include an alkylsilyl group in which one, two or three identical or different alkyl groups bond to a silicon atom, an arylsilyl group in which one, two or three identical or different aryl groups bond to a silicon atom, an alkylarylsilyl group in which one alkyl group and one aryl group bond to a silicon atom, an alkylarylheteroarylsilyl group in which one alkyl group, one aryl group and one heteroaryl group bond to a silicon atom, and the like, and in addition thereto, may include an alkyl (heteroaryl) silyl group, an arylheteroarylsilyl group, an alkyl (aryl fused with an aliphatic hydrocarbon ring) silyl group, an alkyl (aryl) (aryl fused with an aliphatic hydrocarbon ring) silyl group, a cycloalkyl (aryl fused with an aliphatic hydrocarbon ring) silyl group, a cycloalkylarylheteroarylsilyl group, an alkyl (heteroaryl) (aryl fused with an aliphatic hydrocarbon ring) silyl group, and the like.

In addition, specific examples of the silyl group may include trimethylsilyl, triethylsilyl, triphenylsilyl, trimethoxysilyl, dimethoxyphenylsilyl, diphenylmethylsilyl, diphenylvinylsilyl, methylcyclcobutylsilyl, dimethylfurylsilyl, and the like.

In addition, in the present invention, the germanium group (or germyl group, or germane group) refers to a function group in which the silicon (Si) atom in the silyl group is substituted with a germanium (Ge) atom, and the rest are as described for the silyl group.

Specific examples of the germanium group may include trimethylgermane, triethylgermane, triphenylgermane, trimethoxygermane, dimethoxyphenylgermane, diphenylmethylgermane, diphenylvinylgermane, methylcyclobutylgermane, dimethylfurylgermane and the like.

In the present invention, the oxy group is a functional group of —O—R′, which is a substituent in which an oxygen atom bonds to the end of various substituents. Specific examples thereof may include an alkyloxy group when R′ is an alkyl group, an aryloxy group when R′ is an aryl group, a heteroaryloxy group when R′ is a heteroaryl group, a cycloalkyloxy group when R′ is a cycloalkyl group, and the like, but are not limited thereto.

In the present invention, the thioxy group is a functional group of —S—R′, which is a substituent in which a sulfur atom bonds to the end of various substituents. Specific examples thereof may include an alkylthioxy group when R′ is an alkyl group, an arylthioxy group when R′ is an aryl group, a heteroarylthioxy group when R′ is a heteroaryl group, a cycloalkylthioxy group when R′ is a cycloalkyl group, and the like, but are not limited thereto.

In the present invention, the thionyl group is a substituent in which a sulfonyl group bonds to the end of various substituents. Specific examples thereof may include an alkylthionyl group when the substituent at the end is an alkyl group, an arylthionyl group when the substituent at the end is an aryl group, a heteroarylthionyl group when the substituent at the end is a heteroaryl group, a cycloalkylthionyl group when the substituent at the end is a cycloalkyl group, and the like, but are not limited thereto.

In the present invention, examples of the halogen group include fluorine, chlorine, bromine or iodine.

According to one embodiment of the present invention, the compound represented by [Chemical Formula 1] may be any one selected from compounds represented by the following chemical formulae, however, the scope of the present invention is not limited thereby.

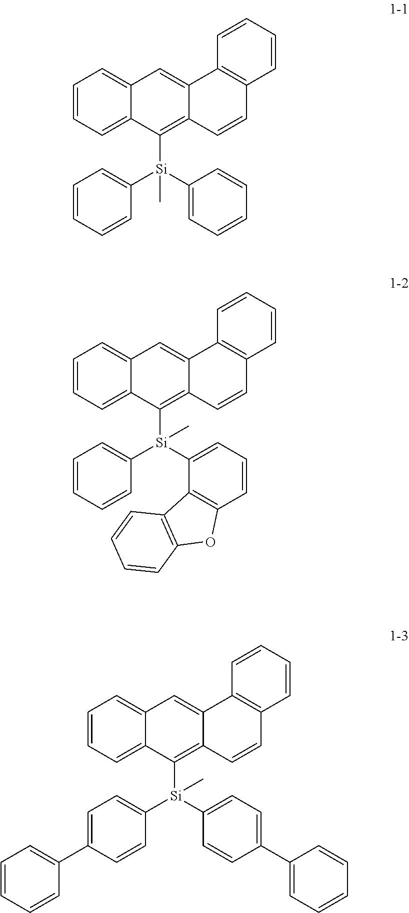 [SMILES: C[Si](c1ccccc1)(c1ccccc1)c1c2ccccc2cc2c1ccc1ccccc12 ; C[Si](c1ccccc1)(c1c2ccccc2cc2c1ccc1ccccc12)c1cccc2oc3ccccc3c12 ; C[Si](c1ccc(-c2ccccc2)cc1)(c1ccc(-c2ccccc2)cc1)c1c2ccccc2cc2c1ccc1ccccc12]

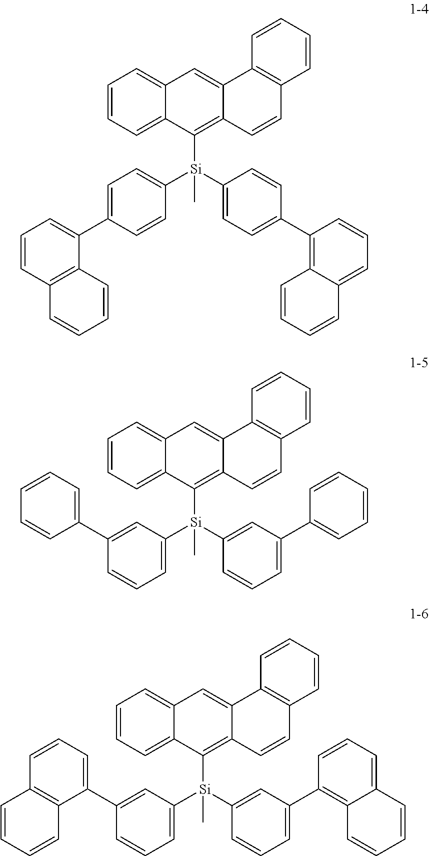 [SMILES: C[Si](c1ccc(-c2cccc3ccccc23)cc1)(c1ccc(-c2cccc3ccccc23)cc1)c1c2ccccc2cc2c1ccc1ccccc12 ; C[Si](c1cccc(-c2ccccc2)c1)(c1cccc(-c2ccccc2)c1)c1c2ccccc2cc2c1ccc1ccccc12 ; C[Si](c1cccc(-c2cccc3ccccc23)c1)(c1cccc(-c2cccc3ccccc23)c1)c1c2ccccc2cc2c1ccc1ccccc12]

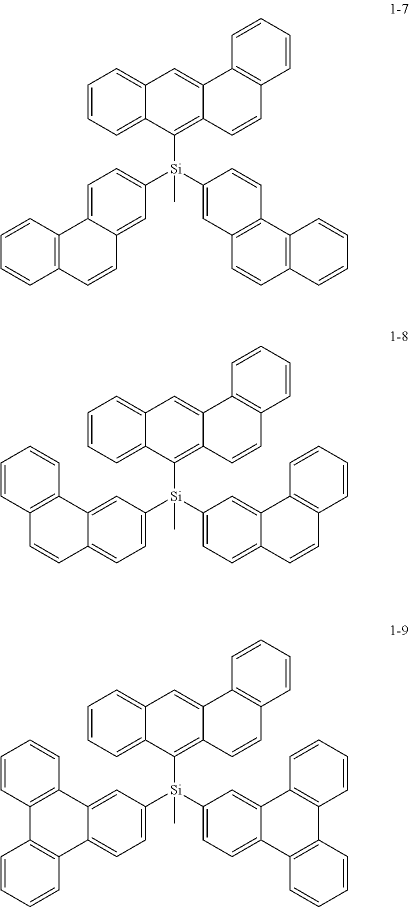 [SMILES: C[Si](c1ccc2c(ccc3ccccc32)c1)(c1ccc2c(ccc3ccccc32)c1)c1c2ccccc2cc2c1ccc1ccccc12 ; C[Si](c1ccc2ccc3ccccc3c2c1)(c1ccc2ccc3ccccc3c2c1)c1c2ccccc2cc2c1ccc1ccccc12 ; C[Si](c1ccc2c3ccccc3c3ccccc3c2c1)(c1ccc2c3ccccc3c3ccccc3c2c1)c1c2ccccc2cc2c1ccc1ccccc12]

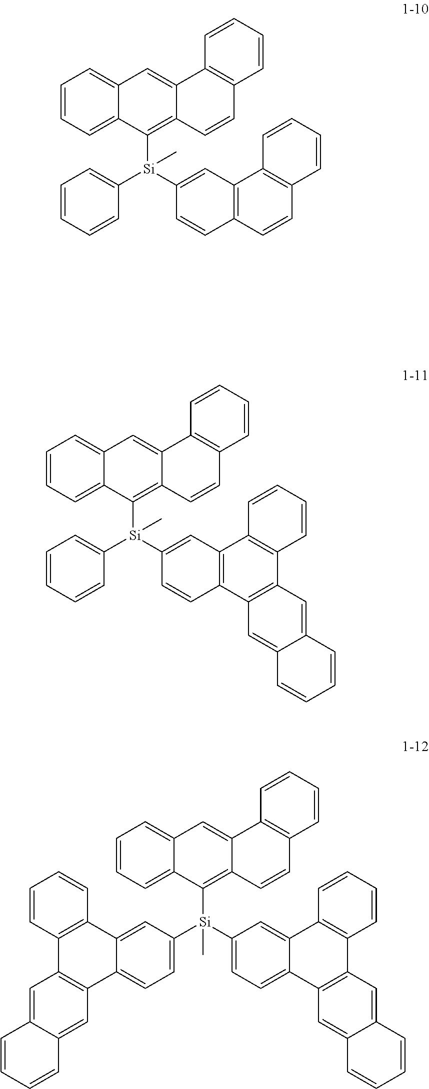 [SMILES: C[Si](c1ccccc1)(c1ccc2ccc3ccccc3c2c1)c1c2ccccc2cc2c1ccc1ccccc12 ; C[Si](c1ccccc1)(c1ccc2c(c1)c1ccccc1c1cc3ccccc3cc21)c1c2ccccc2cc2c1ccc1ccccc12 ; C[Si](c1ccc2c(c1)c1ccccc1c1cc3ccccc3cc21)(c1ccc2c(c1)c1ccccc1c1cc3ccccc3cc21)c1c2ccccc2cc2c1ccc1ccccc12]

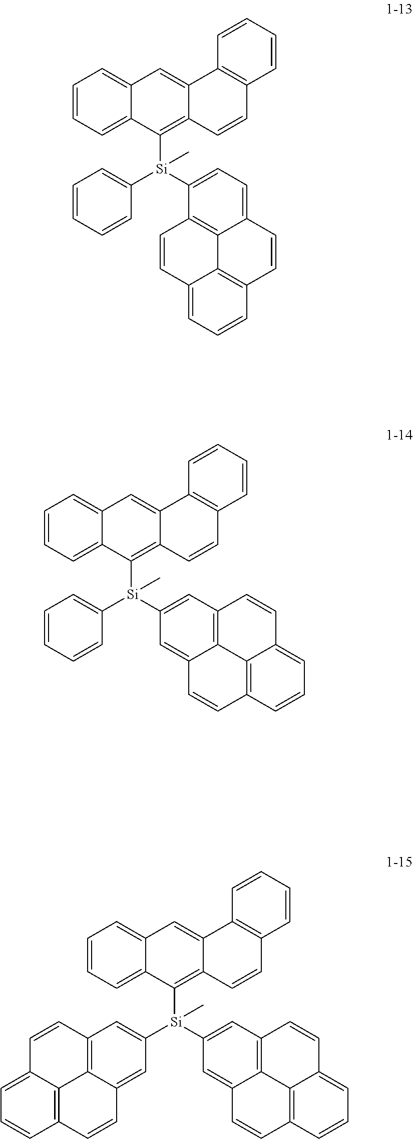 [SMILES: C[Si](c1ccccc1)(c1c2ccccc2cc2c1ccc1ccccc12)c1ccc2ccc3cccc4ccc1c2c34 ; C[Si](c1ccccc1)(c1cc2ccc3cccc4ccc(c1)c2c34)c1c2ccccc2cc2c1ccc1ccccc12 ; C[Si](c1cc2ccc3cccc4ccc(c1)c2c34)(c1cc2ccc3cccc4ccc(c1)c2c34)c1c2ccccc2cc2c1ccc1ccccc12]

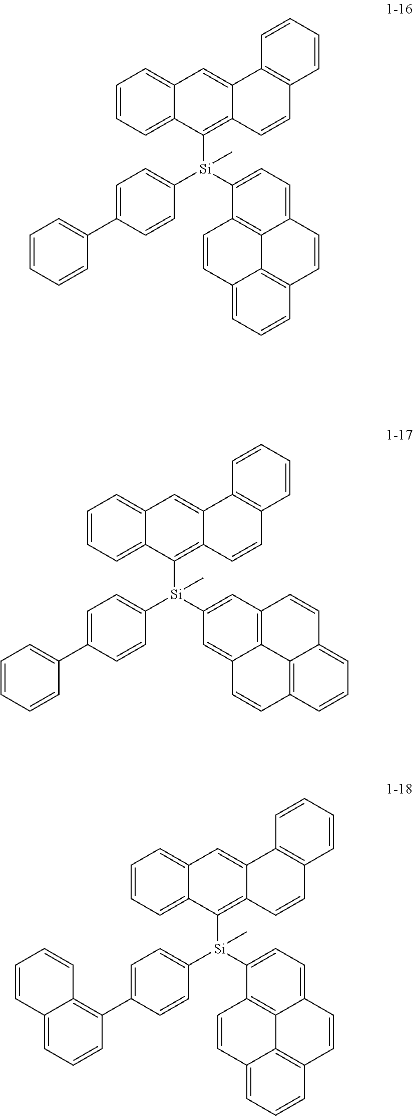 [SMILES: C[Si](c1ccc(-c2ccccc2)cc1)(c1c2ccccc2cc2c1ccc1ccccc12)c1ccc2ccc3cccc4ccc1c2c34 ; C[Si](c1ccc(-c2ccccc2)cc1)(c1cc2ccc3cccc4ccc(c1)c2c34)c1c2ccccc2cc2c1ccc1ccccc12 ; C[Si](c1ccc(-c2cccc3ccccc23)cc1)(c1c2ccccc2cc2c1ccc1ccccc12)c1ccc2ccc3cccc4ccc1c2c34]

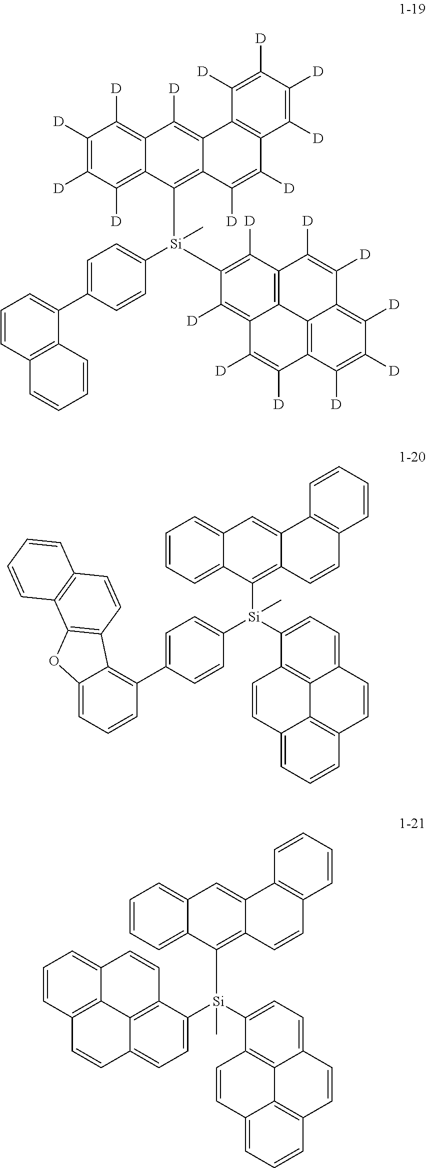 [SMILES: [2H]c1c([2H])c([2H])c2c([2H])c3c(c([2H])c([2H])c4c([2H])c([2H])c([2H])c([2H])c43)c([Si](C)(c3ccc(-c4cccc5ccccc45)cc3)c3c([2H])c4c([2H])c([2H])c5c([2H])c([2H])c([2H])c6c([2H])c([2H])c(c3[2H])c4c56)c2c1[2H] ; C[Si](c1ccc(-c2cccc3oc4c5ccccc5ccc4c23)cc1)(c1c2ccccc2cc2c1ccc1ccccc12)c1ccc2ccc3cccc4ccc1c2c34 ; C[Si](c1c2ccccc2cc2c1ccc1ccccc12)(c1ccc2ccc3cccc4ccc1c2c34)c1ccc2ccc3cccc4ccc1c2c34]

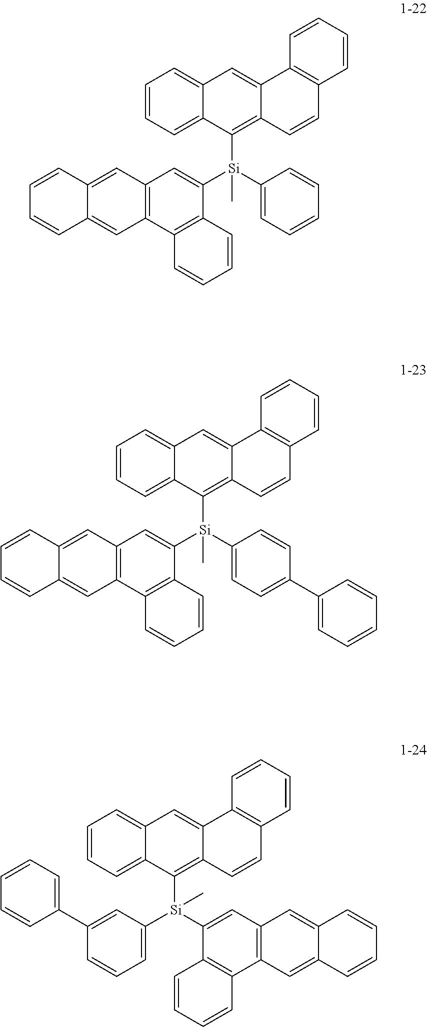 [SMILES: C[Si](c1ccccc1)(c1cc2cc3ccccc3cc2c2ccccc12)c1c2ccccc2cc2c1ccc1ccccc12 ; C[Si](c1ccc(-c2ccccc2)cc1)(c1cc2cc3ccccc3cc2c2ccccc12)c1c2ccccc2cc2c1ccc1ccccc12 ; C[Si](c1cccc(-c2ccccc2)c1)(c1cc2cc3ccccc3cc2c2ccccc12)c1c2ccccc2cc2c1ccc1ccccc12]

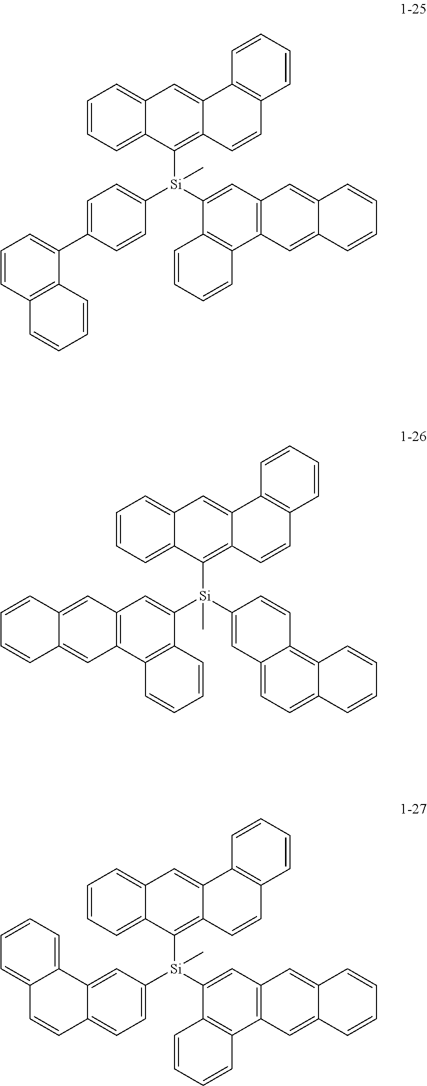 [SMILES: C[Si](c1ccc(-c2cccc3ccccc23)cc1)(c1cc2cc3ccccc3cc2c2ccccc12)c1c2ccccc2cc2c1ccc1ccccc12 ; C[Si](c1ccc2c(ccc3ccccc32)c1)(c1cc2cc3ccccc3cc2c2ccccc12)c1c2ccccc2cc2c1ccc1ccccc12 ; C[Si](c1ccc2ccc3ccccc3c2c1)(c1cc2cc3ccccc3cc2c2ccccc12)c1c2ccccc2cc2c1ccc1ccccc12]

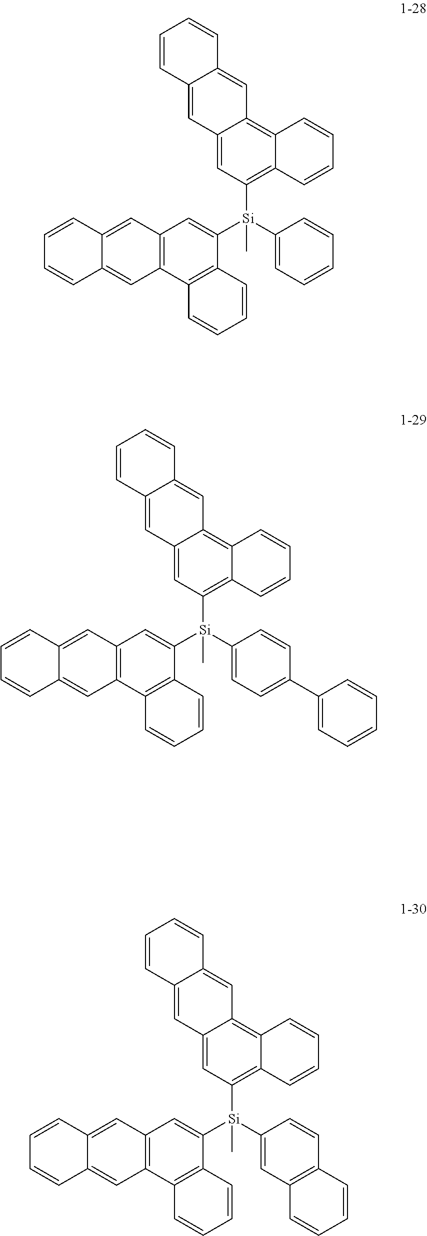 [SMILES: C[Si](c1ccccc1)(c1cc2cc3ccccc3cc2c2ccccc12)c1cc2cc3ccccc3cc2c2ccccc12 ; C[Si](c1ccc(-c2ccccc2)cc1)(c1cc2cc3ccccc3cc2c2ccccc12)c1cc2cc3ccccc3cc2c2ccccc12 ; C[Si](c1ccc2ccccc2c1)(c1cc2cc3ccccc3cc2c2ccccc12)c1cc2cc3ccccc3cc2c2ccccc12]

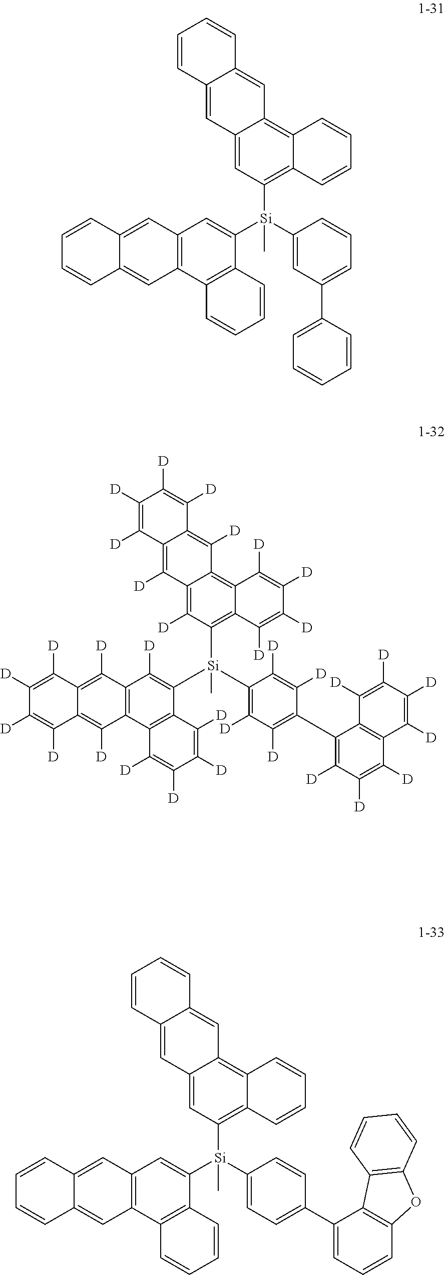 [SMILES: C[Si](c1cccc(-c2ccccc2)c1)(c1cc2cc3ccccc3cc2c2ccccc12)c1cc2cc3ccccc3cc2c2ccccc12 ; [2H]c1c([2H])c([Si](C)(c2c([2H])c3c([2H])c4c([2H])c([2H])c([2H])c([2H])c4c([2H])c3c3c([2H])c([2H])c([2H])c([2H])c23)c2c([2H])c3c([2H])c4c([2H])c([2H])c([2H])c([2H])c4c([2H])c3c3c([2H])c([2H])c([2H])c([2H])c23)c([2H])c([2H])c1-c1c([2H])c([2H])c([2H])c2c([2H])c([2H])c([2H])c([2H])c12 ; C[Si](c1ccc(-c2cccc3oc4ccccc4c23)cc1)(c1cc2cc3ccccc3cc2c2ccccc12)c1cc2cc3ccccc3cc2c2ccccc12]

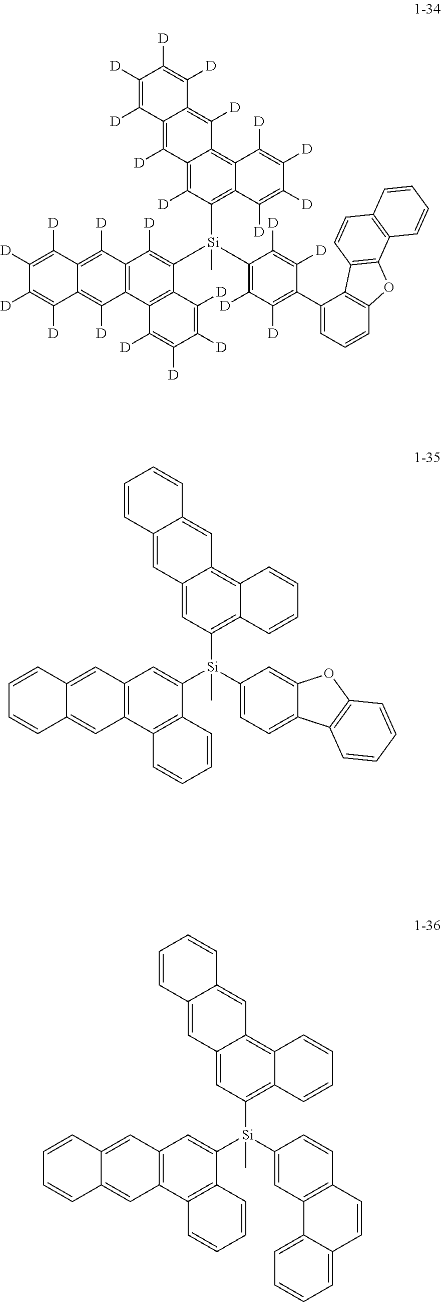 [SMILES: [2H]c1c([2H])c([Si](C)(c2c([2H])c3c([2H])c4c([2H])c([2H])c([2H])c([2H])c4c([2H])c3c3c([2H])c([2H])c([2H])c([2H])c23)c2c([2H])c3c([2H])c4c([2H])c([2H])c([2H])c([2H])c4c([2H])c3c3c([2H])c([2H])c([2H])c([2H])c23)c([2H])c([2H])c1-c1cccc2oc3c4ccccc4ccc3c12 ; C[Si](c1ccc2c(c1)oc1ccccc12)(c1cc2cc3ccccc3cc2c2ccccc12)c1cc2cc3ccccc3cc2c2ccccc12 ; C[Si](c1ccc2ccc3ccccc3c2c1)(c1cc2cc3ccccc3cc2c2ccccc12)c1cc2cc3ccccc3cc2c2ccccc12]

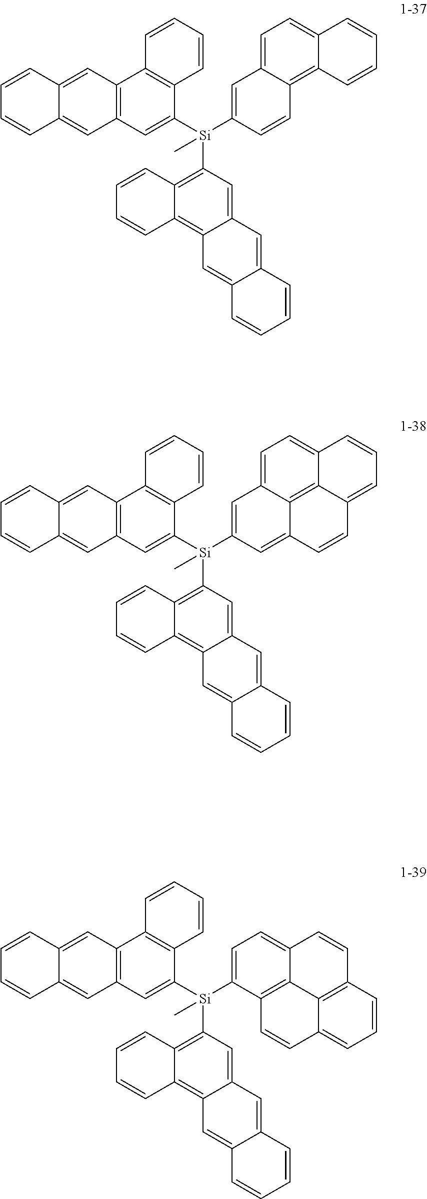 [SMILES: C[Si](c1ccc2c(ccc3ccccc32)c1)(c1cc2cc3ccccc3cc2c2ccccc12)c1cc2cc3ccccc3cc2c2ccccc12 ; C[Si](c1cc2ccc3cccc4ccc(c1)c2c34)(c1cc2cc3ccccc3cc2c2ccccc12)c1cc2cc3ccccc3cc2c2ccccc12 ; C[Si](c1cc2cc3ccccc3cc2c2ccccc12)(c1cc2cc3ccccc3cc2c2ccccc12)c1ccc2ccc3cccc4ccc1c2c34]

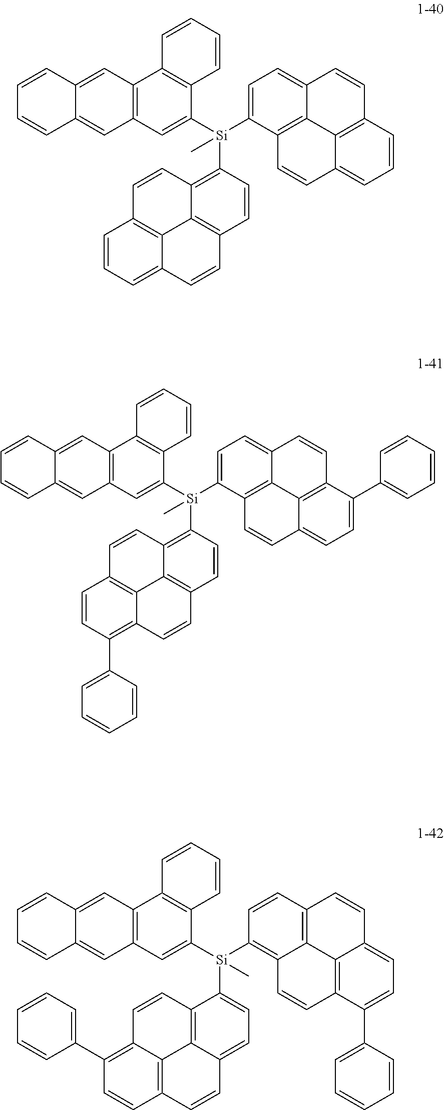 [SMILES: C[Si](c1cc2cc3ccccc3cc2c2ccccc12)(c1ccc2ccc3cccc4ccc1c2c34)c1ccc2ccc3cccc4ccc1c2c34 ; C[Si](c1cc2cc3ccccc3cc2c2ccccc12)(c1ccc2ccc3c(-c4ccccc4)ccc4ccc1c2c43)c1ccc2ccc3c(-c4ccccc4)ccc4ccc1c2c43 ; C[Si](c1cc2cc3ccccc3cc2c2ccccc12)(c1ccc2ccc3ccc(-c4ccccc4)c4ccc1c2c34)c1ccc2ccc3ccc(-c4ccccc4)c4ccc1c2c34]

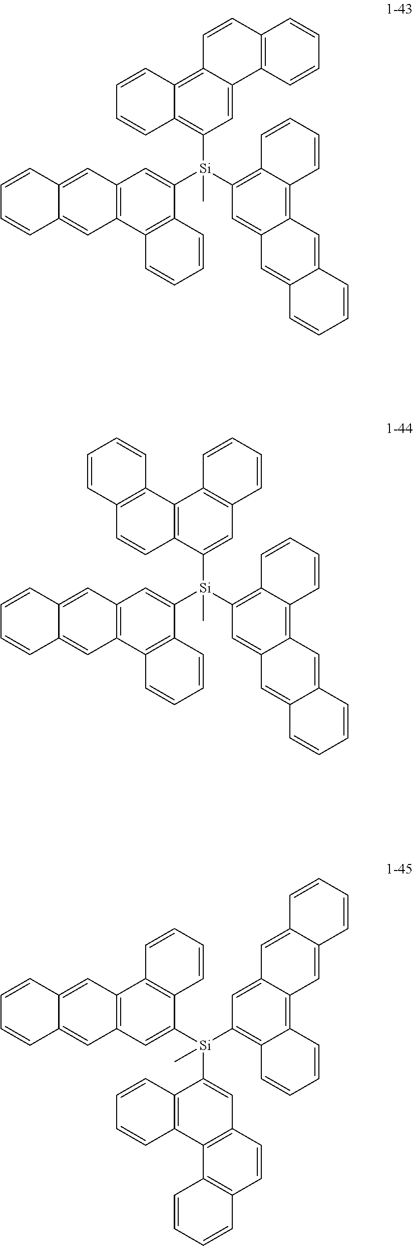 [SMILES: C[Si](c1cc2cc3ccccc3cc2c2ccccc12)(c1cc2cc3ccccc3cc2c2ccccc12)c1cc2c3ccccc3ccc2c2ccccc12 ; C[Si](c1cc2cc3ccccc3cc2c2ccccc12)(c1cc2cc3ccccc3cc2c2ccccc12)c1cc2ccccc2c2c1ccc1ccccc12 ; C[Si](c1cc2cc3ccccc3cc2c2ccccc12)(c1cc2cc3ccccc3cc2c2ccccc12)c1cc2ccc3ccccc3c2c2ccccc12]

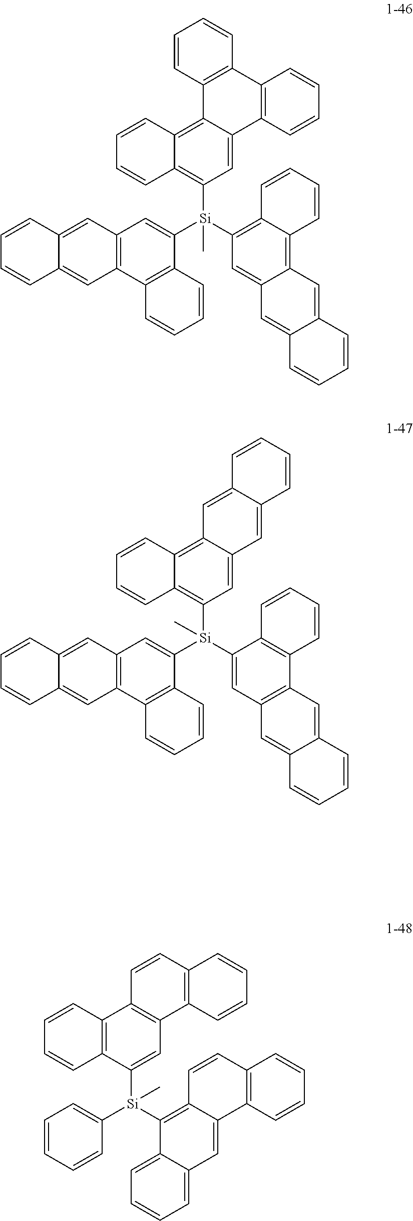 [SMILES: C[Si](c1cc2cc3ccccc3cc2c2ccccc12)(c1cc2cc3ccccc3cc2c2ccccc12)c1cc2c3ccccc3c3ccccc3c2c2ccccc12 ; C[Si](c1cc2cc3ccccc3cc2c2ccccc12)(c1cc2cc3ccccc3cc2c2ccccc12)c1cc2cc3ccccc3cc2c2ccccc12 ; C[Si](c1ccccc1)(c1c2ccccc2cc2c1ccc1ccccc12)c1cc2c3ccccc3ccc2c2ccccc12]

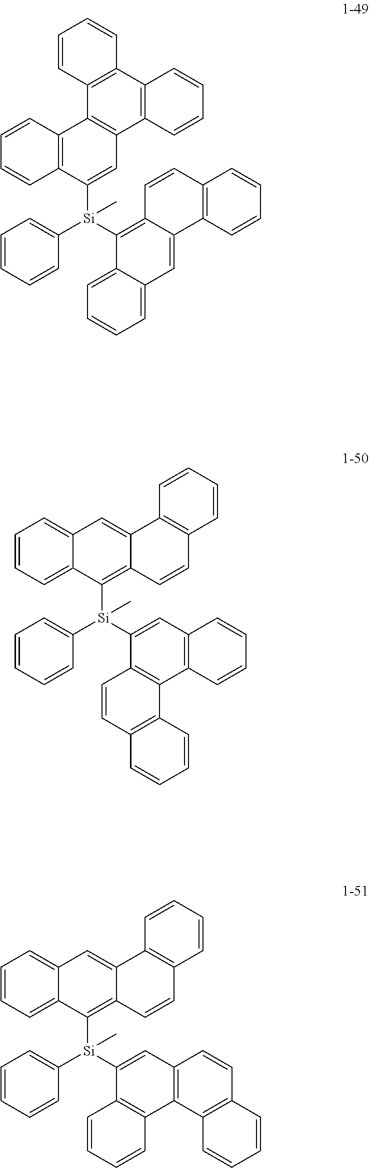 [SMILES: C[Si](c1ccccc1)(c1c2ccccc2cc2c1ccc1ccccc12)c1cc2c3ccccc3c3ccccc3c2c2ccccc12 ; C[Si](c1ccccc1)(c1c2ccccc2cc2c1ccc1ccccc12)c1cc2ccccc2c2c1ccc1ccccc12 ; C[Si](c1ccccc1)(c1c2ccccc2cc2c1ccc1ccccc12)c1cc2ccc3ccccc3c2c2ccccc12]

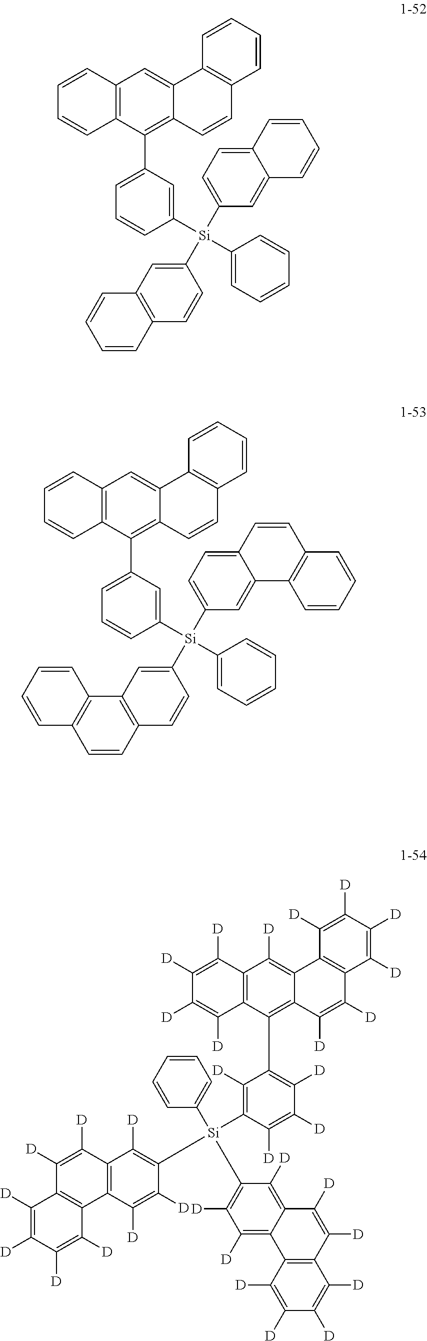 [SMILES: c1ccc([Si](c2cccc(-c3c4ccccc4cc4c3ccc3ccccc34)c2)(c2ccc3ccccc3c2)c2ccc3ccccc3c2)cc1 ; c1ccc([Si](c2cccc(-c3c4ccccc4cc4c3ccc3ccccc34)c2)(c2ccc3ccc4ccccc4c3c2)c2ccc3ccc4ccccc4c3c2)cc1 ; [2H]c1c([2H])c(-c2c3c([2H])c([2H])c([2H])c([2H])c3c([2H])c3c2c([2H])c([2H])c2c([2H])c([2H])c([2H])c([2H])c23)c([2H])c([Si](c2ccccc2)(c2c([2H])c([2H])c3c(c2[2H])c([2H])c([2H])c2c([2H])c([2H])c([2H])c([2H])c23)c2c([2H])c([2H])c3c(c2[2H])c([2H])c([2H])c2c([2H])c([2H])c([2H])c([2H])c23)c1[2H]]

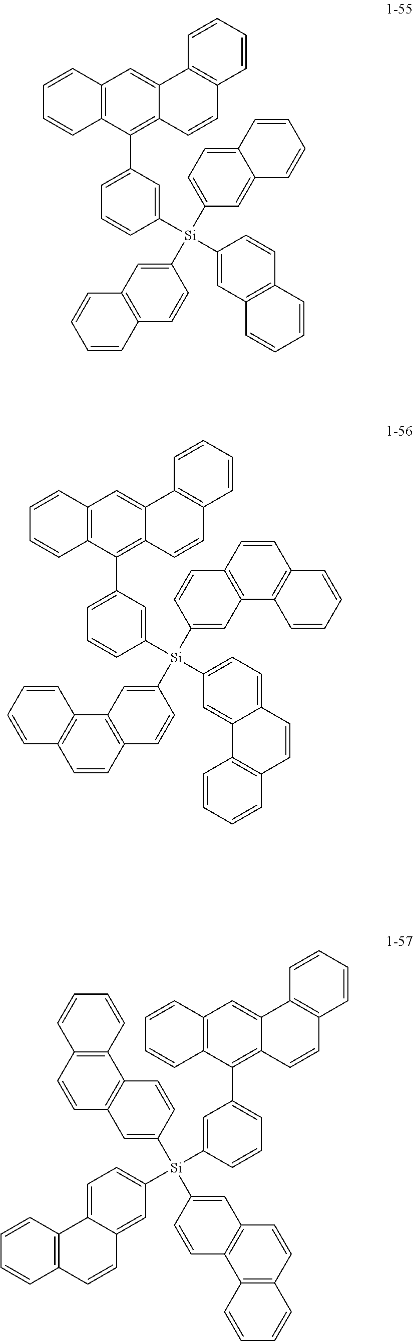 [SMILES: c1cc(-c2c3ccccc3cc3c2ccc2ccccc23)cc([Si](c2ccc3ccccc3c2)(c2ccc3ccccc3c2)c2ccc3ccccc3c2)c1 ; c1cc(-c2c3ccccc3cc3c2ccc2ccccc23)cc([Si](c2ccc3ccc4ccccc4c3c2)(c2ccc3ccc4ccccc4c3c2)c2ccc3ccc4ccccc4c3c2)c1 ; c1cc(-c2c3ccccc3cc3c2ccc2ccccc23)cc([Si](c2ccc3c(ccc4ccccc43)c2)(c2ccc3c(ccc4ccccc43)c2)c2ccc3c(ccc4ccccc43)c2)c1]

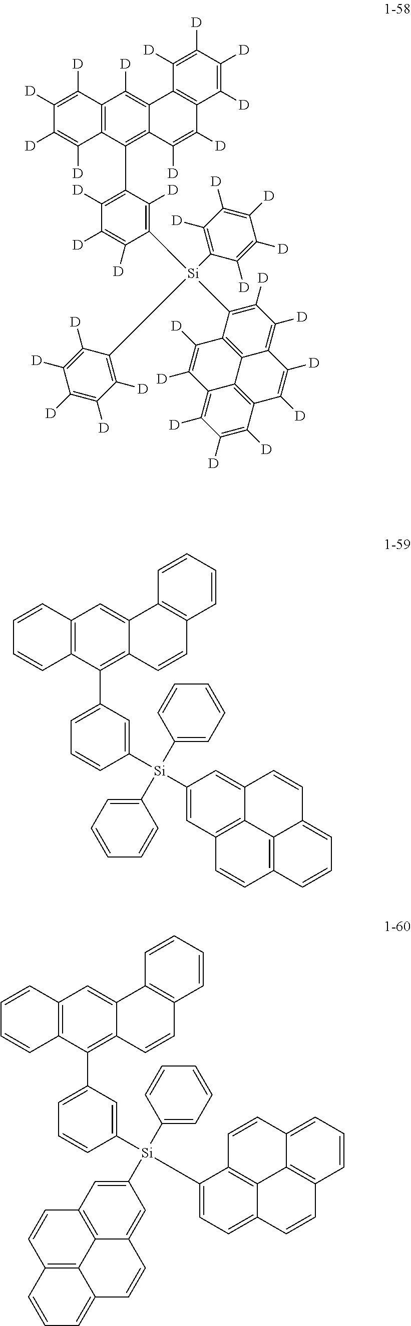 [SMILES: [2H]c1c([2H])c([2H])c([Si](c2c([2H])c([2H])c([2H])c([2H])c2[2H])(c2c([2H])c([2H])c([2H])c(-c3c4c([2H])c([2H])c([2H])c([2H])c4c([2H])c4c3c([2H])c([2H])c3c([2H])c([2H])c([2H])c([2H])c34)c2[2H])c2c([2H])c([2H])c3c([2H])c([2H])c4c([2H])c([2H])c([2H])c5c([2H])c([2H])c2c3c45)c([2H])c1[2H] ; c1ccc([Si](c2ccccc2)(c2cccc(-c3c4ccccc4cc4c3ccc3ccccc34)c2)c2cc3ccc4cccc5ccc(c2)c3c45)cc1 ; c1ccc([Si](c2cccc(-c3c4ccccc4cc4c3ccc3ccccc34)c2)(c2cc3ccc4cccc5ccc(c2)c3c45)c2ccc3ccc4cccc5ccc2c3c45)cc1]

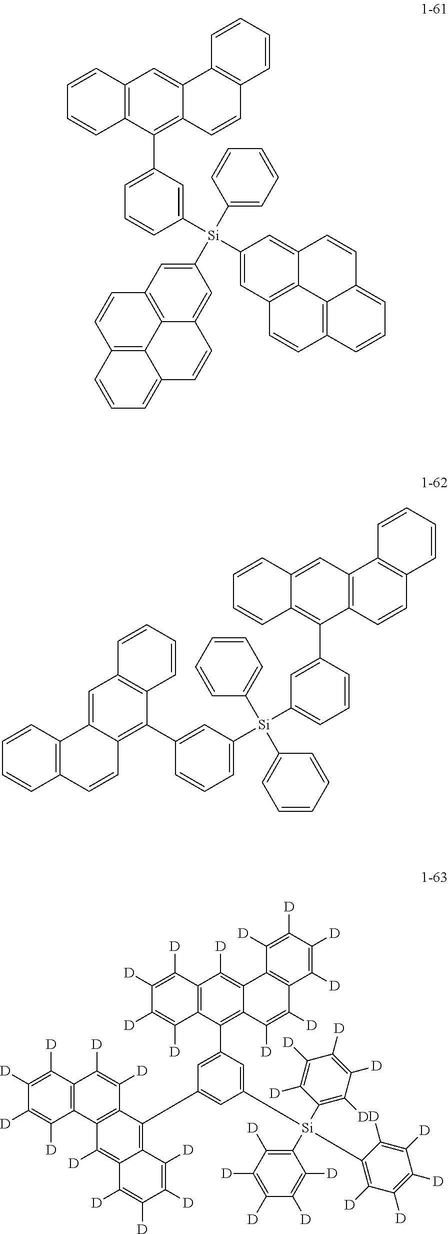

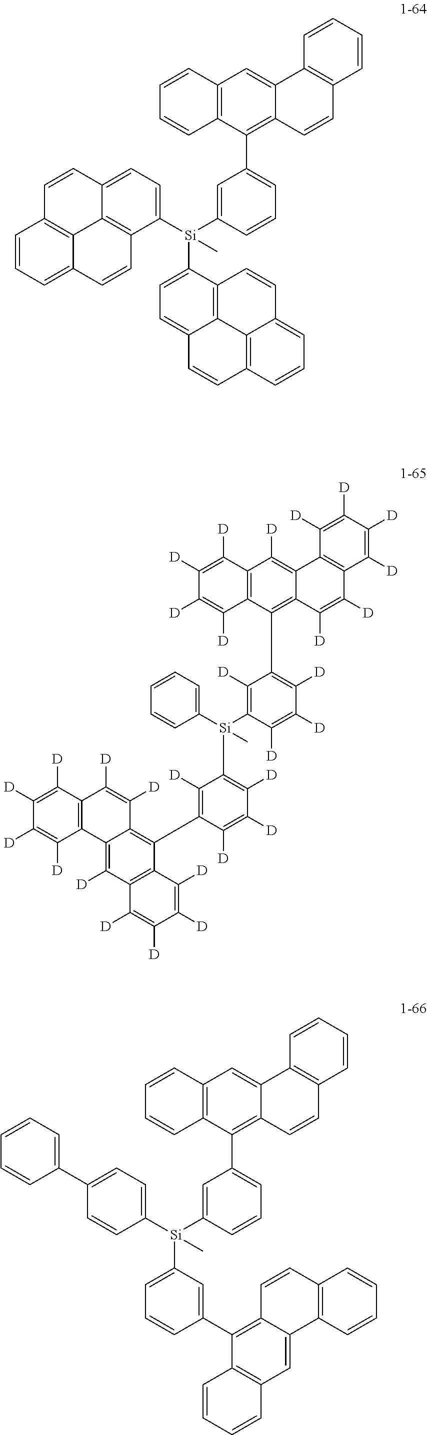 [SMILES: C[Si](c1cccc(-c2c3ccccc3cc3c2ccc2ccccc23)c1)(c1ccc2ccc3cccc4ccc1c2c34)c1ccc2ccc3cccc4ccc1c2c34 ; [2H]c1c([2H])c(-c2c3c([2H])c([2H])c([2H])c([2H])c3c([2H])c3c2c([2H])c([2H])c2c([2H])c([2H])c([2H])c([2H])c23)c([2H])c([Si](C)(c2ccccc2)c2c([2H])c([2H])c([2H])c(-c3c4c([2H])c([2H])c([2H])c([2H])c4c([2H])c4c3c([2H])c([2H])c3c([2H])c([2H])c([2H])c([2H])c34)c2[2H])c1[2H] ; C[Si](c1ccc(-c2ccccc2)cc1)(c1cccc(-c2c3ccccc3cc3c2ccc2ccccc23)c1)c1cccc(-c2c3ccccc3cc3c2ccc2ccccc23)c1]

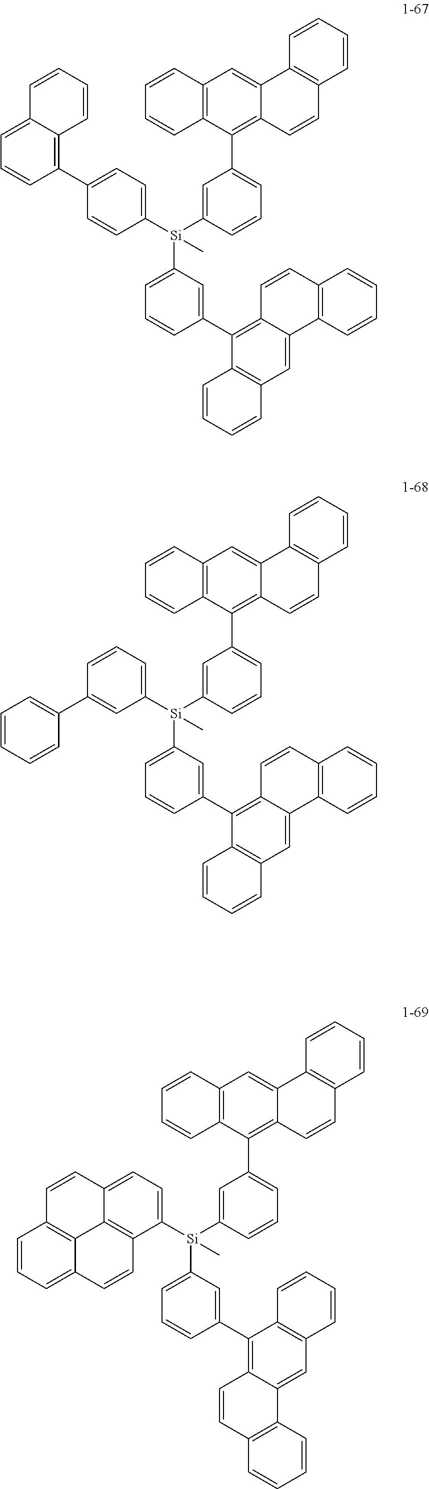 [SMILES: C[Si](c1ccc(-c2cccc3ccccc23)cc1)(c1cccc(-c2c3ccccc3cc3c2ccc2ccccc23)c1)c1cccc(-c2c3ccccc3cc3c2ccc2ccccc23)c1 ; C[Si](c1cccc(-c2ccccc2)c1)(c1cccc(-c2c3ccccc3cc3c2ccc2ccccc23)c1)c1cccc(-c2c3ccccc3cc3c2ccc2ccccc23)c1 ; C[Si](c1cccc(-c2c3ccccc3cc3c2ccc2ccccc23)c1)(c1cccc(-c2c3ccccc3cc3c2ccc2ccccc23)c1)c1ccc2ccc3cccc4ccc1c2c34]

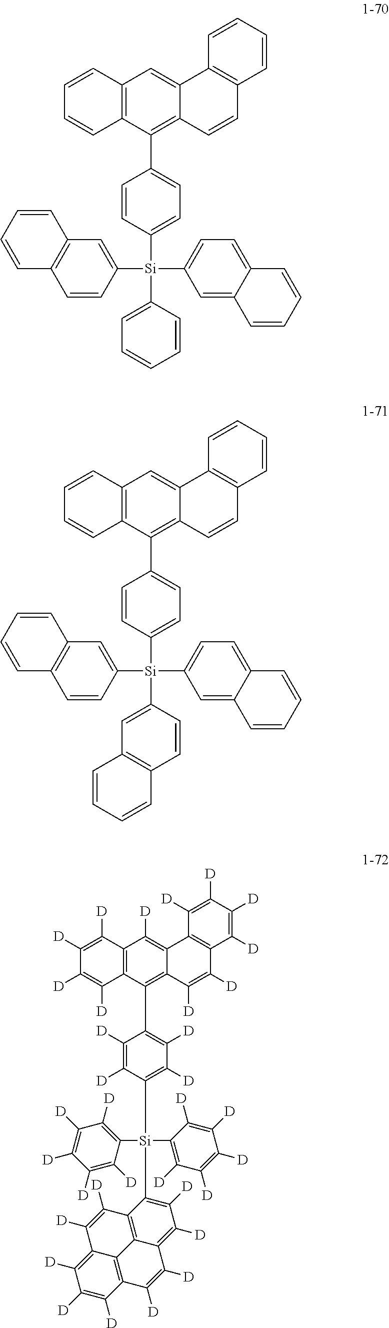 [SMILES: c1ccc([Si](c2ccc(-c3c4ccccc4cc4c3ccc3ccccc34)cc2)(c2ccc3ccccc3c2)c2ccc3ccccc3c2)cc1 ; c1ccc2cc([Si](c3ccc(-c4c5ccccc5cc5c4ccc4ccccc45)cc3)(c3ccc4ccccc4c3)c3ccc4ccccc4c3)ccc2c1 ; [2H]c1c([2H])c([2H])c([Si](c2c([2H])c([2H])c([2H])c([2H])c2[2H])(c2c([2H])c([2H])c(-c3c4c([2H])c([2H])c([2H])c([2H])c4c([2H])c4c3c([2H])c([2H])c3c([2H])c([2H])c([2H])c([2H])c34)c([2H])c2[2H])c2c([2H])c([2H])c3c([2H])c([2H])c4c([2H])c([2H])c([2H])c5c([2H])c([2H])c2c3c45)c([2H])c1[2H]]

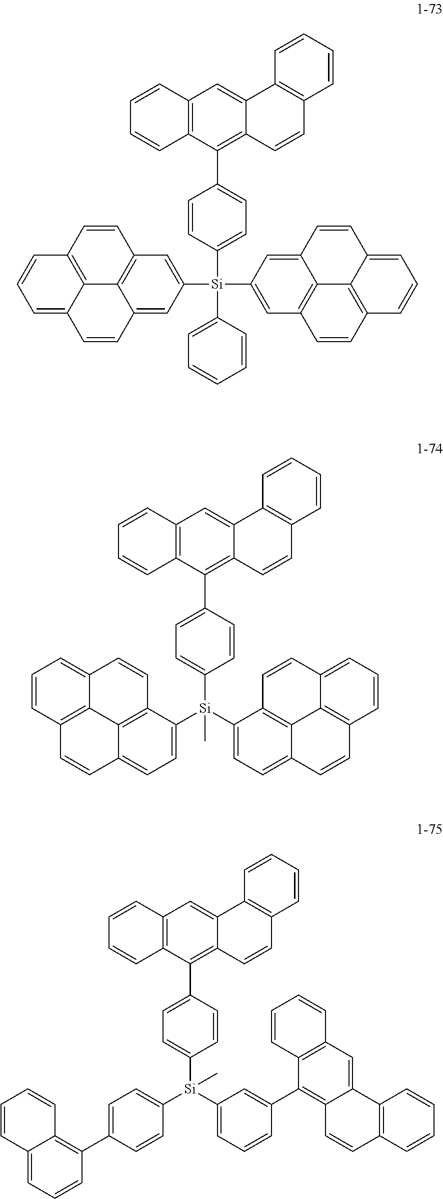 [SMILES: c1ccc([Si](c2ccc(-c3c4ccccc4cc4c3ccc3ccccc34)cc2)(c2cc3ccc4cccc5ccc(c2)c3c45)c2cc3ccc4cccc5ccc(c2)c3c45)cc1 ; C[Si](c1ccc(-c2c3ccccc3cc3c2ccc2ccccc23)cc1)(c1ccc2ccc3cccc4ccc1c2c34)c1ccc2ccc3cccc4ccc1c2c34 ; C[Si](c1ccc(-c2cccc3ccccc23)cc1)(c1ccc(-c2c3ccccc3cc3c2ccc2ccccc23)cc1)c1cccc(-c2c3ccccc3cc3c2ccc2ccccc23)c1]

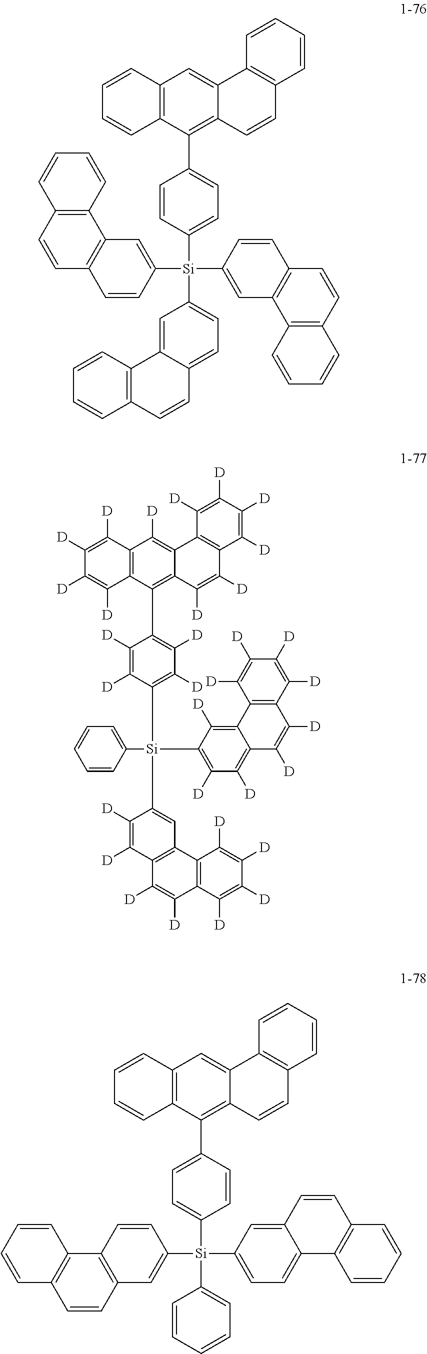 [SMILES: c1ccc2c(-c3ccc([Si](c4ccc5ccc6ccccc6c5c4)(c4ccc5ccc6ccccc6c5c4)c4ccc5ccc6ccccc6c5c4)cc3)c3ccc4ccccc4c3cc2c1 ; [2H]c1c([2H])c([Si](c2ccccc2)(c2cc3c(c([2H])c2[2H])c([2H])c([2H])c2c([2H])c([2H])c([2H])c([2H])c23)c2c([2H])c([2H])c3c([2H])c([2H])c4c([2H])c([2H])c([2H])c([2H])c4c3c2[2H])c([2H])c([2H])c1-c1c2c([2H])c([2H])c([2H])c([2H])c2c([2H])c2c1c([2H])c([2H])c1c([2H])c([2H])c([2H])c([2H])c12 ; c1ccc([Si](c2ccc(-c3c4ccccc4cc4c3ccc3ccccc34)cc2)(c2ccc3c(ccc4ccccc43)c2)c2ccc3c(ccc4ccccc43)c2)cc1]

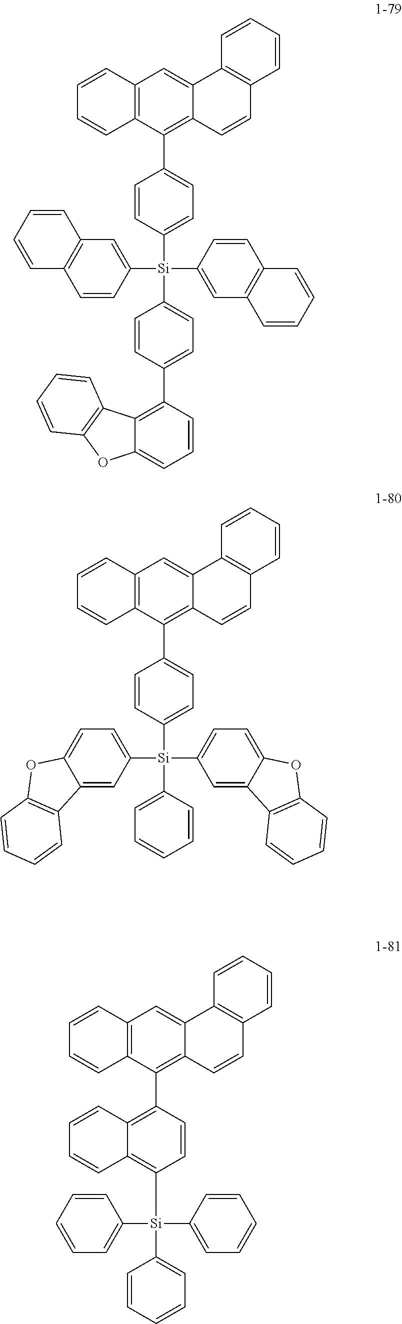 [SMILES: c1ccc2cc([Si](c3ccc(-c4c5ccccc5cc5c4ccc4ccccc45)cc3)(c3ccc(-c4cccc5oc6ccccc6c45)cc3)c3ccc4ccccc4c3)ccc2c1 ; c1ccc([Si](c2ccc(-c3c4ccccc4cc4c3ccc3ccccc34)cc2)(c2ccc3oc4ccccc4c3c2)c2ccc3oc4ccccc4c3c2)cc1 ; c1ccc([Si](c2ccccc2)(c2ccccc2)c2ccc(-c3c4ccccc4cc4c3ccc3ccccc34)c3ccccc23)cc1]

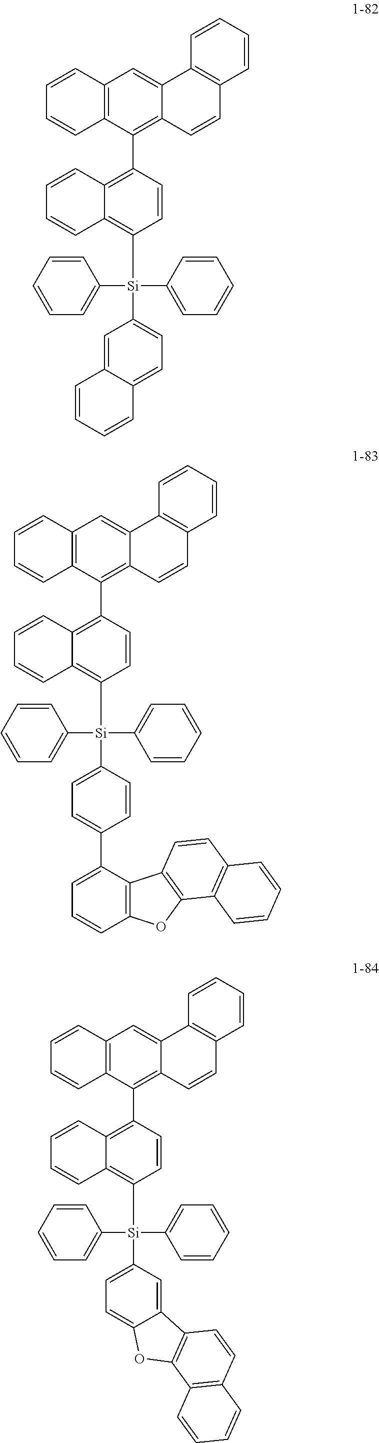 [SMILES: c1ccc([Si](c2ccccc2)(c2ccc3ccccc3c2)c2ccc(-c3c4ccccc4cc4c3ccc3ccccc34)c3ccccc23)cc1 ; c1ccc([Si](c2ccccc2)(c2ccc(-c3cccc4oc5c6ccccc6ccc5c34)cc2)c2ccc(-c3c4ccccc4cc4c3ccc3ccccc34)c3ccccc23)cc1 ; c1ccc([Si](c2ccccc2)(c2ccc3oc4c5ccccc5ccc4c3c2)c2ccc(-c3c4ccccc4cc4c3ccc3ccccc34)c3ccccc23)cc1]

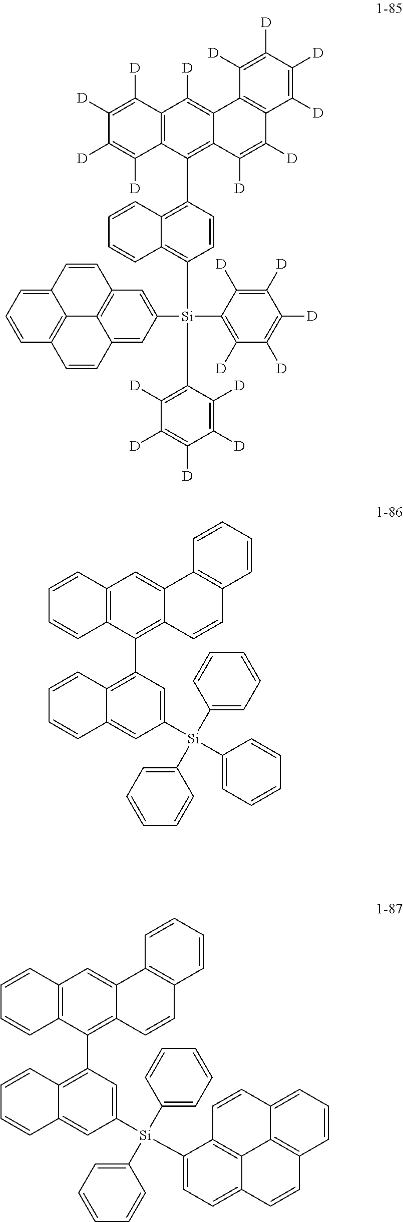 [SMILES: [2H]c1c([2H])c([2H])c([Si](c2cc3ccc4cccc5ccc(c2)c3c45)(c2c([2H])c([2H])c([2H])c([2H])c2[2H])c2ccc(-c3c4c([2H])c([2H])c([2H])c([2H])c4c([2H])c4c3c([2H])c([2H])c3c([2H])c([2H])c([2H])c([2H])c34)c3ccccc23)c([2H])c1[2H] ; c1ccc([Si](c2ccccc2)(c2ccccc2)c2cc(-c3c4ccccc4cc4c3ccc3ccccc34)c3ccccc3c2)cc1 ; c1ccc([Si](c2ccccc2)(c2cc(-c3c4ccccc4cc4c3ccc3ccccc34)c3ccccc3c2)c2ccc3ccc4cccc5ccc2c3c45)cc1]

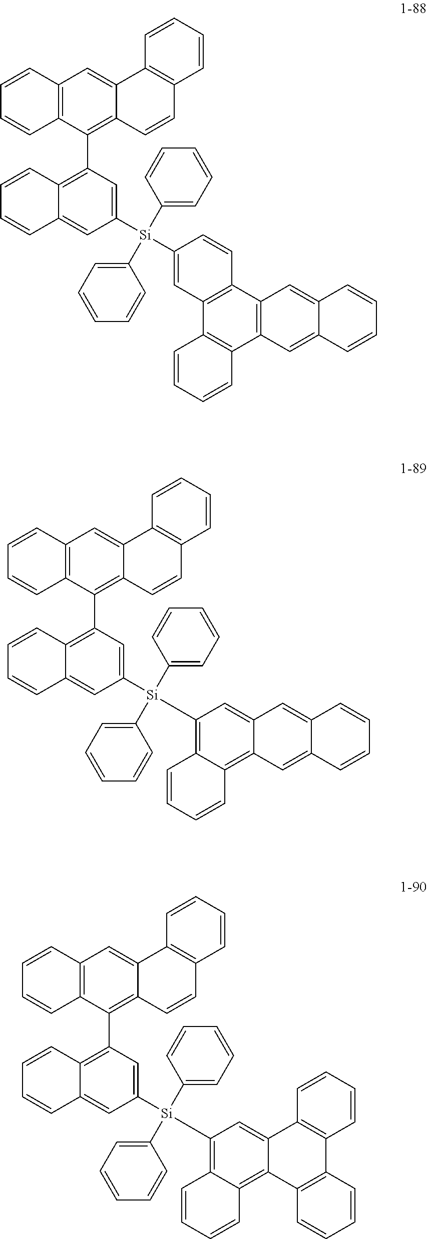 [SMILES: c1ccc([Si](c2ccccc2)(c2cc(-c3c4ccccc4cc4c3ccc3ccccc34)c3ccccc3c2)c2ccc3c(c2)c2ccccc2c2cc4ccccc4cc32)cc1 ; c1ccc([Si](c2ccccc2)(c2cc(-c3c4ccccc4cc4c3ccc3ccccc34)c3ccccc3c2)c2cc3cc4ccccc4cc3c3ccccc23)cc1 ; c1ccc([Si](c2ccccc2)(c2cc(-c3c4ccccc4cc4c3ccc3ccccc34)c3ccccc3c2)c2cc3c4ccccc4c4ccccc4c3c3ccccc23)cc1]

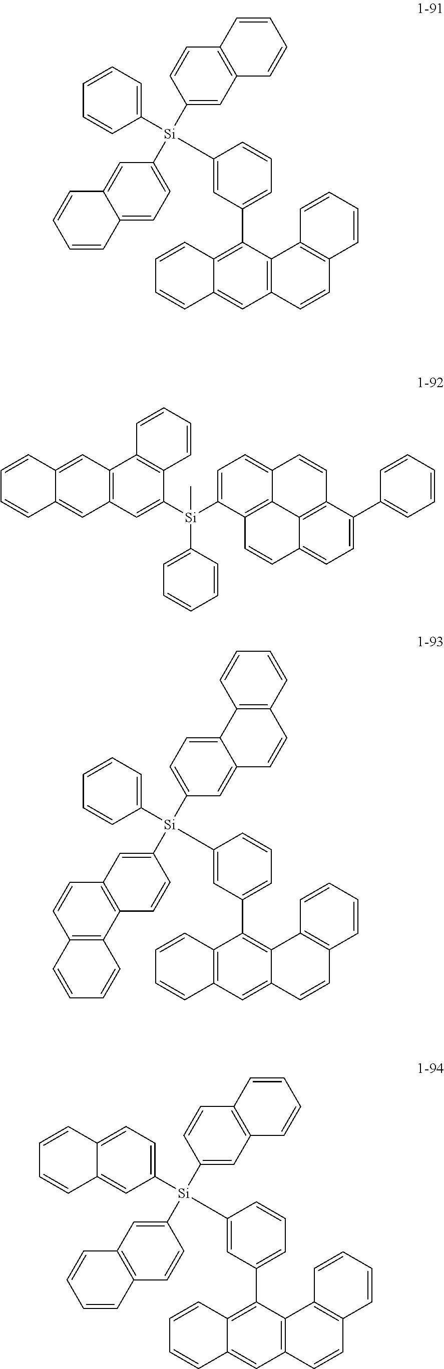 [SMILES: c1ccc([Si](c2cccc(-c3c4ccccc4cc4ccc5ccccc5c34)c2)(c2ccc3ccccc3c2)c2ccc3ccccc3c2)cc1 ; C[Si](c1ccccc1)(c1cc2cc3ccccc3cc2c2ccccc12)c1ccc2ccc3c(-c4ccccc4)ccc4ccc1c2c43 ; c1ccc([Si](c2cccc(-c3c4ccccc4cc4ccc5ccccc5c34)c2)(c2ccc3c(ccc4ccccc43)c2)c2ccc3c(ccc4ccccc43)c2)cc1 ; c1cc(-c2c3ccccc3cc3ccc4ccccc4c23)cc([Si](c2ccc3ccccc3c2)(c2ccc3ccccc3c2)c2ccc3ccccc3c2)c1]

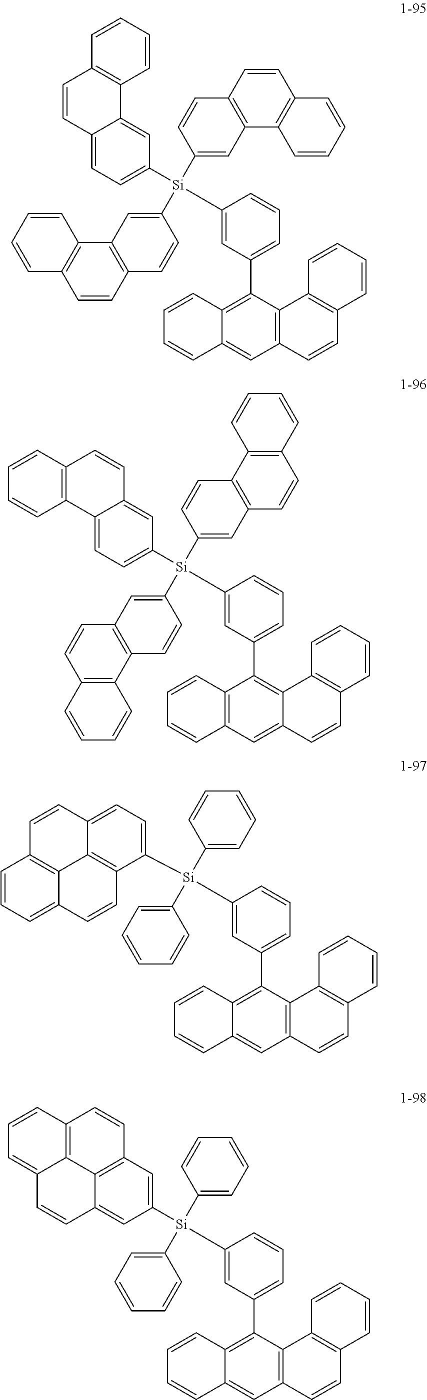

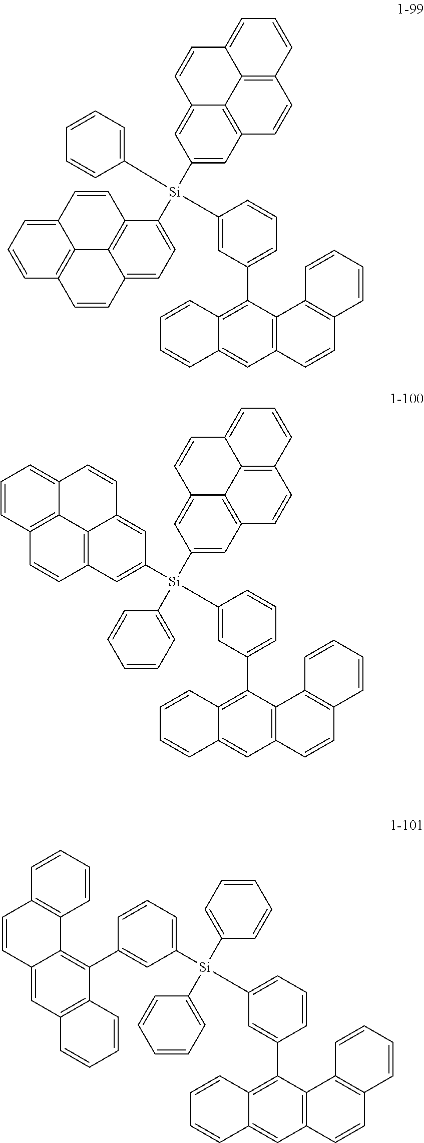

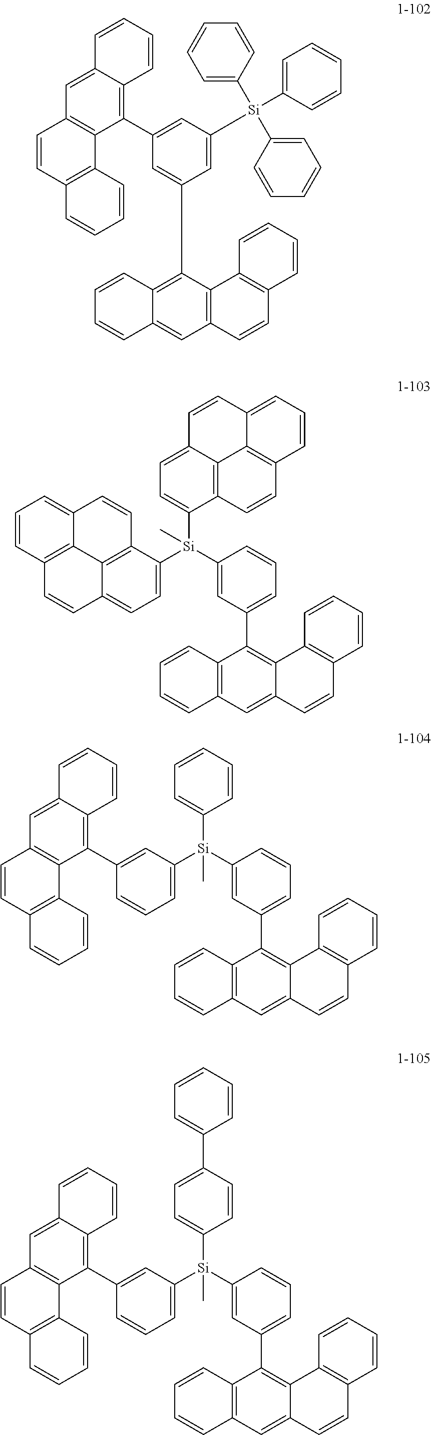

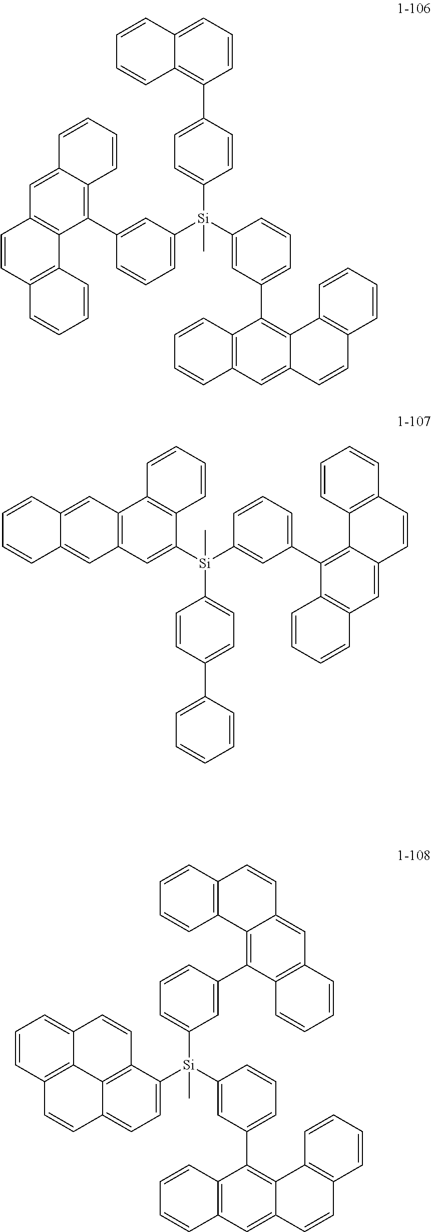 [SMILES: C[Si](c1ccc(-c2cccc3ccccc23)cc1)(c1cccc(-c2c3ccccc3cc3ccc4ccccc4c23)c1)c1cccc(-c2c3ccccc3cc3ccc4ccccc4c23)c1 ; C[Si](c1ccc(-c2ccccc2)cc1)(c1cccc(-c2c3ccccc3cc3ccc4ccccc4c23)c1)c1cc2cc3ccccc3cc2c2ccccc12 ; C[Si](c1cccc(-c2c3ccccc3cc3ccc4ccccc4c23)c1)(c1cccc(-c2c3ccccc3cc3ccc4ccccc4c23)c1)c1ccc2ccc3cccc4ccc1c2c34]

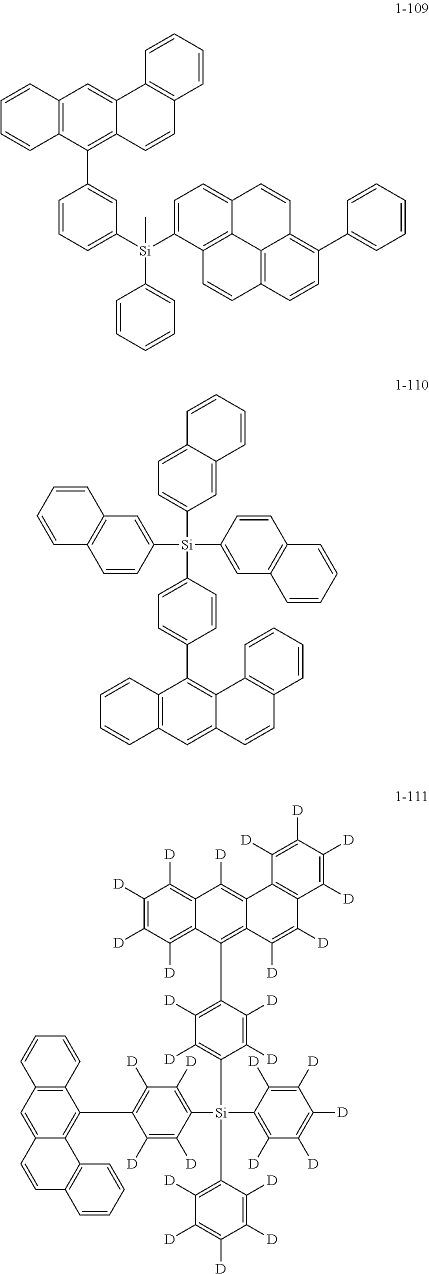 [SMILES: C[Si](c1ccccc1)(c1cccc(-c2c3ccccc3cc3c2ccc2ccccc23)c1)c1ccc2ccc3c(-c4ccccc4)ccc4ccc1c2c43 ; c1ccc2cc([Si](c3ccc(-c4c5ccccc5cc5ccc6ccccc6c45)cc3)(c3ccc4ccccc4c3)c3ccc4ccccc4c3)ccc2c1 ; [2H]c1c([2H])c([2H])c([Si](c2c([2H])c([2H])c([2H])c([2H])c2[2H])(c2c([2H])c([2H])c(-c3c4c([2H])c([2H])c([2H])c([2H])c4c([2H])c4c3c([2H])c([2H])c3c([2H])c([2H])c([2H])c([2H])c34)c([2H])c2[2H])c2c([2H])c([2H])c(-c3c4ccccc4cc4ccc5ccccc5c34)c([2H])c2[2H])c([2H])c1[2H]]

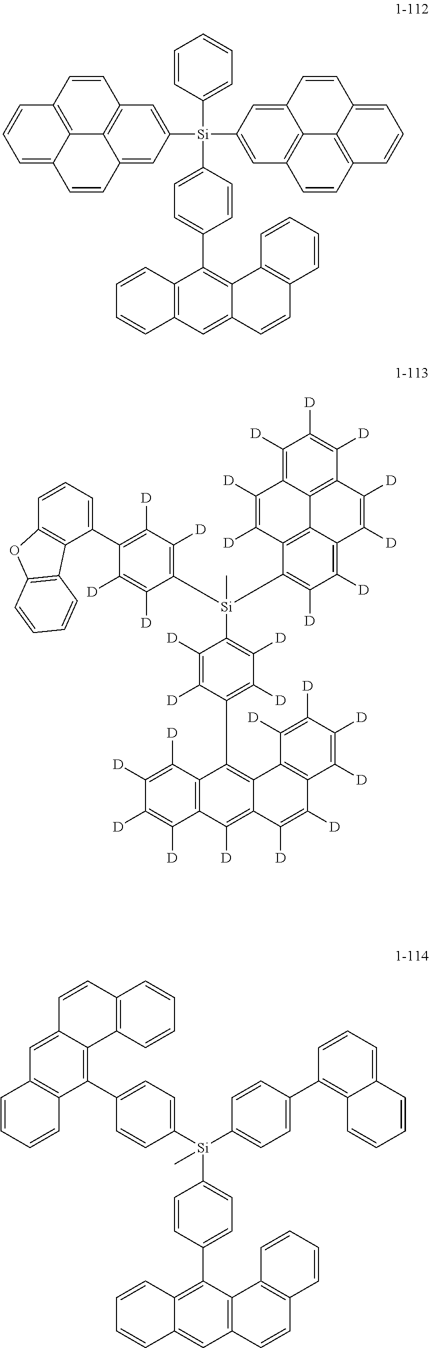 [SMILES: c1ccc([Si](c2ccc(-c3c4ccccc4cc4ccc5ccccc5c34)cc2)(c2cc3ccc4cccc5ccc(c2)c3c45)c2cc3ccc4cccc5ccc(c2)c3c45)cc1 ; [2H]c1c([2H])c([Si](C)(c2c([2H])c([2H])c(-c3c4c([2H])c([2H])c([2H])c([2H])c4c([2H])c4c([2H])c([2H])c5c([2H])c([2H])c([2H])c([2H])c5c34)c([2H])c2[2H])c2c([2H])c([2H])c3c([2H])c([2H])c4c([2H])c([2H])c([2H])c5c([2H])c([2H])c2c3c45)c([2H])c([2H])c1-c1cccc2oc3ccccc3c12 ; C[Si](c1ccc(-c2cccc3ccccc23)cc1)(c1ccc(-c2c3ccccc3cc3ccc4ccccc4c23)cc1)c1ccc(-c2c3ccccc3cc3ccc4ccccc4c23)cc1]

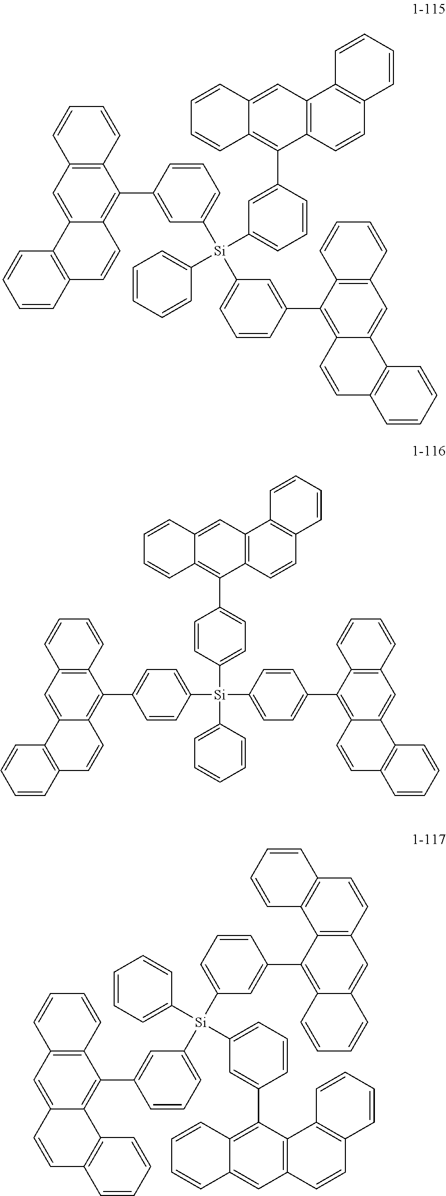 [SMILES: c1ccc([Si](c2cccc(-c3c4ccccc4cc4c3ccc3ccccc34)c2)(c2cccc(-c3c4ccccc4cc4c3ccc3ccccc34)c2)c2cccc(-c3c4ccccc4cc4c3ccc3ccccc34)c2)cc1 ; c1ccc([Si](c2ccc(-c3c4ccccc4cc4c3ccc3ccccc34)cc2)(c2ccc(-c3c4ccccc4cc4c3ccc3ccccc34)cc2)c2ccc(-c3c4ccccc4cc4c3ccc3ccccc34)cc2)cc1 ; c1ccc([Si](c2cccc(-c3c4ccccc4cc4ccc5ccccc5c34)c2)(c2cccc(-c3c4ccccc4cc4ccc5ccccc5c34)c2)c2cccc(-c3c4ccccc4cc4ccc5ccccc5c34)c2)cc1]

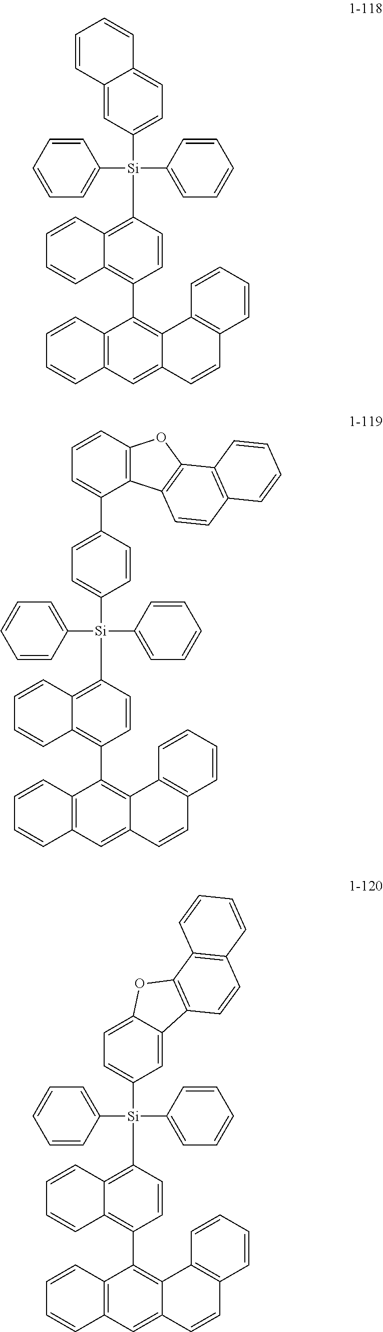 [SMILES: c1ccc([Si](c2ccccc2)(c2ccc3ccccc3c2)c2ccc(-c3c4ccccc4cc4ccc5ccccc5c34)c3ccccc23)cc1 ; c1ccc([Si](c2ccccc2)(c2ccc(-c3cccc4oc5c6ccccc6ccc5c34)cc2)c2ccc(-c3c4ccccc4cc4ccc5ccccc5c34)c3ccccc23)cc1 ; c1ccc([Si](c2ccccc2)(c2ccc3oc4c5ccccc5ccc4c3c2)c2ccc(-c3c4ccccc4cc4ccc5ccccc5c34)c3ccccc23)cc1]

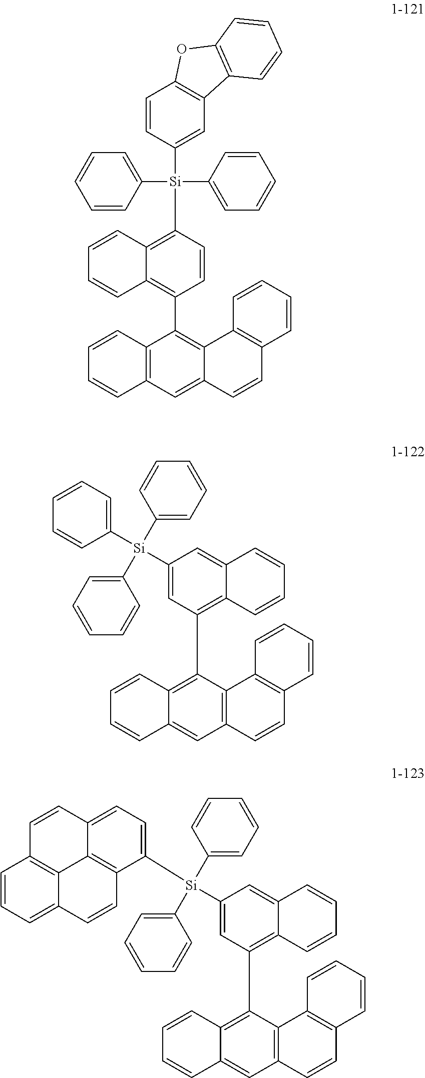 [SMILES: c1ccc([Si](c2ccccc2)(c2ccc3oc4ccccc4c3c2)c2ccc(-c3c4ccccc4cc4ccc5ccccc5c34)c3ccccc23)cc1 ; c1ccc([Si](c2ccccc2)(c2ccccc2)c2cc(-c3c4ccccc4cc4ccc5ccccc5c34)c3ccccc3c2)cc1 ; c1ccc([Si](c2ccccc2)(c2cc(-c3c4ccccc4cc4ccc5ccccc5c34)c3ccccc3c2)c2ccc3ccc4cccc5ccc2c3c45)cc1]

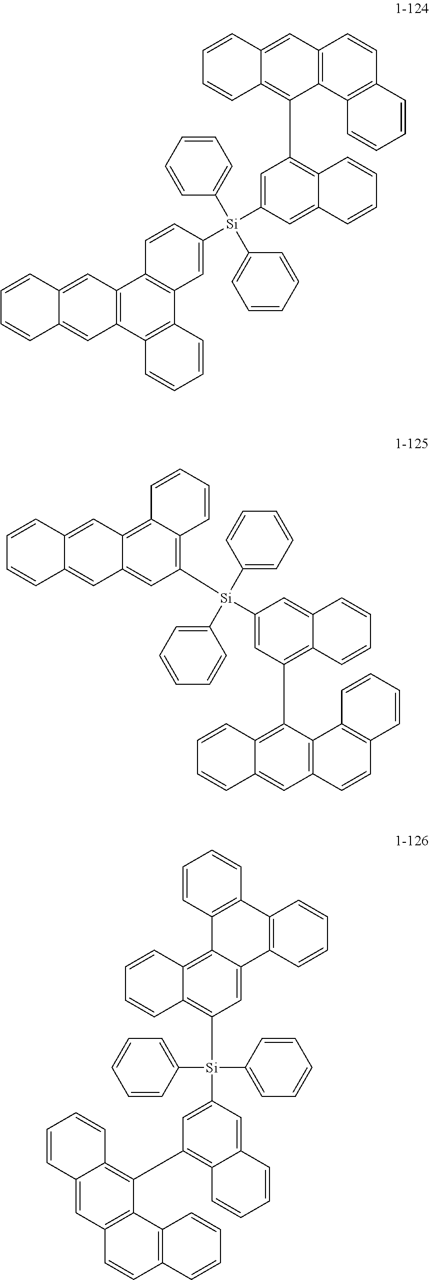 [SMILES: c1ccc([Si](c2ccccc2)(c2cc(-c3c4ccccc4cc4ccc5ccccc5c34)c3ccccc3c2)c2ccc3c(c2)c2ccccc2c2cc4ccccc4cc32)cc1 ; c1ccc([Si](c2ccccc2)(c2cc(-c3c4ccccc4cc4ccc5ccccc5c34)c3ccccc3c2)c2cc3cc4ccccc4cc3c3ccccc23)cc1 ; c1ccc([Si](c2ccccc2)(c2cc(-c3c4ccccc4cc4ccc5ccccc5c34)c3ccccc3c2)c2cc3c4ccccc4c4ccccc4c3c3ccccc23)cc1]

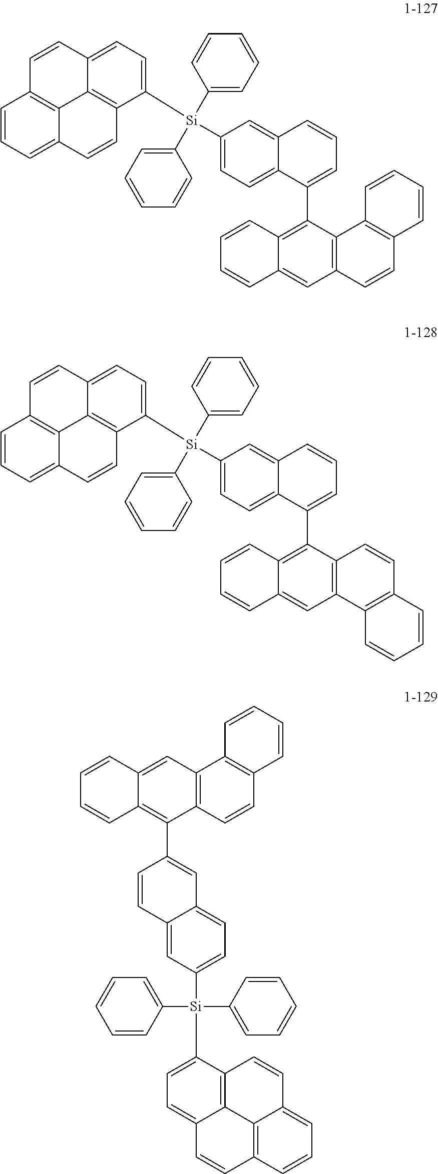 [SMILES: c1ccc([Si](c2ccccc2)(c2ccc3c(-c4c5ccccc5cc5ccc6ccccc6c45)cccc3c2)c2ccc3ccc4cccc5ccc2c3c45)cc1 ; c1ccc([Si](c2ccccc2)(c2ccc3c(-c4c5ccccc5cc5c4ccc4ccccc45)cccc3c2)c2ccc3ccc4cccc5ccc2c3c45)cc1 ; c1ccc([Si](c2ccccc2)(c2ccc3cc(-c4c5ccccc5cc5c4ccc4ccccc45)ccc3c2)c2ccc3ccc4cccc5ccc2c3c45)cc1]

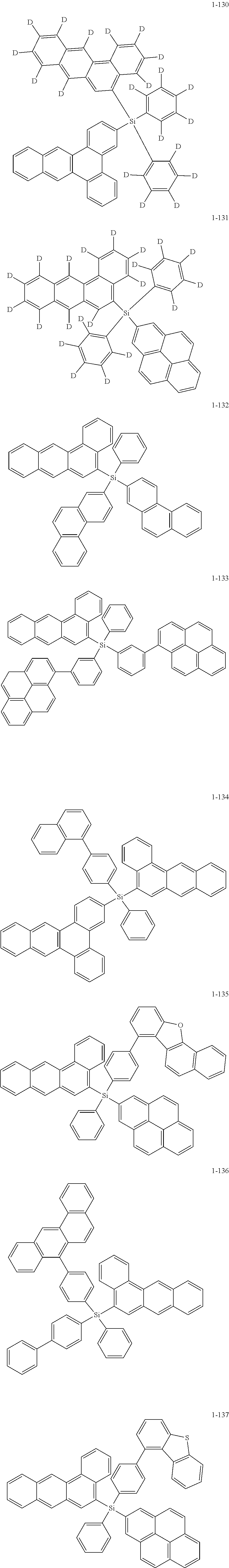

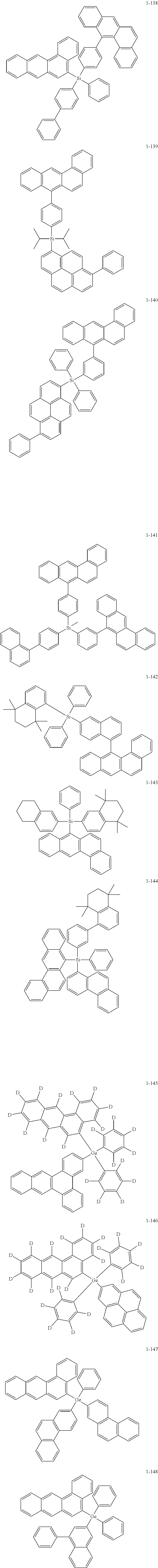

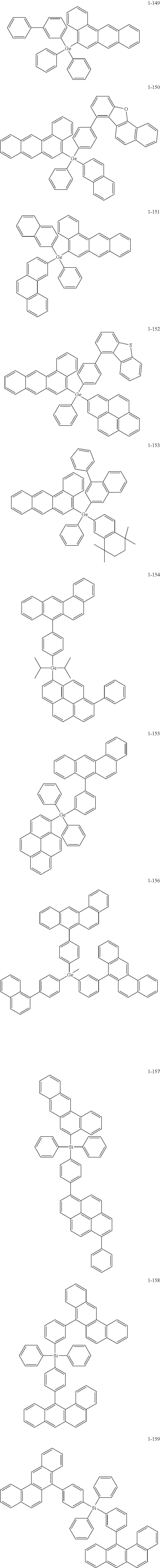

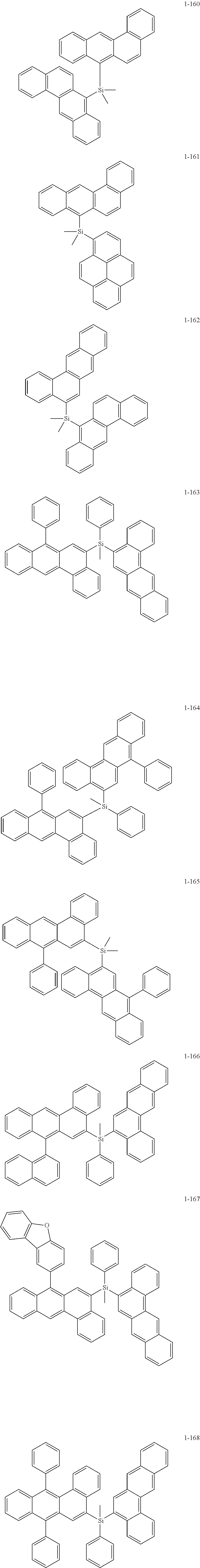

In addition, another aspect of the present invention relates to an organic light-emitting device including: a first electrode; a second electrode; and one or more organic layers interposed between the first electrode and the second electrode, wherein the organic layer, preferably a light-emitting layer including a host and a dopant, includes the compound represented by [Chemical Formula 1] including the following [Structural Formula 1] defined above as a host material of the light-emitting layer.

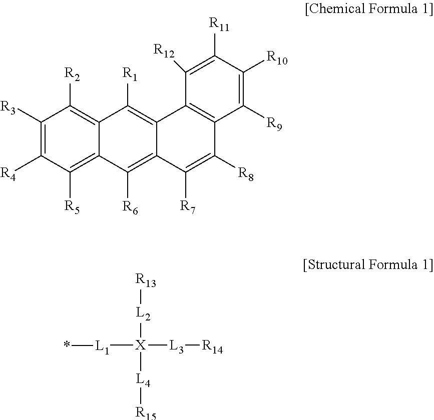

In addition, in the present invention, each light-emitting layer has a structure composed of a host and a dopant, and herein, the content of the dopant may be typically selected in a range of about 0.01 parts by weight to about 20 parts by weight based on about 100 parts by weight of the host, however, the dopant content is not limited thereto.

In addition, the light-emitting layer may further include various host and dopant materials in addition to the compound according to the present invention, and accordingly, in the light-emitting layer, one or more compounds different from each other may be mixed or co-deposited and used as the dopant material as well as the host material.

Accordingly, the organic light-emitting device according to one embodiment of the present invention may include: a first electrode; a second electrode provided opposite to the first electrode; and a first light-emitting layer including a first host and a first dopant, and a second light-emitting layer including a second host and a second dopant, the first light-emitting layer and the second light-emitting layer being interposed between the first electrode and the second electrode.

Herein, at least one of the first host and the second host may include one or more of the compounds represented by [Chemical Formula 1].

In the organic light-emitting device according to a specific embodiment of the present invention, one of the first host and the second host may include the compound represented by [Chemical Formula 1], and the other of the first host and the second host may include an anthracene compound represented by the following [Chemical Formula 2].

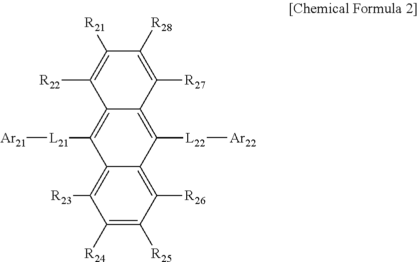

In [Chemical Formula 2],
R₂₁ to R₂₈ are the same as or different from each other, and each independently selected from hydrogen, deuterium, tritium, a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted or unsubstituted C₂-C₃₀ alkenyl group, a substituted or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group.

L₂₁ and L₂₂ are the same as or different from each other, and each independently a single bond, or selected from a substituted or unsubstituted C₆-C₃₀ arylene group, a substituted or unsubstituted C₂-C₃₀ heteroarylene group, and a substituted or unsubstituted arylene group fused with a C₈-C₃₀ aliphatic hydrocarbon ring.

Ar₂₁ and Ar₂₂ are the same as or different from each other, and each independently selected from a substituted or unsubstituted C₆-C₅₀ aryl group, a substituted or unsubstituted C₂-C₅₀ heteroaryl group, a substituted or unsubstituted C₃-C₅₀ cycloalkyl group, a substituted or unsubstituted C₂-C₅₀ heterocycloalkyl group, and a substituted or unsubstituted cyclic group in which a C₃-C₃₀ aliphatic ring and a C₅-C₃₀ aromatic ring are fused.

In addition, hydrogen atoms bonded to carbon atoms in [Chemical Formula 2] may be substituted with deuterium or tritium in a number ranging from 0 to 60.

The ‘substituted’ in the ‘substituted or unsubstituted’ in [Chemical Formula 2] means being substituted with one or more substituents selected from the group consisting of deuterium, tritium, a C₁-C₂₄ alkyl group, a C₁-C₂₄ halogenated alkyl group, a C₂-C₂₄ alkenyl group, a C₂-C₂₄ alkynyl group, a C₃-C₃₀ cycloalkyl group, a C₁-C₂₄ heteroalkyl group, a C₆-C₃₀ aryl group, a C₇-C₃₀ arylalkyl group, a C₇-C₃₀ alkylaryl group, a C₂-C₃₀ heteroaryl group, a C₂-C₃₀ heteroarylalkyl group, a cyclic group in which a C₃-C₂₄ aliphatic ring and a C₅-C₂₄ aromatic ring are fused, a C₁-C₃₀ amine group, a C₁-C₃₀ silyl group, a C₁-C₃₀ germanium group, a C₁-C₃₀ oxy group, a C₁-C₃₀ thioxy group, a C₁-C₃₀ thionyl group, a cyano group, a halogen group, a thiol group, a hydroxyl group and a nitro group, and when there are two or more substituents, they are the same as or different from each other, and at least one hydrogen atom in the compound formed from [Chemical Formula 2] may be substituted with deuterium or tritium.

According to one embodiment of the present invention, Ar₂₁ in the anthracene compound represented by [Chemical Formula 2] may be represented by the following [Structural Formula 2].

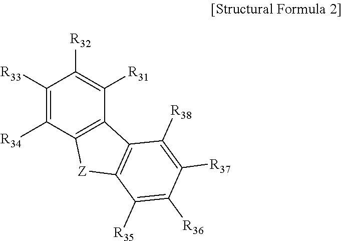

In [Structural Formula 2],
Z is O or S.

One of R₃₁ to R₃₈ is linked to L₂₁ in [Chemical Formula 2] via a single bond.

The remainders of R₃₁ to R₃₈ excluding the one linked to L₂₁ via a single bond are the same as or different from each other, and each independently selected from hydrogen, deuterium, tritium, a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted or unsubstituted C₂-C₃₀ group, alkenyl a substituted or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group.

In addition, the adjacent R₃₁ to R₃₈ may each be linked to each other to further form an alicyclic or aromatic monocyclic or polycyclic ring.

In addition, the ‘substituted’ in the ‘substituted or unsubstituted’ in [Structural Formula 2] means being substituted with one or more substituents selected from the group consisting of deuterium, tritium, a C₁-C₂₄ alkyl group, a C₁-C₂₄ halogenated alkyl group, a C₂-C₂₄ alkenyl group, a C₂-C₂₄ alkynyl group, a C₃-C₃₀ cycloalkyl group, a C₁-C₂₄ heteroalkyl group, a C₆-C₃₀ aryl group, a C₇-C₃₀ arylalkyl group, a C₇-C₃₀ alkylaryl group, a C₂-C₃₀ heteroaryl group, a C₂-C₃₀ heteroarylalkyl group, a cyclic group in which a C₃-C₂₄ aliphatic ring and a C₅-C₂₄ aromatic ring are fused, a C₁-C₃₀ amine group, a C₁-C₃₀ silyl group, a C₁-C₃₀ germanium group, a C₁-C₃₀ Oxy group, a C₁-C₃₀ thioxy group, a C₁-C₃₀ thionyl group, a cyano group, a halogen group, a thiol group, a hydroxyl group and a nitro group, and when there are two or more substituents, they are the same as or different from each other, and at least one hydrogen atom in the compound formed from [Structural Formula 2] may be substituted with deuterium or tritium.

According to one embodiment of the present invention, the anthracene compound represented by [Chemical Formula 2] may include at least one deuterium atom.

In addition, according to another embodiment of the present invention, the organic light-emitting device according to the present invention is characterized in that one of the first host and the second host includes two or more different anthracene compounds represented by [Chemical Formula 2].

For example, in the organic light-emitting device according to the present invention, the first host may include the compound represented by [Chemical Formula 1], the second host may include two or more of the anthracene compounds represented by [Chemical Formula 2], or vice versa.

Herein, among the two or more different anthracene compounds represented by [Chemical Formula 2], at least one is a compound in which Ar₂₁ is a substituted or unsubstituted C₆-C₃₀ aryl group, and at least one other is a compound in which Ar₂₁ is a substituted or unsubstituted C₂-C₃₀ heteroaryl group.

More preferably, when Ar₂₁ is a substituted or unsubstituted C₂-C₃₀ heteroaryl group, Ar₂₁ may be represented by [Structural Formula 2].

According to one embodiment of the present invention, the first light-emitting layer in the organic light-emitting device further includes the compound represented by [Chemical Formula 1] and a host compound different from the compound represented by [Chemical Formula 1] as the first host, and may include the compound represented by [Chemical Formula 1] and the host compound different therefrom in a ratio of 1:9 to 9:1, more preferably in a ratio of 3:7 to 7:3.

Herein, when the first host is composed of two or more compounds, these may be mixed in one deposition source and deposited by sublimation or vaporization, or may each be sublimated or vaporized in a plurality of deposition sources and co-deposited on the first light-emitting layer.

Herein, as the host compound different from the compound represented by [Chemical Formula 1], a compound having a structural formula different from the structural formula of [Chemical Formula 1] may also be used, or, as long as it is different from the compound previously used (the compound corresponding to the compound represented by [Chemical Formula 1] and already used), any compound that is included in the structure of [Chemical Formula 1] but is different may also be used.

Meanwhile, as the compound having a structural formula different from the structural formula of [Chemical Formula 1] in the first light-emitting layer, anthracene-based compounds, benzanthracene-based compounds, phenanthrene-based compounds, pyrene-based compounds, fluorene-based compounds, spirofluorene-based compounds, chrysene-based compounds, carbazole-based compounds, biphenyl-based compounds or the like known in the art may be used. Herein, the anthracene-based compounds refer to compounds including at least one, preferably 1 to 3 anthracene groups in the molecule, and the remaining benzanthracene-based compounds, phenanthrene-based compounds, pyrene-based compounds, fluorene-based compounds, spirofluorene-based compounds, chrysene-based compounds, carbazole-based compounds, or biphenyl-based compounds also refer to compounds including at least one, preferably 1 to 3 corresponding groups in the molecule.

According to one embodiment of the present invention, the second light-emitting layer in the organic light-emitting device further includes the compound represented by [Chemical Formula 2] and a host compound different from the compound represented by [Chemical Formula 2] as the second host, and may include the compound represented by [Chemical Formula 2] and the host compound different therefrom in a ratio of 1:9 to 9:1, more preferably in a ratio of 3:7 to 7:3.

Herein, when the second host is composed of two or more compounds, these may be mixed in one deposition source and deposited by sublimation or vaporization, or may each be sublimated or vaporized in a plurality of deposition sources and co-deposited on the second light-emitting layer.

Herein, as the host compound different from the compound represented by [Chemical Formula 2], a compound having a structural formula different from the structural formula of [Chemical Formula 2] may also be used, or, as long as it is different from the compound previously used (the compound corresponding to the compound represented by [Chemical Formula 2] and already used), any compound that is included in the structure of [Chemical Formula 2] but is different may also be used.

In addition, as the compound having a structural formula different from the structural formula of [Chemical Formula 2] in the second light-emitting layer, anthracene-based compounds, benzanthracene-based compounds, phenanthrene-based compounds, pyrene-based compounds, fluorene-based compounds, spirofluorene-based compounds, chrysene-based compounds, carbazole-based compounds, biphenyl-based compounds or the like known in the art may be used, and descriptions thereof are the same as the descriptions provided above.

According to one embodiment of the present invention, the first host in the first light-emitting layer may include the compound represented by [Chemical Formula 1] and the host compound different from the compound represented by [Chemical Formula 1] in a ratio of 1:9 to 9:1, more preferably in a ratio of 3:7 to 7:3. In addition, the second host in the second light-emitting layer may include the compound represented by [Chemical Formula 2] and the host compound different from the compound represented by [Chemical Formula 2] in a ratio of 1:9 to 9:1, more preferably in a ratio of 3:7 to 7:3.

In addition, as one embodiment of the present invention, specific examples of the compound represented by [Chemical Formula 2] may include compounds described below, however, the compound is not limited thereto.

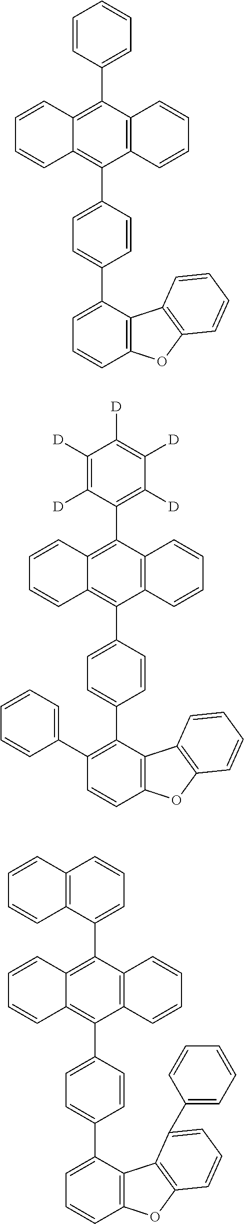

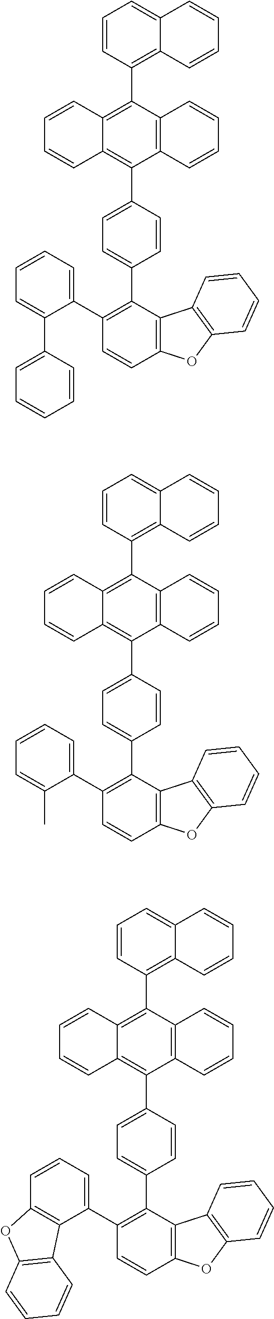 [SMILES: c1ccc(-c2ccccc2-c2ccc3oc4ccccc4c3c2-c2ccc(-c3c4ccccc4c(-c4cccc5ccccc45)c4ccccc34)cc2)cc1 ; Cc1ccccc1-c1ccc2oc3ccccc3c2c1-c1ccc(-c2c3ccccc3c(-c3cccc4ccccc34)c3ccccc23)cc1 ; c1ccc2c(-c3c4ccccc4c(-c4ccc(-c5c(-c6cccc7oc8ccccc8c67)ccc6oc7ccccc7c56)cc4)c4ccccc34)cccc2c1]

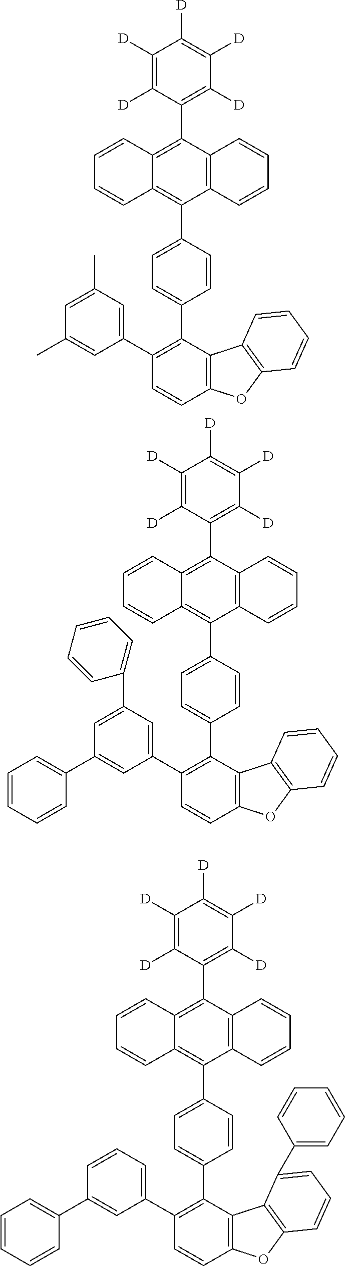

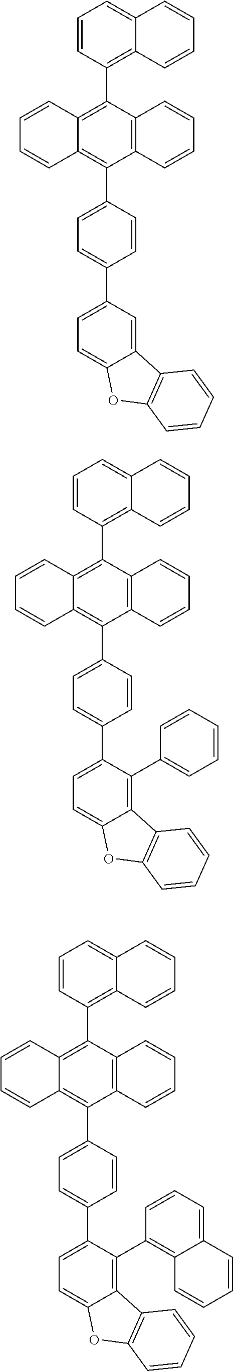

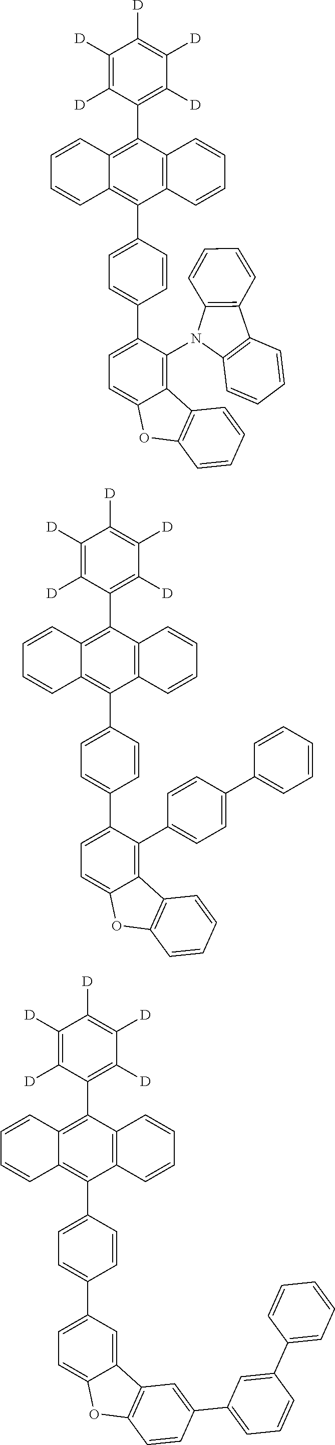 [SMILES: [2H]c1c([2H])c([2H])c(-c2c3ccccc3c(-c3ccc(-c4ccc5oc6ccccc6c5c4-n4c5ccccc5c5ccccc54)cc3)c3ccccc23)c([2H])c1[2H] ; [2H]c1c([2H])c([2H])c(-c2c3ccccc3c(-c3ccc(-c4ccc5oc6ccccc6c5c4-c4ccc(-c5ccccc5)cc4)cc3)c3ccccc23)c([2H])c1[2H] ; [2H]c1c([2H])c([2H])c(-c2c3ccccc3c(-c3ccc(-c4ccc5oc6ccc(-c7cccc(-c8ccccc8)c7)cc6c5c4)cc3)c3ccccc23)c([2H])c1[2H]]

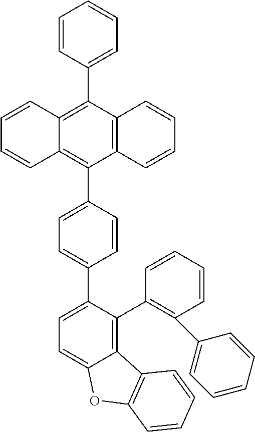 [SMILES: c1ccc(-c2ccccc2-c2c(-c3ccc(-c4c5ccccc5c(-c5ccccc5)c5ccccc45)cc3)ccc3oc4ccccc4c23)cc1]

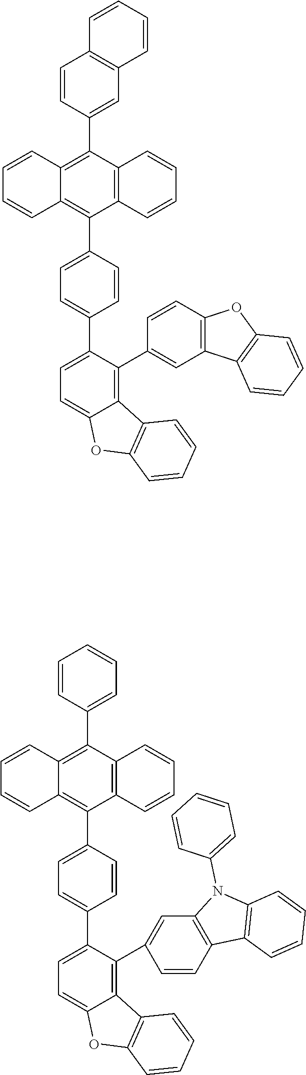 [SMILES: c1ccc2cc(-c3c4ccccc4c(-c4ccc(-c5ccc6oc7ccccc7c6c5-c5ccc6oc7ccccc7c6c5)cc4)c4ccccc34)ccc2c1 ; c1ccc(-c2c3ccccc3c(-c3ccc(-c4ccc5oc6ccccc6c5c4-c4ccc5c6ccccc6n(-c6ccccc6)c5c4)cc3)c3ccccc23)cc1]

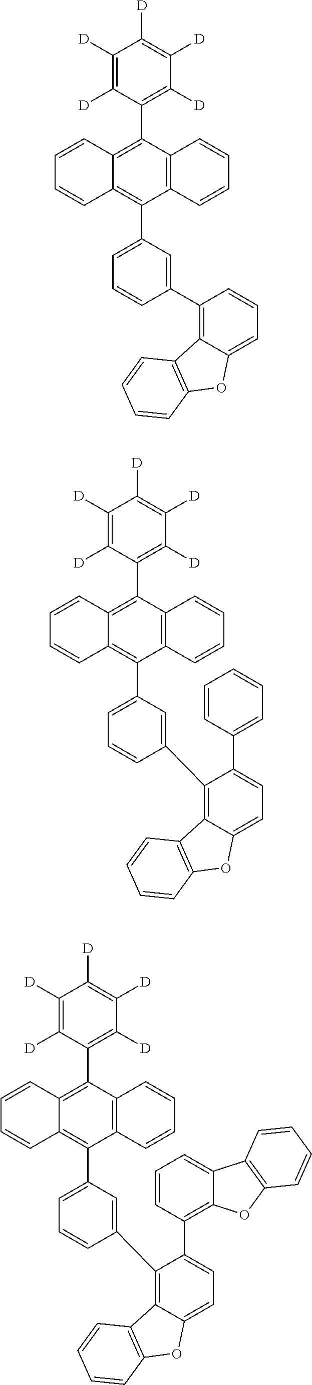 [SMILES: [2H]c1c([2H])c([2H])c(-c2c3ccccc3c(-c3cccc(-c4cccc5oc6ccccc6c45)c3)c3ccccc23)c([2H])c1[2H] ; [2H]c1c([2H])c([2H])c(-c2c3ccccc3c(-c3cccc(-c4c(-c5ccccc5)ccc5oc6ccccc6c45)c3)c3ccccc23)c([2H])c1[2H] ; [2H]c1c([2H])c([2H])c(-c2c3ccccc3c(-c3cccc(-c4c(-c5cccc6c5oc5ccccc56)ccc5oc6ccccc6c45)c3)c3ccccc23)c([2H])c1[2H]]

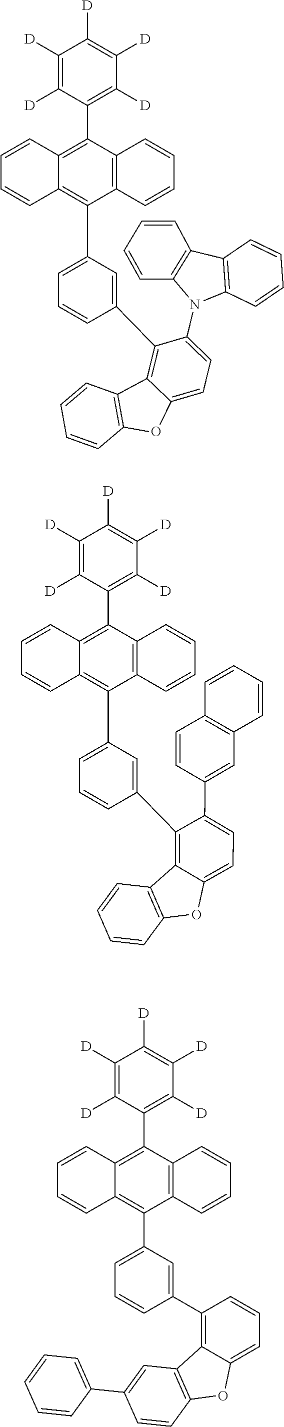

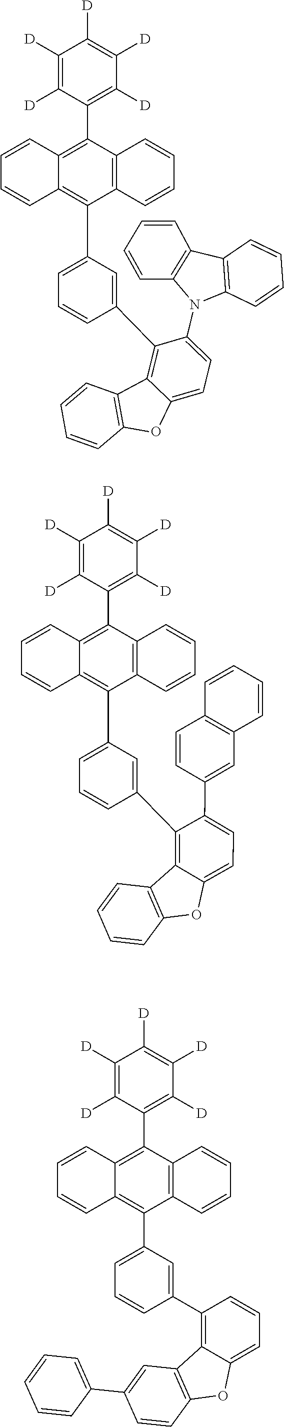

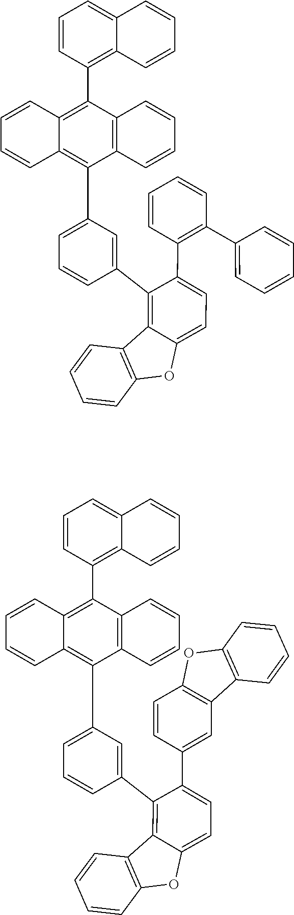 [SMILES: c1ccc(-c2ccccc2-c2ccc3oc4ccccc4c3c2-c2cccc(-c3c4ccccc4c(-c4cccc5ccccc45)c4ccccc34)c2)cc1 ; c1cc(-c2c3ccccc3c(-c3cccc4ccccc34)c3ccccc23)cc(-c2c(-c3ccc4oc5ccccc5c4c3)ccc3oc4ccccc4c23)c1]

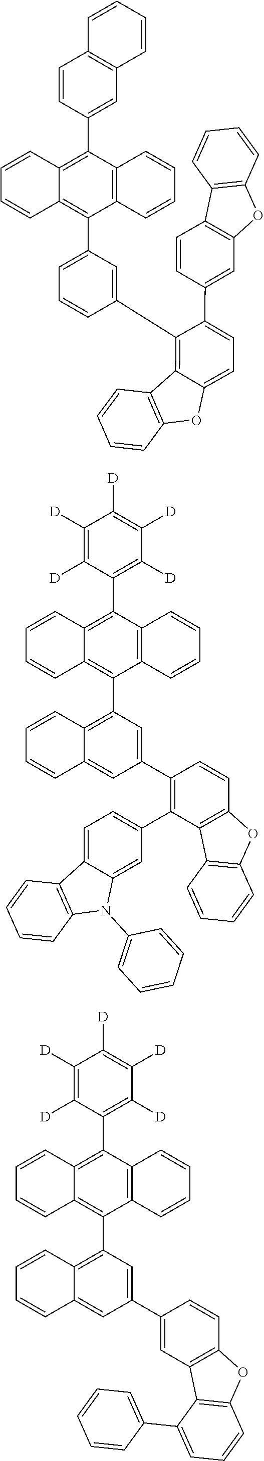

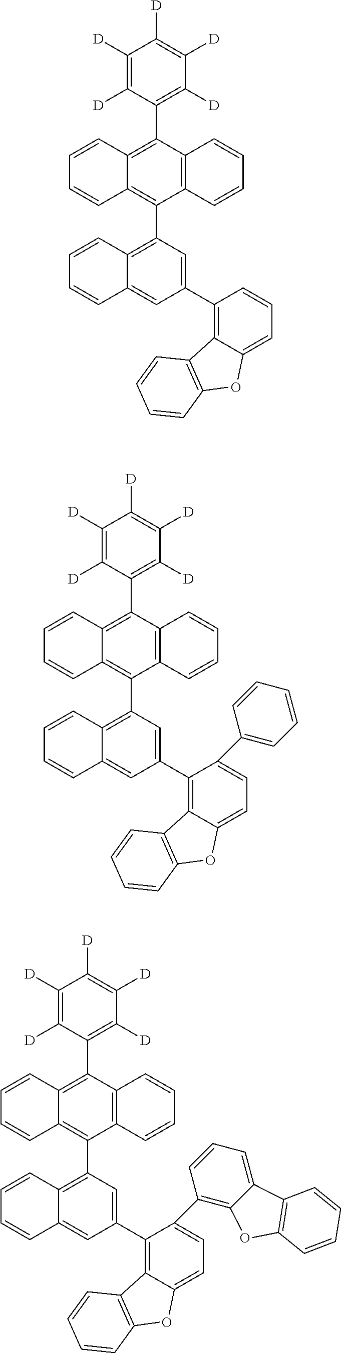 [SMILES: [2H]c1c([2H])c([2H])c(-c2c3ccccc3c(-c3cc(-c4cccc5oc6ccccc6c45)cc4ccccc34)c3ccccc23)c([2H])c1[2H] ; [2H]c1c([2H])c([2H])c(-c2c3ccccc3c(-c3cc(-c4c(-c5ccccc5)ccc5oc6ccccc6c45)cc4ccccc34)c3ccccc23)c([2H])c1[2H] ; [2H]c1c([2H])c([2H])c(-c2c3ccccc3c(-c3cc(-c4c(-c5cccc6c5oc5ccccc56)ccc5oc6ccccc6c45)cc4ccccc34)c3ccccc23)c([2H])c1[2H]]

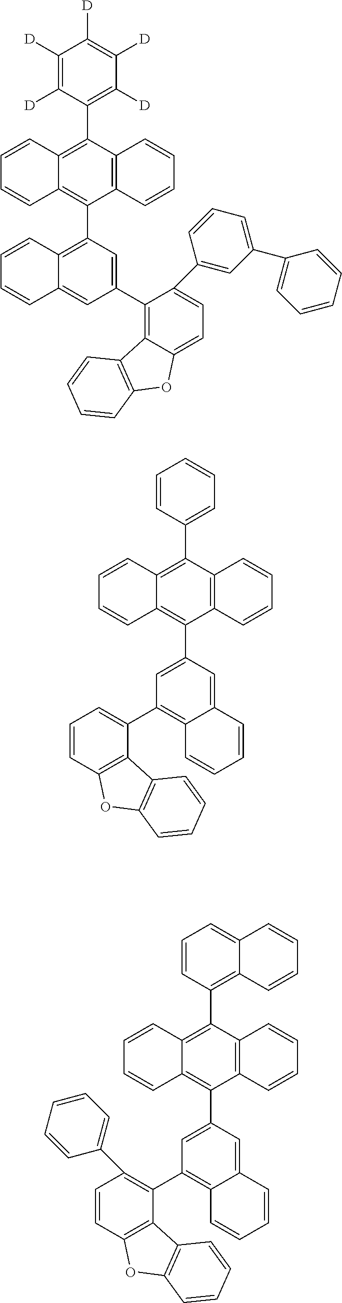 [SMILES: [2H]c1c([2H])c([2H])c(-c2c3ccccc3c(-c3cc(-c4c(-c5cccc(-c6ccccc6)c5)ccc5oc6ccccc6c45)cc4ccccc34)c3ccccc23)c([2H])c1[2H] ; c1ccc(-c2c3ccccc3c(-c3cc(-c4cccc5oc6ccccc6c45)c4ccccc4c3)c3ccccc23)cc1 ; c1ccc(-c2ccc3oc4ccccc4c3c2-c2cc(-c3c4ccccc4c(-c4cccc5ccccc45)c4ccccc34)cc3ccccc23)cc1]

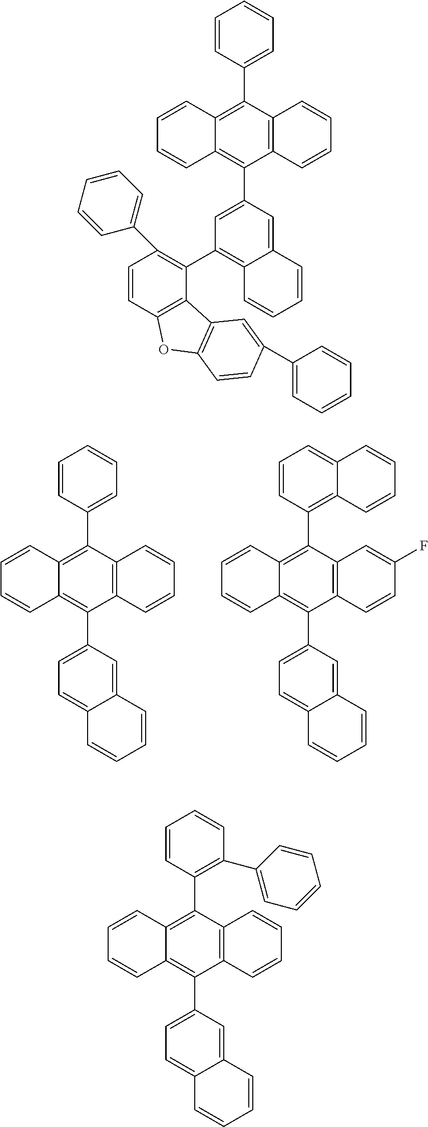

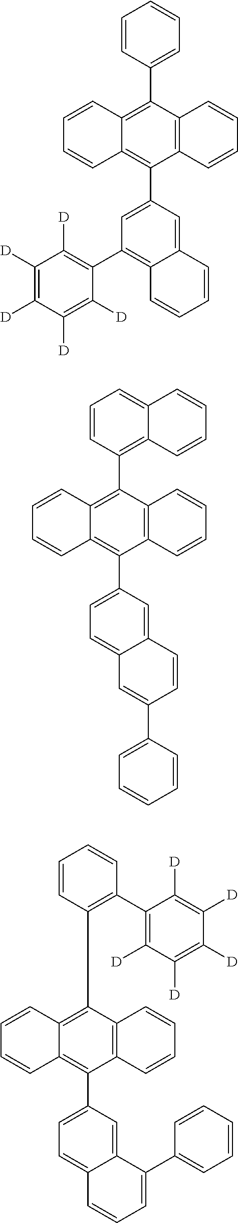

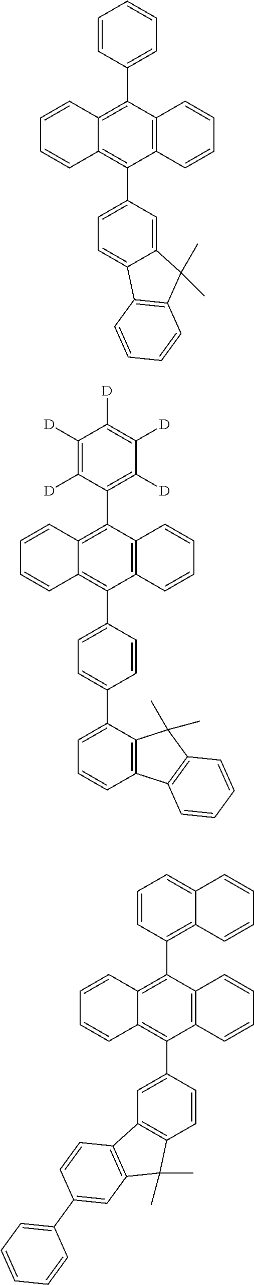

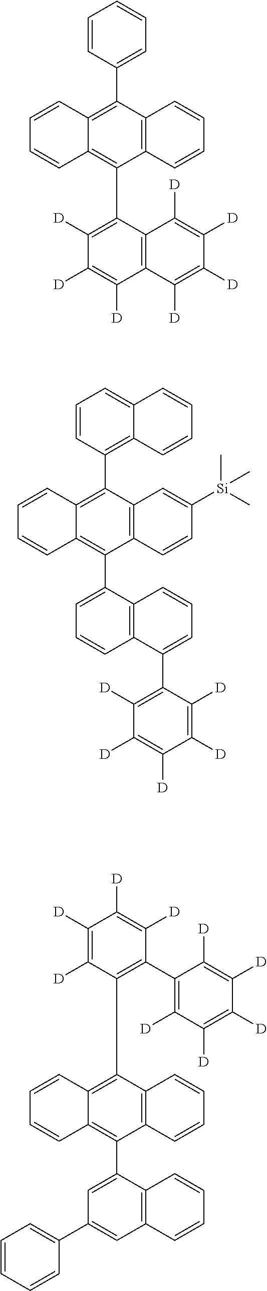 [SMILES: [2H]c1c([2H])c([2H])c2c(-c3c4ccccc4c(-c4ccccc4)c4ccccc34)c([2H])c([2H])c([2H])c2c1[2H] ; [2H]c1c([2H])c([2H])c(-c2cccc3c(-c4c5ccccc5c(-c5cccc6ccccc56)c5cc([Si](C)(C)C)ccc45)cccc23)c([2H])c1[2H] ; [2H]c1c([2H])c([2H])c(-c2c([2H])c([2H])c([2H])c([2H])c2-c2c3ccccc3c(-c3cc(-c4ccccc4)cc4ccccc34)c3ccccc23)c([2H])c1[2H]]

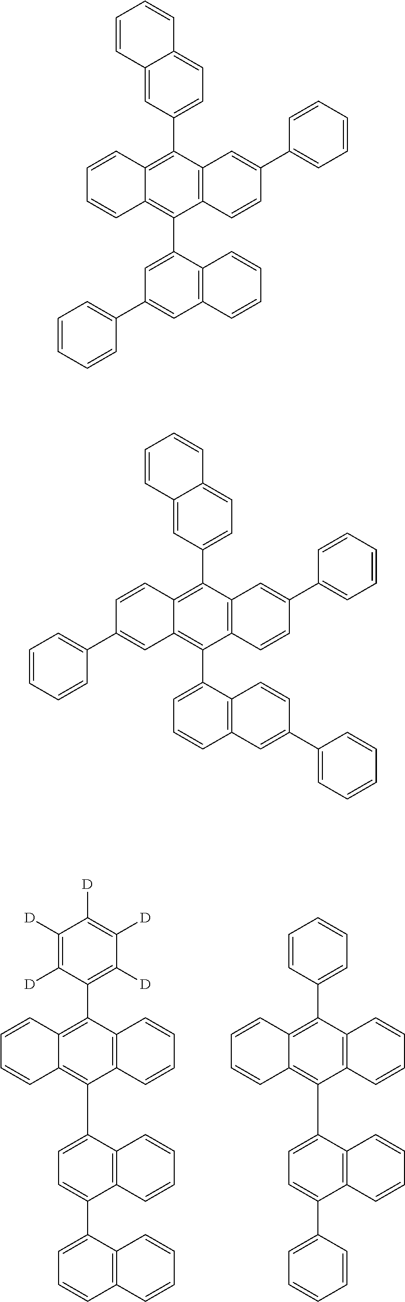

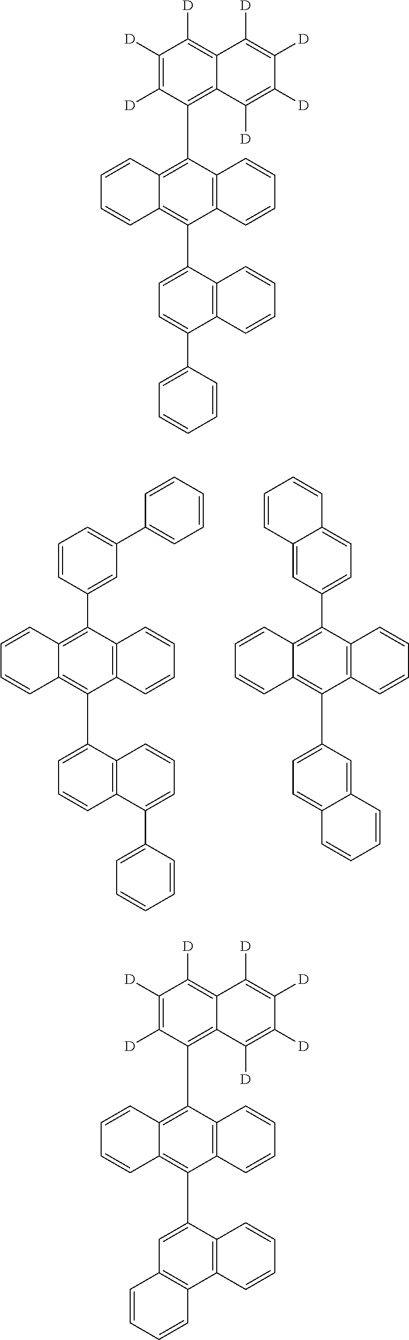

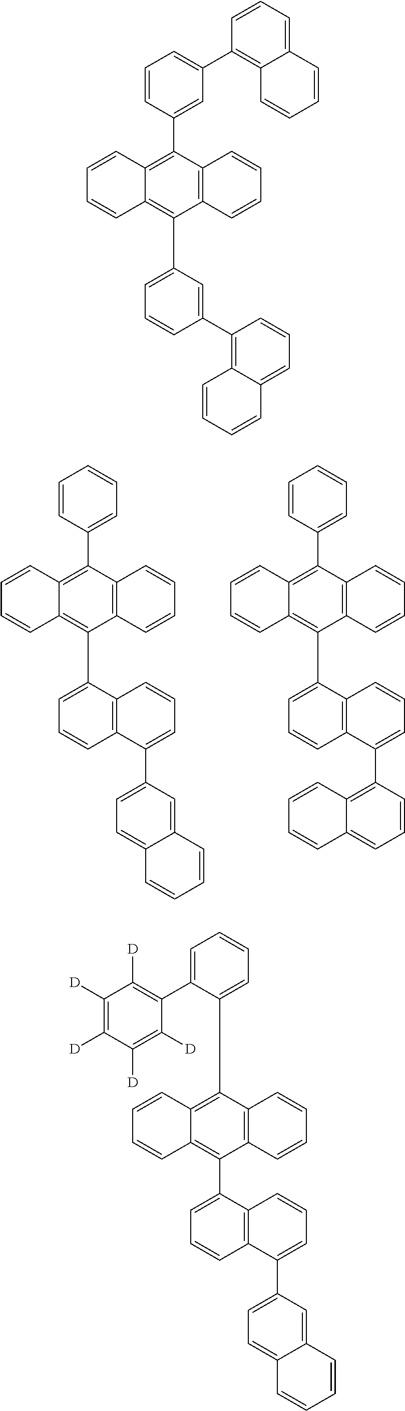

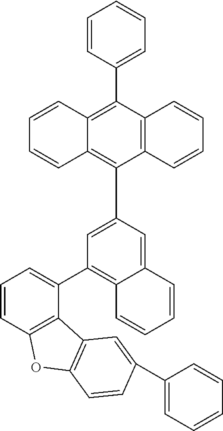 [SMILES: c1ccc(-c2ccc3oc4cccc(-c5cc(-c6c7ccccc7c(-c7ccccc7)c7ccccc67)cc6ccccc56)c4c3c2)cc1]

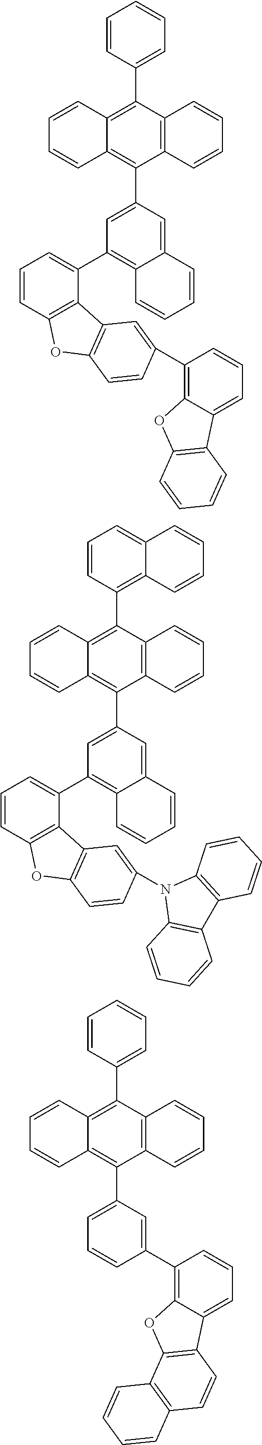

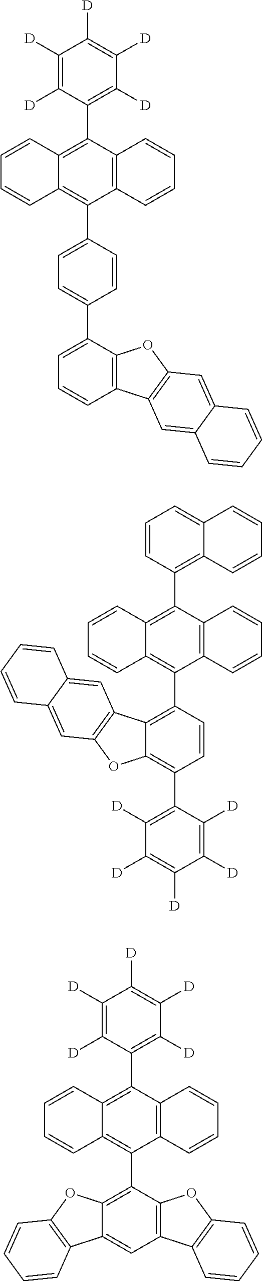

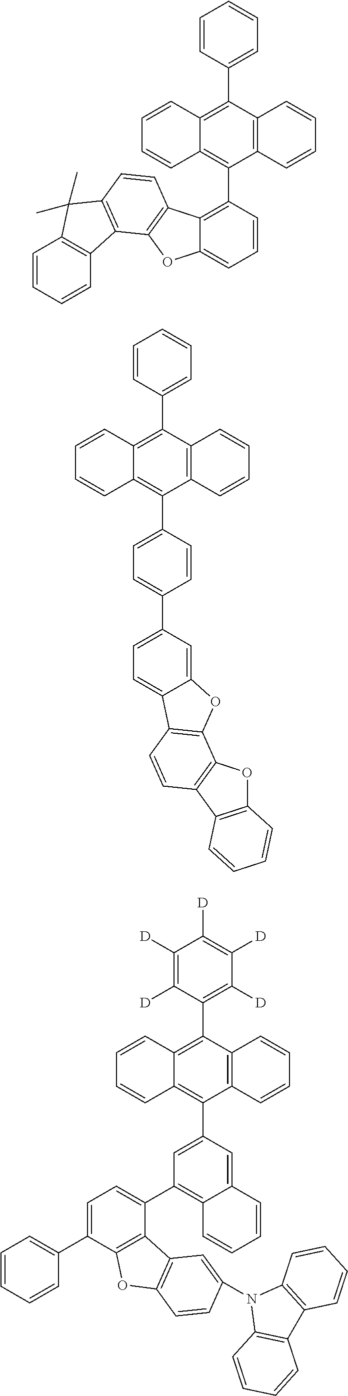

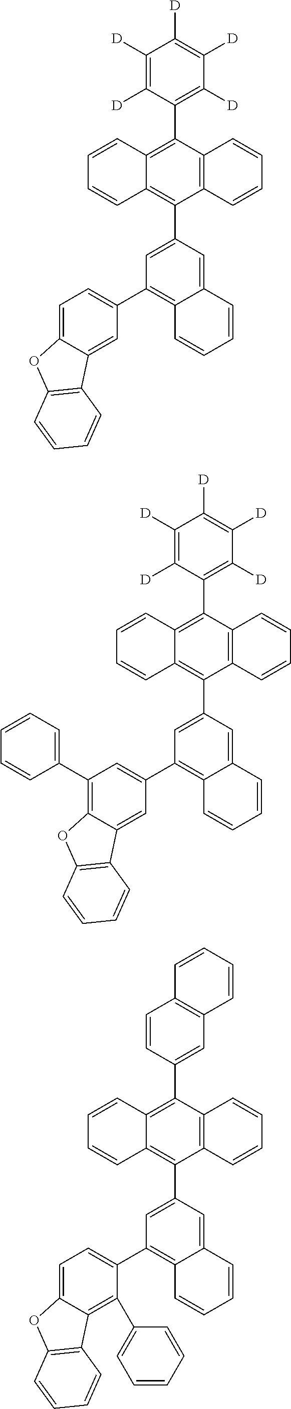 [SMILES: [2H]c1c([2H])c([2H])c(-c2c3ccccc3c(-c3cc(-c4ccc5oc6ccccc6c5c4)c4ccccc4c3)c3ccccc23)c([2H])c1[2H] ; [2H]c1c([2H])c([2H])c(-c2c3ccccc3c(-c3cc(-c4cc(-c5ccccc5)c5oc6ccccc6c5c4)c4ccccc4c3)c3ccccc23)c([2H])c1[2H] ; c1ccc(-c2c(-c3cc(-c4c5ccccc5c(-c5ccc6ccccc6c5)c5ccccc45)cc4ccccc34)ccc3oc4ccccc4c23)cc1]

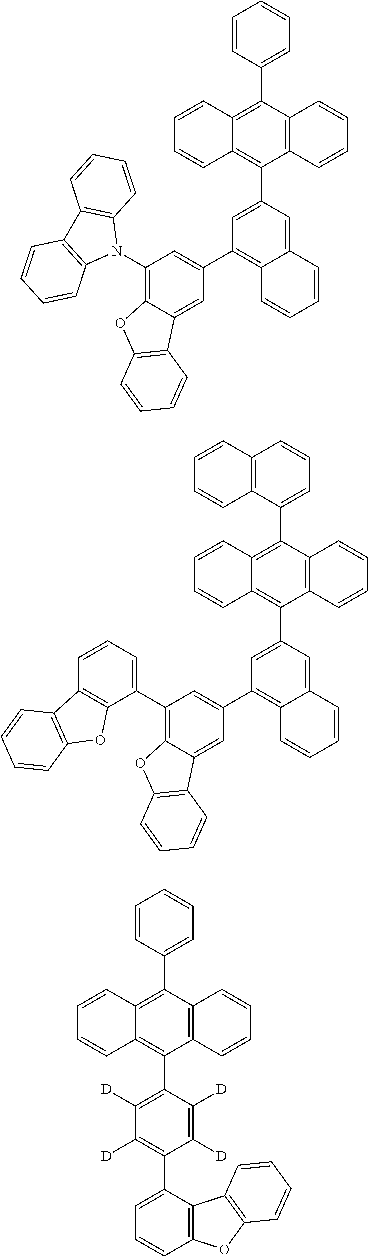

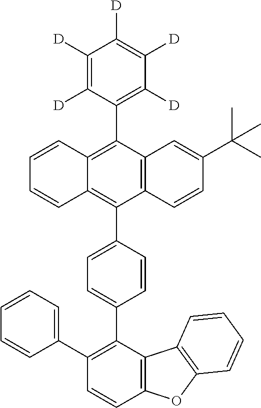 [SMILES: [2H]c1c([2H])c([2H])c(-c2c3ccccc3c(-c3ccc(-c4c(-c5ccccc5)ccc5oc6ccccc6c45)cc3)c3ccc(C(C)(C)C)cc23)c([2H])c1[2H]]

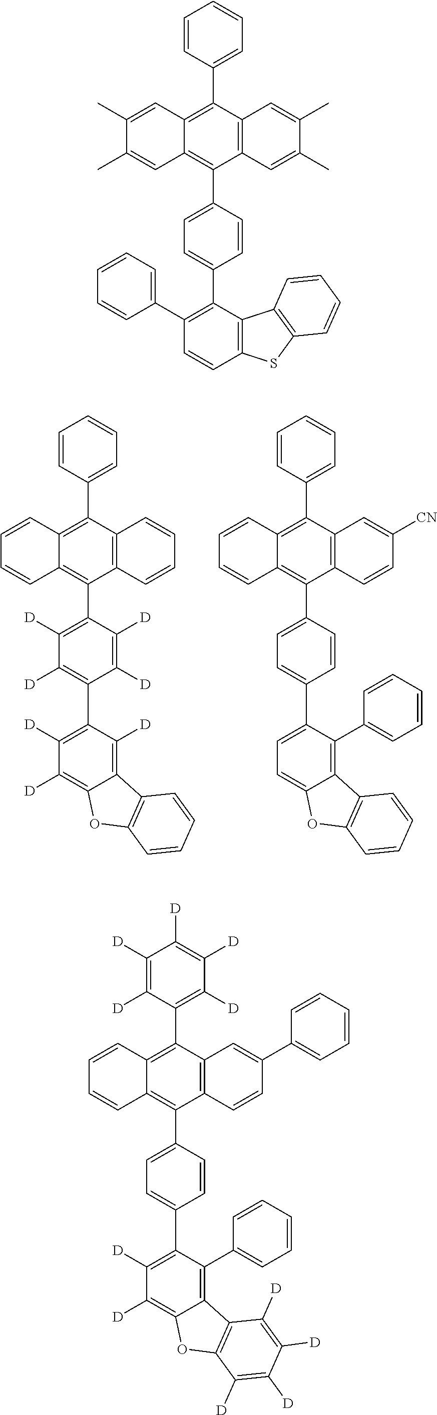

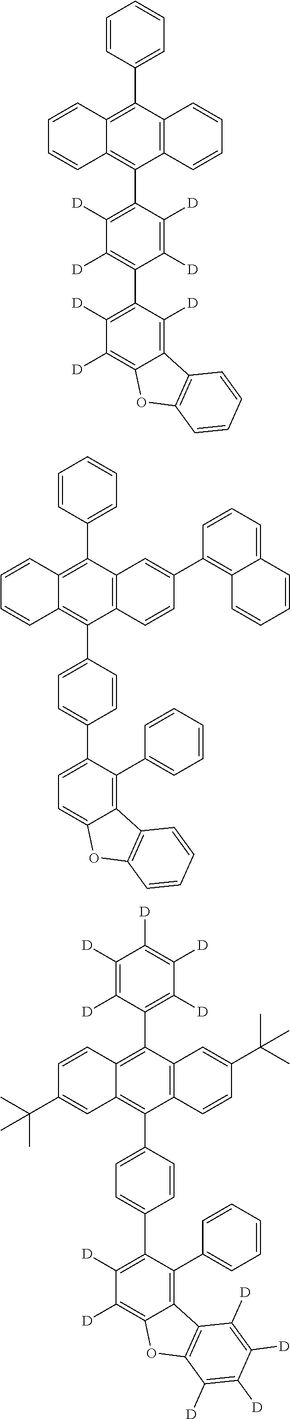

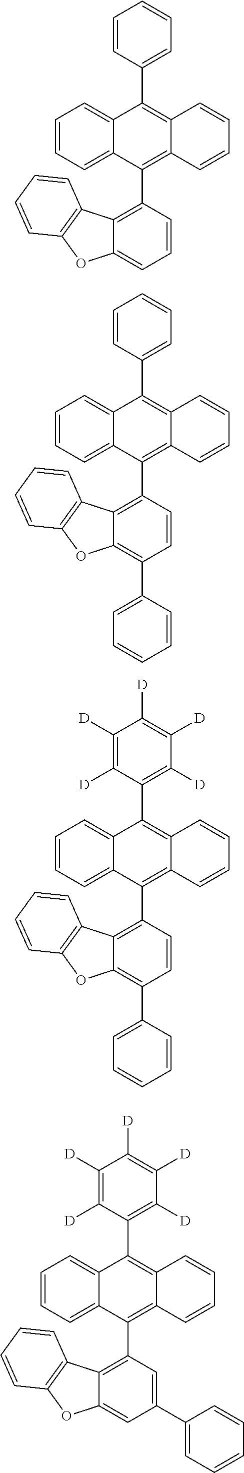

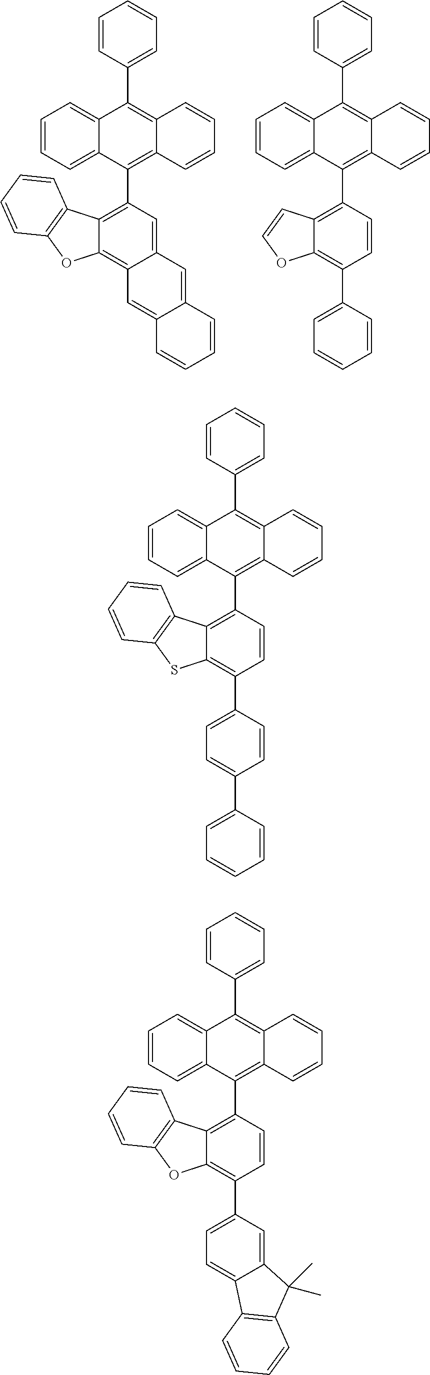

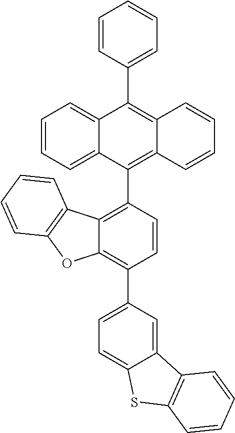 [SMILES: c1ccc(-c2c3ccccc3c(-c3ccc(-c4ccc5sc6ccccc6c5c4)c4oc5ccccc5c34)c3ccccc23)cc1]

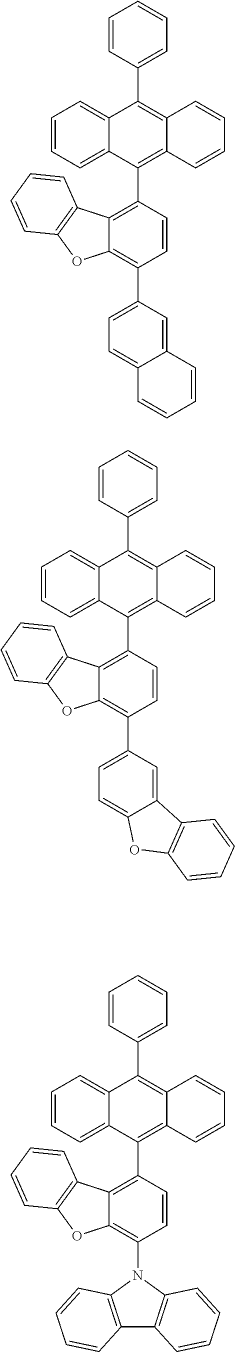 [SMILES: c1ccc(-c2c3ccccc3c(-c3ccc(-c4ccc5ccccc5c4)c4oc5ccccc5c34)c3ccccc23)cc1 ; c1ccc(-c2c3ccccc3c(-c3ccc(-c4ccc5oc6ccccc6c5c4)c4oc5ccccc5c34)c3ccccc23)cc1 ; c1ccc(-c2c3ccccc3c(-c3ccc(-n4c5ccccc5c5ccccc54)c4oc5ccccc5c34)c3ccccc23)cc1]

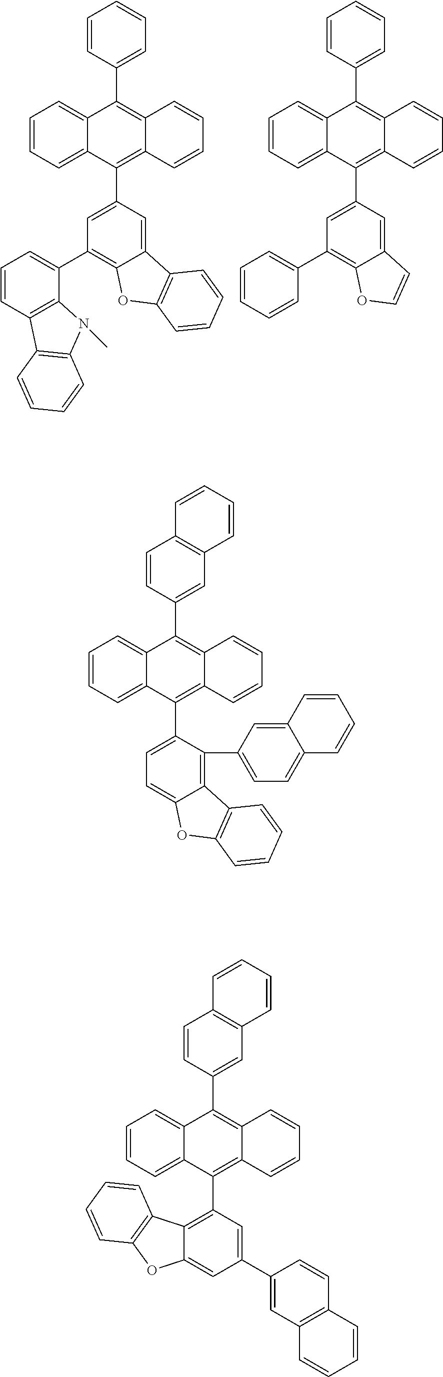

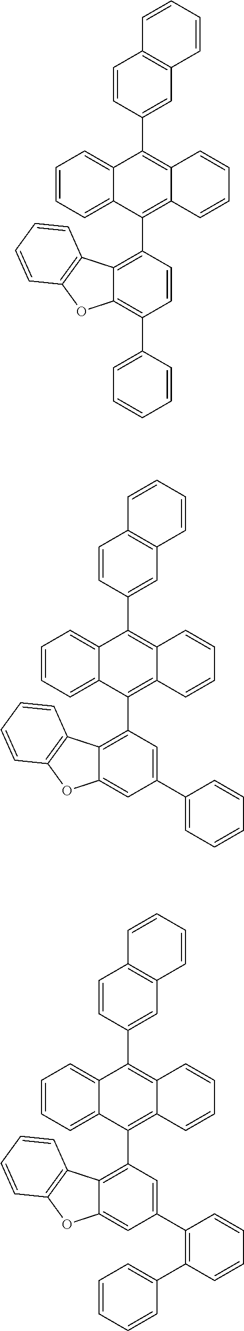 [SMILES: c1ccc(-c2ccc(-c3c4ccccc4c(-c4ccc5ccccc5c4)c4ccccc34)c3c2oc2ccccc23)cc1 ; c1ccc(-c2cc(-c3c4ccccc4c(-c4ccc5ccccc5c4)c4ccccc34)c3c(c2)oc2ccccc23)cc1 ; c1ccc(-c2ccccc2-c2cc(-c3c4ccccc4c(-c4ccc5ccccc5c4)c4ccccc34)c3c(c2)oc2ccccc23)cc1]

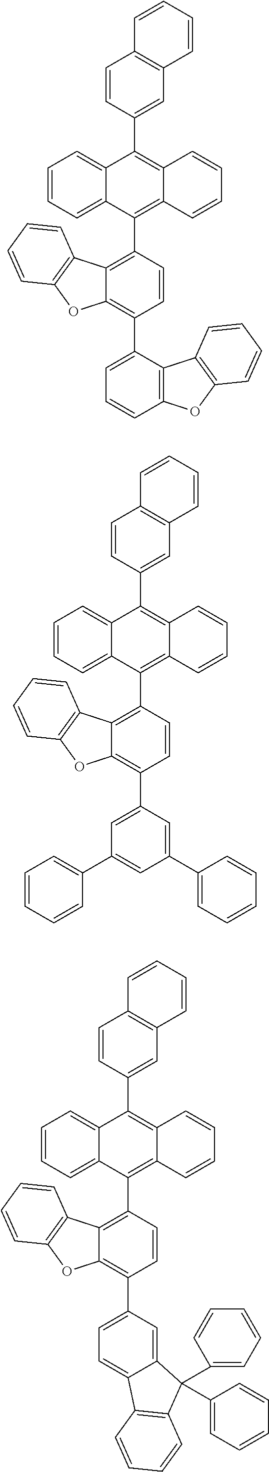 [SMILES: c1ccc2cc(-c3c4ccccc4c(-c4ccc(-c5cccc6oc7ccccc7c56)c5oc6ccccc6c45)c4ccccc34)ccc2c1 ; c1ccc(-c2cc(-c3ccccc3)cc(-c3ccc(-c4c5ccccc5c(-c5ccc6ccccc6c5)c5ccccc45)c4c3oc3ccccc34)c2)cc1 ; c1ccc(C2(c3ccccc3)c3ccccc3-c3ccc(-c4ccc(-c5c6ccccc6c(-c6ccc7ccccc7c6)c6ccccc56)c5c4oc4ccccc45)cc32)cc1]

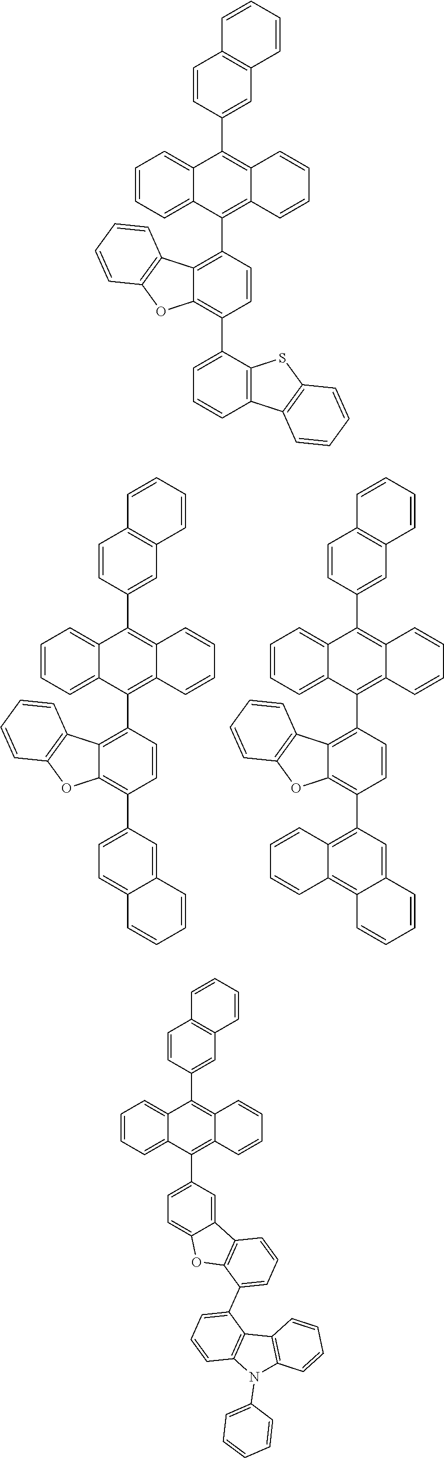

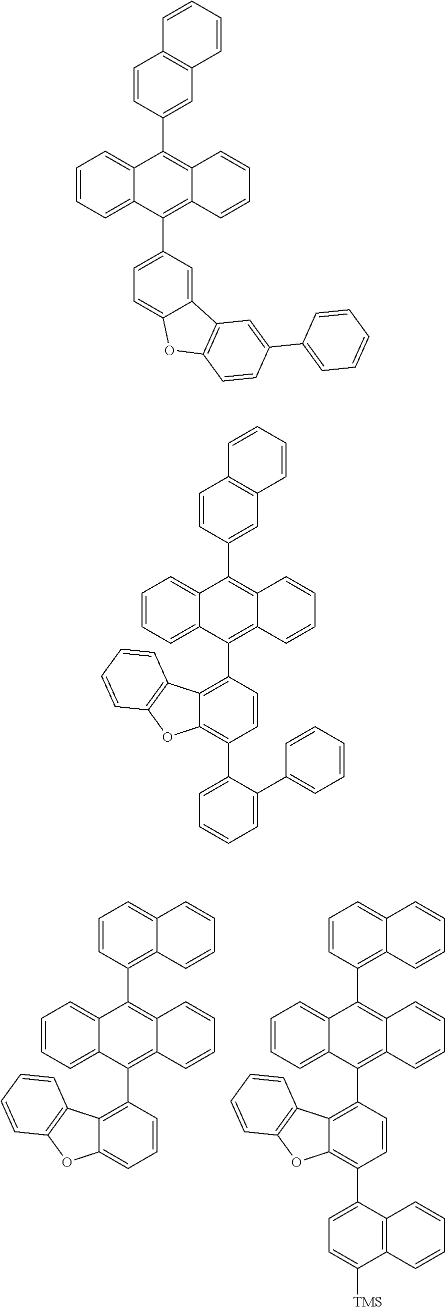

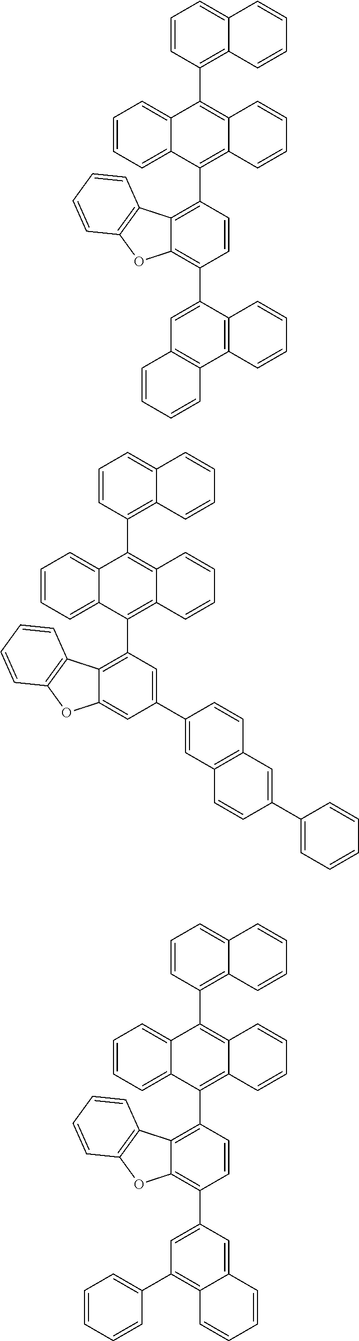

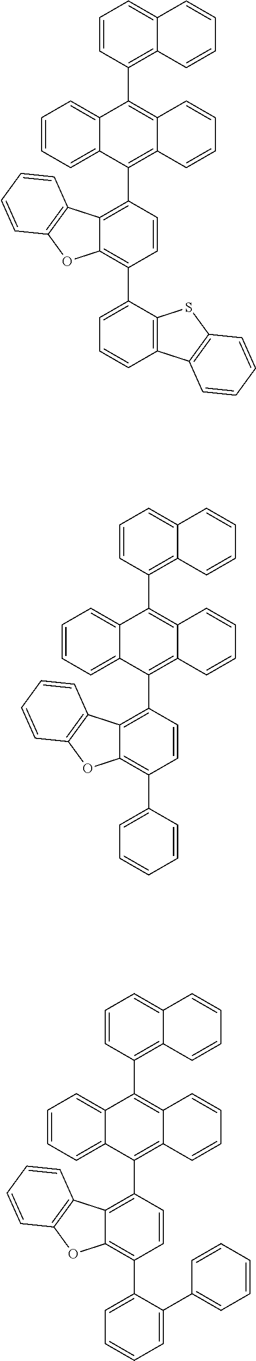 [SMILES: c1ccc2c(-c3c4ccccc4c(-c4ccc(-c5cccc6c5sc5ccccc56)c5oc6ccccc6c45)c4ccccc34)cccc2c1 ; c1ccc(-c2ccc(-c3c4ccccc4c(-c4cccc5ccccc45)c4ccccc34)c3c2oc2ccccc23)cc1 ; c1ccc(-c2ccccc2-c2ccc(-c3c4ccccc4c(-c4cccc5ccccc45)c4ccccc34)c3c2oc2ccccc23)cc1]

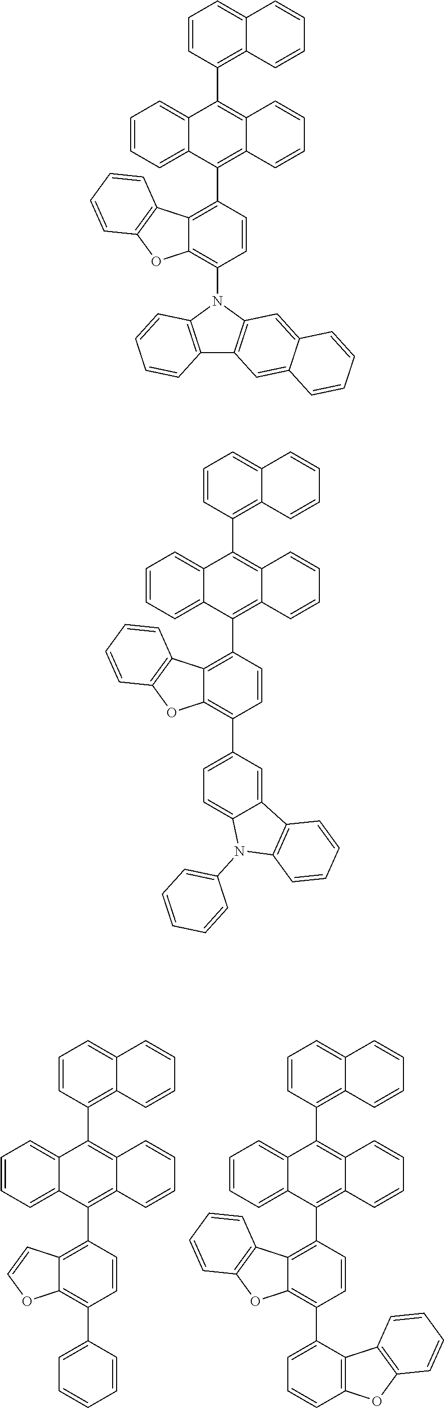

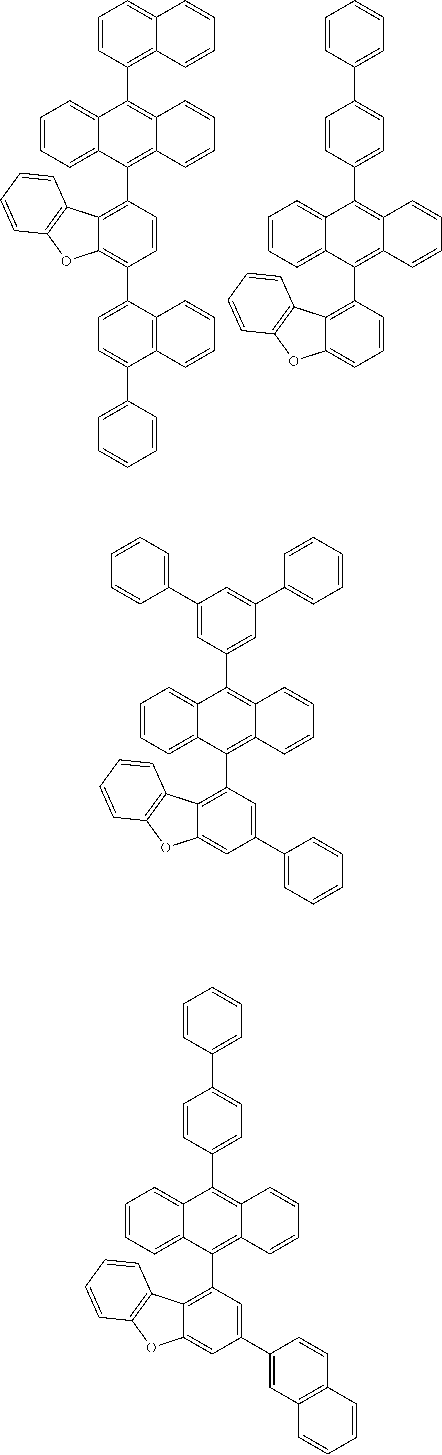

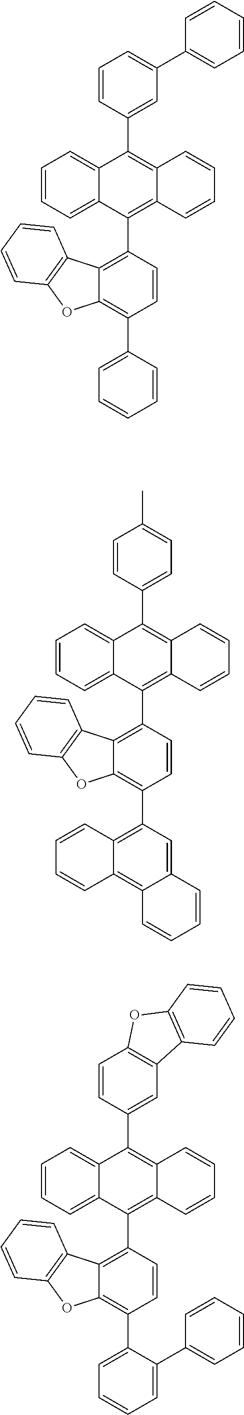 [SMILES: c1ccc(-c2cccc(-c3c4ccccc4c(-c4ccc(-c5ccccc5)c5oc6ccccc6c45)c4ccccc34)c2)cc1 ; Cc1ccc(-c2c3ccccc3c(-c3ccc(-c4cc5ccccc5c5ccccc45)c4oc5ccccc5c34)c3ccccc23)cc1 ; c1ccc(-c2ccccc2-c2ccc(-c3c4ccccc4c(-c4ccc5oc6ccccc6c5c4)c4ccccc34)c3c2oc2ccccc23)cc1]

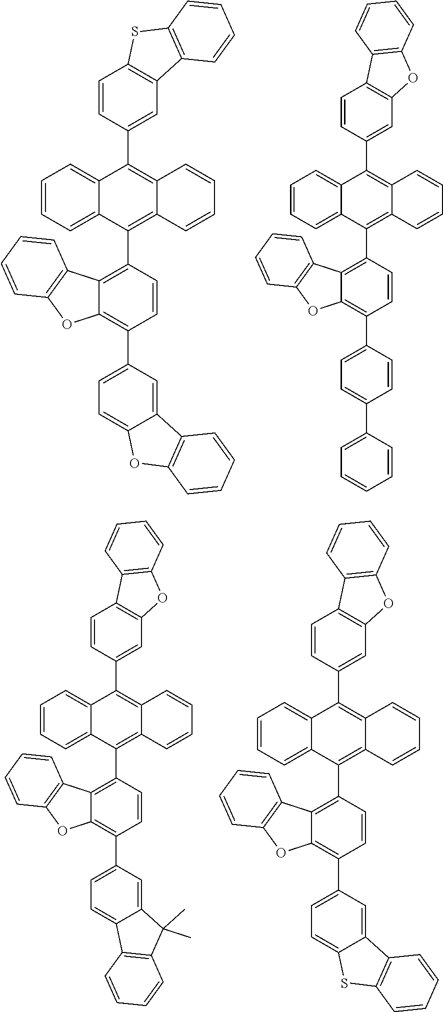

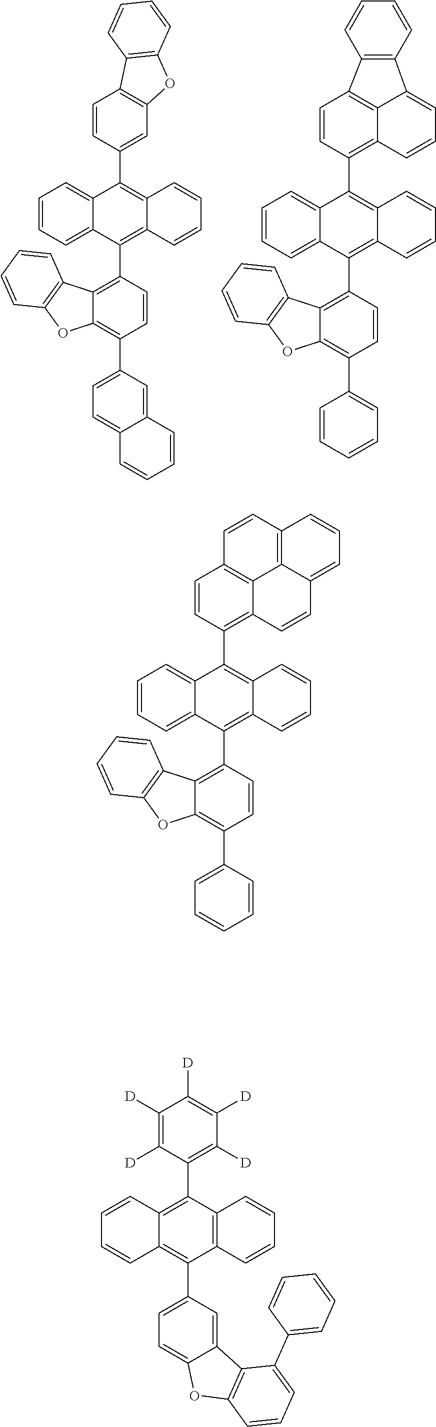 [SMILES: c1ccc2cc(-c3ccc(-c4c5ccccc5c(-c5ccc6c(c5)oc5ccccc56)c5ccccc45)c4c3oc3ccccc34)ccc2c1 ; c1ccc(-c2ccc(-c3c4ccccc4c(-c4ccc5c6c(cccc46)-c4ccccc4-5)c4ccccc34)c3c2oc2ccccc23)cc1 ; c1ccc(-c2ccc(-c3c4ccccc4c(-c4ccc5ccc6cccc7ccc4c5c67)c4ccccc34)c3c2oc2ccccc23)cc1 ; [2H]c1c([2H])c([2H])c(-c2c3ccccc3c(-c3ccc4oc5cccc(-c6ccccc6)c5c4c3)c3ccccc23)c([2H])c1[2H]]

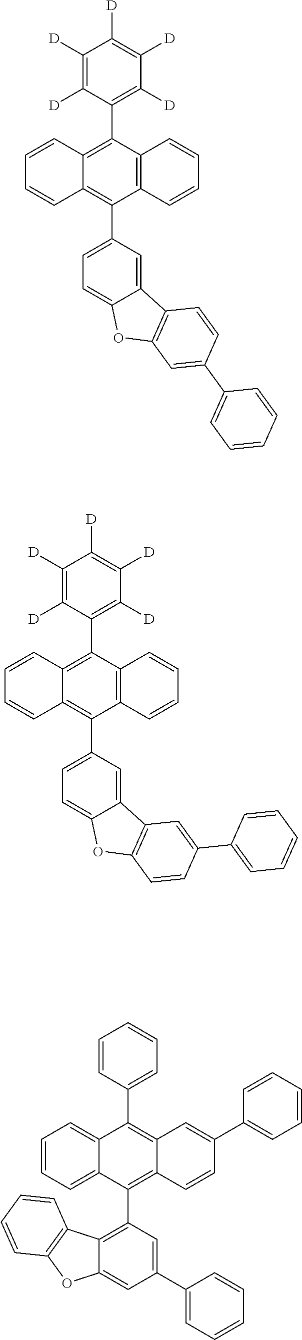 [SMILES: [2H]c1c([2H])c([2H])c(-c2c3ccccc3c(-c3ccc4oc5cc(-c6ccccc6)ccc5c4c3)c3ccccc23)c([2H])c1[2H] ; [2H]c1c([2H])c([2H])c(-c2c3ccccc3c(-c3ccc4oc5ccc(-c6ccccc6)cc5c4c3)c3ccccc23)c([2H])c1[2H] ; c1ccc(-c2cc(-c3c4ccccc4c(-c4ccccc4)c4cc(-c5ccccc5)ccc34)c3c(c2)oc2ccccc23)cc1]

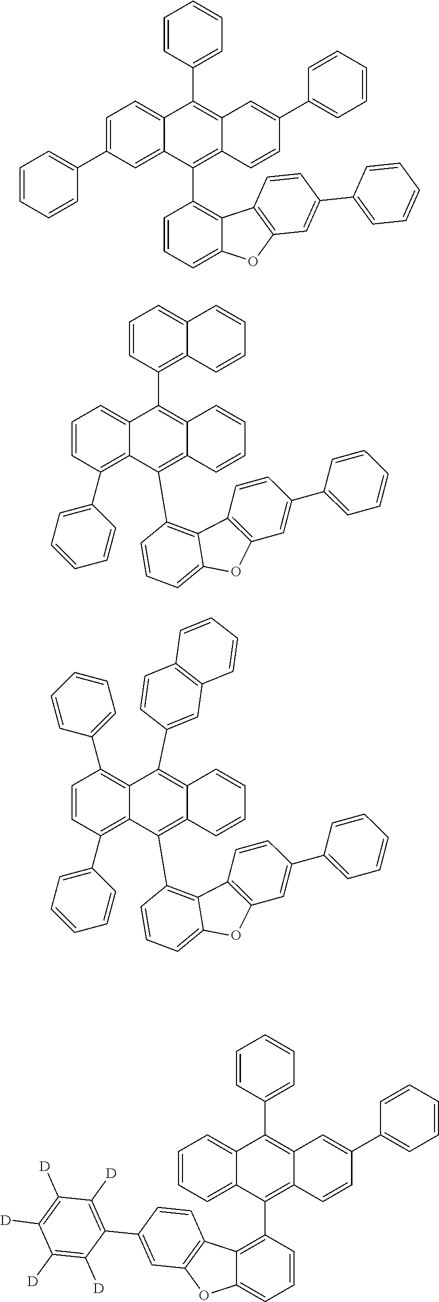

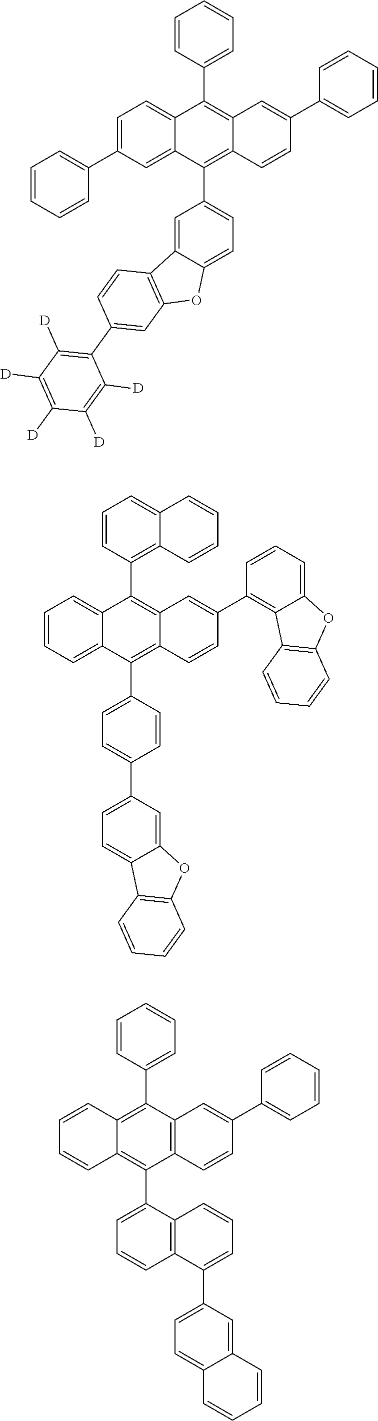

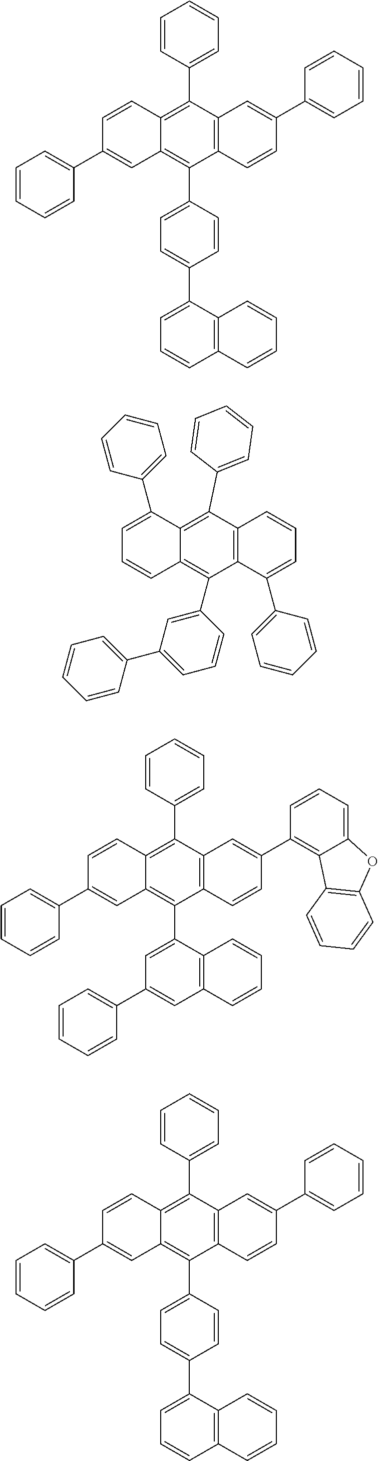

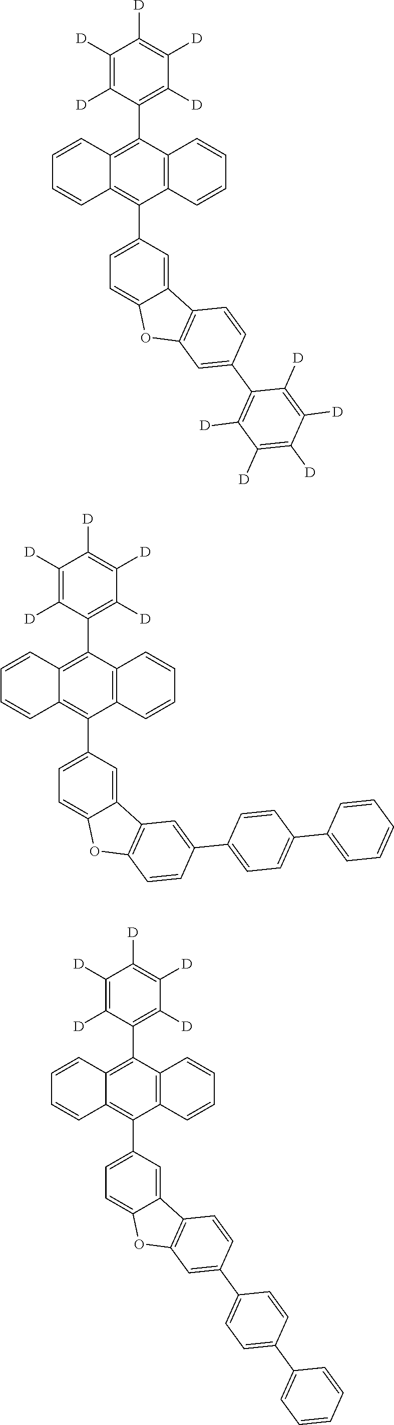 [SMILES: [2H]c1c([2H])c([2H])c(-c2ccc3c(c2)oc2ccc(-c4c5ccccc5c(-c5c([2H])c([2H])c([2H])c([2H])c5[2H])c5ccccc45)cc23)c([2H])c1[2H] ; [2H]c1c([2H])c([2H])c(-c2c3ccccc3c(-c3ccc4oc5ccc(-c6ccc(-c7ccccc7)cc6)cc5c4c3)c3ccccc23)c([2H])c1[2H] ; [2H]c1c([2H])c([2H])c(-c2c3ccccc3c(-c3ccc4oc5cc(-c6ccc(-c7ccccc7)cc6)ccc5c4c3)c3ccccc23)c([2H])c1[2H]]

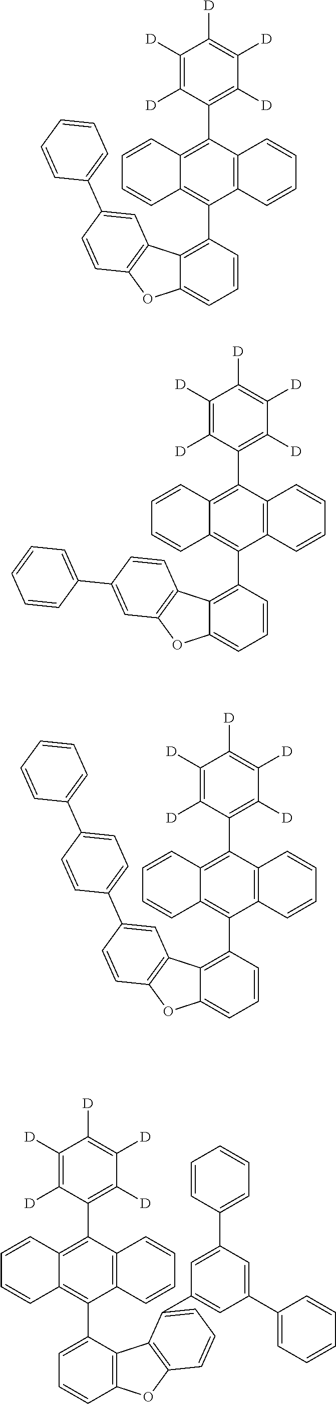 [SMILES: [2H]c1c([2H])c([2H])c(-c2c3ccccc3c(-c3cccc4oc5ccc(-c6ccccc6)cc5c34)c3ccccc23)c([2H])c1[2H] ; [2H]c1c([2H])c([2H])c(-c2c3ccccc3c(-c3cccc4oc5cc(-c6ccccc6)ccc5c34)c3ccccc23)c([2H])c1[2H] ; [2H]c1c([2H])c([2H])c(-c2c3ccccc3c(-c3cccc4oc5ccc(-c6ccc(-c7ccccc7)cc6)cc5c34)c3ccccc23)c([2H])c1[2H] ; [2H]c1c([2H])c([2H])c(-c2c3ccccc3c(-c3cccc4oc5cccc(-c6cc(-c7ccccc7)cc(-c7ccccc7)c6)c5c34)c3ccccc23)c([2H])c1[2H]]

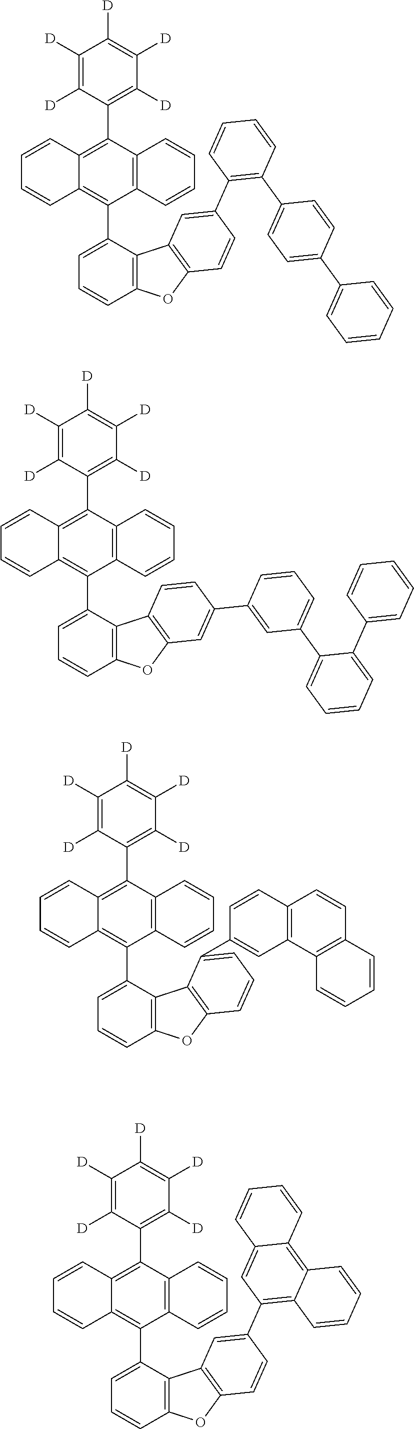 [SMILES: [2H]c1c([2H])c([2H])c(-c2c3ccccc3c(-c3cccc4oc5ccc(-c6ccccc6-c6ccc(-c7ccccc7)cc6)cc5c34)c3ccccc23)c([2H])c1[2H] ; [2H]c1c([2H])c([2H])c(-c2c3ccccc3c(-c3cccc4oc5cc(-c6cccc(-c7ccccc7-c7ccccc7)c6)ccc5c34)c3ccccc23)c([2H])c1[2H] ; [2H]c1c([2H])c([2H])c(-c2c3ccccc3c(-c3cccc4oc5cccc(-c6ccc7ccc8ccccc8c7c6)c5c34)c3ccccc23)c([2H])c1[2H] ; [2H]c1c([2H])c([2H])c(-c2c3ccccc3c(-c3cccc4oc5ccc(-c6cc7ccccc7c7ccccc67)cc5c34)c3ccccc23)c([2H])c1[2H]]

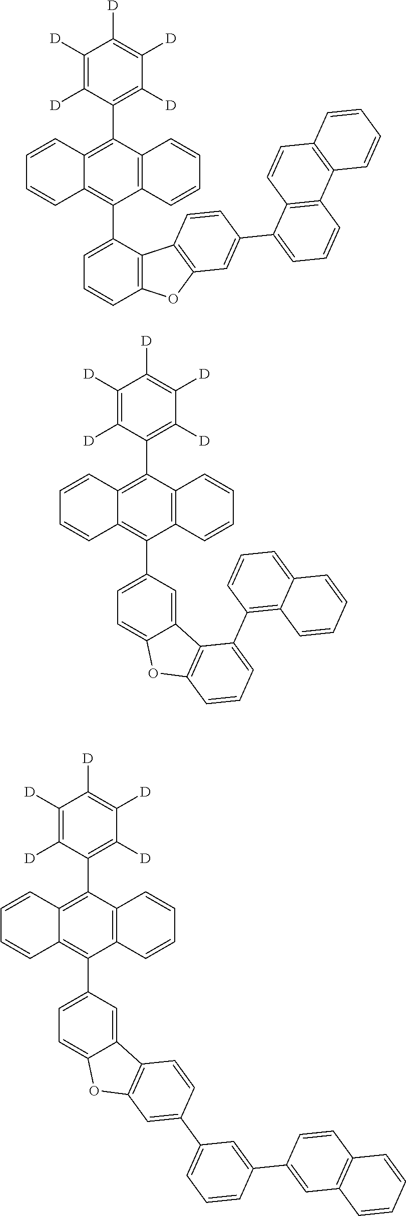 [SMILES: [2H]c1c([2H])c([2H])c(-c2c3ccccc3c(-c3cccc4oc5cc(-c6cccc7c6ccc6ccccc67)ccc5c34)c3ccccc23)c([2H])c1[2H] ; [2H]c1c([2H])c([2H])c(-c2c3ccccc3c(-c3ccc4oc5cccc(-c6cccc7ccccc67)c5c4c3)c3ccccc23)c([2H])c1[2H] ; [2H]c1c([2H])c([2H])c(-c2c3ccccc3c(-c3ccc4oc5cc(-c6cccc(-c7ccc8ccccc8c7)c6)ccc5c4c3)c3ccccc23)c([2H])c1[2H]]

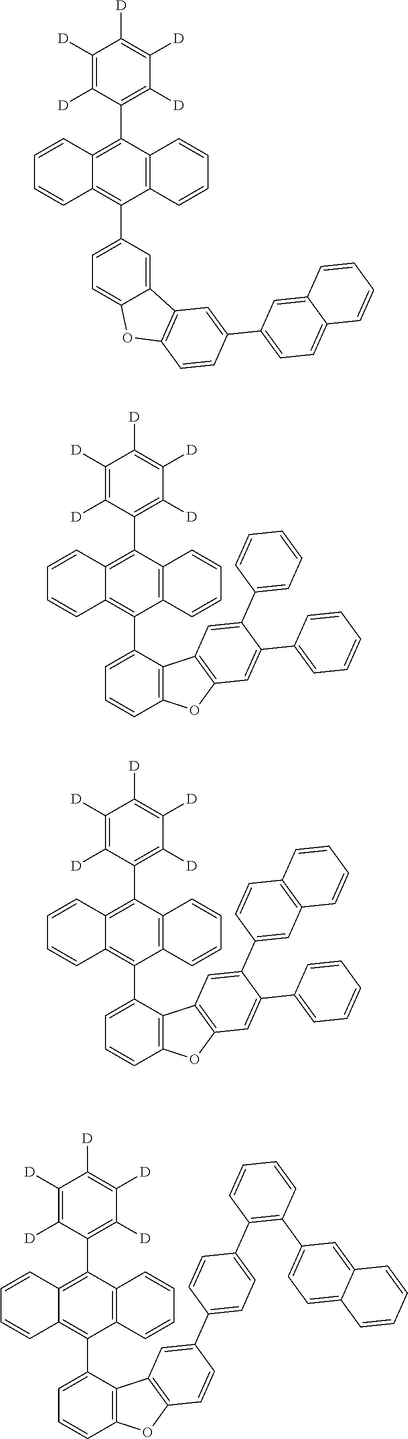 [SMILES: [2H]c1c([2H])c([2H])c(-c2c3ccccc3c(-c3ccc4oc5ccc(-c6ccc7ccccc7c6)cc5c4c3)c3ccccc23)c([2H])c1[2H] ; [2H]c1c([2H])c([2H])c(-c2c3ccccc3c(-c3cccc4oc5cc(-c6ccccc6)c(-c6ccccc6)cc5c34)c3ccccc23)c([2H])c1[2H] ; [2H]c1c([2H])c([2H])c(-c2c3ccccc3c(-c3cccc4oc5cc(-c6ccccc6)c(-c6ccc7ccccc7c6)cc5c34)c3ccccc23)c([2H])c1[2H] ; [2H]c1c([2H])c([2H])c(-c2c3ccccc3c(-c3cccc4oc5ccc(-c6ccc(-c7ccccc7-c7ccc8ccccc8c7)cc6)cc5c34)c3ccccc23)c([2H])c1[2H]]

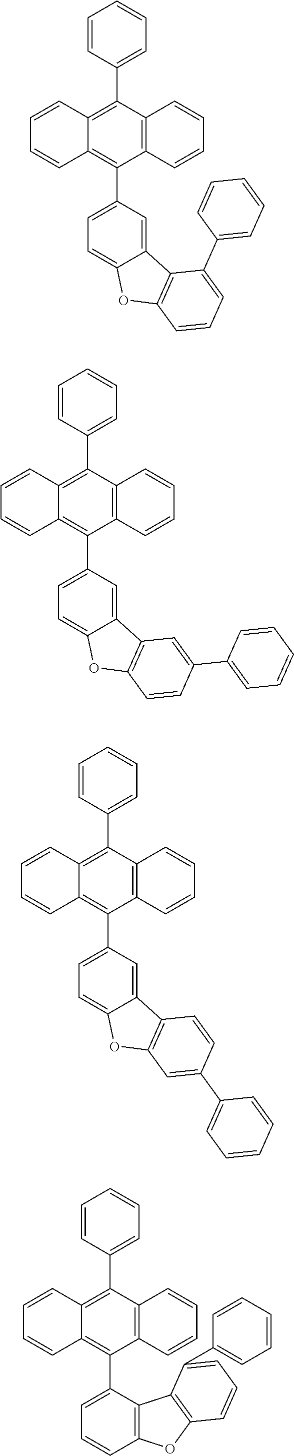 [SMILES: c1ccc(-c2c3ccccc3c(-c3ccc4oc5cccc(-c6ccccc6)c5c4c3)c3ccccc23)cc1 ; c1ccc(-c2ccc3oc4ccc(-c5c6ccccc6c(-c6ccccc6)c6ccccc56)cc4c3c2)cc1 ; c1ccc(-c2ccc3c(c2)oc2ccc(-c4c5ccccc5c(-c5ccccc5)c5ccccc45)cc23)cc1 ; c1ccc(-c2c3ccccc3c(-c3cccc4oc5cccc(-c6ccccc6)c5c34)c3ccccc23)cc1]

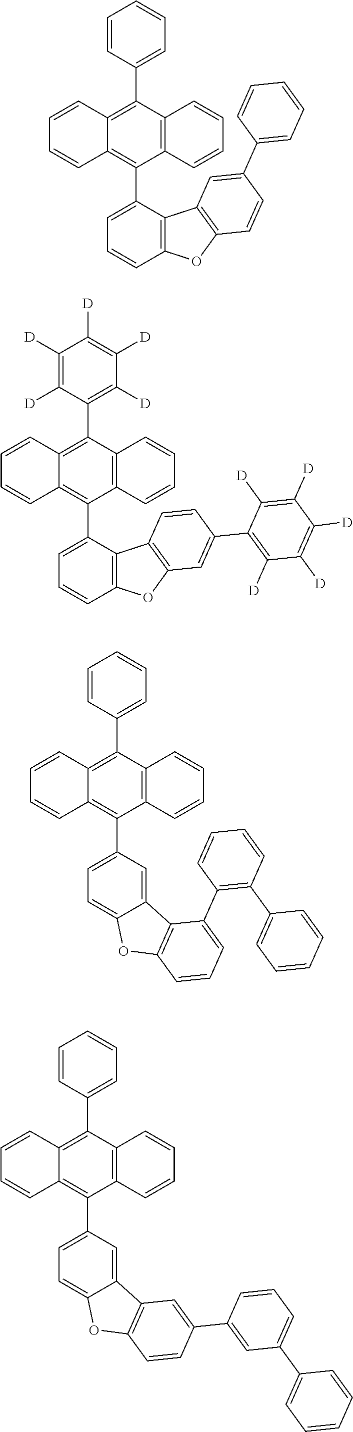 [SMILES: c1ccc(-c2ccc3oc4cccc(-c5c6ccccc6c(-c6ccccc6)c6ccccc56)c4c3c2)cc1 ; [2H]c1c([2H])c([2H])c(-c2ccc3c(c2)oc2cccc(-c4c5ccccc5c(-c5c([2H])c([2H])c([2H])c([2H])c5[2H])c5ccccc45)c23)c([2H])c1[2H] ; c1ccc(-c2ccccc2-c2cccc3oc4ccc(-c5c6ccccc6c(-c6ccccc6)c6ccccc56)cc4c23)cc1 ; c1ccc(-c2cccc(-c3ccc4oc5ccc(-c6c7ccccc7c(-c7ccccc7)c7ccccc67)cc5c4c3)c2)cc1]

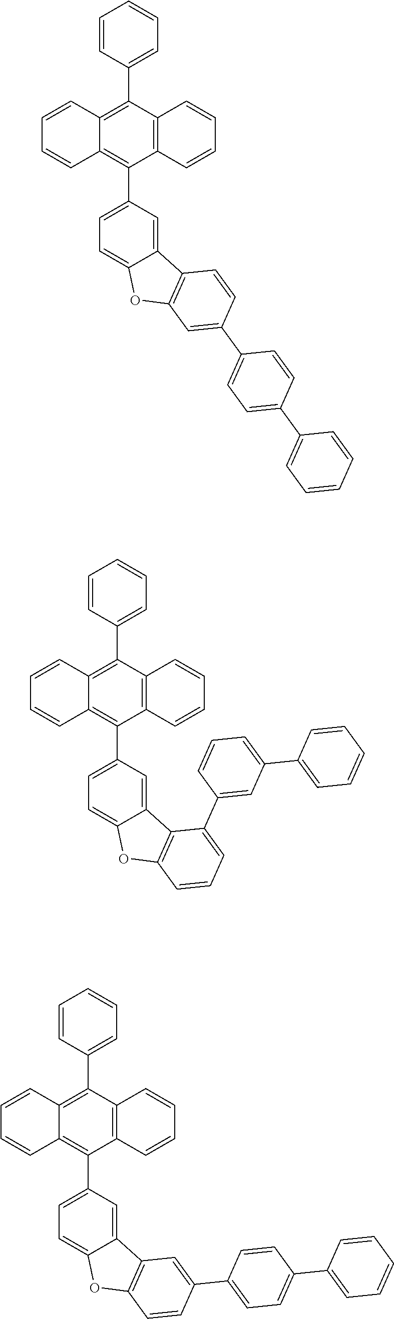 [SMILES: c1ccc(-c2ccc(-c3ccc4c(c3)oc3ccc(-c5c6ccccc6c(-c6ccccc6)c6ccccc56)cc34)cc2)cc1 ; c1ccc(-c2cccc(-c3cccc4oc5ccc(-c6c7ccccc7c(-c7ccccc7)c7ccccc67)cc5c34)c2)cc1 ; c1ccc(-c2ccc(-c3ccc4oc5ccc(-c6c7ccccc7c(-c7ccccc7)c7ccccc67)cc5c4c3)cc2)cc1]

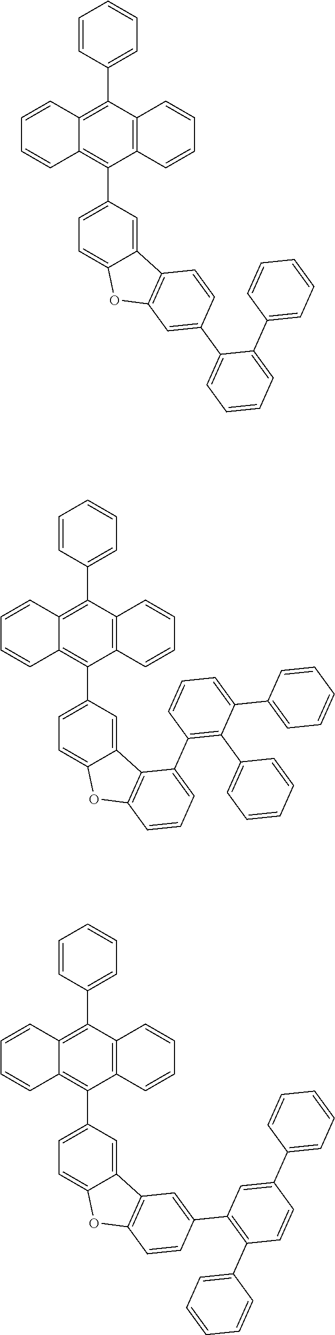 [SMILES: c1ccc(-c2ccccc2-c2ccc3c(c2)oc2ccc(-c4c5ccccc5c(-c5ccccc5)c5ccccc45)cc23)cc1 ; c1ccc(-c2cccc(-c3cccc4oc5ccc(-c6c7ccccc7c(-c7ccccc7)c7ccccc67)cc5c34)c2-c2ccccc2)cc1 ; c1ccc(-c2ccc(-c3ccccc3)c(-c3ccc4oc5ccc(-c6c7ccccc7c(-c7ccccc7)c7ccccc67)cc5c4c3)c2)cc1]

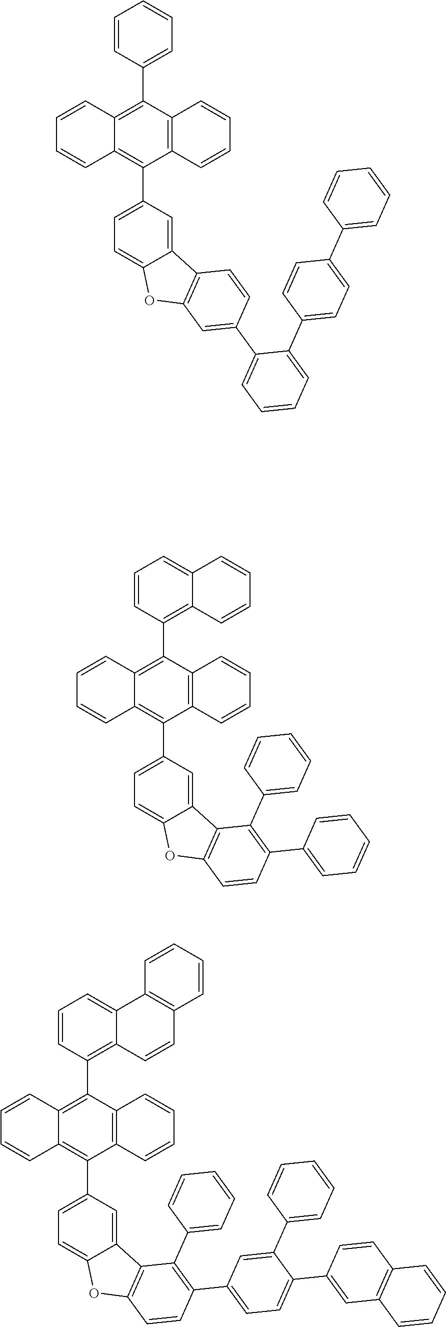 [SMILES: c1ccc(-c2ccc(-c3ccccc3-c3ccc4c(c3)oc3ccc(-c5c6ccccc6c(-c6ccccc6)c6ccccc56)cc34)cc2)cc1 ; c1ccc(-c2ccc3oc4ccc(-c5c6ccccc6c(-c6cccc7ccccc67)c6ccccc56)cc4c3c2-c2ccccc2)cc1 ; c1ccc(-c2cc(-c3ccc4oc5ccc(-c6c7ccccc7c(-c7cccc8c7ccc7ccccc78)c7ccccc67)cc5c4c3-c3ccccc3)ccc2-c2ccc3ccccc3c2)cc1]

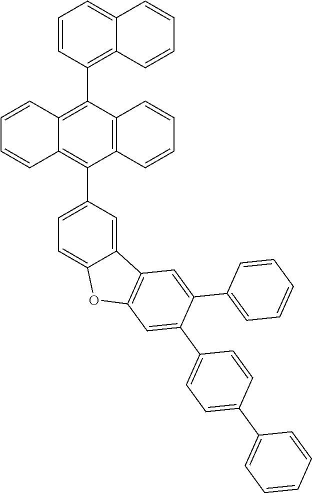 [SMILES: c1ccc(-c2ccc(-c3cc4oc5ccc(-c6c7ccccc7c(-c7cccc8ccccc78)c7ccccc67)cc5c4cc3-c3ccccc3)cc2)cc1]

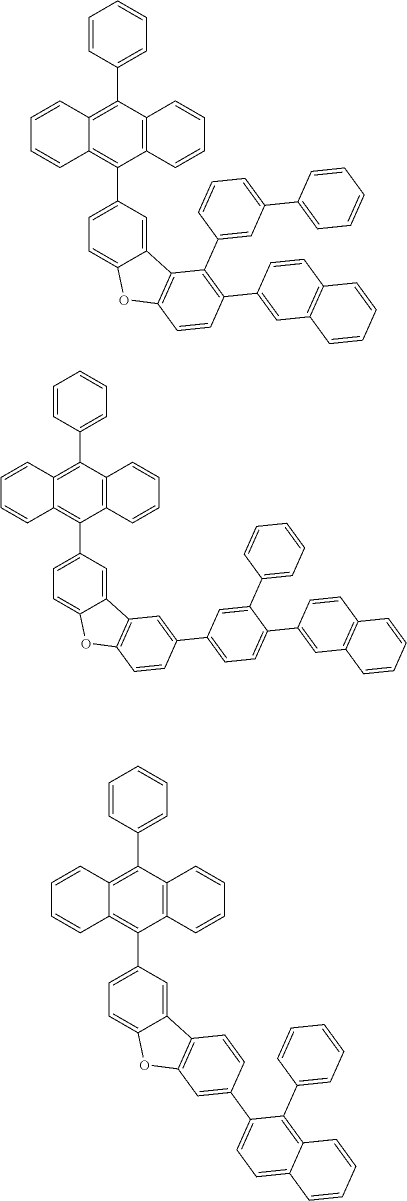 [SMILES: c1ccc(-c2cccc(-c3c(-c4ccc5ccccc5c4)ccc4oc5ccc(-c6c7ccccc7c(-c7ccccc7)c7ccccc67)cc5c34)c2)cc1 ; c1ccc(-c2cc(-c3ccc4oc5ccc(-c6c7ccccc7c(-c7ccccc7)c7ccccc67)cc5c4c3)ccc2-c2ccc3ccccc3c2)cc1 ; c1ccc(-c2c(-c3ccc4c(c3)oc3ccc(-c5c6ccccc6c(-c6ccccc6)c6ccccc56)cc34)ccc3ccccc23)cc1]

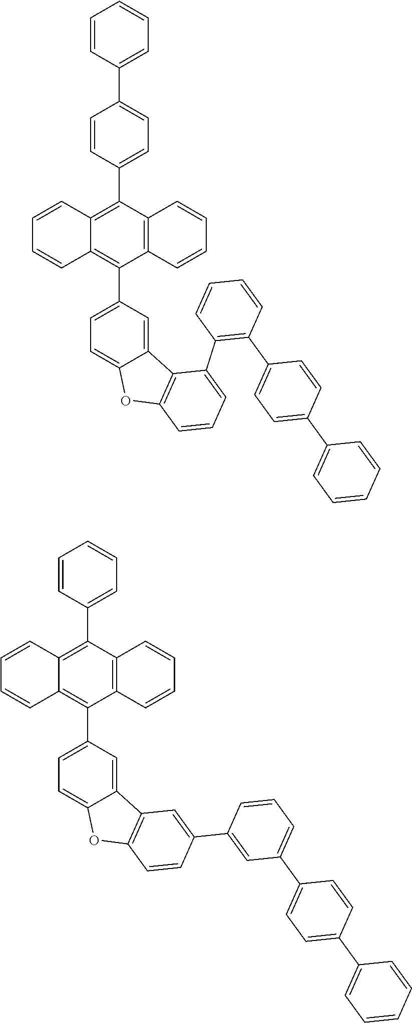 [SMILES: c1ccc(-c2ccc(-c3ccccc3-c3cccc4oc5ccc(-c6c7ccccc7c(-c7ccc(-c8ccccc8)cc7)c7ccccc67)cc5c34)cc2)cc1 ; c1ccc(-c2ccc(-c3cccc(-c4ccc5oc6ccc(-c7c8ccccc8c(-c8ccccc8)c8ccccc78)cc6c5c4)c3)cc2)cc1]

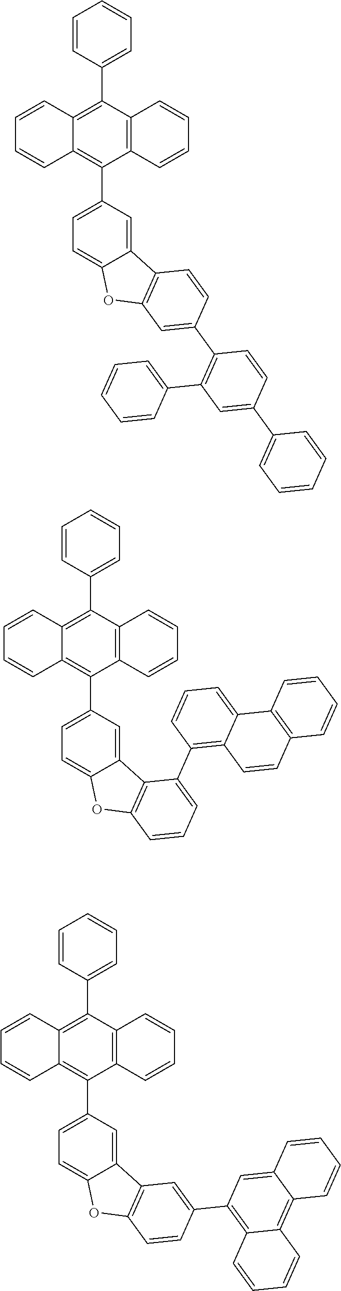 [SMILES: c1ccc(-c2ccc(-c3ccc4c(c3)oc3ccc(-c5c6ccccc6c(-c6ccccc6)c6ccccc56)cc34)c(-c3ccccc3)c2)cc1 ; c1ccc(-c2c3ccccc3c(-c3ccc4oc5cccc(-c6cccc7c6ccc6ccccc67)c5c4c3)c3ccccc23)cc1 ; c1ccc(-c2c3ccccc3c(-c3ccc4oc5ccc(-c6cc7ccccc7c7ccccc67)cc5c4c3)c3ccccc23)cc1]

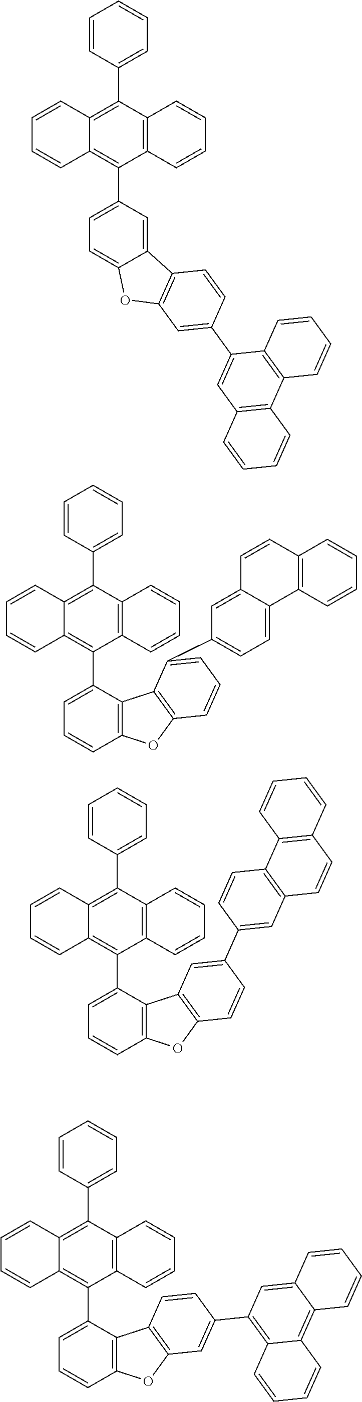

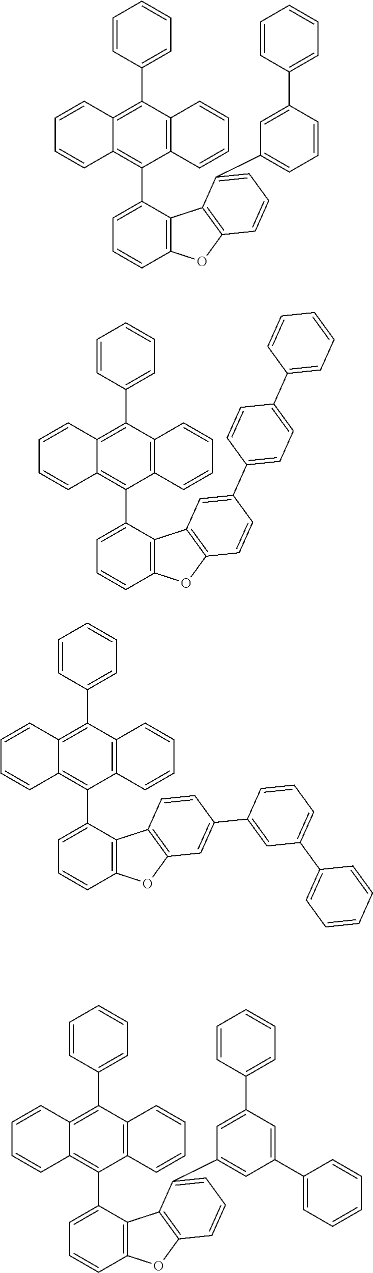 [SMILES: c1ccc(-c2cccc(-c3cccc4oc5cccc(-c6c7ccccc7c(-c7ccccc7)c7ccccc67)c5c34)c2)cc1 ; c1ccc(-c2ccc(-c3ccc4oc5cccc(-c6c7ccccc7c(-c7ccccc7)c7ccccc67)c5c4c3)cc2)cc1 ; c1ccc(-c2cccc(-c3ccc4c(c3)oc3cccc(-c5c6ccccc6c(-c6ccccc6)c6ccccc56)c34)c2)cc1 ; c1ccc(-c2cc(-c3ccccc3)cc(-c3cccc4oc5cccc(-c6c7ccccc7c(-c7ccccc7)c7ccccc67)c5c34)c2)cc1]

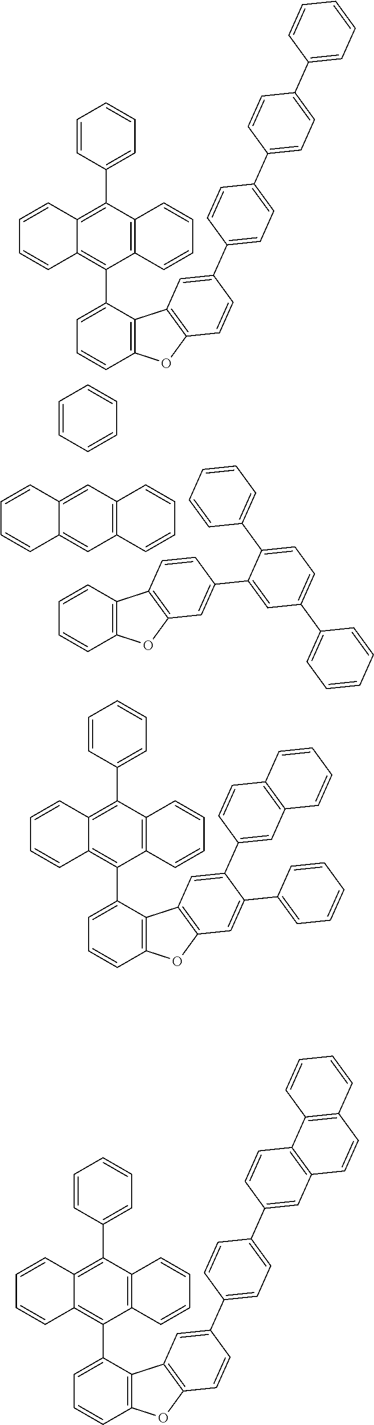

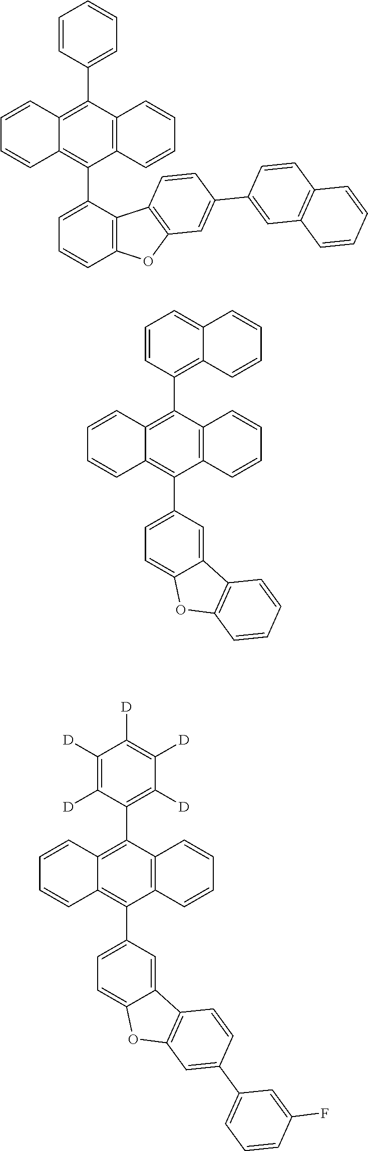 [SMILES: c1ccc(-c2c3ccccc3c(-c3cccc4oc5cc(-c6ccc7ccccc7c6)ccc5c34)c3ccccc23)cc1 ; c1ccc2c(-c3c4ccccc4c(-c4ccc5oc6ccccc6c5c4)c4ccccc34)cccc2c1 ; [2H]c1c([2H])c([2H])c(-c2c3ccccc3c(-c3ccc4oc5cc(-c6cccc(F)c6)ccc5c4c3)c3ccccc23)c([2H])c1[2H]]

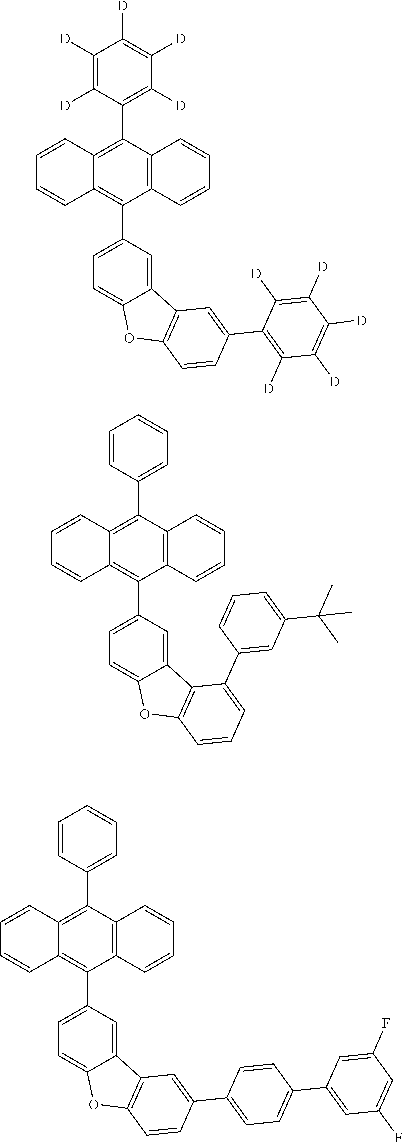 [SMILES: [2H]c1c([2H])c([2H])c(-c2ccc3oc4ccc(-c5c6ccccc6c(-c6c([2H])c([2H])c([2H])c([2H])c6[2H])c6ccccc56)cc4c3c2)c([2H])c1[2H] ; CC(C)(C)c1cccc(-c2cccc3oc4ccc(-c5c6ccccc6c(-c6ccccc6)c6ccccc56)cc4c23)c1 ; Fc1cc(F)cc(-c2ccc(-c3ccc4oc5ccc(-c6c7ccccc7c(-c7ccccc7)c7ccccc67)cc5c4c3)cc2)c1]

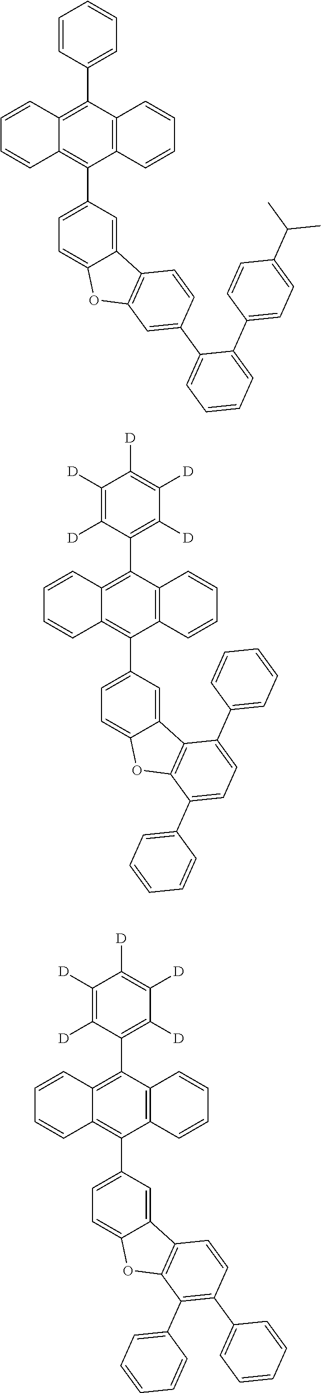 [SMILES: CC(C)c1ccc(-c2ccccc2-c2ccc3c(c2)oc2ccc(-c4c5ccccc5c(-c5ccccc5)c5ccccc45)cc23)cc1 ; [2H]c1c([2H])c([2H])c(-c2c3ccccc3c(-c3ccc4oc5c(-c6ccccc6)ccc(-c6ccccc6)c5c4c3)c3ccccc23)c([2H])c1[2H] ; [2H]c1c([2H])c([2H])c(-c2c3ccccc3c(-c3ccc4oc5c(-c6ccccc6)c(-c6ccccc6)ccc5c4c3)c3ccccc23)c([2H])c1[2H]]

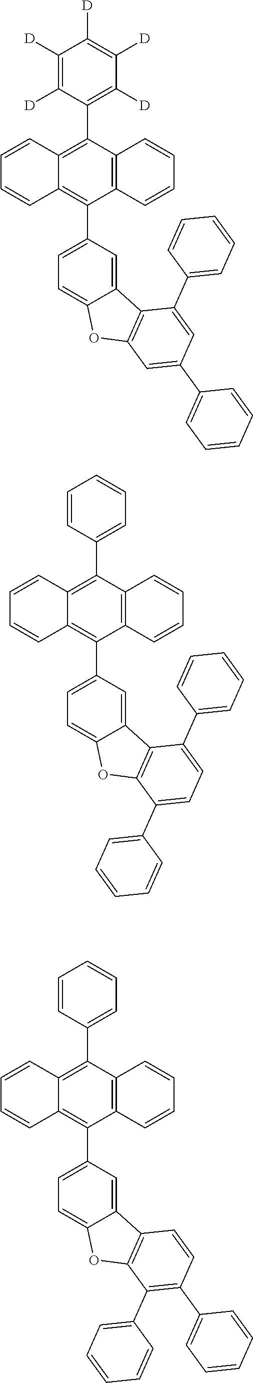 [SMILES: [2H]c1c([2H])c([2H])c(-c2c3ccccc3c(-c3ccc4oc5cc(-c6ccccc6)cc(-c6ccccc6)c5c4c3)c3ccccc23)c([2H])c1[2H] ; c1ccc(-c2c3ccccc3c(-c3ccc4oc5c(-c6ccccc6)ccc(-c6ccccc6)c5c4c3)c3ccccc23)cc1 ; c1ccc(-c2ccc3c(oc4ccc(-c5c6ccccc6c(-c6ccccc6)c6ccccc56)cc43)c2-c2ccccc2)cc1]

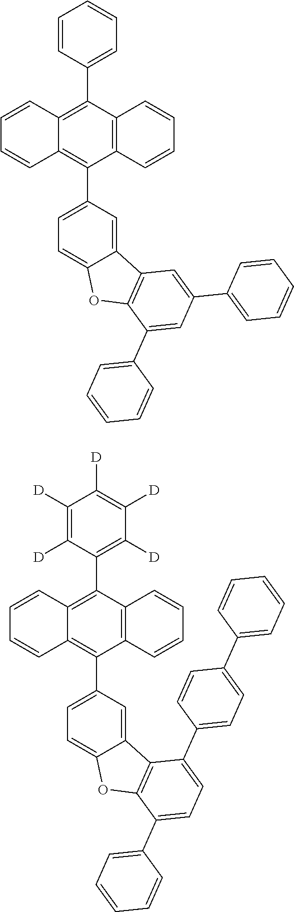

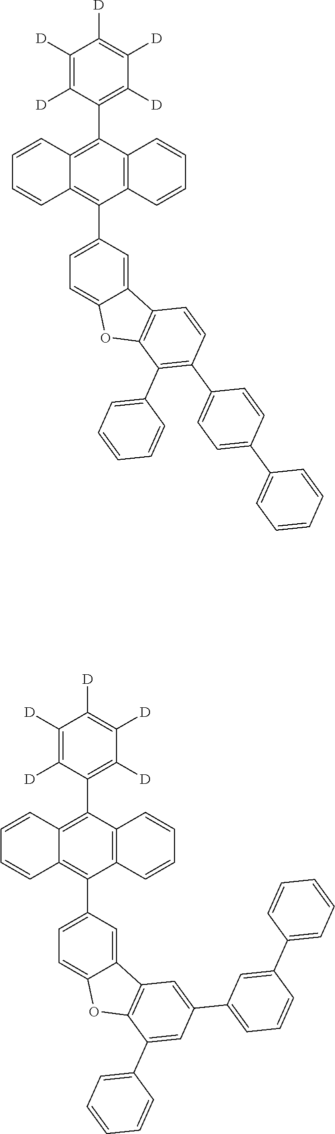 [SMILES: [2H]c1c([2H])c([2H])c(-c2c3ccccc3c(-c3ccc4oc5c(-c6ccccc6)c(-c6ccc(-c7ccccc7)cc6)ccc5c4c3)c3ccccc23)c([2H])c1[2H] ; [2H]c1c([2H])c([2H])c(-c2c3ccccc3c(-c3ccc4oc5c(-c6ccccc6)cc(-c6cccc(-c7ccccc7)c6)cc5c4c3)c3ccccc23)c([2H])c1[2H]]

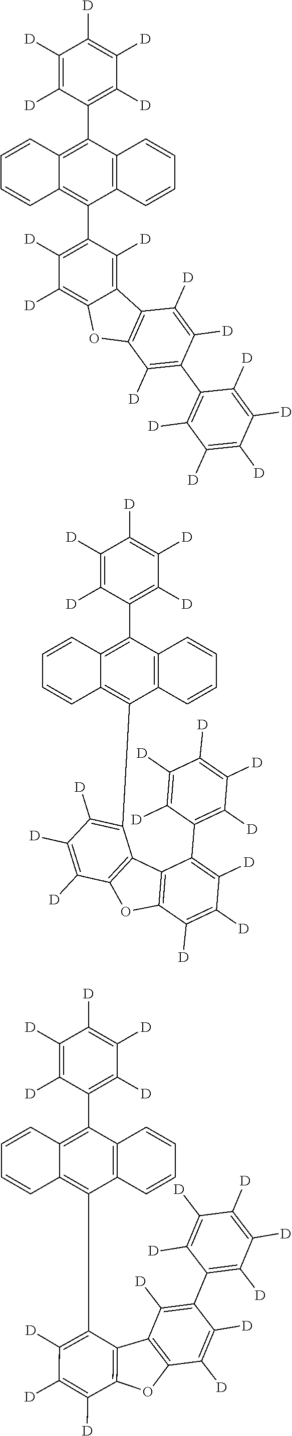 [SMILES: [2H]c1c([2H])c([2H])c(-c2c([2H])c([2H])c3c(oc4c([2H])c([2H])c(-c5c6ccccc6c(-c6c([2H])c([2H])c([2H])c([2H])c6[2H])c6ccccc56)c([2H])c43)c2[2H])c([2H])c1[2H] ; [2H]c1c([2H])c([2H])c(-c2c3ccccc3c(-c3c([2H])c([2H])c([2H])c4oc5c([2H])c([2H])c([2H])c(-c6c([2H])c([2H])c([2H])c([2H])c6[2H])c5c34)c3ccccc23)c([2H])c1[2H] ; [2H]c1c([2H])c([2H])c(-c2c([2H])c([2H])c3oc4c([2H])c([2H])c([2H])c(-c5c6ccccc6c(-c6c([2H])c([2H])c([2H])c([2H])c6[2H])c6ccccc56)c4c3c2[2H])c([2H])c1[2H]]

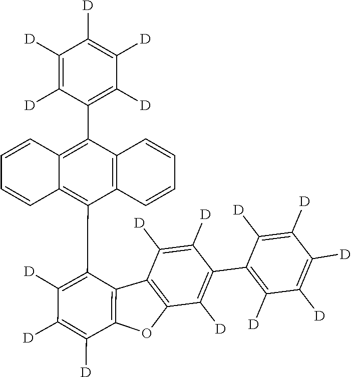 [SMILES: [2H]c1c([2H])c([2H])c(-c2c([2H])c([2H])c3c(oc4c([2H])c([2H])c([2H])c(-c5c6ccccc6c(-c6c([2H])c([2H])c([2H])c([2H])c6[2H])c6ccccc56)c43)c2[2H])c([2H])c1[2H]]

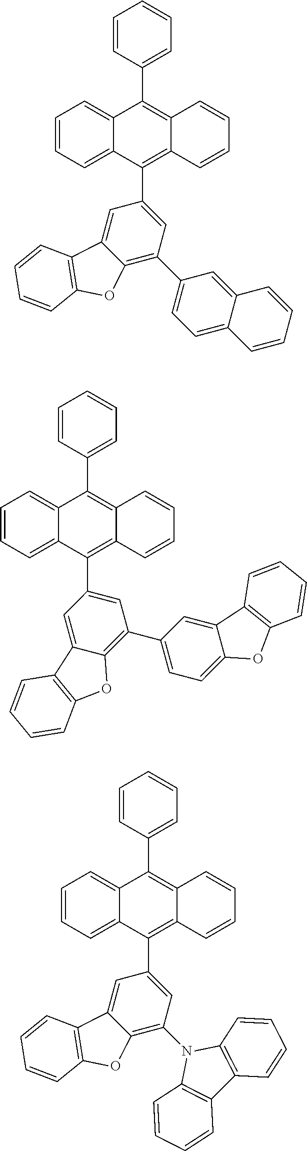 [SMILES: c1ccc(-c2c3ccccc3c(-c3cc(-c4ccc5ccccc5c4)c4oc5ccccc5c4c3)c3ccccc23)cc1 ; c1ccc(-c2c3ccccc3c(-c3cc(-c4ccc5oc6ccccc6c5c4)c4oc5ccccc5c4c3)c3ccccc23)cc1 ; c1ccc(-c2c3ccccc3c(-c3cc(-n4c5ccccc5c5ccccc54)c4oc5ccccc5c4c3)c3ccccc23)cc1]

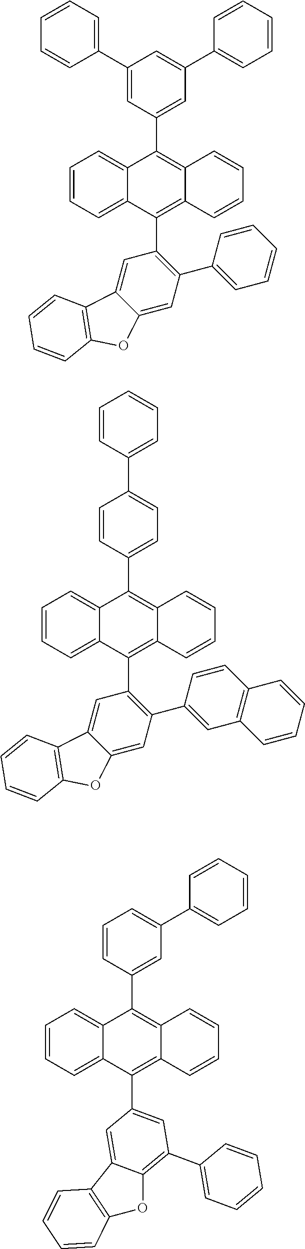

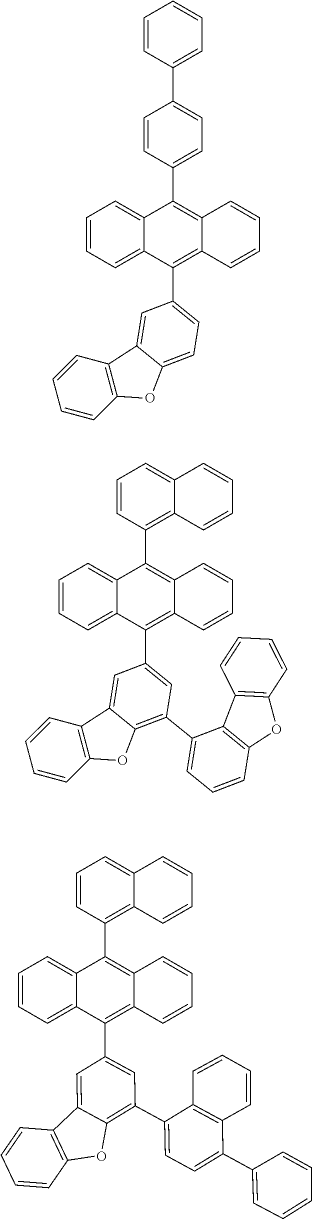 [SMILES: c1ccc(-c2ccc(-c3c4ccccc4c(-c4ccc5oc6ccccc6c5c4)c4ccccc34)cc2)cc1 ; c1ccc2c(-c3c4ccccc4c(-c4cc(-c5cccc6oc7ccccc7c56)c5oc6ccccc6c5c4)c4ccccc34)cccc2c1 ; c1ccc(-c2ccc(-c3cc(-c4c5ccccc5c(-c5cccc6ccccc56)c5ccccc45)cc4c3oc3ccccc34)c3ccccc23)cc1]

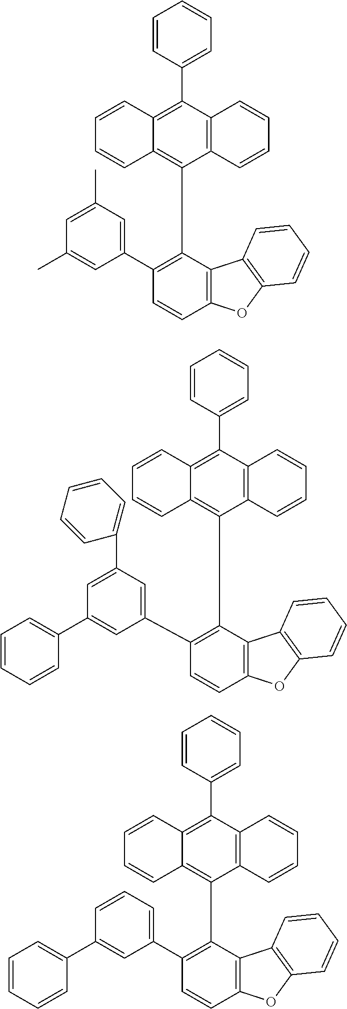

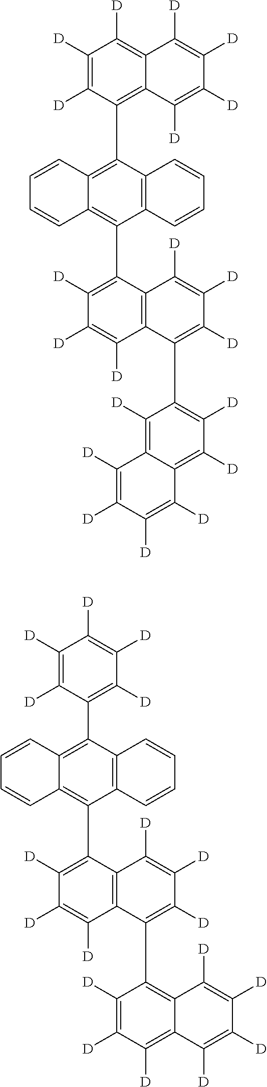 [SMILES: [2H]c1c([2H])c([2H])c2c([2H])c(-c3c([2H])c([2H])c([2H])c4c(-c5c6ccccc6c(-c6c([2H])c([2H])c([2H])c7c([2H])c([2H])c([2H])c([2H])c67)c6ccccc56)c([2H])c([2H])c([2H])c34)c([2H])c([2H])c2c1[2H] ; [2H]c1c([2H])c([2H])c(-c2c3ccccc3c(-c3c([2H])c([2H])c([2H])c4c(-c5c([2H])c([2H])c([2H])c6c([2H])c([2H])c([2H])c([2H])c56)c([2H])c([2H])c([2H])c34)c3ccccc23)c([2H])c1[2H]]

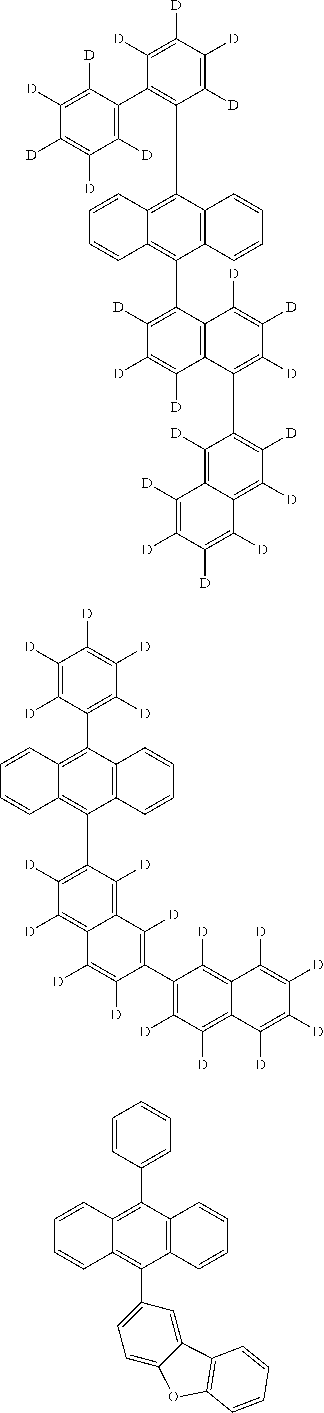 [SMILES: [2H]c1c([2H])c([2H])c(-c2c([2H])c([2H])c([2H])c([2H])c2-c2c3ccccc3c(-c3c([2H])c([2H])c([2H])c4c(-c5c([2H])c([2H])c6c([2H])c([2H])c([2H])c([2H])c6c5[2H])c([2H])c([2H])c([2H])c34)c3ccccc23)c([2H])c1[2H] ; [2H]c1c([2H])c([2H])c(-c2c3ccccc3c(-c3c([2H])c([2H])c4c([2H])c([2H])c(-c5c([2H])c([2H])c6c([2H])c([2H])c([2H])c([2H])c6c5[2H])c([2H])c4c3[2H])c3ccccc23)c([2H])c1[2H] ; c1ccc(-c2c3ccccc3c(-c3ccc4oc5ccccc5c4c3)c3ccccc23)cc1]

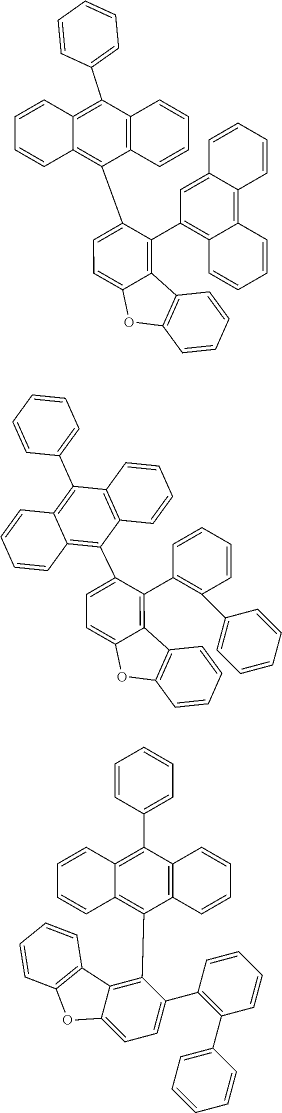 [SMILES: c1ccc(-c2c3ccccc3c(-c3ccc4oc5ccccc5c4c3-c3cc4ccccc4c4ccccc34)c3ccccc23)cc1 ; c1ccc(-c2ccccc2-c2c(-c3c4ccccc4c(-c4ccccc4)c4ccccc34)ccc3oc4ccccc4c23)cc1 ; c1ccc(-c2ccccc2-c2ccc3oc4ccccc4c3c2-c2c3ccccc3c(-c3ccccc3)c3ccccc23)cc1]

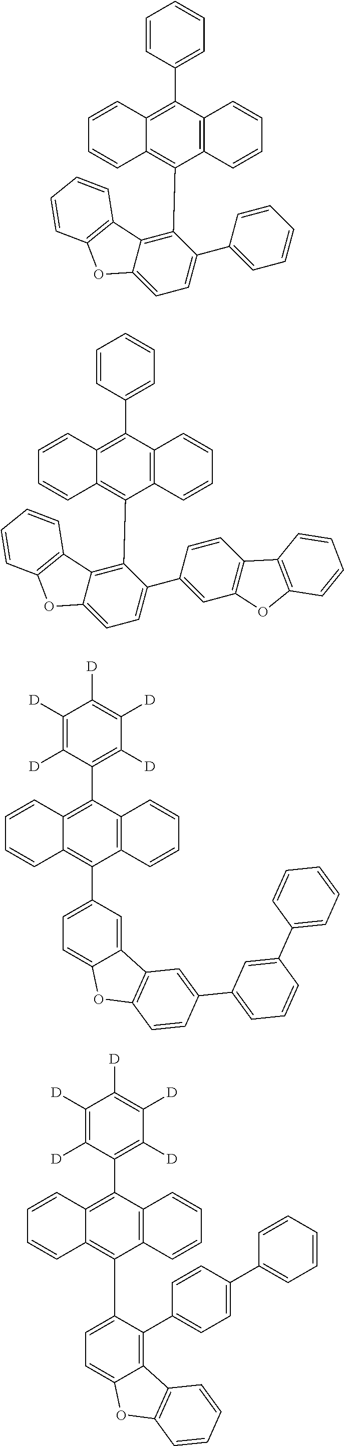

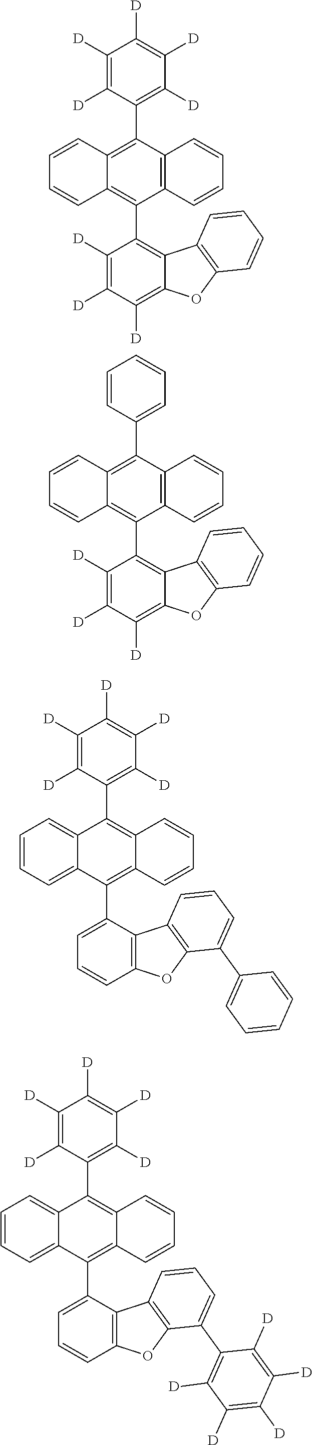

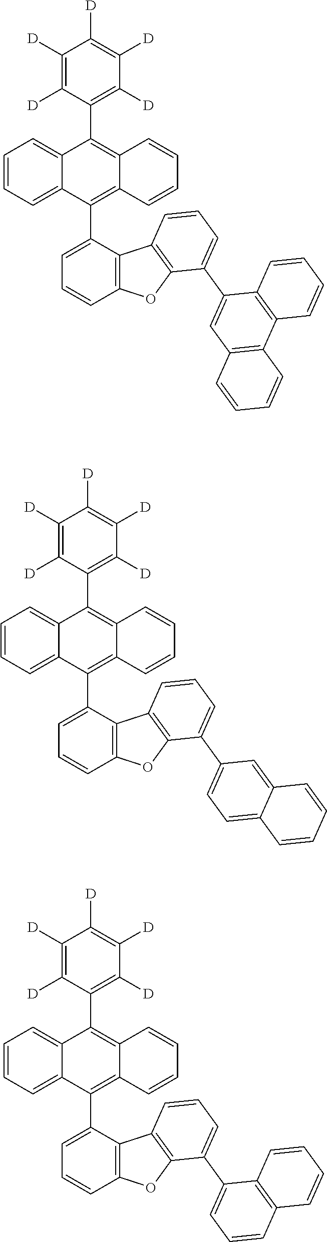 [SMILES: [2H]c1c([2H])c([2H])c(-c2c3ccccc3c(-c3cccc4oc5c(-c6cc7ccccc7c7ccccc67)cccc5c34)c3ccccc23)c([2H])c1[2H] ; [2H]c1c([2H])c([2H])c(-c2c3ccccc3c(-c3cccc4oc5c(-c6ccc7ccccc7c6)cccc5c34)c3ccccc23)c([2H])c1[2H] ; [2H]c1c([2H])c([2H])c(-c2c3ccccc3c(-c3cccc4oc5c(-c6cccc7ccccc67)cccc5c34)c3ccccc23)c([2H])c1[2H]]

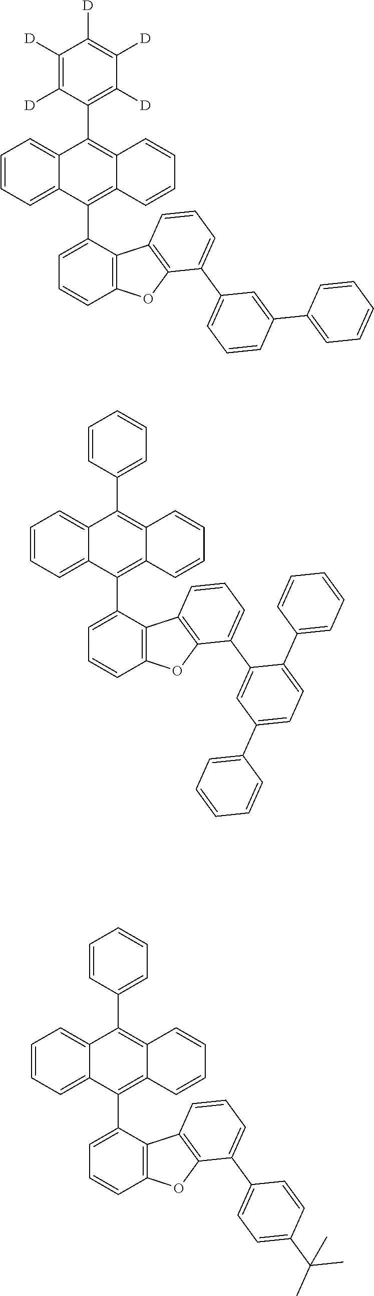 [SMILES: [2H]c1c([2H])c([2H])c(-c2c3ccccc3c(-c3cccc4oc5c(-c6cccc(-c7ccccc7)c6)cccc5c34)c3ccccc23)c([2H])c1[2H] ; c1ccc(-c2ccc(-c3ccccc3)c(-c3cccc4c3oc3cccc(-c5c6ccccc6c(-c6ccccc6)c6ccccc56)c34)c2)cc1 ; CC(C)(C)c1ccc(-c2cccc3c2oc2cccc(-c4c5ccccc5c(-c5ccccc5)c5ccccc45)c23)cc1]

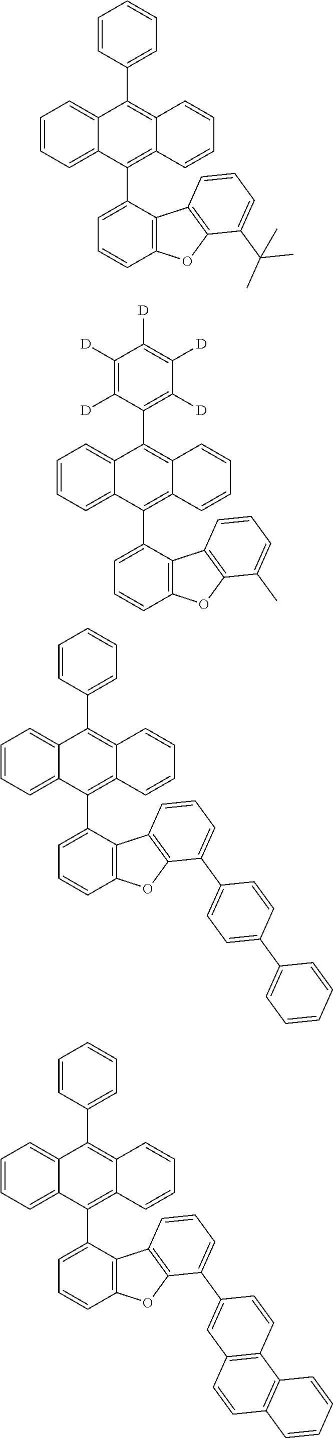

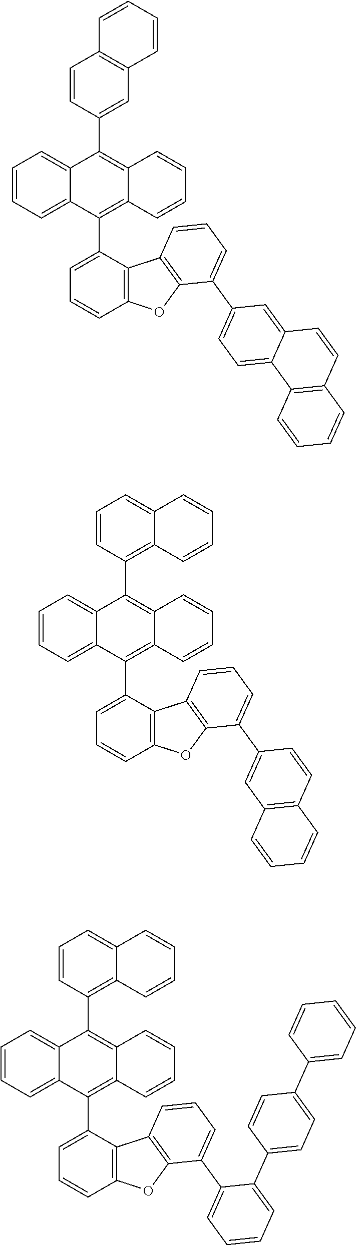 [SMILES: c1ccc2cc(-c3c4ccccc4c(-c4cccc5oc6c(-c7ccc8c(ccc9ccccc98)c7)cccc6c45)c4ccccc34)ccc2c1 ; c1ccc2cc(-c3cccc4c3oc3cccc(-c5c6ccccc6c(-c6cccc7ccccc67)c6ccccc56)c34)ccc2c1 ; c1ccc(-c2ccc(-c3ccccc3-c3cccc4c3oc3cccc(-c5c6ccccc6c(-c6cccc7ccccc67)c6ccccc56)c34)cc2)cc1]

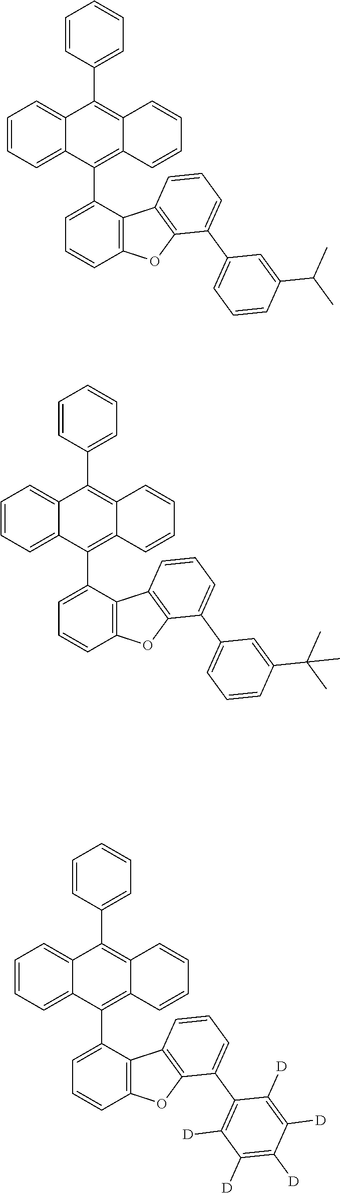 [SMILES: CC(C)c1cccc(-c2cccc3c2oc2cccc(-c4c5ccccc5c(-c5ccccc5)c5ccccc45)c23)c1 ; CC(C)(C)c1cccc(-c2cccc3c2oc2cccc(-c4c5ccccc5c(-c5ccccc5)c5ccccc45)c23)c1 ; [2H]c1c([2H])c([2H])c(-c2cccc3c2oc2cccc(-c4c5ccccc5c(-c5ccccc5)c5ccccc45)c23)c([2H])c1[2H]]

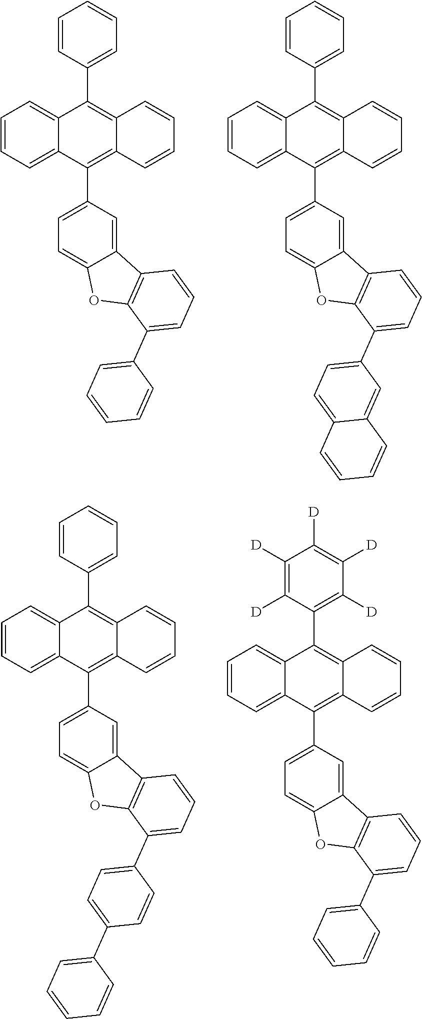

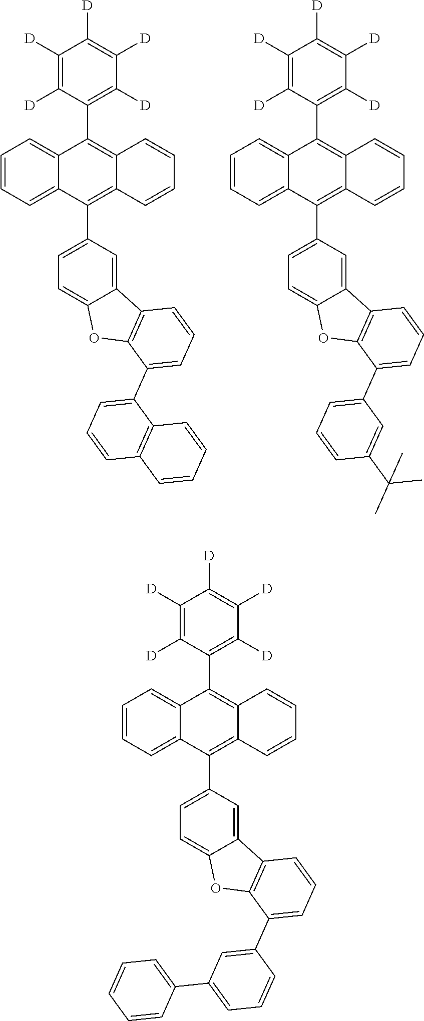 [SMILES: [2H]c1c([2H])c([2H])c(-c2c3ccccc3c(-c3ccc4oc5c(-c6cccc7ccccc67)cccc5c4c3)c3ccccc23)c([2H])c1[2H] ; [2H]c1c([2H])c([2H])c(-c2c3ccccc3c(-c3ccc4oc5c(-c6cccc(C(C)(C)C)c6)cccc5c4c3)c3ccccc23)c([2H])c1[2H] ; [2H]c1c([2H])c([2H])c(-c2c3ccccc3c(-c3ccc4oc5c(-c6cccc(-c7ccccc7)c6)cccc5c4c3)c3ccccc23)c([2H])c1[2H]]

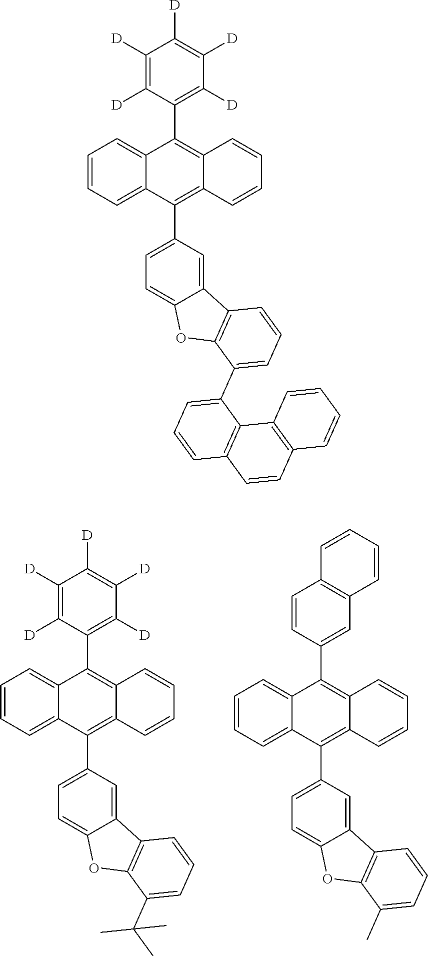 [SMILES: [2H]c1c([2H])c([2H])c(-c2c3ccccc3c(-c3ccc4oc5c(-c6cccc7ccc8ccccc8c67)cccc5c4c3)c3ccccc23)c([2H])c1[2H] ; [2H]c1c([2H])c([2H])c(-c2c3ccccc3c(-c3ccc4oc5c(C(C)(C)C)cccc5c4c3)c3ccccc23)c([2H])c1[2H] ; Cc1cccc2c1oc1ccc(-c3c4ccccc4c(-c4ccc5ccccc5c4)c4ccccc34)cc12]

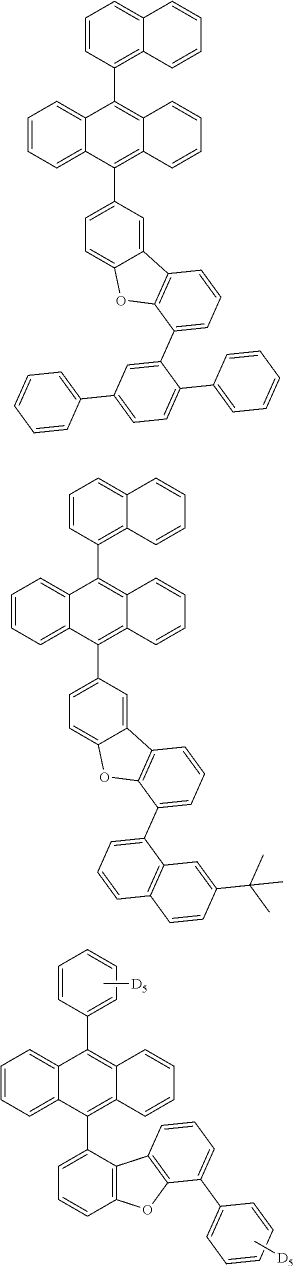

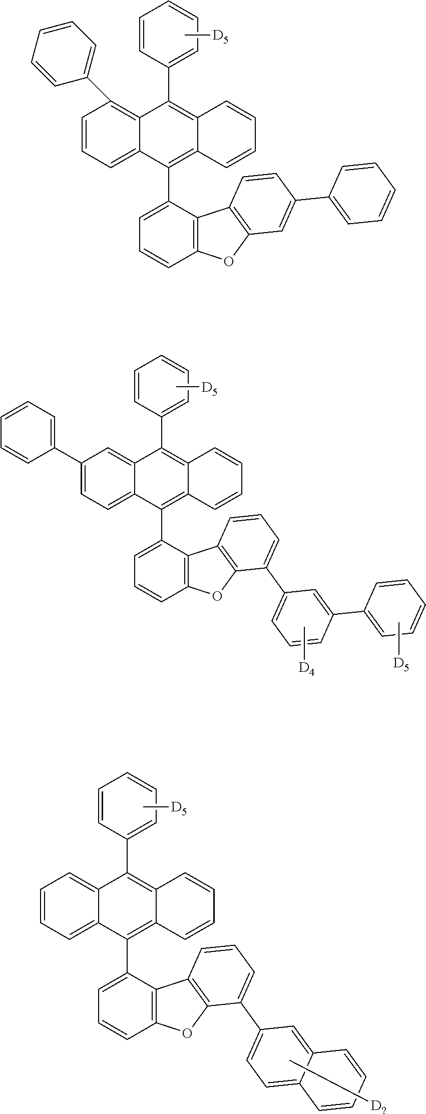

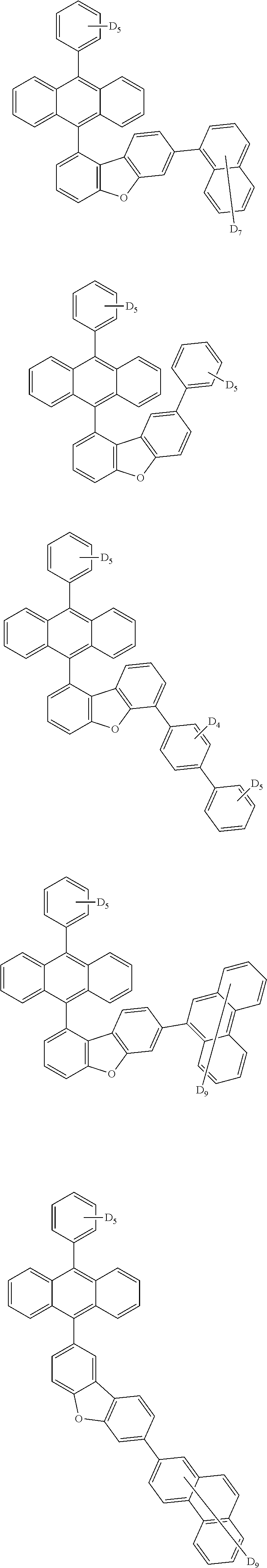

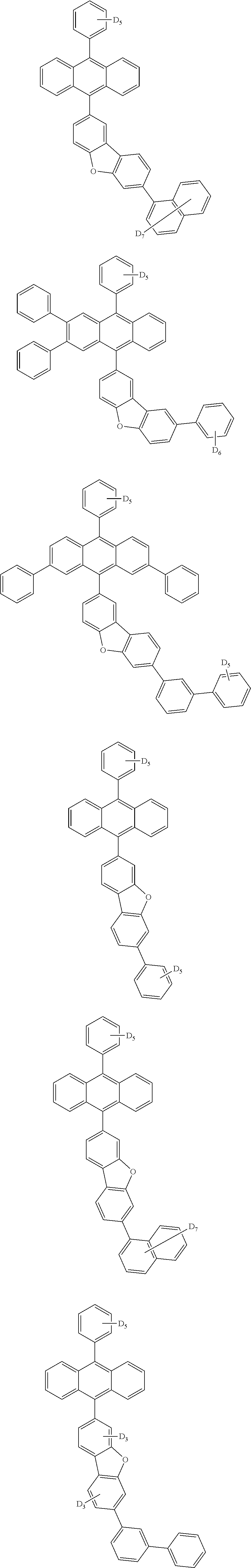

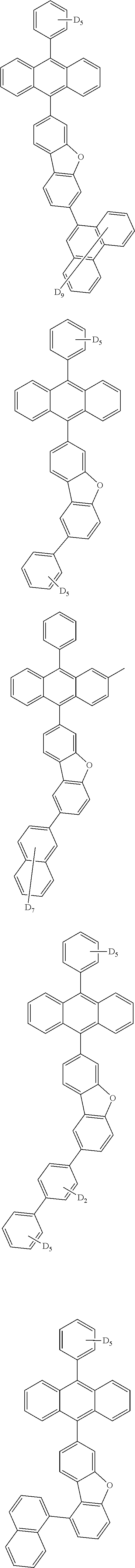

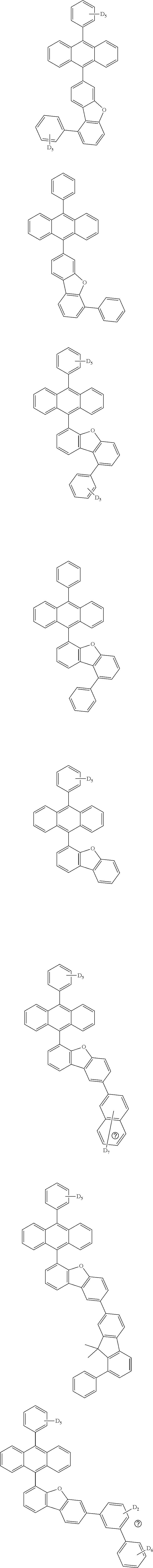

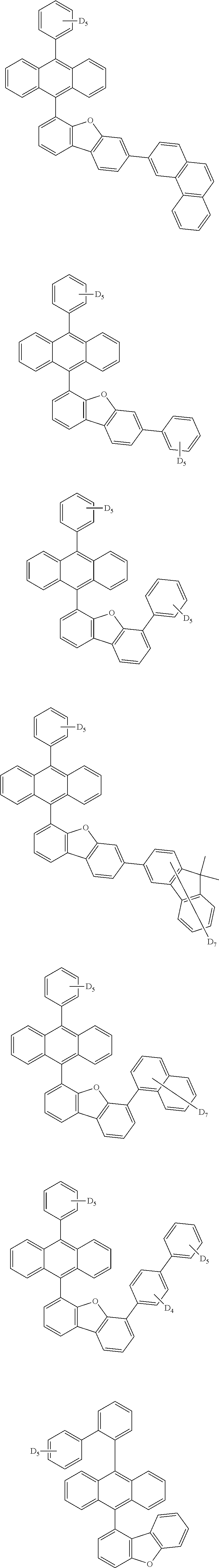

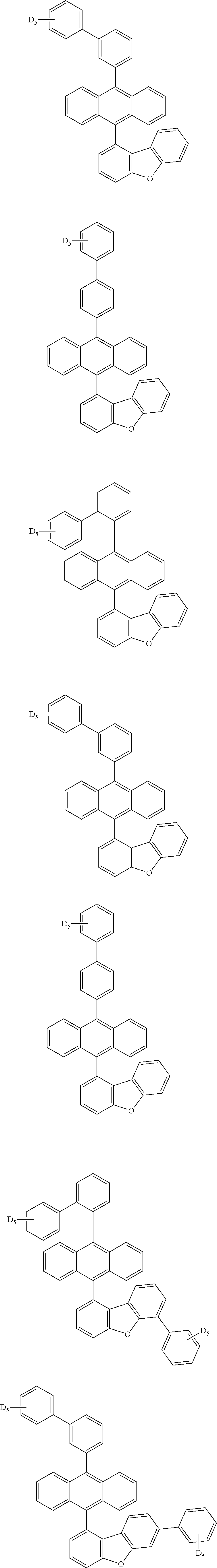

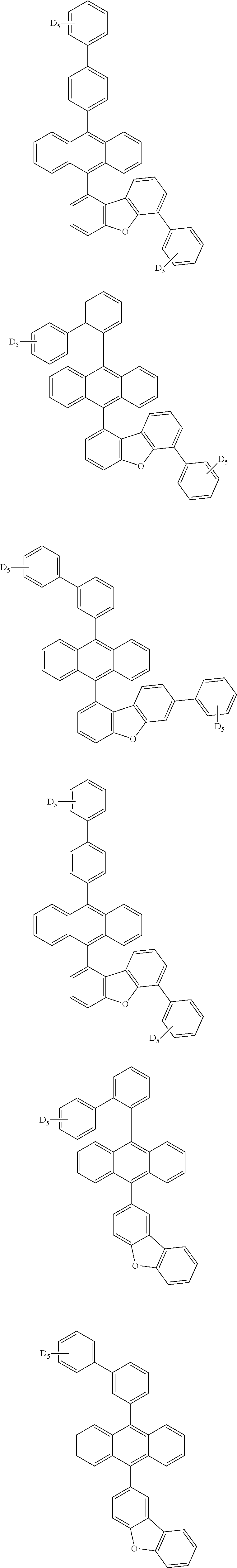

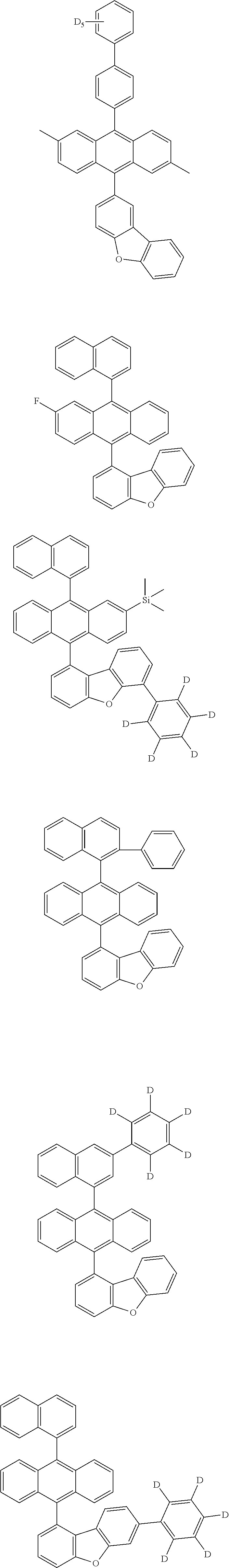

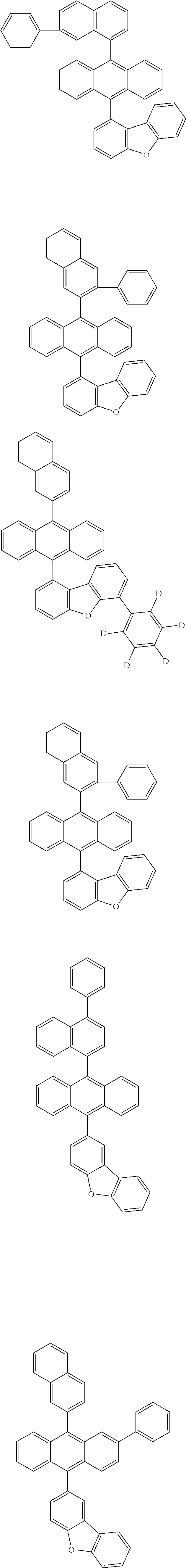 [SMILES: c1ccc(-c2ccc3cccc(-c4c5ccccc5c(-c5cccc6oc7ccccc7c56)c5ccccc45)c3c2)cc1 ; c1ccc(-c2cc3ccccc3cc2-c2c3ccccc3c(-c3cccc4oc5ccccc5c34)c3ccccc23)cc1 ; [2H]c1c([2H])c([2H])c(-c2cccc3c2oc2cccc(-c4c5ccccc5c(-c5ccc6ccccc6c5)c5ccccc45)c23)c([2H])c1[2H] ; c1ccc(-c2cc3ccccc3cc2-c2c3ccccc3c(-c3cccc4oc5ccccc5c34)c3ccccc23)cc1 ; c1ccc(-c2ccc(-c3c4ccccc4c(-c4ccc5oc6ccccc6c5c4)c4ccccc34)c3ccccc23)cc1 ; c1ccc(-c2ccc3c(-c4ccc5oc6ccccc6c5c4)c4ccccc4c(-c4ccc5ccccc5c4)c3c2)cc1]

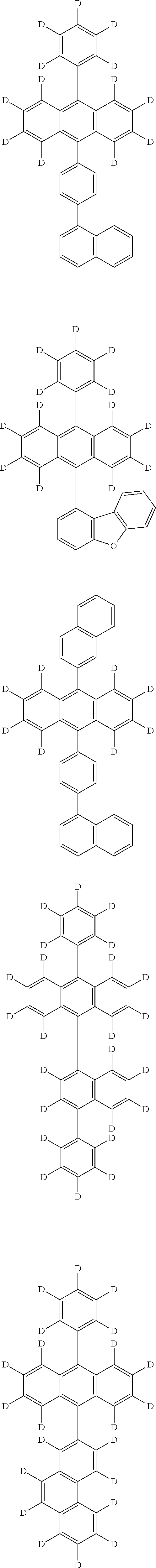

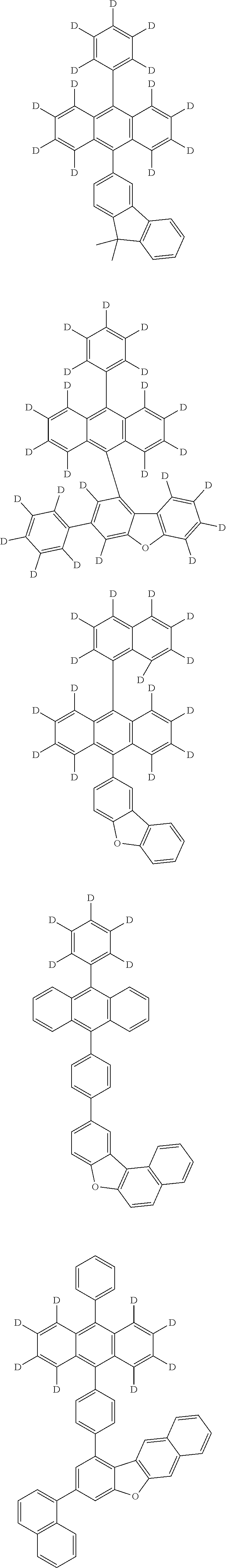

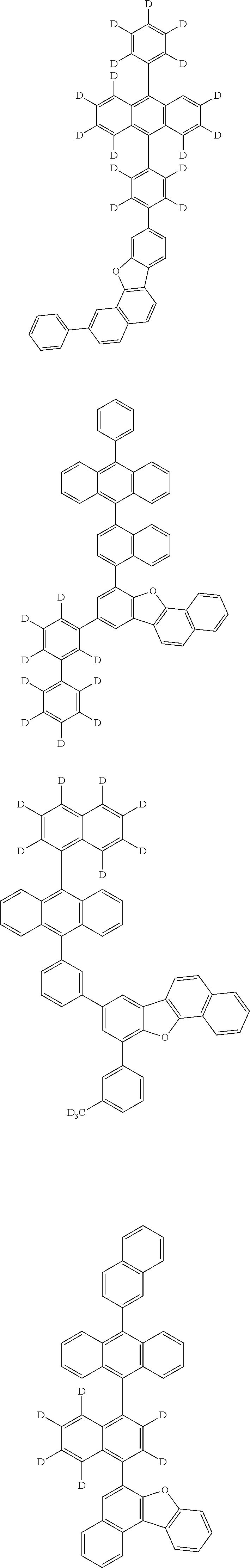

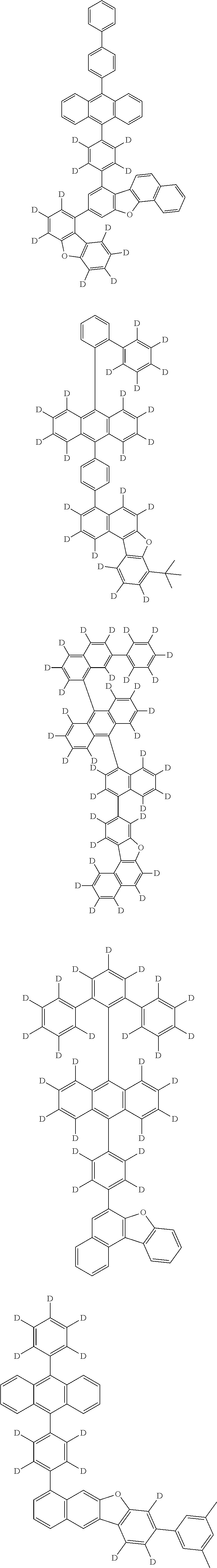

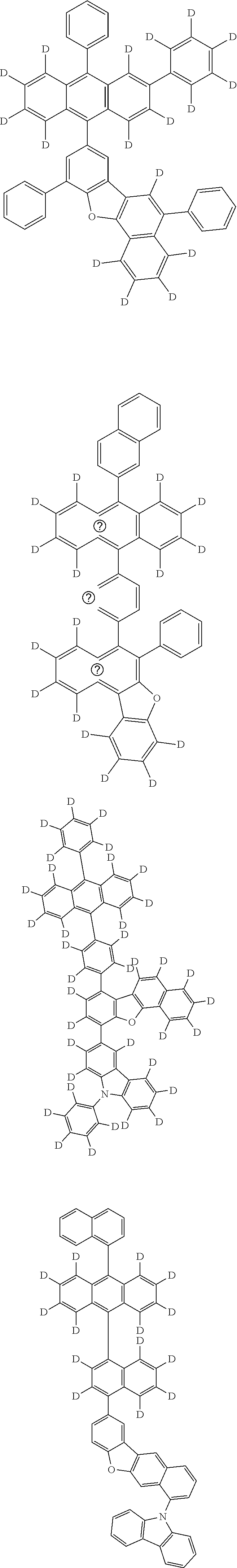

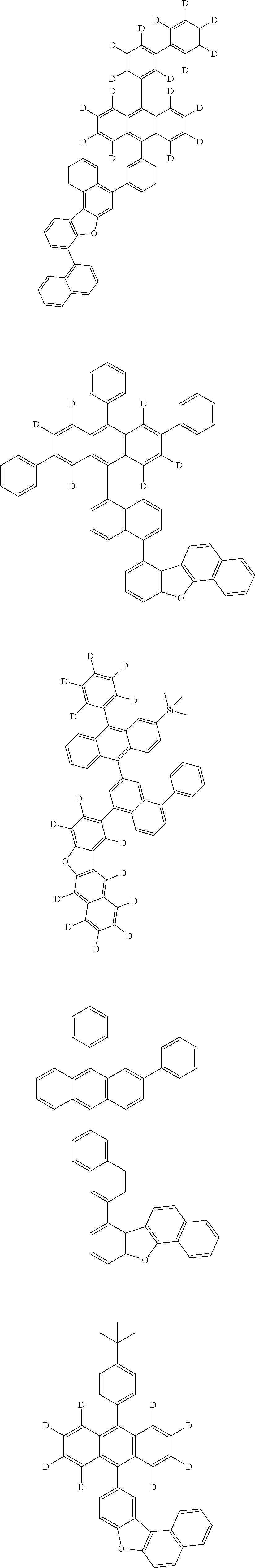

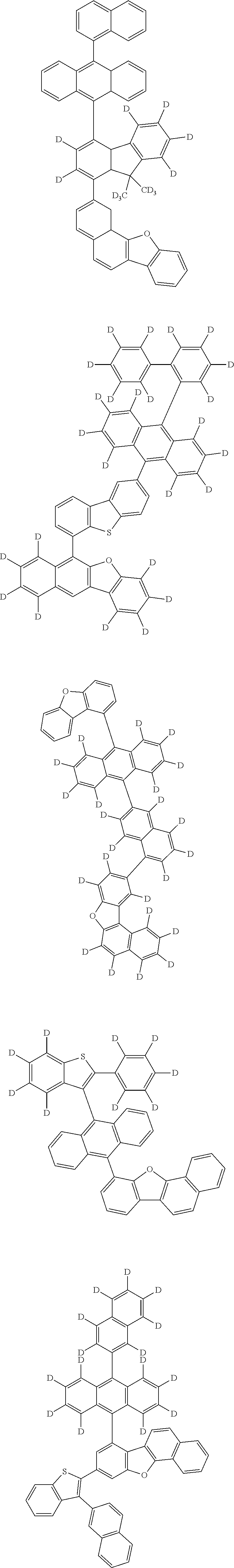

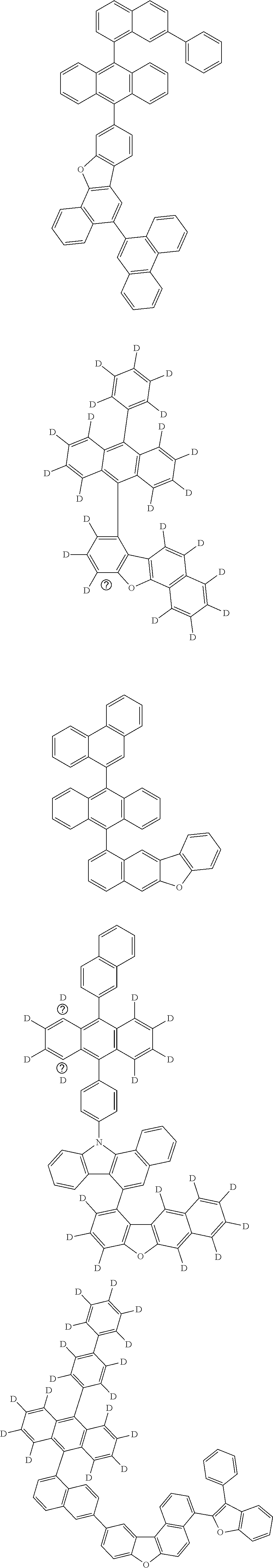

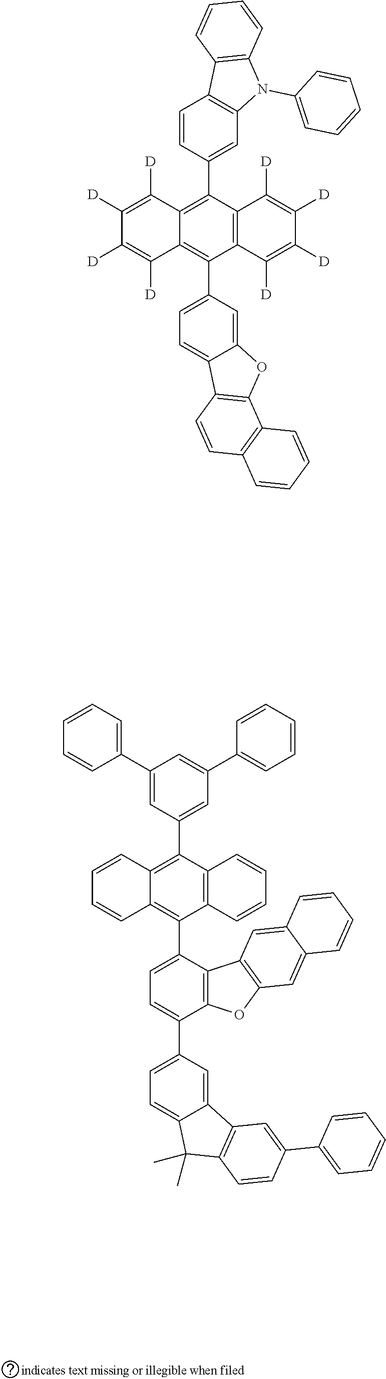 [SMILES: [2H]c1c([2H])c([2H])c2c(-c3ccc4c5ccccc5n(-c5ccccc5)c4c3)c3c([2H])c([2H])c([2H])c([2H])c3c(-c3ccc4c(c3)oc3c5ccccc5ccc43)c2c1[2H] ; CC1(C)c2ccc(-c3ccccc3)cc2-c2cc(-c3ccc(-c4c5ccccc5c(-c5cc(-c6ccccc6)cc(-c6ccccc6)c5)c5ccccc45)c4c3oc3cc5ccccc5cc34)ccc21]

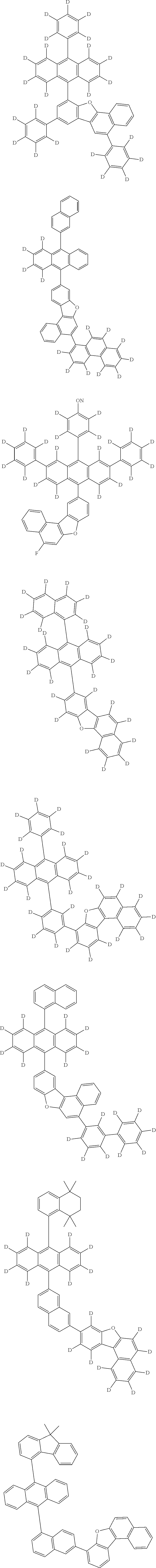

In addition, in the organic light-emitting device according to the present invention, each of the light-emitting layers such as the first light-emitting layer and the second light-emitting layer has a structure composed of a host and a dopant, and herein, the content of the dopant may be typically selected in a range of about 0.01 parts by weight to about 20 parts by weight based on about 100 parts by weight of the host, however, the dopant content is not limited thereto.

Accordingly, in the organic light-emitting device according to the present invention, the light-emitting layer may further include various host and dopant materials in addition to the compound according to the present invention, and accordingly, in the light-emitting layer, one or more compounds different from each other may be mixed or laminated and used as the dopant material as well as the host material.

In addition, in the organic light-emitting device according to a specific embodiment of the present invention, at least one of the first dopant and the second dopant may include at least one of a polycyclic compound represented by the following [Chemical Formula 3] or a multimer of a polycyclic aromatic compound having a plurality of structures represented by [Chemical Formula 3], wherein the multimer has a form in which rings included in the unit structure represented by [Chemical Formula 3] are shared by a plurality of the unit structures for bonding, or has a form in which rings included in the unit structure represented by [Chemical Formula 3] are shared and fused for bonding.

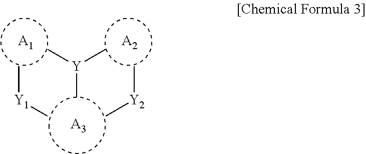

In [Chemical Formula 3],
Y is selected from B, CR₄₀, N, P═O and P═S.

Y₁ and Y₂ are the same as or different from each other, and each independently selected from O, S, NR₄₁, CR₄₂R₄₃, SiR₄₄R₄₅ and GeR₄₆R₄₇.

A₁ to A₃ are the same as or different from each other, and each independently selected from a substituted or unsubstituted C₆-C₅₀ aromatic hydrocarbon ring, a substituted or unsubstituted C₂-C₅₀ aromatic heteroring, a substituted or unsubstituted C₅-C₅₀ aliphatic hydrocarbon ring, and a substituted or unsubstituted ring in which a C₃-C₃₀ aliphatic ring and a C₅-C₃₀ aromatic ring are fused.

R₄₀ to R₄₇ are the same as or different from each other, and each independently selected from hydrogen, deuterium, tritium, a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted or unsubstituted C₂-C₃₀ alkenyl group, a substituted or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group.

In addition, R₄₀ to R₄₇ may be linked to the ring A₁ to A₃ to further form an alicyclic or aromatic monocyclic or polycyclic ring.

In addition, R₄₂ and R₄₃, R₄₄ and R₄₅, R₄₆ and R⁴⁷ may each be linked to each other to further form an alicyclic or aromatic monocyclic or polycyclic ring.

The ‘substituted’ in the ‘substituted or unsubstituted’ in [Chemical Formula 3] means being substituted with one or more substituents selected from the group consisting of deuterium, tritium, a C₁-C₂₄ alkyl group, a C₁-C₂₄ halogenated alkyl group, a C₂-C₂₄ alkenyl group, a C₂-C₂₄ alkynyl group, a C₃-C₃₀ cycloalkyl group, a C₁-C₂₄ heteroalkyl group, a C₆-C₃₀ aryl group, a C₇-C₃₀ arylalkyl group, a C₇-C₃₀ alkylaryl group, a C₂-C₃₀ heteroaryl group, a C₂-C₃₀ heteroarylalkyl group, a cyclic group in which a C₃-C₂₄ aliphatic ring and a C₅-C₂₄ aromatic ring are fused, a C₁-C₃₀ amine group, a C₁-C₃₀ silyl group, a C₁-C₃₀ germanium group, a C₁-C₃₀ oxy group, a C₁-C₃₀ thioxy group, a C₁-C₃₀ thionyl group, a cyano group, a halogen group, a thiol group, a hydroxyl group and a nitro group, and when there are two or more substituents, they are the same as or different from each other, and at least one hydrogen atom in the compound formed from [Chemical Formula 3] may be substituted with deuterium or tritium.

According to one embodiment of the present invention, the polycyclic compound represented by [Chemical Formula 3] may be represented by the following [Chemical Formula 3-1] or [Chemical Formula 3-2].

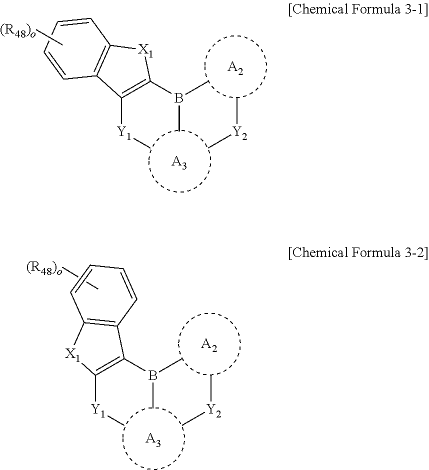

In [Chemical Formula 3-1] and [Chemical Formula 3-2],
X₁ is O or S.

Y₁ and Y₂ are the same as or different from each other, and each independently selected from O, S, NR₄₁, CR₄₂R₄₃, SiR₄₄R₄₅ and GeR₄₆R₄₇.

A₂ and A₃ are the same as or different from each other, and each independently selected from a substituted or unsubstituted C₆-C₅₀ aromatic hydrocarbon ring, a substituted or unsubstituted C₂-C₅₀ aromatic heteroring, a substituted or unsubstituted C₅-C₅₀ aliphatic hydrocarbon ring, and a substituted or unsubstituted ring in which a C₃-C₃₀ aliphatic ring and a C₅-C₃₀ aromatic ring are fused.

R₄₁ to R₄₈ are the same as or different from each other, and each independently selected from hydrogen, deuterium, tritium, a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted or unsubstituted C₂-C₃₀ alkenyl group, a substituted or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group.

o is 4, and the substituents R₄₈s are each the same as or different from each other.

In addition, the adjacent substituents Rags may each be linked to each other to further form an alicyclic or aromatic monocyclic or polycyclic ring, and R₄₁ to R₄₇ may be linked to the ring A₁ to A₃ to further form an alicyclic or aromatic monocyclic or polycyclic ring.

In addition, R₄₂ and R₄₃, R₄₄ and R₄₅, R₄₆ and R₄₇ may each be linked to each other to further form an alicyclic or aromatic monocyclic or polycyclic ring.

The ‘substituted’ in the ‘substituted or unsubstituted’ in [Chemical Formula 3-1] and [Chemical Formula 3-2] means being substituted with one or more substituents selected from the group consisting of deuterium, tritium, a C₁-C₂₄ alkyl group, a C₁-C₂₄ halogenated alkyl group, a C₂-C₂₄ alkenyl group, a C₂-C₂₄ alkynyl group, a C₃-C₃₀ cycloalkyl group, a C₁-C₂₄ heteroalkyl group, a C₆-C₃₀ aryl group, a C₇-C₃₀ arylalkyl group, a C₇-C₃₀ alkylaryl group, a C₂-C₃₀ heteroaryl group, a C₂-C₃₀ heteroarylalkyl group, a cyclic group in which a C₃-C₂₄ aliphatic ring and a C₅-C₂₄ aromatic ring are fused, a C₁-C₃₀ amine group, a C₁-C₃₀ silyl group, a C₁-C₃₀ germanium group, a C₁-C₃₀ oxy group, a C₁-C₃₀ thioxy group, a C₁-C₃₀ thionyl group, a cyano group, a halogen group, a thiol group, a hydroxyl group and a nitro group, and when there are two or more substituents, they are the same as or different from each other, and at least one hydrogen atom in the compound formed from [Chemical Formula 3-1] and [Chemical Formula 3-2] may be substituted with deuterium or tritium.

According to one embodiment of the present invention, in the organic light-emitting device according to the present invention, both the first dopant of the first light-emitting layer and the second dopant of the second light-emitting layer may each include at least one polycyclic compound represented by [Chemical Formula 3].

In addition, as one embodiment of the present invention, specific examples of the compound represented by [Chemical Formula 3] may include compounds described below, however, the compound is not limited thereto.

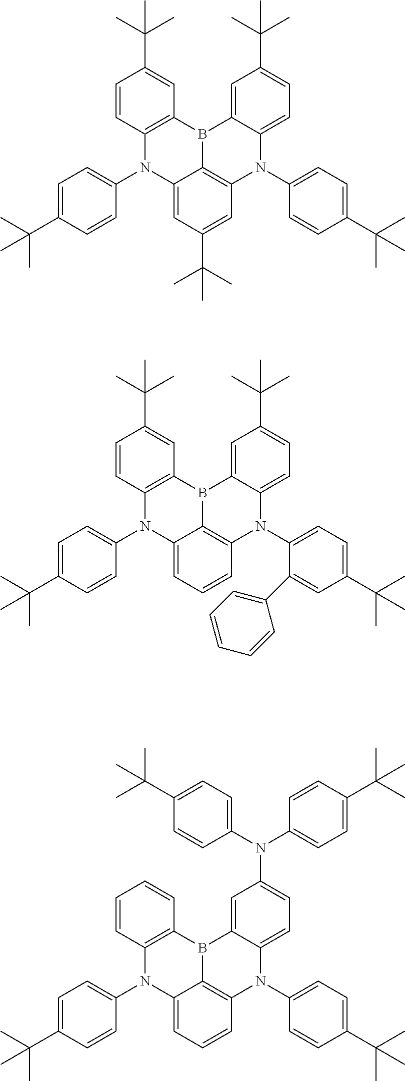

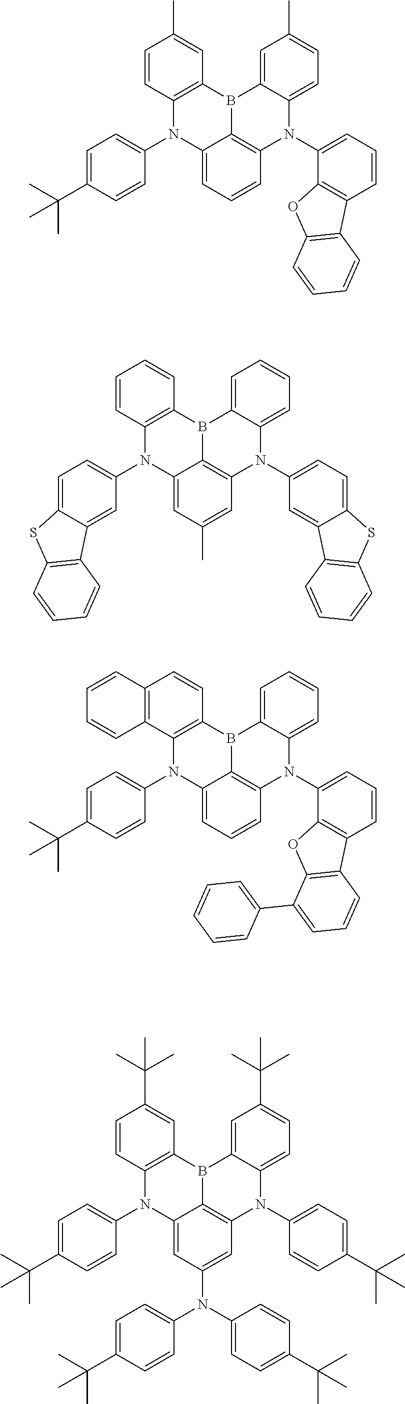 [SMILES: Cc1ccc2c(c1)B1c3cc(C)ccc3N(c3cccc4c3oc3ccccc34)c3cccc(c31)N2c1ccc(C(C)(C)C)cc1 ; Cc1cc2c3c(c1)N(c1ccc4sc5ccccc5c4c1)c1ccccc1B3c1ccccc1N2c1ccc2sc3ccccc3c2c1 ; CC(C)(C)c1ccc(N2c3cccc4c3B(c3ccccc3N4c3cccc4c3oc3c(-c5ccccc5)cccc34)c3ccc4ccccc4c32)cc1 ; CC(C)(C)c1ccc(N(c2ccc(C(C)(C)C)cc2)c2cc3c4c(c2)N(c2ccc(C(C)(C)C)cc2)c2ccc(C(C)(C)C)cc2B4c2cc(C(C)(C)C)ccc2N3c2ccc(C(C)(C)C)cc2)cc1]

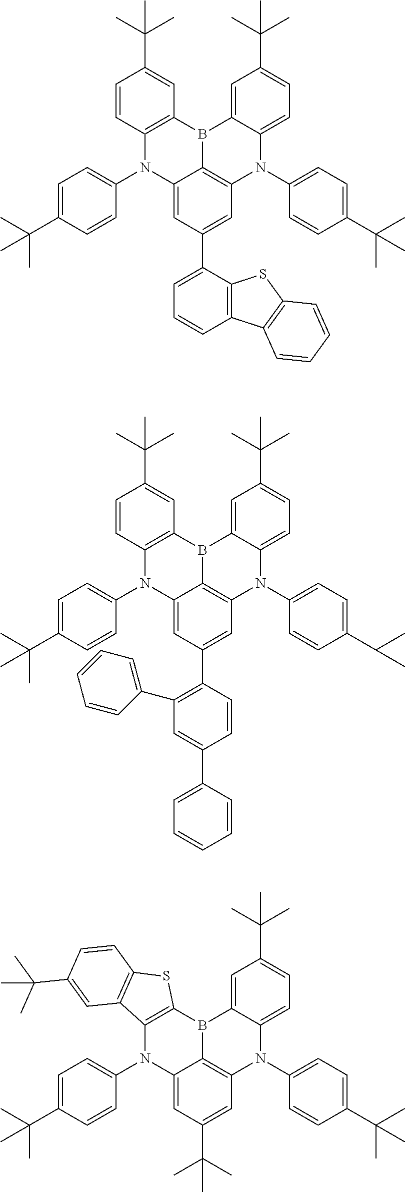

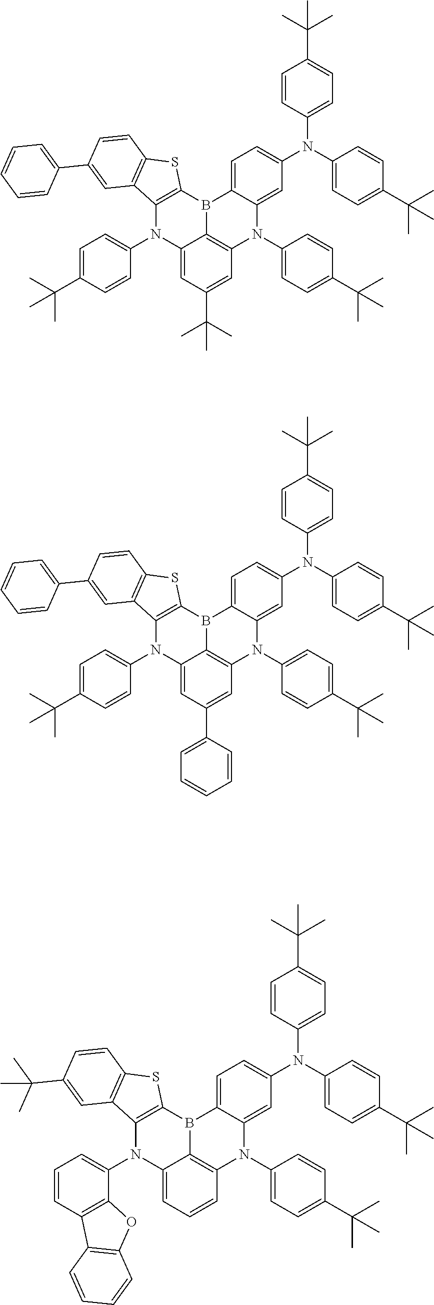

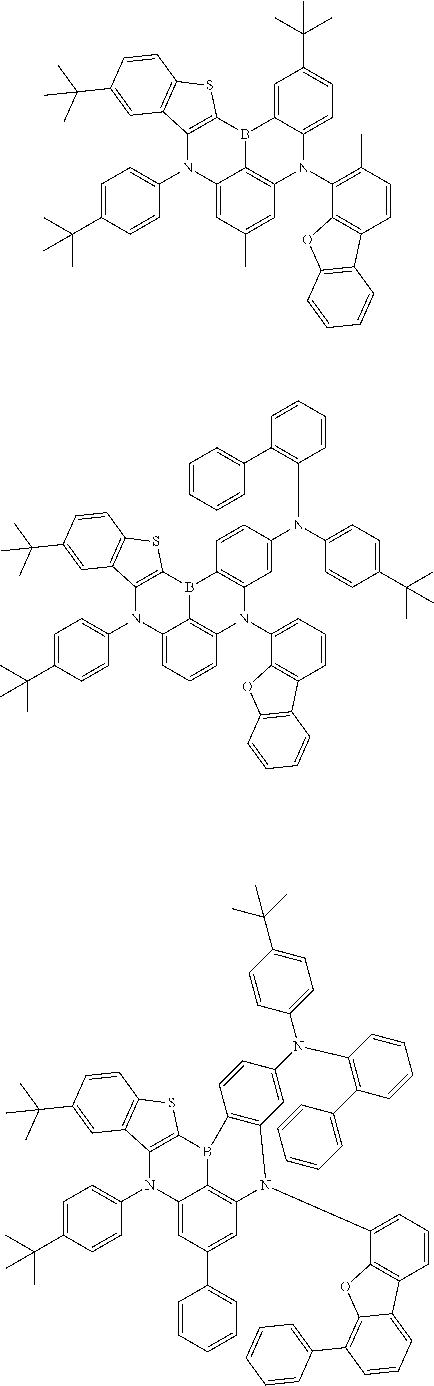

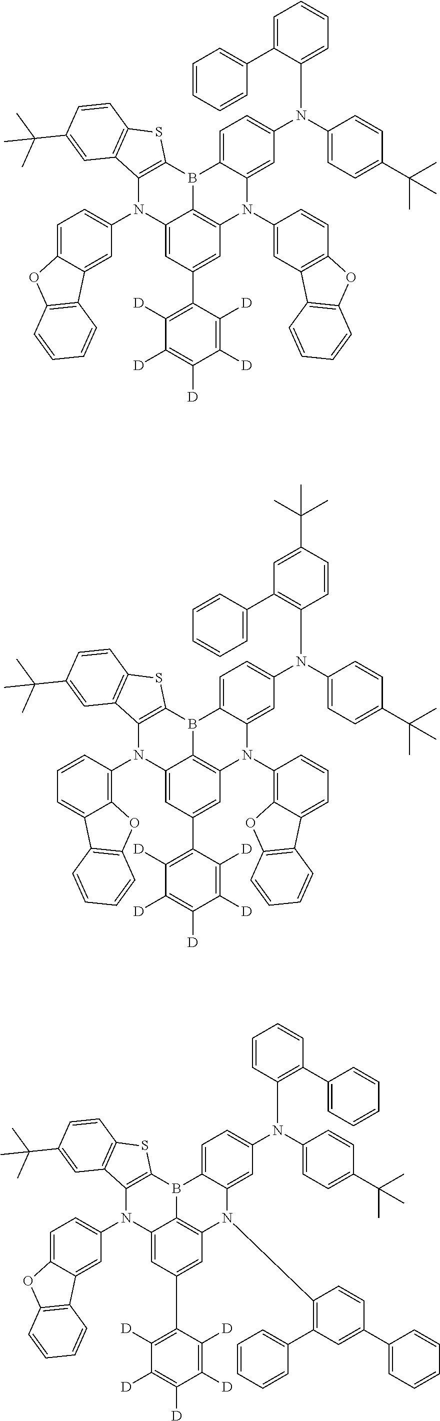

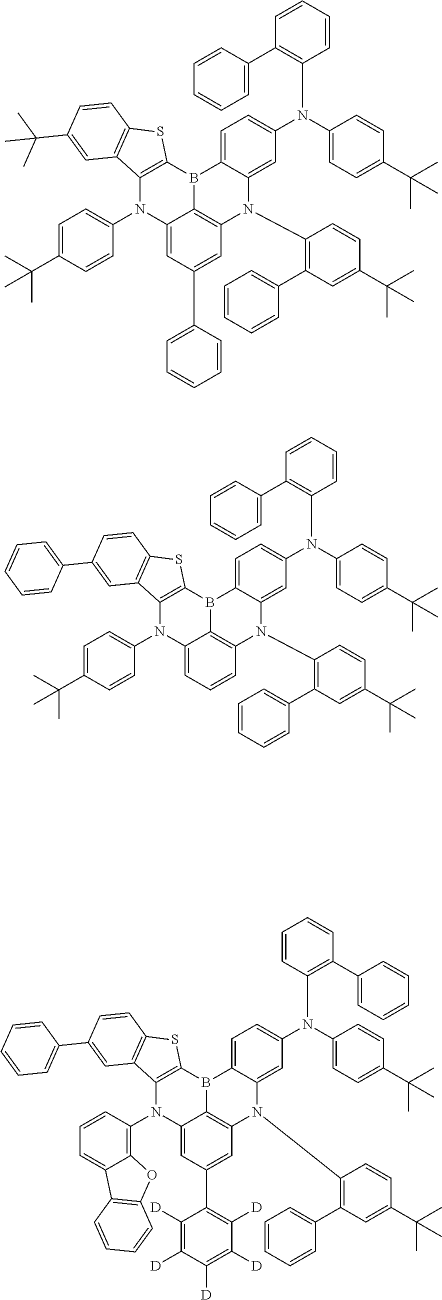 [SMILES: CC(C)(C)c1ccc(N(c2ccc3c(c2)N(c2ccc(C(C)(C)C)cc2-c2ccccc2)c2cc(-c4ccccc4)cc4c2B3c2sc3ccc(C(C)(C)C)cc3c2N4c2ccc(C(C)(C)C)cc2)c2ccccc2-c2ccccc2)cc1 ; CC(C)(C)c1ccc(N(c2ccc3c(c2)N(c2ccc(C(C)(C)C)cc2-c2ccccc2)c2cccc4c2B3c2sc3ccc(-c5ccccc5)cc3c2N4c2ccc(C(C)(C)C)cc2)c2ccccc2-c2ccccc2)cc1 ; [2H]c1c([2H])c([2H])c(-c2cc3c4c(c2)N(c2cccc5c2oc2ccccc25)c2c(sc5ccc(-c6ccccc6)cc25)B4c2ccc(N(c4ccc(C(C)(C)C)cc4)c4ccccc4-c4ccccc4)cc2N3c2ccc(C(C)(C)C)cc2-c2ccccc2)c([2H])c1[2H]]

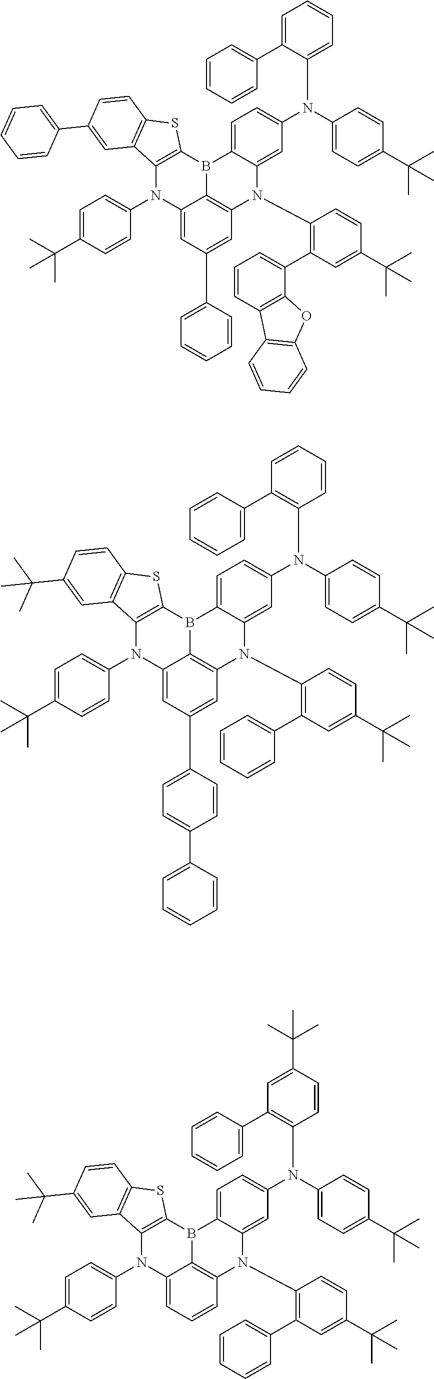

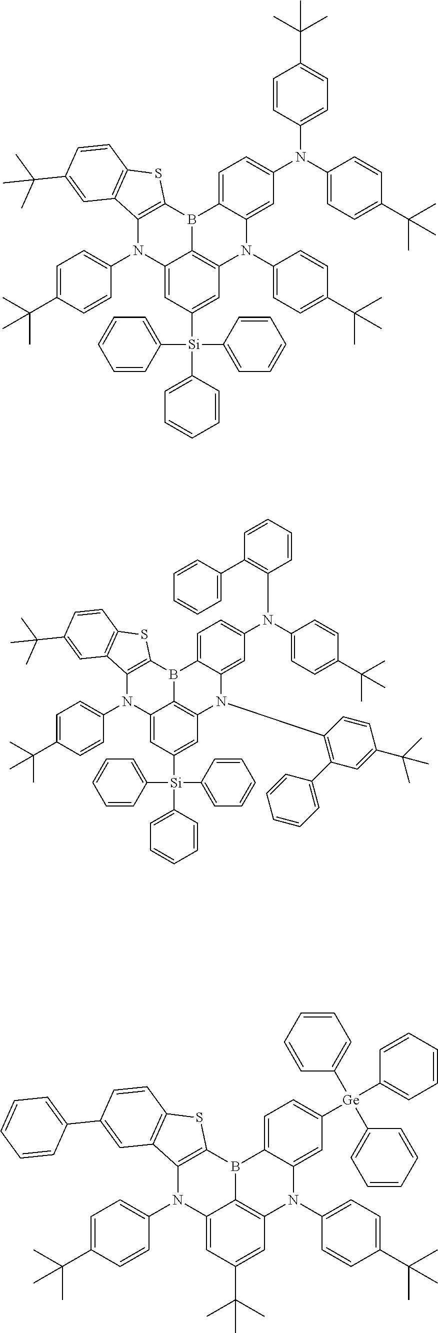

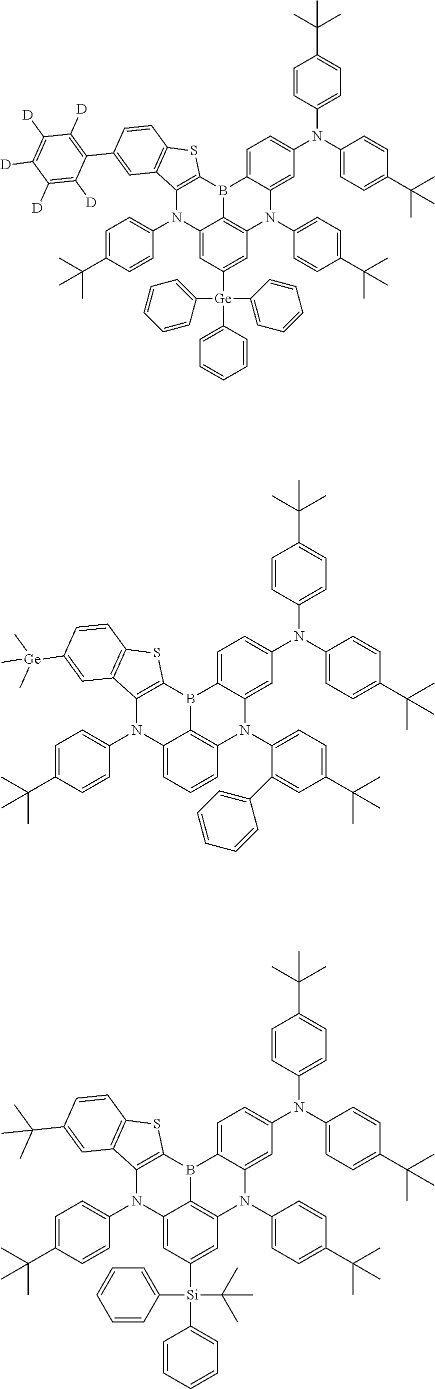

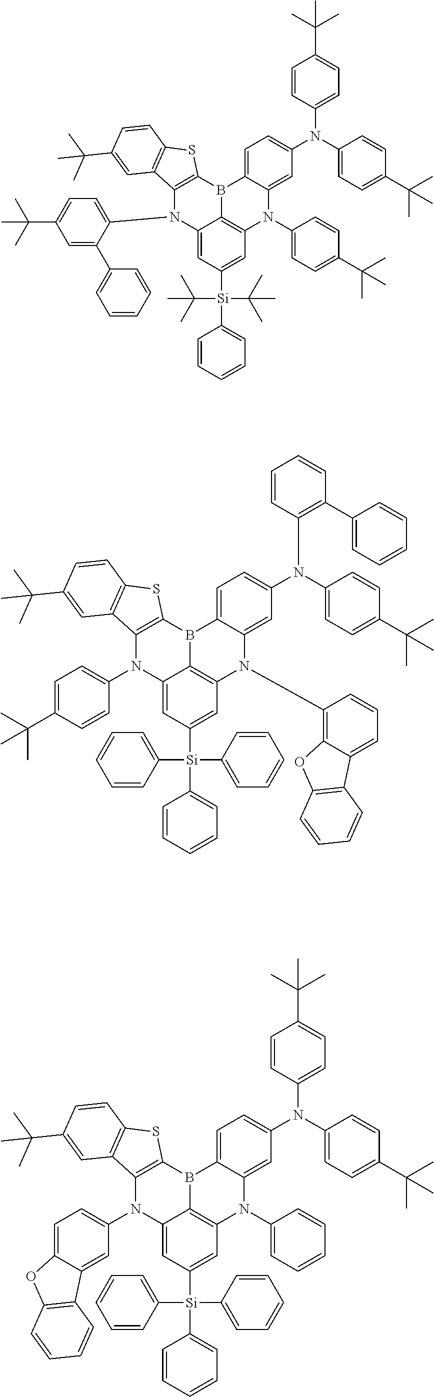

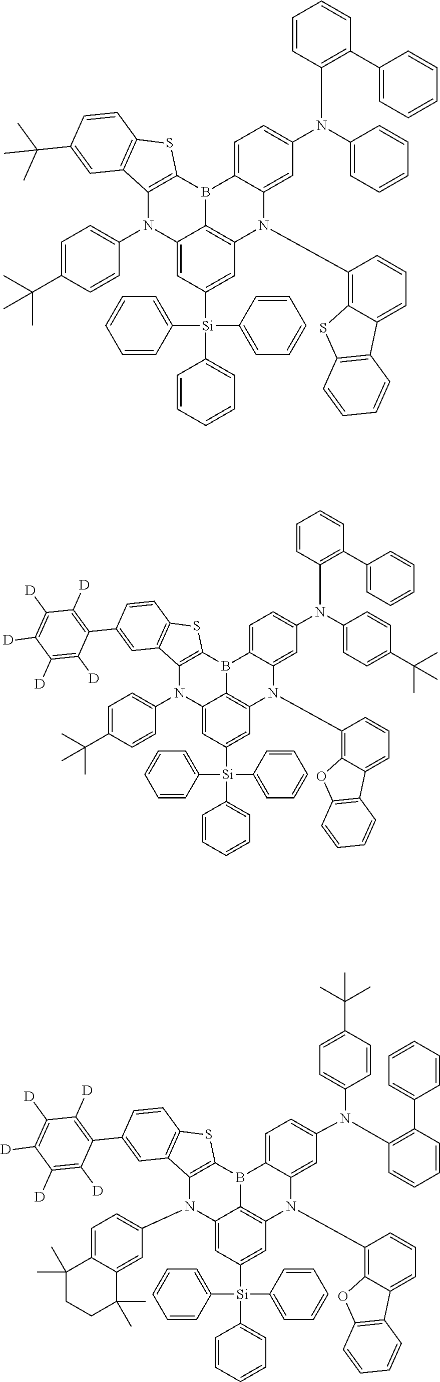

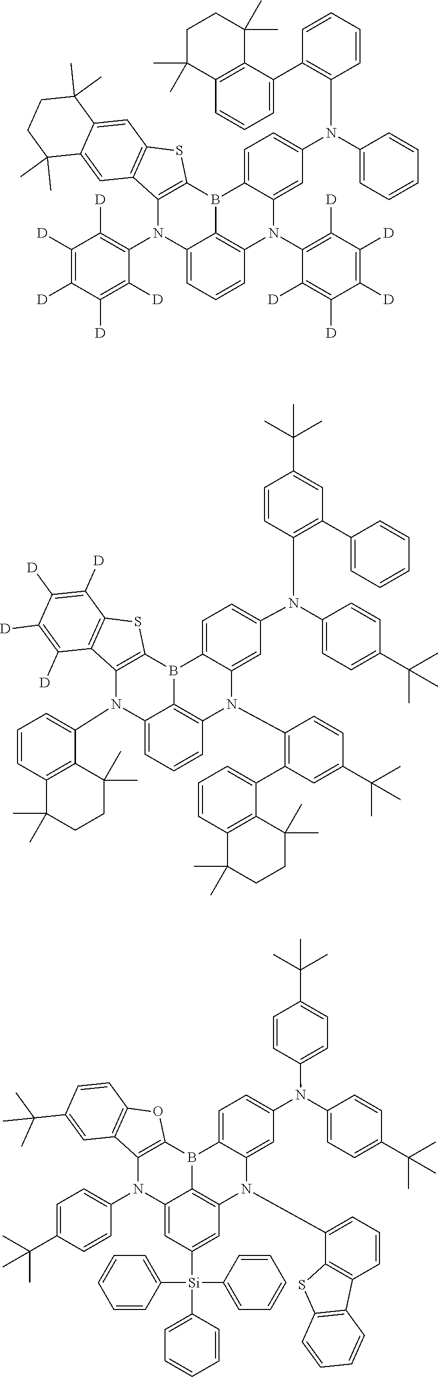

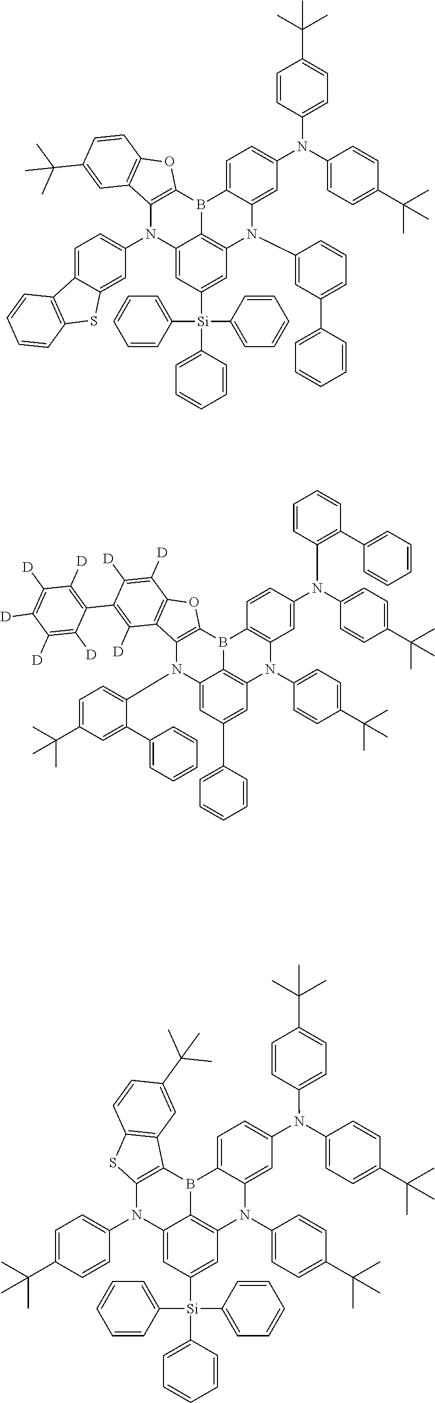

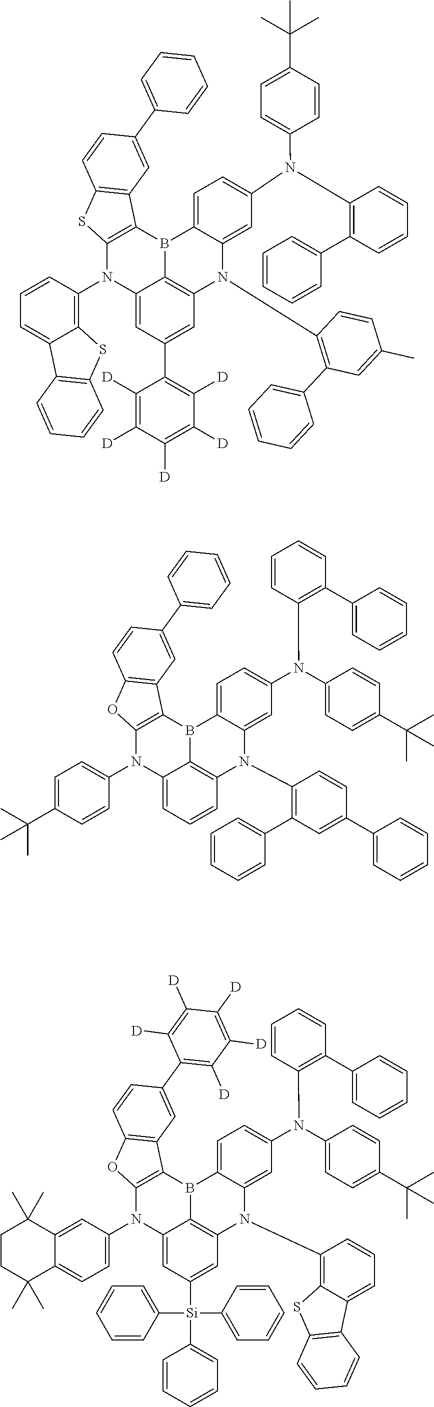

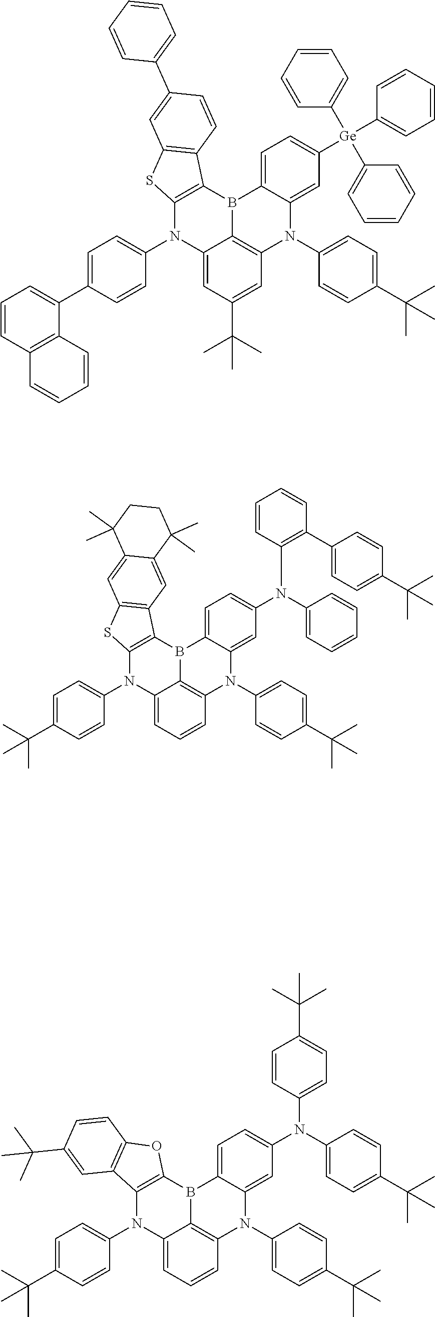

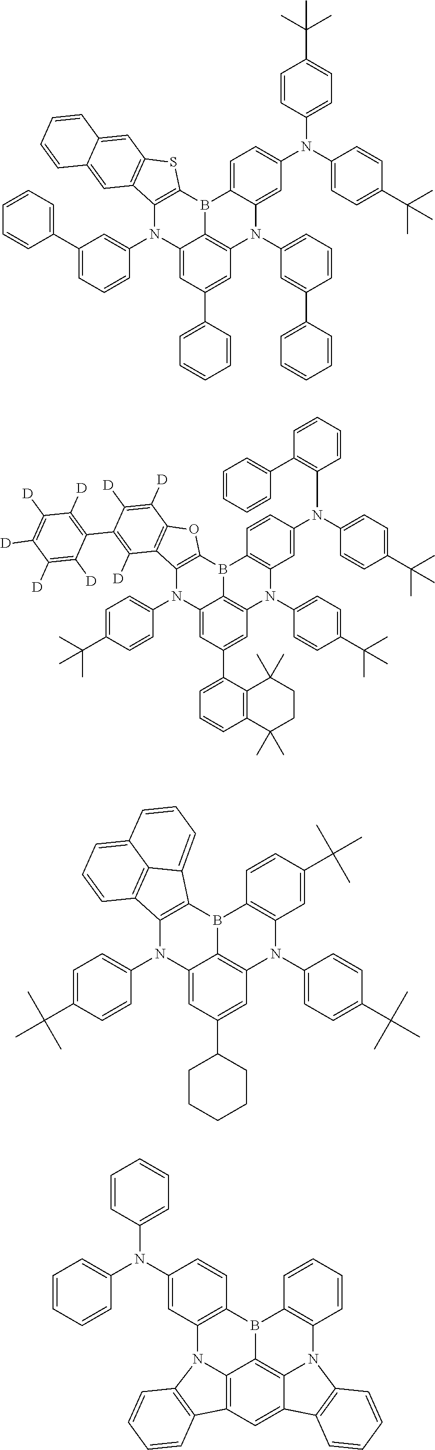

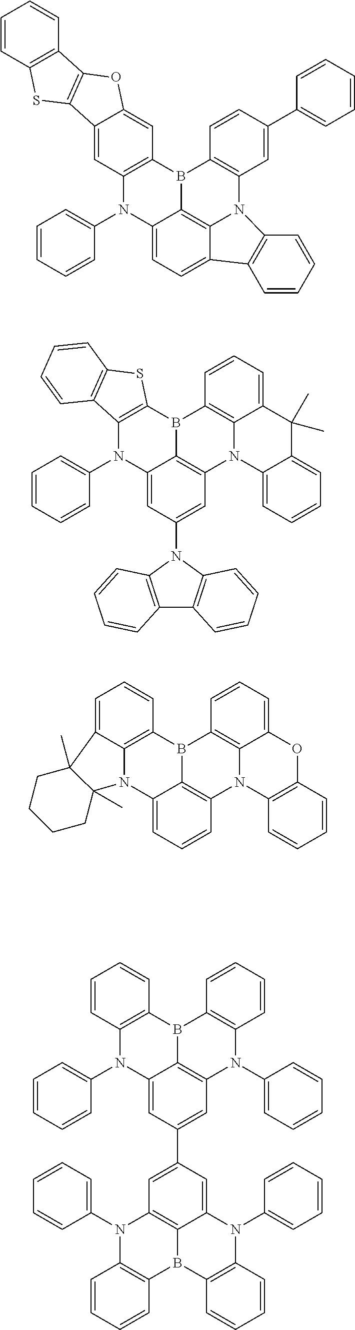 [SMILES: c1ccc(-c2ccc3c(c2)-n2c4ccccc4c4ccc5c(c42)B3c2cc3oc4c6ccccc6sc4c3cc2N5c2ccccc2)cc1 ; CC1(C)c2ccccc2N2c3cc(-n4c5ccccc5c5ccccc54)cc4c3B(c3cccc1c32)c1sc2ccccc2c1N4c1ccccc1 ; CC12CCCCC1(C)N1c3cccc4c3B(c3cccc5c3N4c3ccccc3O5)c3cccc2c31 ; c1ccc(N2c3ccccc3B3c4ccccc4N(c4ccccc4)c4cc(-c5cc6c7c(c5)N(c5ccccc5)c5ccccc5B7c5ccccc5N6c5ccccc5)cc2c43)cc1]

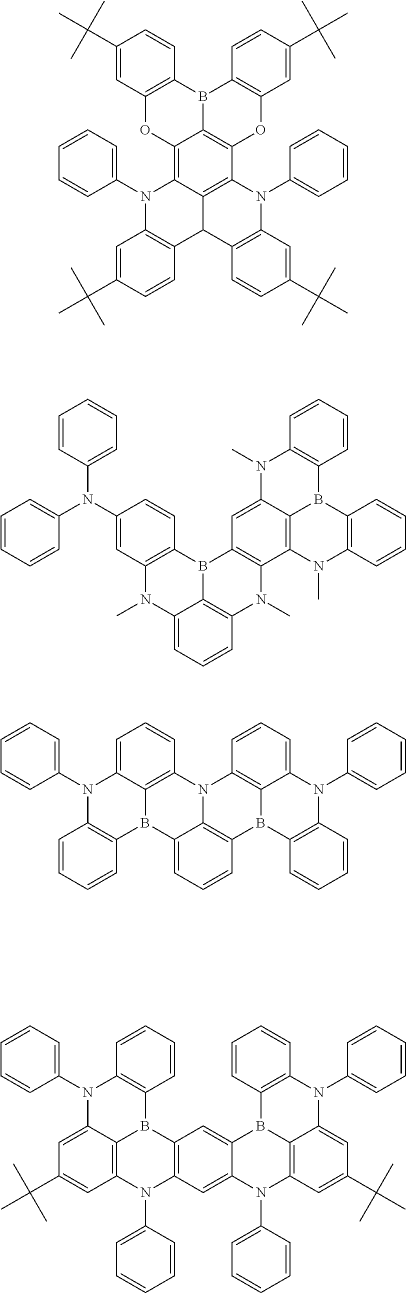 [SMILES: CC(C)(C)c1ccc2c(c1)Oc1c3c(c4c5c1N(c1ccccc1)c1cc(C(C)(C)C)ccc1C5c1ccc(C(C)(C)C)cc1N4c1ccccc1)Oc1cc(C(C)(C)C)ccc1B23 ; CN1c2cc(N(c3ccccc3)c3ccccc3)ccc2B2c3cc4c5c(c3N(C)c3cccc1c32)N(C)c1ccccc1B5c1ccccc1N4C ; c1ccc(N2c3ccccc3B3c4cccc5c4N(c4cccc2c43)c2cccc3c2B5c2ccccc2N3c2ccccc2)cc1 ; CC(C)(C)c1cc2c3c(c1)N(c1ccccc1)c1cc4c(cc1B3c1ccccc1N2c1ccccc1)B1c2ccccc2N(c2ccccc2)c2cc(C(C)(C)C)cc(c21)N4c1ccccc1]

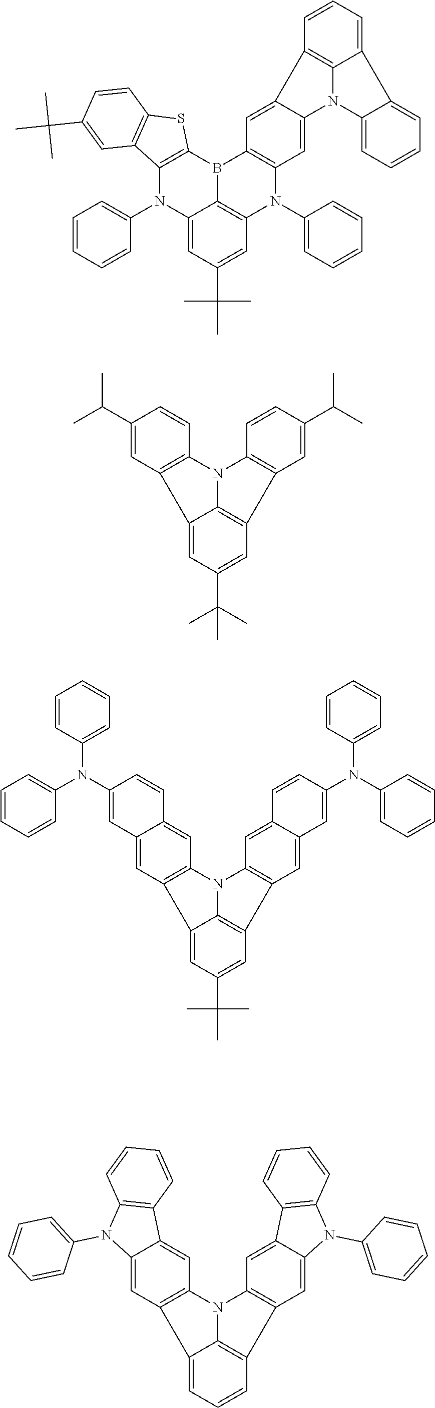 [SMILES: CC(C)(C)c1cc2c3c(c1)N(c1ccccc1)c1c(sc4ccc(C(C)(C)C)cc14)B3c1cc3c4cccc5c6ccccc6n(c3cc1N2c1ccccc1)c54 ; CC(C)c1ccc2c(c1)c1cc(C(C)(C)C)cc3c4cc(C(C)C)ccc4n2c13 ; CC(C)(C)c1cc2c3cc4cc(N(c5ccccc5)c5ccccc5)ccc4cc3n3c4cc5ccc(N(c6ccccc6)c6ccccc6)cc5cc4c(c1)c23 ; c1ccc(-n2c3ccccc3c3cc4c(cc32)c2cccc3c5cc6c(cc5n4c23)c2ccccc2n6-c2ccccc2)cc1]

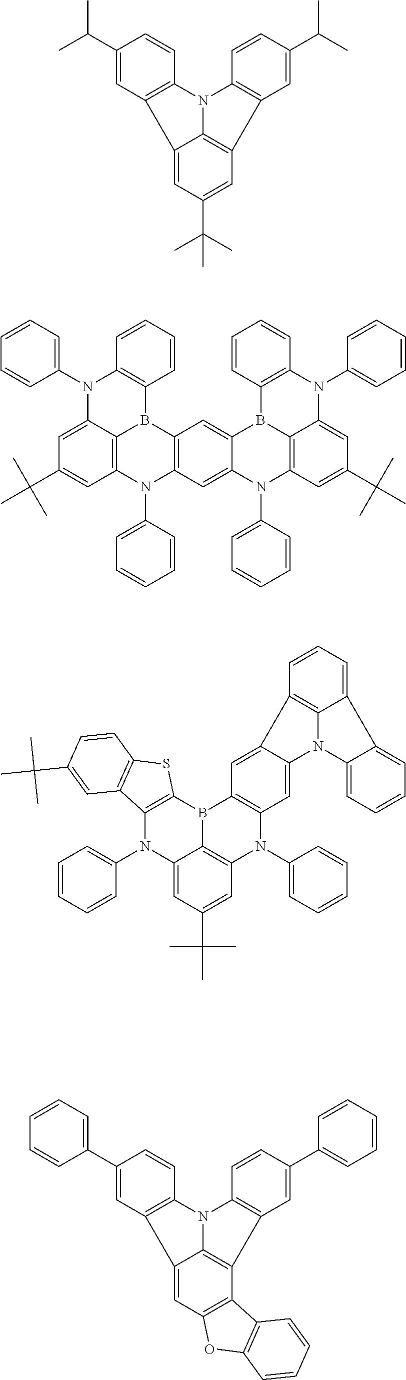

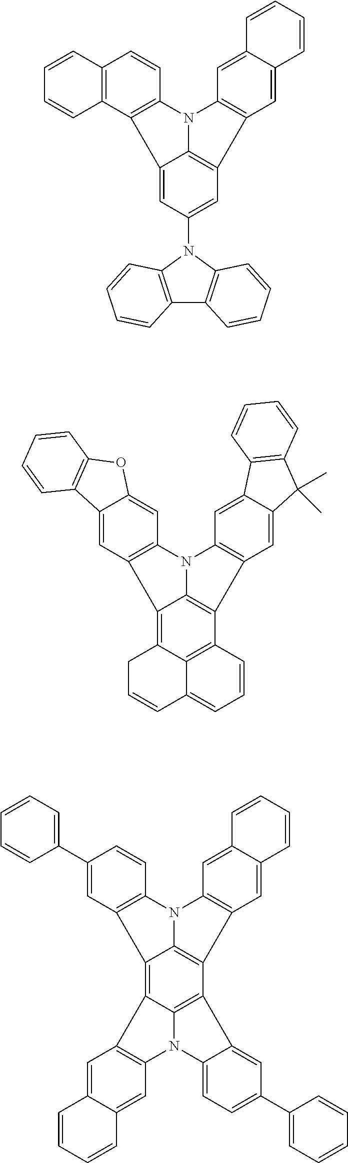 [SMILES: c1ccc2cc3c(cc2c1)c1cc(-n2c4ccccc4c4ccccc42)cc2c4c5ccccc5ccc4n3c12 ; CC1(C)c2ccccc2-c2cc3c(cc21)c1c2cccc4c2c(c2c5cc6c(cc5n3c21)oc1ccccc16)CC=C4 ; c1ccc(-c2ccc3c(c2)c2c4c5cc6ccccc6cc5n5c6ccc(-c7ccccc7)cc6c(c6c7cc8ccccc8cc7n3c26)c45)cc1]

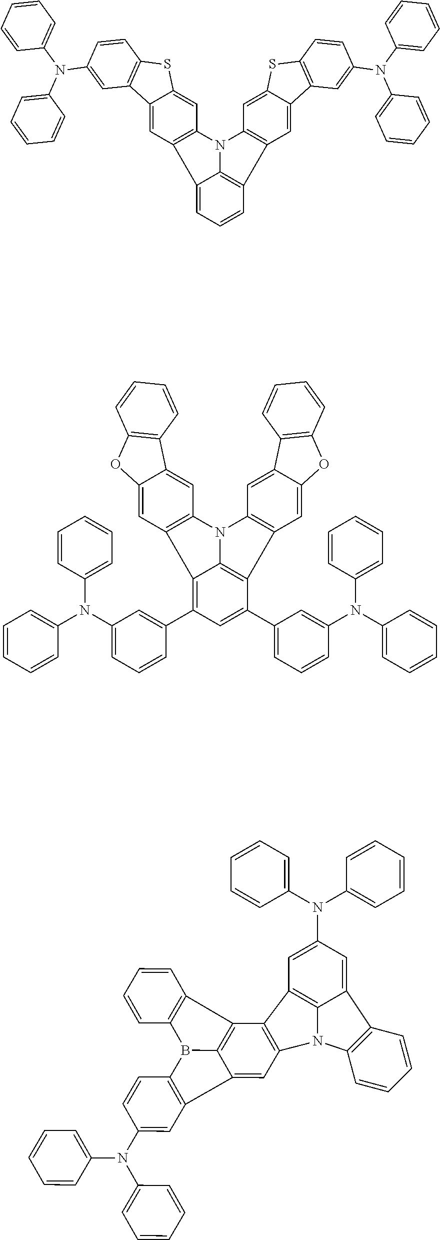 [SMILES: c1ccc(N(c2ccccc2)c2ccc3sc4cc5c(cc4c3c2)c2cccc3c4cc6c(cc4n5c23)sc2ccc(N(c3ccccc3)c3ccccc3)cc26)cc1 ; c1ccc(N(c2ccccc2)c2cccc(-c3cc(-c4cccc(N(c5ccccc5)c5ccccc5)c4)c4c5cc6oc7ccccc7c6cc5n5c6cc7c(cc6c3c45)oc3ccccc37)c2)cc1 ; c1ccc(N(c2ccccc2)c2ccc3c(c2)-c2cc4c(c5c2B3c2ccccc2-5)c2cc(N(c3ccccc3)c3ccccc3)cc3c5ccccc5n4c32)cc1]

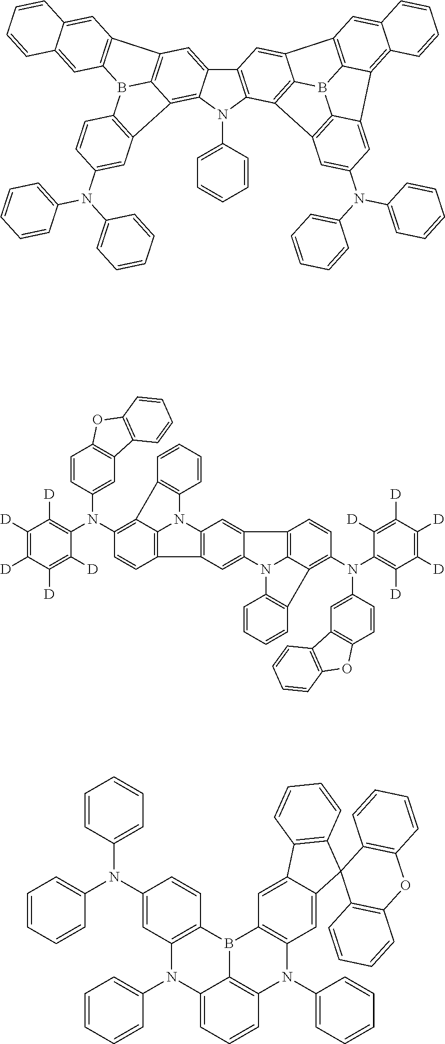 [SMILES: c1ccc(N(c2ccccc2)c2ccc3c(c2)-c2c4c(cc5c6cc7c8c(c6n(-c6ccccc6)c25)-c2cc(N(c5ccccc5)c5ccccc5)cc5c2B8c2c-7cc6ccccc6c2-5)-c2cc5ccccc5cc2B34)cc1 ; [2H]c1c([2H])c([2H])c(N(c2ccc3oc4ccccc4c3c2)c2ccc3c4cc5c(cc4n4c6ccccc6c2c34)c2ccc(N(c3ccc4oc6ccccc6c4c3)c3c([2H])c([2H])c([2H])c([2H])c3[2H])c3c4ccccc4n5c23)c([2H])c1[2H] ; c1ccc(N(c2ccccc2)c2ccc3c(c2)N(c2ccccc2)c2cccc4c2B3c2cc3c(cc2N4c2ccccc2)C2(c4ccccc4Oc4ccccc42)c2ccccc2-3)cc1]

The organic layer of the organic light-emitting device according to the present invention may be formed in a single layer structure, but may be formed in a multilayer structure in which two or more organic layers are laminated. For example, the organic layer may have a structure including a hole injection layer, a hole transport layer, a hole blocking layer, a light-emitting layer, an electron blocking layer, an electron transport layer, an electron injection layer and the like. However, the structure is not limited thereto, and may also include a smaller or larger number of organic layers, and a preferred organic material layer structure of the organic light-emitting device according to the present invention will be described in more detail in examples described below.

Hereinafter, one embodiment of the organic light-emitting device according to the present invention will be described in more detail.

The organic light-emitting device of the present invention includes an anode, a hole transport layer, a light-emitting layer, an electron transport layer and a cathode. As necessary, the organic light-emitting device of the present invention may further include a hole injection layer between the anode and the hole transport layer, and an electron injection layer between the electron transport layer and the cathode. In addition thereto, one or two intermediate layers may be further formed, a hole blocking layer or an electron blocking layer may be further formed, and as described above, organic layers having various functions such as a capping layer may be further included depending on the device properties.

Meanwhile, the specific structure of the organic light-emitting device according to one embodiment of the present invention, a method for manufacturing the same, and the materials of each organic layer may be examined as follows.

First, a material for an anode electrode is coated on a substrate to form an anode. Herein, substrates used in common organic light-emitting devices may be used as the substrate, and organic substrates or transparent plastic substrates having excellent transparency, surface smoothness, handling readiness and waterproofness are preferred. As the material for an anode electrode, indium tin oxide (ITO), indium zinc oxide (IZO), tin oxide (SnO₂), zinc oxide (ZnO) or the like, which is transparent and has excellent conductivity, is used.

A hole injection layer material is coated on the anode electrode by vacuum thermal deposition or spin coating to form a hole injection layer. Then, a hole transport layer material is coated on the hole injection layer by vacuum thermal deposition or spin coating to form a hole transport layer.

The hole injection layer material is not particularly limited as long as it is commonly used in the art. Examples thereof may include 4,4′,4″-tris(2-naphthylphenyl-phenylamino)triphenylamine (2-TNATA), N,N′-di(1-naphthyl)-N, N′-diphenylbenzidine (NPD), N,N′-diphenyl-N, N′-bis(3-methylphenyl)-1,1′-biphenyl-4,4′-diamine (TPD), N,N′-diphenyl-N, N′-bis(4-(phenyl-m-tolylamino)phenyl) biphenyl-4,4′-diamine (DNTPD), 1,4,5,8,9,11-hexaazatriphenylenehexacarbonitrile (HAT-CN), and the like.

The hole transport layer material is not particularly limited as well as long as it is commonly used in the art. Examples thereof may include N,N′-bis(3-methylphenyl)-N, N′-diphenyl-(1,1-biphenyl)-4,4′-diamine (TPD), N,N′-di(naphthalen-1-yl)-N, N′-diphenylbenzidine (x-NPD) and the like.

Subsequently, a hole auxiliary layer and a light-emitting layer are laminated on the hole transport layer. The light-emitting layer may be used either alone, or the first light-emitting layer and the second light-emitting layer may each be laminated using a vacuum deposition method or a spin coating method. Herein, as a host material in the first light-emitting layer or the second light-emitting layer in the organic light-emitting device, one or more of the compounds represented by [Chemical Formula 1] and [Chemical Formula 2] according to the present invention may be used, and as a dopant material in the first light-emitting layer or the second light-emitting layer, the compound represented by [Chemical Formula 3] according to the present invention may be used. Materials constituting these are as described above. In addition, as a method for forming the light-emitting layer, one or a plurality of first host materials and a dopant material are deposited (co-deposited) from a plurality of different deposition sources to form a thin film, or a plurality of the hosts (for example, first host material and second host material) are pre-mixed, and the mixed hosts may be co-deposited using a deposition source different from that of the dopant.

Herein, when each host is separately laminated using a plurality of different deposition sources, there is a disadvantage in that the manufacturing process becomes complicated, however, since the thin film is formed without the respective materials being brought into contact with each other in advance, deterioration in device properties caused by interactions between different types of compounds, which occurs when they are pre-mixed in a single deposition source, may be prevented. On the other hand, when they are pre-mixed, there is an advantage in that the manufacturing apparatus or manufacturing process may be simplified. A hole blocking layer may be optionally formed as a thin film on the light-emitting layer using a method of vacuum deposition or spin coating. When holes pass through an organic light-emitting layer and flow into a cathode, lifespan and efficiency of a device are reduced, and the hole blocking layer performs a role of preventing this problem by using a material having a very low highest occupied molecular orbital (HOMO) level. The hole blocking material used herein is not particularly limited, but needs to have higher ionization potential than a light-emitting compound while having an electron transport ability. Representative examples thereof may include BAlq, BCP, TPBI and the like.

As a material used for the hole blocking layer, BAlq, BCP, Bphen, TPBI, TAZ, BeBq₂, OXD-7, Liq and the like may be used, however, the material is not limited thereto.

After depositing an electron transport layer on the hole blocking layer using a method of vacuum deposition or spin coating, an electron injection layer is formed thereon, and a metal for forming a cathode is vacuum thermal deposited on the electron injection layer to form a cathode, and as a result, the organic light-emitting device according to one embodiment of the present invention is completed.

Herein, as the metal for forming a cathode, lithium (Li), magnesium (Mg), aluminum (Al), aluminum-lithium (Al—Li), calcium (Ca), magnesium-indium (Mg—In), magnesium-silver (Mg—Ag) or the like may be used, and in order to obtain a top emission-type light-emitting device, a transmissive cathode using ITO or IZO may be used.

As a material for the electron transport layer, known electron transport materials functioning to stably transport electrons injected from the cathode may be used. Examples of the known electron transport material may include materials such as particularly quinoline derivatives, tris(8-quinolinolato)aluminum (Alq₃), TAZ, BAlq, beryllium bis(benzoquinolin-10-olate) (Bebq₂) and oxadiazole derivatives (PBD, BMD, BND and the like).

In addition, each of the organic layers may be formed using a monomolecular deposition method or solution process. Herein, the monomolecular deposition method refers to a method of forming a thin film by evaporating a material used for forming each of the layers through heating and the like under vacuum or reduced pressure, and the solution process refers to a method of forming a thin film by mixing a material used for forming each of the layers with a solvent, and then applying a method such as ink-jet printing, roll-to-roll coating, screen printing, spray coating, dip coating or spin coating on the mixture.

In addition, the organic light-emitting device of the present invention may be used in devices selected from flat-panel display devices, flexible display devices, stretchable display devices, monochromatic or white flat-panel lighting devices, monochromatic or white flexible lighting devices, display devices for vehicles, display devices for virtual or augmented reality, and the like.

Hereinafter, preferred synthesis examples of compounds and device examples are provided in order to help understand the present invention. However, the following examples are for illustrative purposes only, and the scope of the present invention is not limited thereby.

### Synthesis Example 1: Synthesis of [Compound 1-7]

### Synthesis Example 1-1: Synthesis of A-1

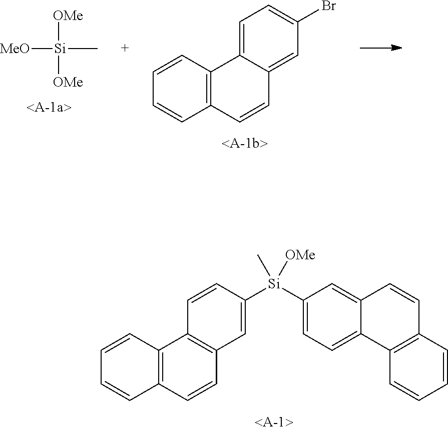

<A-1b> (50 g) and THF (500 mL) were introduced to a round-bottom flask under a nitrogen atmosphere, and after cooling the mixture to −78° C., 1.6 M n-butyllithium (139 mL) was slowly added dropwise thereto. The mixture was stirred for 1 hour, then <A-1a> (12 g) was introduced thereto, and the mixture was further stirred for 1 hour and stirred for 12 hours at room temperature. After the reaction was terminated, the result was extracted with water, and the organic layer was concentrated under reduced pressure and then separated by column chromatography to obtain <A-1> (28.3 g, 75%).

### Synthesis Example 1-2: Synthesis of [Compound 1-7]

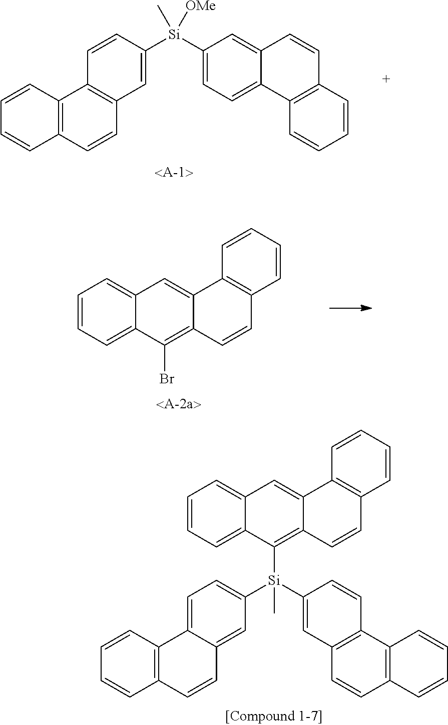 [SMILES: CO[Si](C)(c1ccc2c(ccc3ccccc32)c1)c1ccc2c(ccc3ccccc32)c1 ; Brc1c2ccccc2cc2c1ccc1ccccc12 ; C[Si](c1ccc2c(ccc3ccccc32)c1)(c1ccc2c(ccc3ccccc32)c1)c1c2ccccc2cc2c1ccc1ccccc12]

<A-2a> (24.4 g) and THF (250 mL) were introduced to a round-bottom flask under a nitrogen atmosphere, and after cooling the mixture to −78° C., 1.6 M n-butyllithium (57 mL) was slowly added dropwise thereto. The mixture was stirred for 1 hour, then <A-1> (28.3 g) dissolved in THF (110 mL) was introduced thereto, and the mixture was further stirred for 1 hour and stirred for 12 hours at room temperature. After the reaction was terminated, the result was extracted with water, and the organic layer was concentrated under reduced pressure and then separated by column chromatography to obtain [Compound 1-7] (20.2 g, 49%).

MS (MALDI-TOF): m/z 624.23 [M⁺]

### Synthesis Example 2: Synthesis of [Compound 1-11]

### Synthesis Example 2-1: Synthesis of B-1

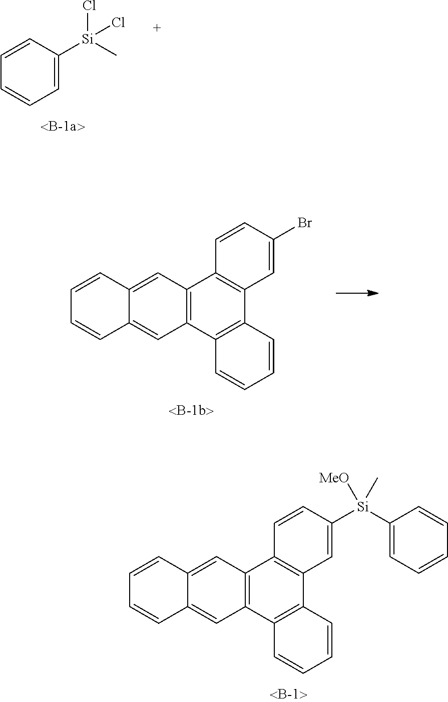

<B-1b> (45 g) and THF (450 mL) were introduced to a round-bottom flask under a nitrogen atmosphere, and after cooling the mixture to −78° C., 1.6 M n-butyllithium (300 mL) was slowly added dropwise thereto. The mixture was stirred for 1 hour, then <B-1a> (20 g) was introduced thereto, and the mixture was further stirred for 1 hour and stirred for 12 hours at room temperature. After the reaction was terminated, a mixture of methanol (68 mL) and triethylamine (34 mL) was introduced thereto, and the result was extracted with water after 10 minutes. The organic layer was concentrated under reduced pressure, and then separated by column chromatography to obtain <B-1> (31.9 g, 71%).

### Synthesis Example 2-2: Synthesis of [Compound 1-11]

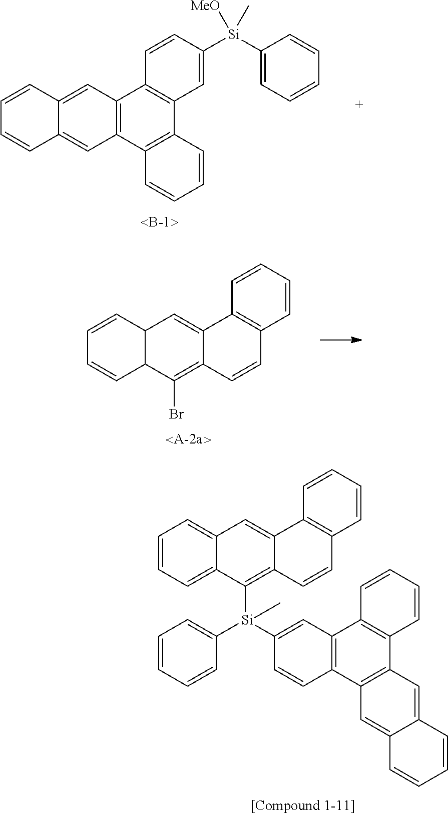 [SMILES: CO[Si](C)(c1ccccc1)c1ccc2c(c1)c1ccccc1c1cc3ccccc3cc21 ; BrC1=c2ccc3ccccc3c2=CC2C=CC=CC12 ; C[Si](c1ccccc1)(c1ccc2c(c1)c1ccccc1c1cc3ccccc3cc21)c1c2ccccc2cc2c1ccc1ccccc12]

[Compound 1-11] was obtained by performing a synthesis in the same manner as in Synthesis Example 1-2, except that <B-1> was used instead of <A-1>. (Yield 44%)

MS (MALDI-TOF): m/z 624.23 [M⁺]

### Synthesis Example 3: Synthesis of [Compound 1-14]

### Synthesis Example 3-1: Synthesis of C-1

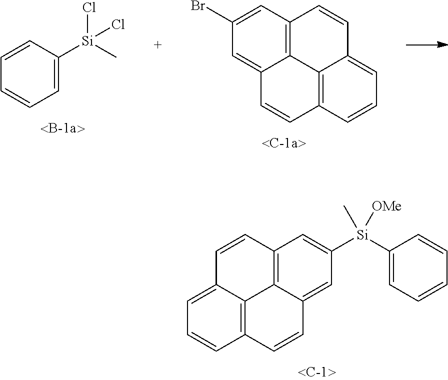

<C-1> was obtained by performing a synthesis in the same manner as in Synthesis Example 2-1, except that <C-1a> was used instead of <B-1b>. (Yield 73%)

### Synthesis Example 3-2: Synthesis of [Compound 1-14]

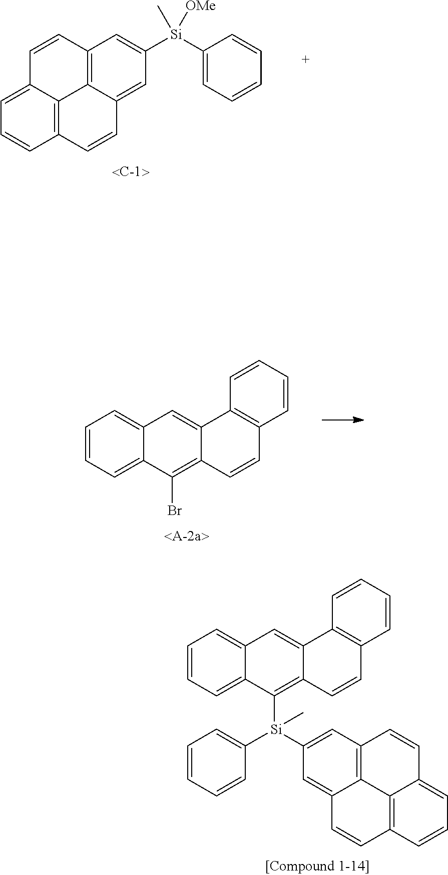 [SMILES: CO[Si](C)(c1ccccc1)c1cc2ccc3cccc4ccc(c1)c2c34 ; Brc1c2ccccc2cc2c1ccc1ccccc12 ; C[Si](c1ccccc1)(c1cc2ccc3cccc4ccc(c1)c2c34)c1c2ccccc2cc2c1ccc1ccccc12]

[Compound 1-14] was obtained by performing a synthesis in the same manner as in Synthesis Example 1-2, except that <C-1> was used instead of <A-1>. (Yield 42%)

MS (MALDI-TOF): m/z 548.20 [M⁺]

### Synthesis Example 4: Synthesis of [Compound 1-19]

### Synthesis Example 4-1: Synthesis of D-1

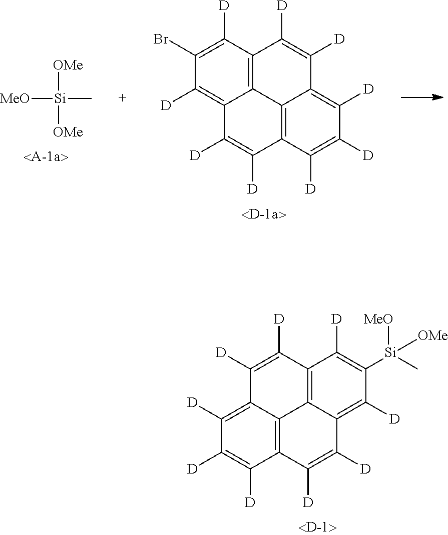

<D-1> was obtained by performing a synthesis in the same manner as in Synthesis Example 1-1, except that <D-1a> was used instead of <A-1b>. (Yield 73%)

### Synthesis Example 4-2: Synthesis of D-2

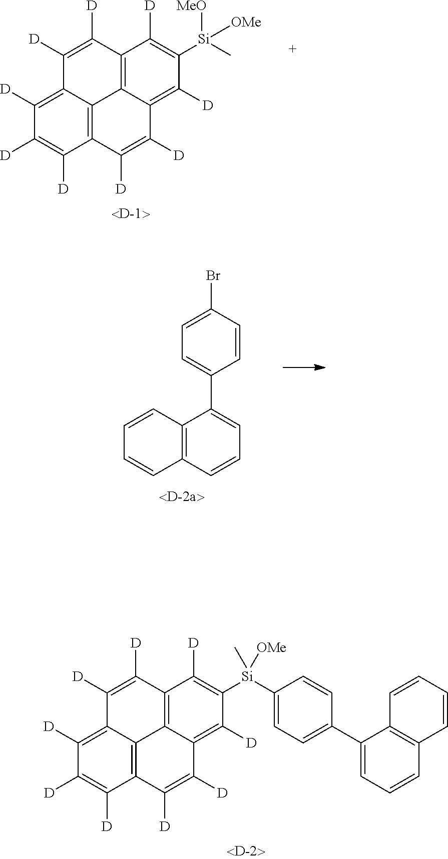 [SMILES: [2H]c1c([2H])c2c([2H])c([2H])c3c([2H])c([Si](C)(OC)OC)c([2H])c4c([2H])c([2H])c(c1[2H])c2c34 ; Brc1ccc(-c2cccc3ccccc23)cc1 ; [2H]c1c([2H])c2c([2H])c([2H])c3c([2H])c([Si](C)(OC)c4ccc(-c5cccc6ccccc56)cc4)c([2H])c4c([2H])c([2H])c(c1[2H])c2c34]

<D-2> was obtained by performing a synthesis in the same manner as in Synthesis Example 1-2, except that <D-1> was used instead of <A-1>, and <D-2a> was used instead of <A-2a>. (Yield 76%)

### Synthesis Example 4-3: Synthesis of [Compound 1-19]

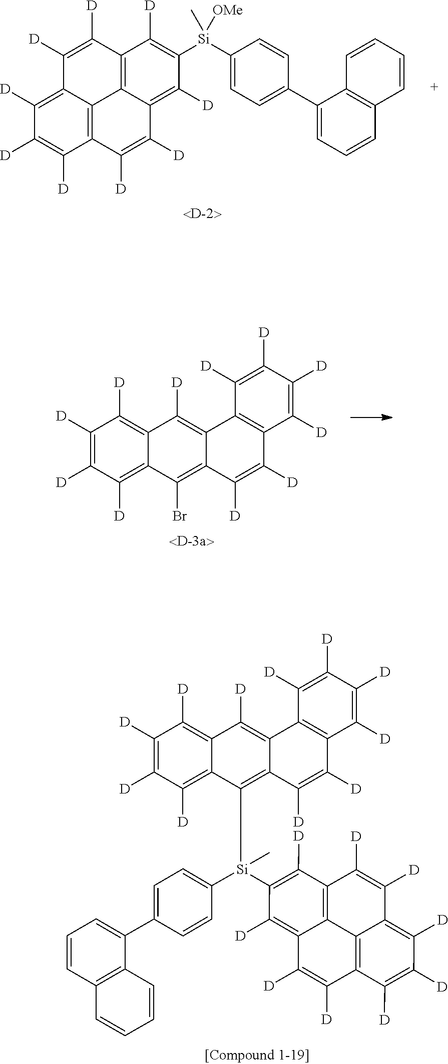 [SMILES: [2H]c1c([2H])c2c([2H])c([2H])c3c([2H])c([Si](C)(OC)c4ccc(-c5cccc6ccccc56)cc4)c([2H])c4c([2H])c([2H])c(c1[2H])c2c34 ; [2H]c1c([2H])c([2H])c2c([2H])c3c(c([2H])c([2H])c4c([2H])c([2H])c([2H])c([2H])c43)c(Br)c2c1[2H] ; [2H]c1c([2H])c([2H])c2c([2H])c3c(c([2H])c([2H])c4c([2H])c([2H])c([2H])c([2H])c43)c([Si](C)(c3ccc(-c4cccc5ccccc45)cc3)c3c([2H])c4c([2H])c([2H])c5c([2H])c([2H])c([2H])c6c([2H])c([2H])c(c3[2H])c4c56)c2c1[2H]]

[Compound 1-19] was obtained by performing a synthesis in the same manner as in Synthesis Example 1-2, except that <D-2> was used instead of <A-1>, and <D-3a> was used instead of <A-2a>. (Yield 40%)

MS (MALDI-TOF): m/z 694.37 [M⁺]

### Synthesis Example 5: Synthesis of [Compound 1-32]

### Synthesis Example 5-1: Synthesis of E-1

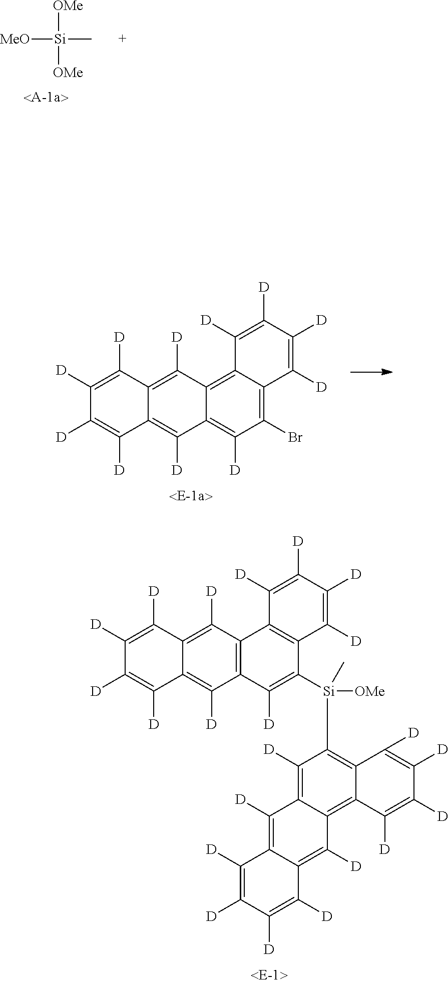

<E-1> was obtained by performing a synthesis in the same manner as in Synthesis Example 1-1, except that <E-1a> was used instead of <A-1b>. (Yield 67%)

### Synthesis Example 5-2: Synthesis of [Compound 1-32]

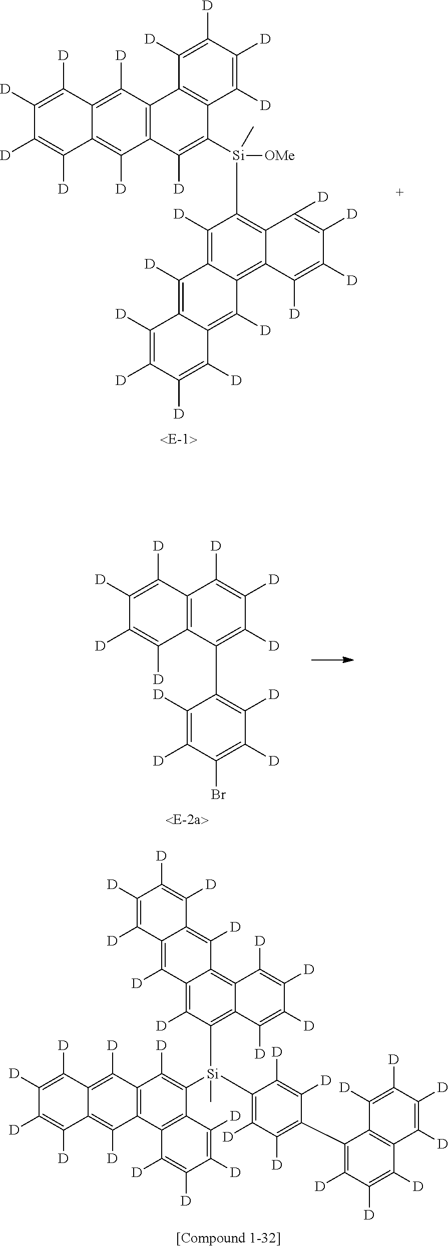

[Compound 1-32] was obtained by performing a synthesis in the same manner as in Synthesis Example 1-2, except that <E-1> was used instead of <A-1>, and <E-2a> was used instead of <A-2a>. (Yield 45%)

MS (MALDI-TOF): m/z 733.47 [M⁺]

### Synthesis Example 6: Synthesis of [Compound 1-34]

### Synthesis Example 6-1: Synthesis of F-1

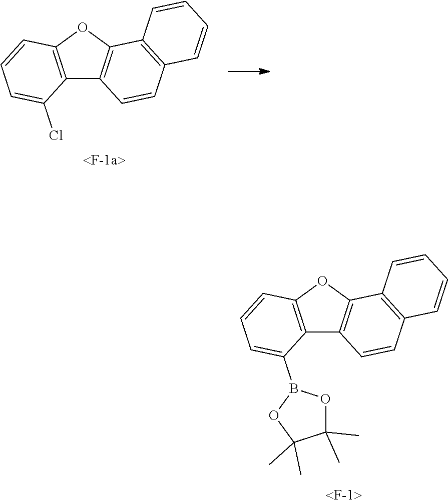 [SMILES: Clc1cccc2oc3c4ccccc4ccc3c12 ; CC1(C)OB(c2cccc3oc4c5ccccc5ccc4c23)OC1(C)C]

<F-1a> (30 g), bis(pinacolato)diboron (45 g), KOAc (35 g), PdCl₂ (dppf) (2.6 g) and 1,4-dioxane (300 mL) were introduced to a round-bottom flask under a nitrogen atmosphere, and the mixture was heated and refluxed for 12 hours. After the reaction was terminated, the result was extracted with water to separate the layers, and the organic layer was concentrated under reduced pressure and then separated by column chromatography to obtain <F-1> (31.9 g, 78%).

### Synthesis Example 6-2: Synthesis of F-2

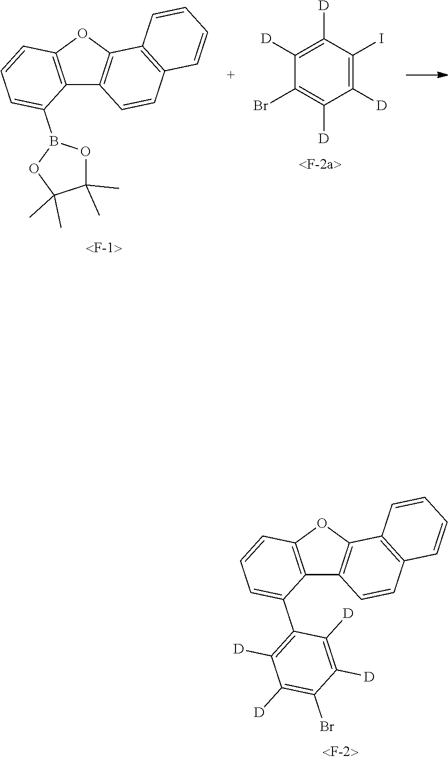 [SMILES: CC1(C)OB(c2cccc3oc4c5ccccc5ccc4c23)OC1(C)C ; [2H]c1c([2H])c(I)c([2H])c([2H])c1Br ; [2H]c1c([2H])c(-c2cccc3oc4c5ccccc5ccc4c23)c([2H])c([2H])c1Br]

<F-1> (30 g), <F-2a> (27.1 g), Pd(PPh₃)₄ (3 g), K₂CO₃ (30.1 g), THF (300 mL) and water (90.3 mL) were introduced to a round-bottom flask under a nitrogen atmosphere, and the mixture was heated and refluxed for 12 hours. After the reaction was terminated, the result was extracted with water to separate the layers, and the organic layer was concentrated under reduced pressure and then separated by column chromatography to obtain <F-2> (26.3 g, 81%).

### Synthesis Example 6-3: Synthesis of [Compound 1-34]

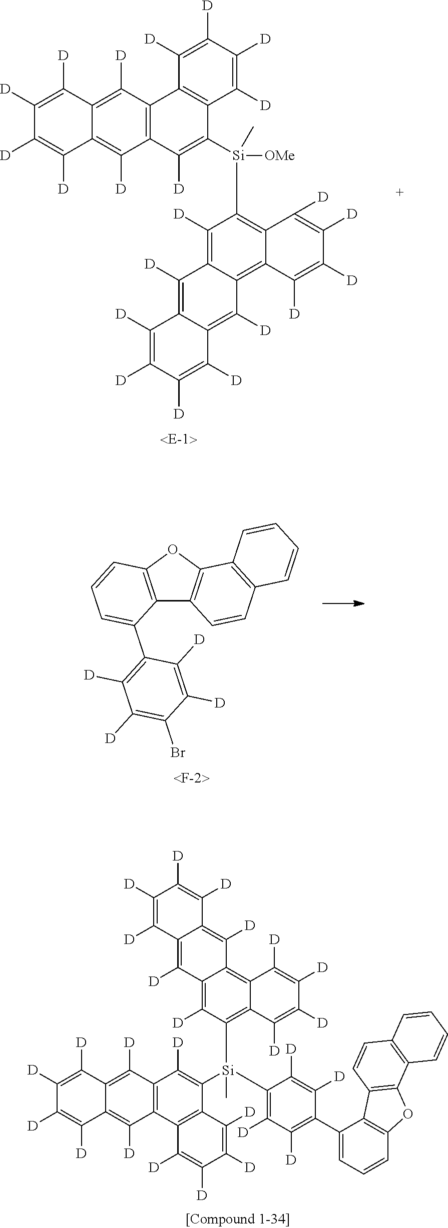

[Compound 1-34] was obtained by performing a synthesis in the same manner as in Synthesis Example 1-2, except that <E-1> was used instead of <A-1>, and <F-2> was used instead of <A-2a>. (Yield 47%)

MS (MALDI-TOF): m/z 816.43 [M⁺]

### Synthesis Example 7: Synthesis of [Compound 1-36]

### Synthesis Example 7-1: Synthesis of G-1

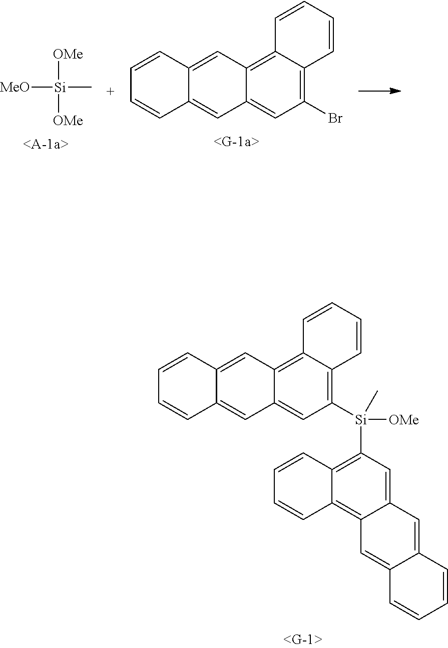

<G-1> was obtained by performing a synthesis in the same manner as in Synthesis Example 1-1, except that <G-1a> was used instead of <A-1b>. (Yield 54%)

### Synthesis Example 7-2: Synthesis of [Compound 1-36]

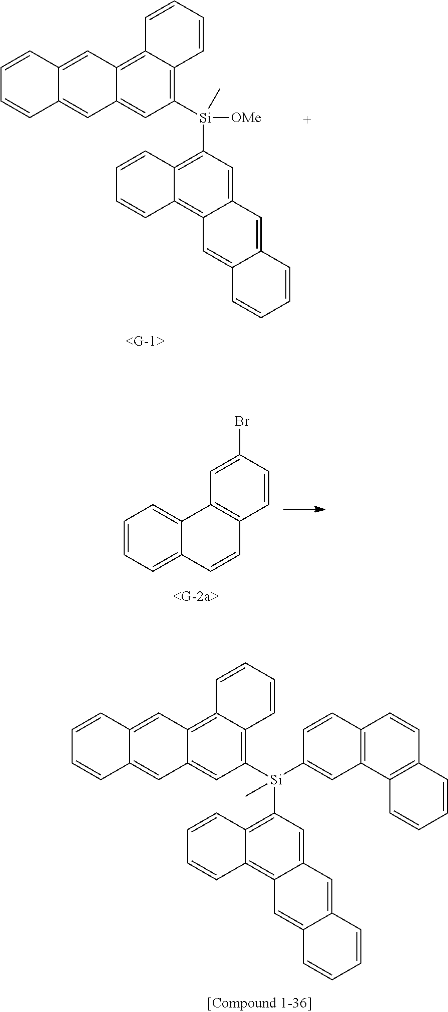 [SMILES: CO[Si](C)(c1cc2cc3ccccc3cc2c2ccccc12)c1cc2cc3ccccc3cc2c2ccccc12 ; Brc1ccc2ccc3ccccc3c2c1 ; C[Si](c1ccc2ccc3ccccc3c2c1)(c1cc2cc3ccccc3cc2c2ccccc12)c1cc2cc3ccccc3cc2c2ccccc12]

[Compound 1-36] was obtained by performing a synthesis in the same manner as in Synthesis Example 1-2, except that <G-1> was used instead of <A-1>, and <G-2a> was used instead of <A-2a>. (Yield 70%) in

MS (MALDI-TOF): m/z 674.24 [M⁺]

### Synthesis Example 8: Synthesis of [Compound 1-39]

### Synthesis Example 8-1: Synthesis of [Compound 1-39]

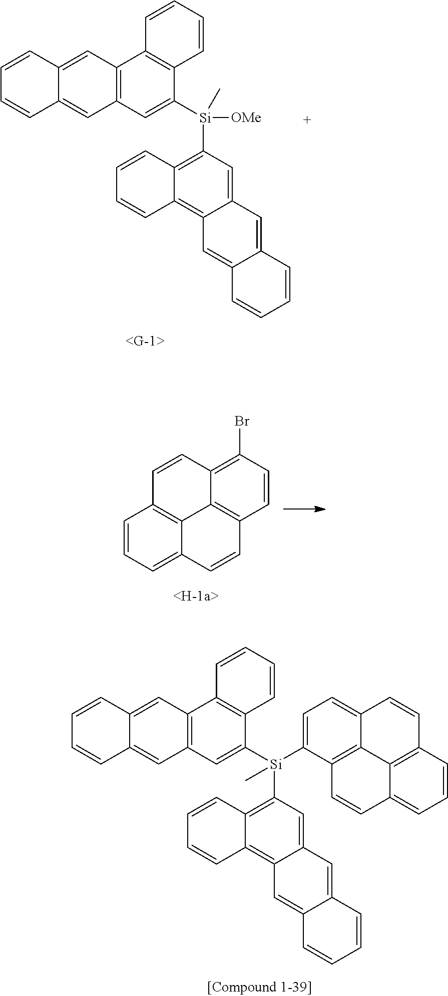 [SMILES: CO[Si](C)(c1cc2cc3ccccc3cc2c2ccccc12)c1cc2cc3ccccc3cc2c2ccccc12 ; Brc1ccc2ccc3cccc4ccc1c2c34 ; C[Si](c1cc2cc3ccccc3cc2c2ccccc12)(c1cc2cc3ccccc3cc2c2ccccc12)c1ccc2ccc3cccc4ccc1c2c34]

[Compound 1-39] was obtained by performing a synthesis in the same manner as in Synthesis Example 1-2, except that <G-1> was used instead of <A-1>, and <H-1a> was used instead of <A-2a>. (Yield 49%)

MS (MALDI-TOF): m/z 698.24 [M⁺]

### Synthesis Example 9: Synthesis of [Compound 1-41]

### Synthesis Example 9-1: Synthesis of I-1

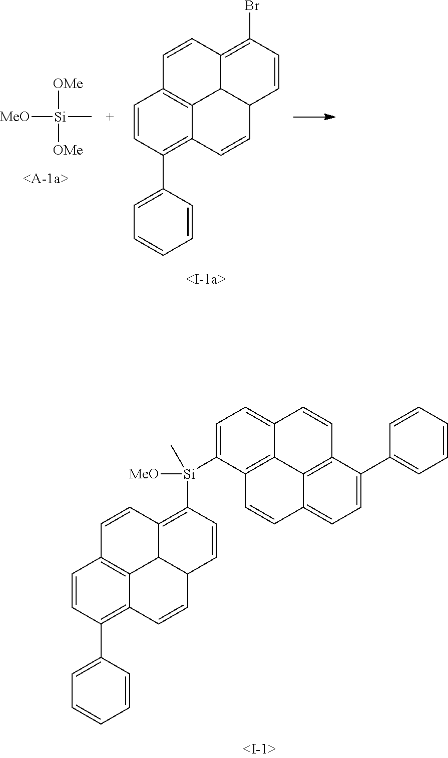

<I-1> was obtained by performing a synthesis in the same manner as in Synthesis Example 1-1, except that <I-1a> was used instead of <A-1b>. (Yield 68%)

### Synthesis Example 9-2: Synthesis of [Compound 1-41]

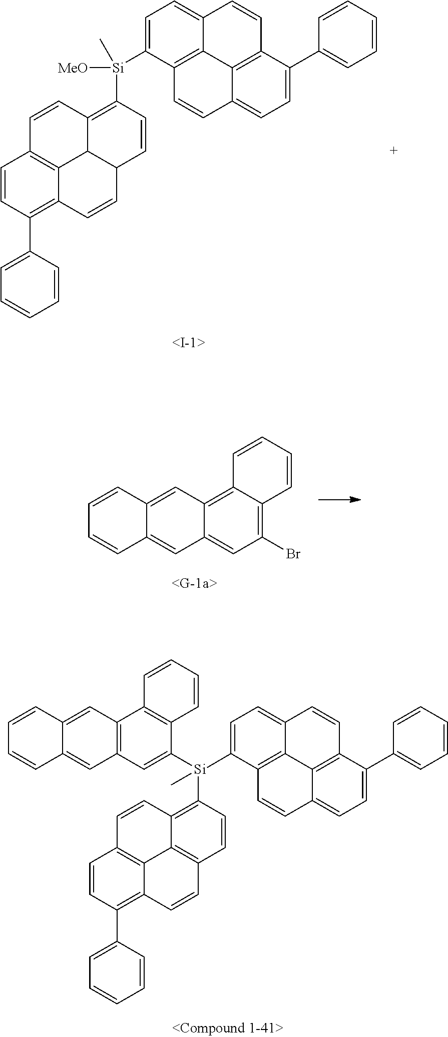 [SMILES: CO[Si](C)(C1=C2C=Cc3ccc(-c4ccccc4)c4c3C2C(C=C1)C=C4)c1ccc2ccc3c(-c4ccccc4)ccc4ccc1c2c43 ; Brc1cc2cc3ccccc3cc2c2ccccc12 ; C[Si](c1cc2cc3ccccc3cc2c2ccccc12)(c1ccc2ccc3c(-c4ccccc4)ccc4ccc1c2c43)c1ccc2ccc3c(-c4ccccc4)ccc4ccc1c2c43]

[Compound 1-41] was obtained by performing a synthesis in the same manner as in Synthesis Example 1-2, except that <I-1> was used instead of <A-1>, and <G-1a> was used instead of <A-2a>. (Yield 46%)

MS (MALDI-TOF): m/z 824.29 [M⁺]

### Synthesis Example 10: Synthesis of [Compound 1-47]

### Synthesis Example 10-1: Synthesis of [Compound 1-47]

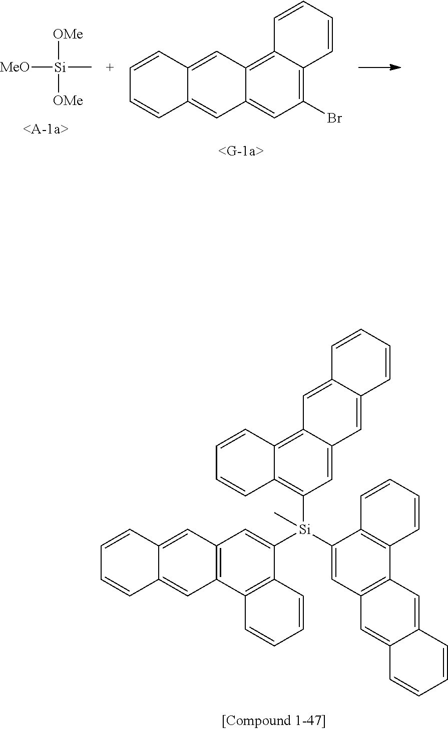

[Compound 1-47] was obtained by performing a synthesis in the same manner as in Synthesis Example 1-1, except that <G-1a> was used instead of <A-1b>. (Yield 48%)

MS (MALDI-TOF): m/z 724.26 [M⁺]

### Synthesis Example 11: Synthesis of [Compound 1-54]

### Synthesis Example 11-1: Synthesis of J-1

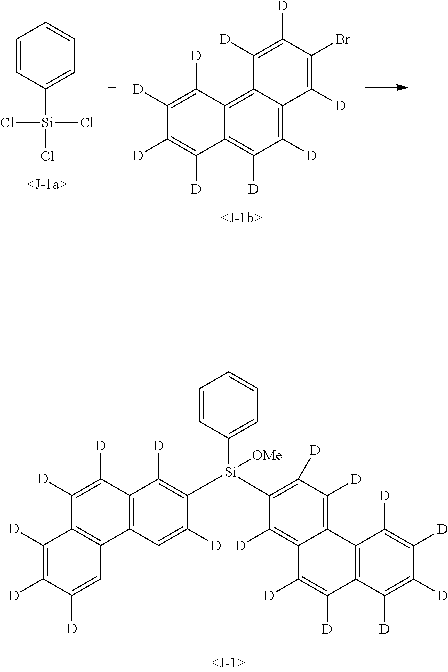 [SMILES: Cl[Si](Cl)(Cl)c1ccccc1 ; [2H]c1c([2H])c([2H])c2c(c1[2H])c([2H])c([2H])c1c([2H])c(Br)c([2H])c([2H])c12 ; [2H]c1cc2c(c([2H])c1[2H])c([2H])c([2H])c1c([2H])c([Si](OC)(c3ccccc3)c3c([2H])c([2H])c4c(c3[2H])c([2H])c([2H])c3c([2H])c([2H])c([2H])c([2H])c34)c([2H])cc12]

<J-1> was obtained by performing a synthesis in the same manner as in Synthesis Example 2-1, except that <J-1a> was used instead of <B-1a>, and <J-1b> was used instead of <B-1b>. (Yield 73%)

### Synthesis Example 11-2: Synthesis of J-2

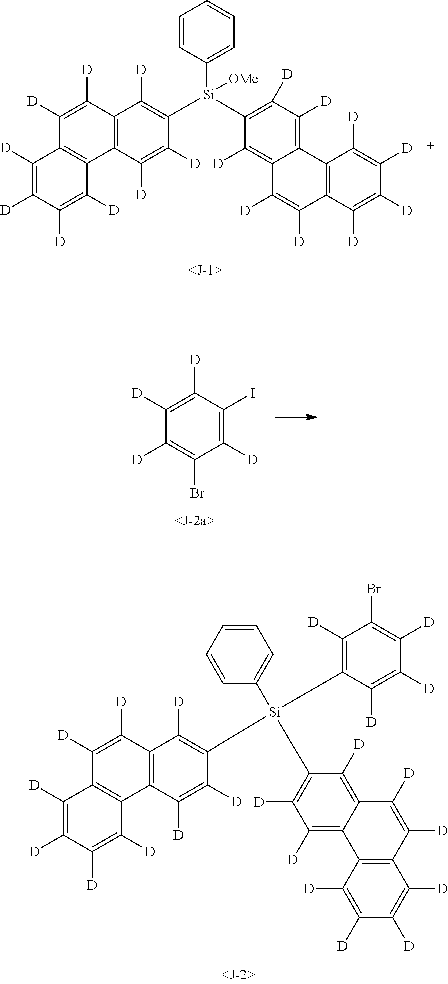 [SMILES: [2H]c1c([2H])c([2H])c2c(c1[2H])c([2H])c([2H])c1c([2H])c([Si](OC)(c3ccccc3)c3c([2H])c([2H])c4c(c3[2H])c([2H])c([2H])c3c([2H])c([2H])c([2H])c([2H])c34)c([2H])c([2H])c12 ; [2H]c1c([2H])c(Br)c([2H])c(I)c1[2H] ; [2H]c1c([2H])c(Br)c([2H])c([Si](c2ccccc2)(c2c([2H])c([2H])c3c(c2[2H])c([2H])c([2H])c2c([2H])c([2H])c([2H])c([2H])c23)c2c([2H])c([2H])c3c(c2[2H])c([2H])c([2H])c2c([2H])c([2H])c([2H])c([2H])c23)c1[2H]]

<J-2> was obtained by performing a synthesis in the same manner as in Synthesis Example 1-2, except that <J-1> was used instead of <A-1>, and <J-2a> was used instead of <A-2a>. (Yield 82%)

### Synthesis Example 11-3: Synthesis of J-3

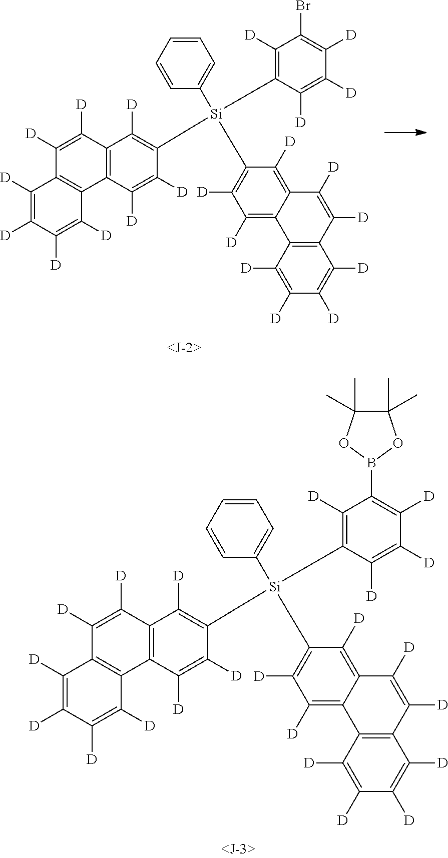 [SMILES: [2H]c1c([2H])c(Br)c([2H])c([Si](c2ccccc2)(c2c([2H])c([2H])c3c(c2[2H])c([2H])c([2H])c2c([2H])c([2H])c([2H])c([2H])c23)c2c([2H])c([2H])c3c(c2[2H])c([2H])c([2H])c2c([2H])c([2H])c([2H])c([2H])c23)c1[2H] ; [2H]c1c([2H])c(B2OC(C)(C)C(C)(C)O2)c([2H])c([Si](c2ccccc2)(c2c([2H])c([2H])c3c(c2[2H])c([2H])c([2H])c2c([2H])c([2H])c([2H])c([2H])c23)c2c([2H])c([2H])c3c(c2[2H])c([2H])c([2H])c2c([2H])c([2H])c([2H])c([2H])c23)c1[2H]]

<J-3> was obtained by performing a synthesis in the same manner as in Synthesis Example 6-1, except that <J-2> was used instead of <F-1a>. (Yield 84%)

### Synthesis Example 11-4: Synthesis of [Compound 1-54]

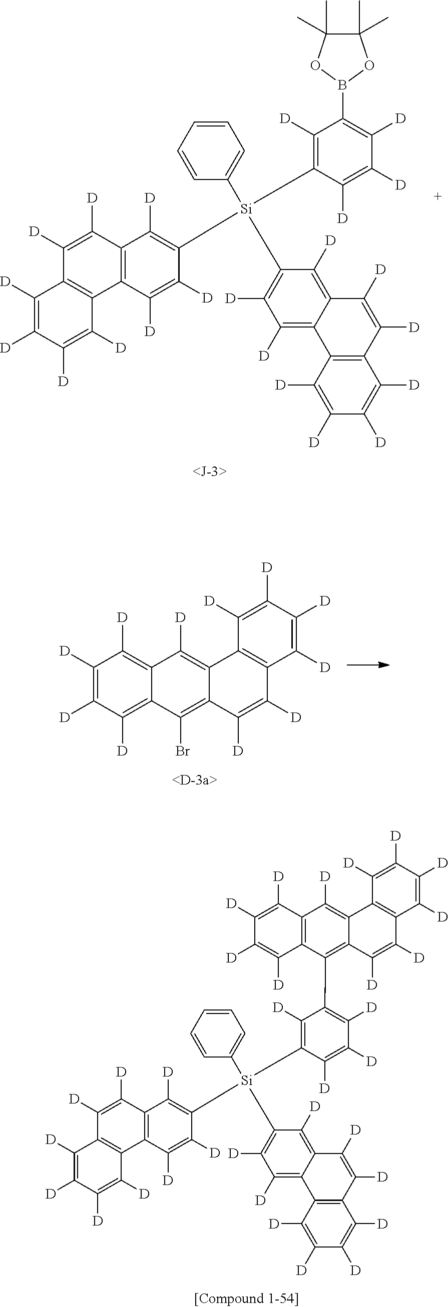

[Compound 1-54] was obtained by performing a synthesis in the same manner as in Synthesis Example 6-2, except that <J-3> was used instead of <F-1>, and <D-3a> was used instead of <F-2a>. (Yield 76%)

MS (MALDI-TOF): m/z 795.48 [M⁺]

### Synthesis Example 12: Synthesis of [Compound 1-58]

### Synthesis Example 12-1: Synthesis of K-1

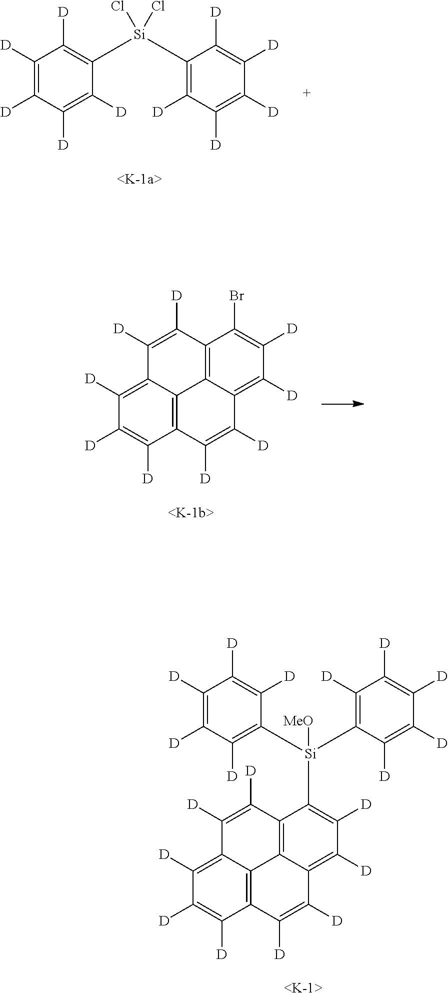 [SMILES: [2H]c1c([2H])c([2H])c([Si](Cl)(Cl)c2c([2H])c([2H])c([2H])c([2H])c2[2H])c([2H])c1[2H] ; [2H]c1c([2H])c2c([2H])c([2H])c3c([2H])c([2H])c(Br)c4c([2H])c([2H])c(c1[2H])c2c34 ; [2H]c1c([2H])c([2H])c([Si](OC)(c2c([2H])c([2H])c([2H])c([2H])c2[2H])c2c([2H])c([2H])c3c([2H])c([2H])c4c([2H])c([2H])c([2H])c5c([2H])c([2H])c2c3c45)c([2H])c1[2H]]

<K-1> was obtained by performing a synthesis in the same manner as in Synthesis Example 2-1, except that <K-1a> was used instead of <B-1a>, and <K-1b> was used instead of <B-1b>. (Yield 70%)

### Synthesis Example 12-2: Synthesis of K-2

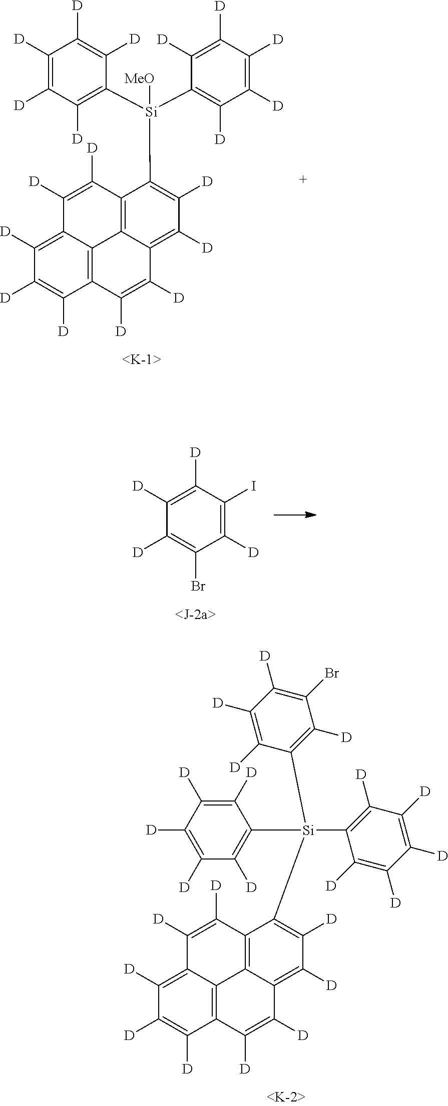 [SMILES: [2H]c1c([2H])c([2H])c([Si](OC)(c2c([2H])c([2H])c([2H])c([2H])c2[2H])c2c([2H])c([2H])c3c([2H])c([2H])c4c([2H])c([2H])c([2H])c5c([2H])c([2H])c2c3c45)c([2H])c1[2H] ; [2H]c1c([2H])c(Br)c([2H])c(I)c1[2H] ; [2H]c1c([2H])c([2H])c([Si](c2c([2H])c([2H])c([2H])c([2H])c2[2H])(c2c([2H])c([2H])c([2H])c(Br)c2[2H])c2c([2H])c([2H])c3c([2H])c([2H])c4c([2H])c([2H])c([2H])c5c([2H])c([2H])c2c3c45)c([2H])c1[2H]]

<K-2> was obtained by performing a synthesis in the same manner as in Synthesis Example 1-2, except that <K-1> was used instead of <A-1>, and <J-2a> was used instead of <A-2a>. (Yield 84%)

### Synthesis Example 12-3: Synthesis of K-3

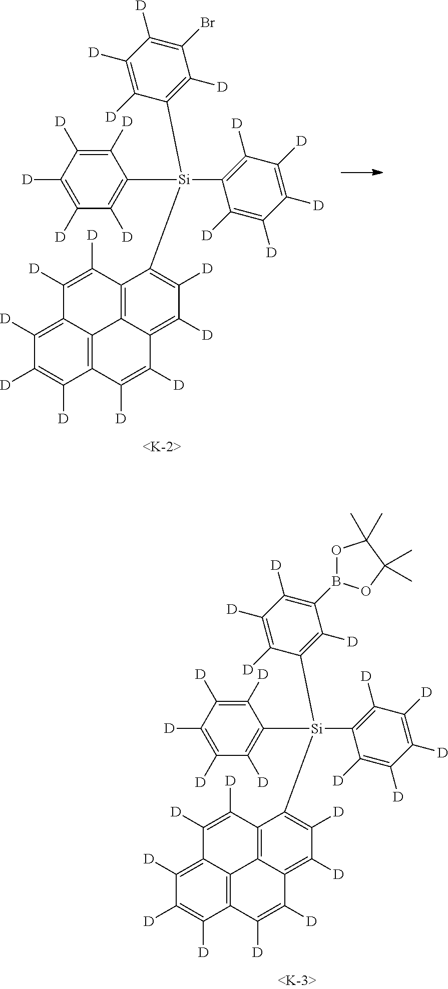 [SMILES: [2H]c1c([2H])c([2H])c([Si](c2c([2H])c([2H])c([2H])c([2H])c2[2H])(c2c([2H])c([2H])c([2H])c(Br)c2[2H])c2c([2H])c([2H])c3c([2H])c([2H])c4c([2H])c([2H])c([2H])c5c([2H])c([2H])c2c3c45)c([2H])c1[2H] ; [2H]c1c([2H])c([2H])c([Si](c2c([2H])c([2H])c([2H])c([2H])c2[2H])(c2c([2H])c([2H])c([2H])c(B3OC(C)(C)C(C)(C)O3)c2[2H])c2c([2H])c([2H])c3c([2H])c([2H])c4c([2H])c([2H])c([2H])c5c([2H])c([2H])c2c3c45)c([2H])c1[2H]]

<K-3> was obtained by performing a synthesis in the same manner as in Synthesis Example 6-1, except that <K-2> was used instead of <F-1a>. (Yield 85%)

### Synthesis Example 12-4: Synthesis of [Compound 1-58]

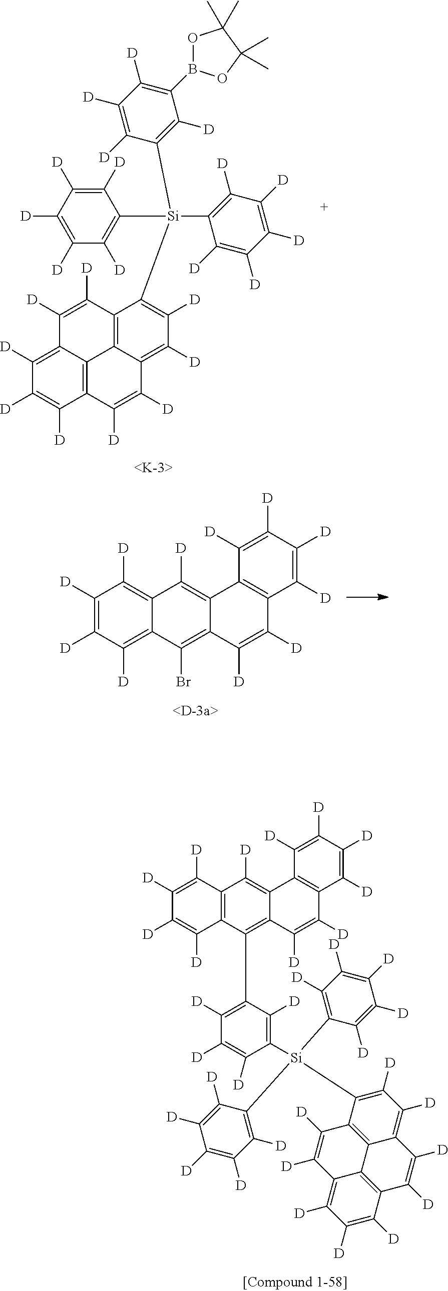

[Compound 1-58] was obtained by performing a synthesis in the same manner as in Synthesis Example 6-2, except that <K-3> was used instead of <F-1>, and <D-3a> was used instead of <F-2a>. (Yield 71%)

MS (MALDI-TOF): m/z 720.46 [M⁺]

### Synthesis Example 13: Synthesis of [Compound 1-61]

### Synthesis Example 13-1: Synthesis of L-1

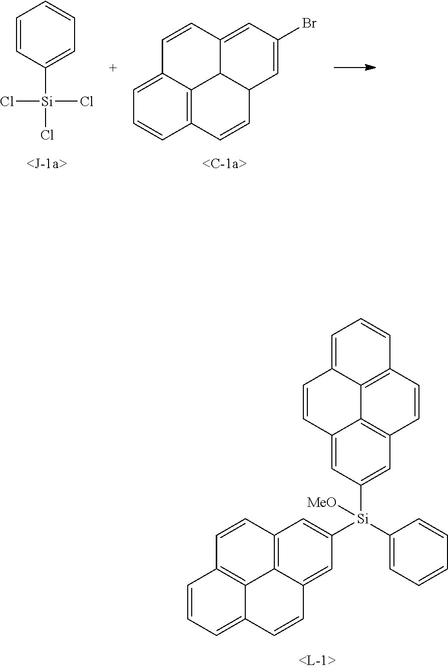 [SMILES: Cl[Si](Cl)(Cl)c1ccccc1 ; BrC1=CC2C=Cc3cccc4c3C2C(=C1)C=C4 ; CO[Si](c1ccccc1)(c1cc2ccc3cccc4ccc(c1)c2c34)c1cc2ccc3cccc4ccc(c1)c2c34]

<L-1> was obtained by performing a synthesis in the same manner as in Synthesis Example 2-1, except that <J-1a> was used instead of <B-1a>, and <C-1a> was used instead of <B-1b>. (Yield 72%)

### Synthesis Example 13-2: Synthesis of L-2

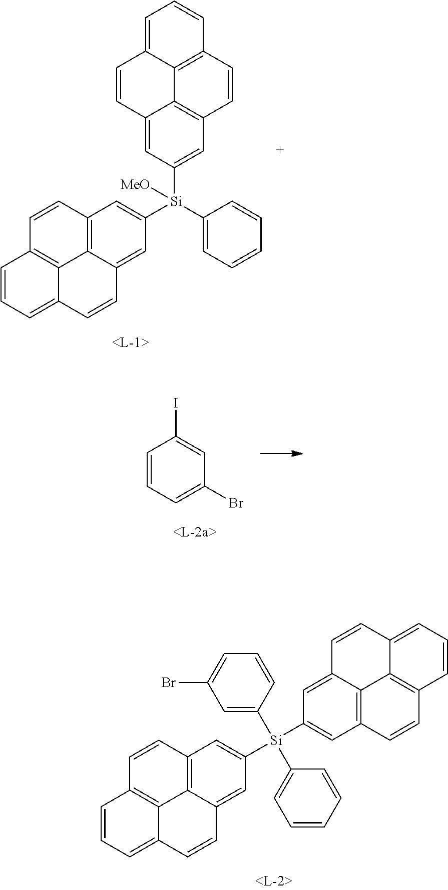 [SMILES: CO[Si](c1ccccc1)(c1cc2ccc3cccc4ccc(c1)c2c34)c1cc2ccc3cccc4ccc(c1)c2c34 ; Brc1cccc(I)c1 ; Brc1cccc([Si](c2ccccc2)(c2cc3ccc4cccc5ccc(c2)c3c45)c2cc3ccc4cccc5ccc(c2)c3c45)c1]

<1-2> was obtained by performing a synthesis in the same manner as in Synthesis Example 1-2, except that <L-1> was used instead of <A-1>, and <L-2a> was used instead of <A-2a>. (Yield 77%)

### Synthesis Example 13-3: Synthesis of L-3

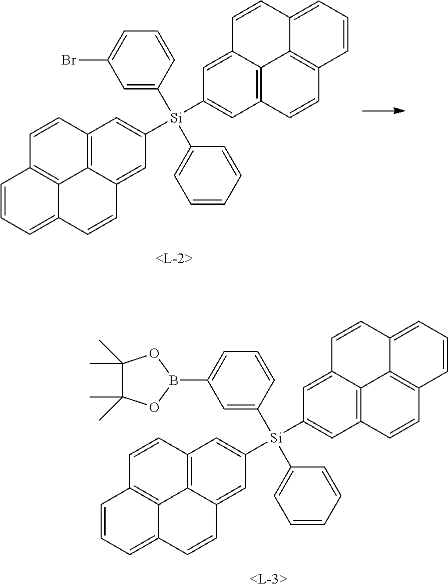 [SMILES: Brc1cccc([Si](c2ccccc2)(c2cc3ccc4cccc5ccc(c2)c3c45)c2cc3ccc4cccc5ccc(c2)c3c45)c1 ; CC1(C)OB(c2cccc([Si](c3ccccc3)(c3cc4ccc5cccc6ccc(c3)c4c56)c3cc4ccc5cccc6ccc(c3)c4c56)c2)OC1(C)C]

<L-3> was obtained by performing a synthesis in the same manner as in Synthesis Example 6-1, except that <L-2> was used instead of <F-1a>. (Yield 84%)

### Synthesis Example 13-4: Synthesis of [Compound 1-61]

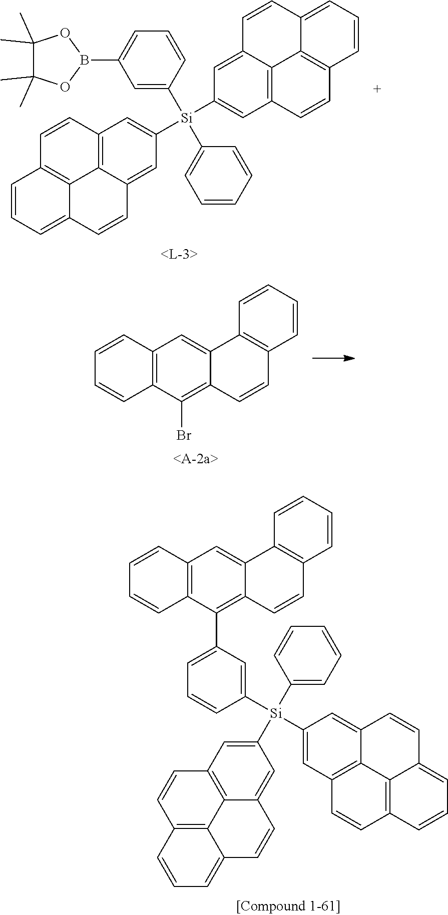 [SMILES: CC1(C)OB(c2cccc([Si](c3ccccc3)(c3cc4ccc5cccc6ccc(c3)c4c56)c3cc4ccc5cccc6ccc(c3)c4c56)c2)OC1(C)C ; Brc1c2ccccc2cc2c1ccc1ccccc12 ; c1ccc([Si](c2cccc(-c3c4ccccc4cc4c3ccc3ccccc34)c2)(c2cc3ccc4cccc5ccc(c2)c3c45)c2cc3ccc4cccc5ccc(c2)c3c45)cc1]

[Compound 1-61] was obtained by performing a synthesis in the same manner as in Synthesis Example 6-2, except that <L-3> was used instead of <F-1>, and <A-2a> was used instead of <F-2a>. (Yield 54%)

MS (MALDI-TOF): m/z 810.27 [M⁺]

### Synthesis Example 14: Synthesis of [Compound 1-62]

### Synthesis Example 14-1: Synthesis of M-1

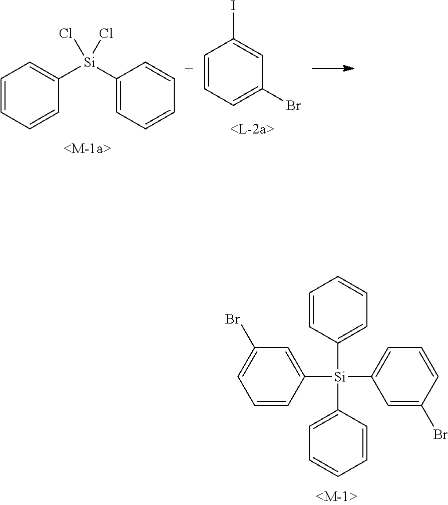

<M-1> was obtained by performing a synthesis in the same manner as in Synthesis Example 2-1, except that <M-1a> was used instead of <B-1a>, and <L-2a> was used instead of <B-1b>. (Yield 79%)

### Synthesis Example 14-2: Synthesis of M-2

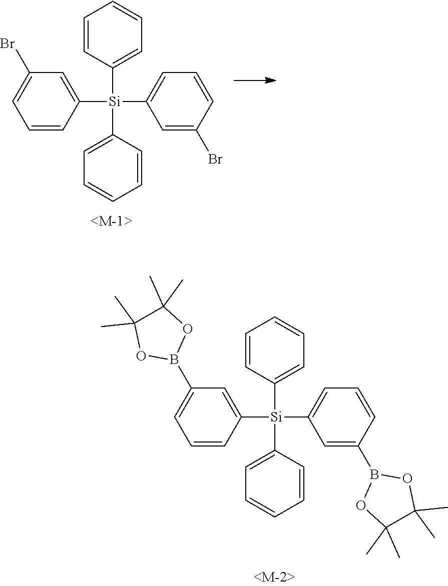

<M-2> was obtained by performing a synthesis in the same manner as in Synthesis Example 6-1, except that <M-1> was used instead of <F-1a>. (Yield 76%)

### Synthesis Example 14-3: Synthesis of [Compound 1-62]

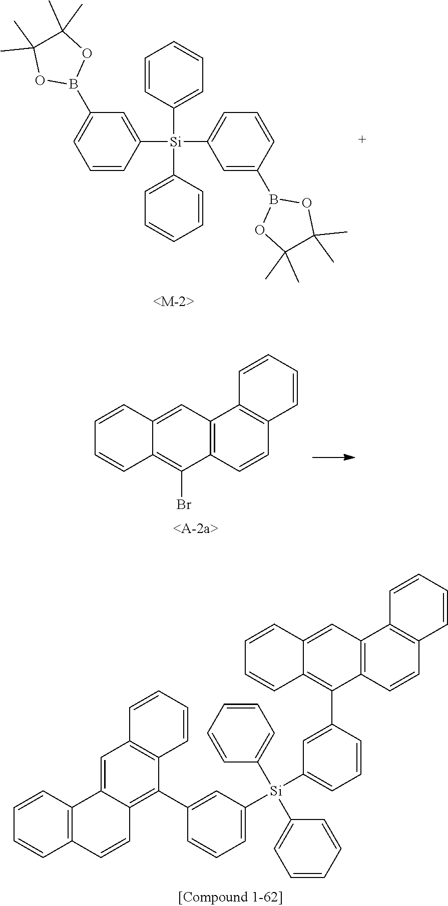

[Compound 1-62] was obtained by performing a synthesis in the same manner as in Synthesis Example 6-2, except that <M-2> was used instead of <F-1>, and <A-2a> was used instead of <F-2a>. (Yield 50%)

MS (MALDI-TOF): m/z 788.29 [M⁺]

### Synthesis Example 15: Synthesis of [Compound 1-63]

### Synthesis Example 15-1: Synthesis of N-1

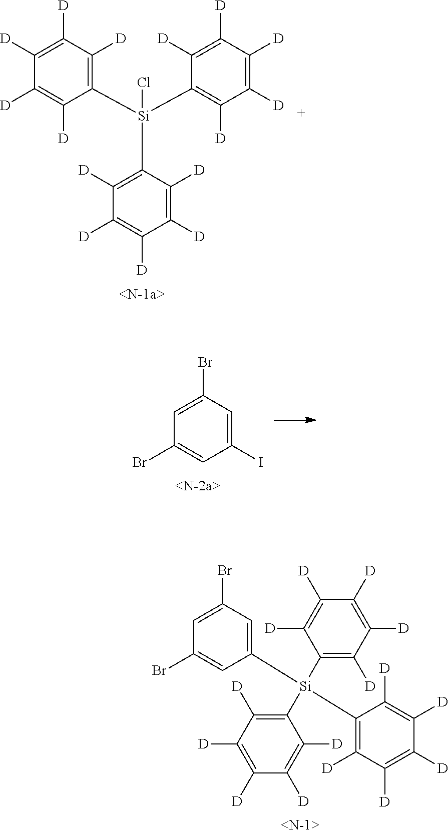 [SMILES: [2H]c1c([2H])c([2H])c([Si](Cl)(c2c([2H])c([2H])c([2H])c([2H])c2[2H])c2c([2H])c([2H])c([2H])c([2H])c2[2H])c([2H])c1[2H] ; Brc1cc(Br)cc(I)c1 ; [2H]c1c([2H])c([2H])c([Si](c2cc(Br)cc(Br)c2)(c2c([2H])c([2H])c([2H])c([2H])c2[2H])c2c([2H])c([2H])c([2H])c([2H])c2[2H])c([2H])c1[2H]]

<N-1> was obtained by performing a synthesis in the same manner as in Synthesis Example 2-1, except that <N-1a> was used instead of <B-1a>, and <N-2a> was used instead of <B-1b>. (Yield 60%)

### Synthesis Example 15-2: Synthesis of N-2

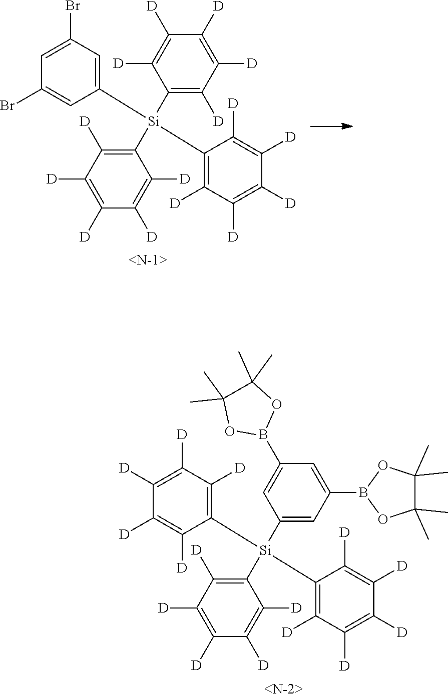 [SMILES: [2H]c1c([2H])c([2H])c([Si](c2cc(Br)cc(Br)c2)(c2c([2H])c([2H])c([2H])c([2H])c2[2H])c2c([2H])c([2H])c([2H])c([2H])c2[2H])c([2H])c1[2H] ; [2H]c1c([2H])c([2H])c([Si](c2cc(B3OC(C)(C)C(C)(C)O3)cc(B3OC(C)(C)C(C)(C)O3)c2)(c2c([2H])c([2H])c([2H])c([2H])c2[2H])c2c([2H])c([2H])c([2H])c([2H])c2[2H])c([2H])c1[2H]]

<N-2> was obtained by performing a synthesis in the same manner as in Synthesis Example 6-1, except that <N-1> was used instead of <F-1a>. (Yield 67%)

### Synthesis Example 15-3: Synthesis of [Compound 1-63]

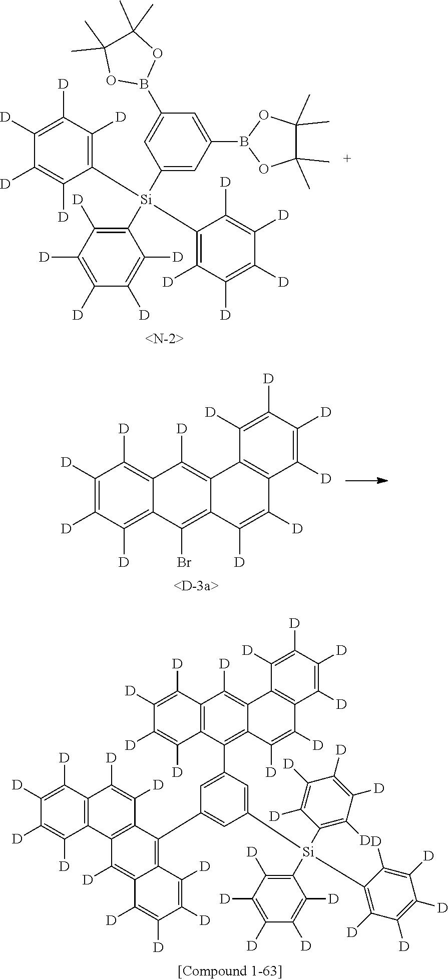

[Compound 1-63] was obtained by performing a synthesis in the same manner as in Synthesis Example 6-2, except that <N-2> was used instead of <F-1>, and <D-3a> was used instead of <F-2a>. (Yield 65%)

MS (MALDI-TOF): m/z 825.52 [M⁺]

### Synthesis Example 16: Synthesis of [Compound 1-64]

### Synthesis Example 16-1: Synthesis of 0-1

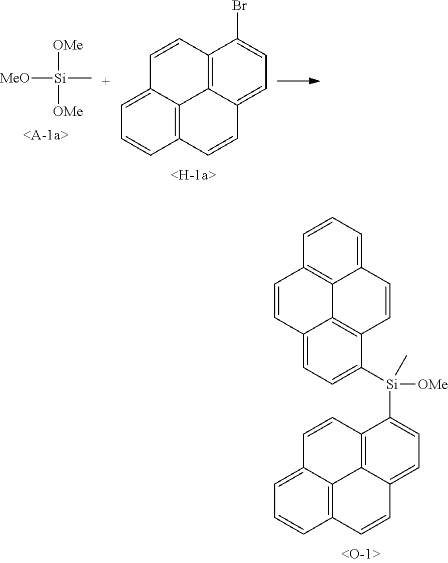

<0-1> was obtained by performing a synthesis in the same manner as in Synthesis Example 1-1, except that <H-1a> was used instead of <A-1b>. (Yield 69%)

### Synthesis Example 16-2: Synthesis of 0-2

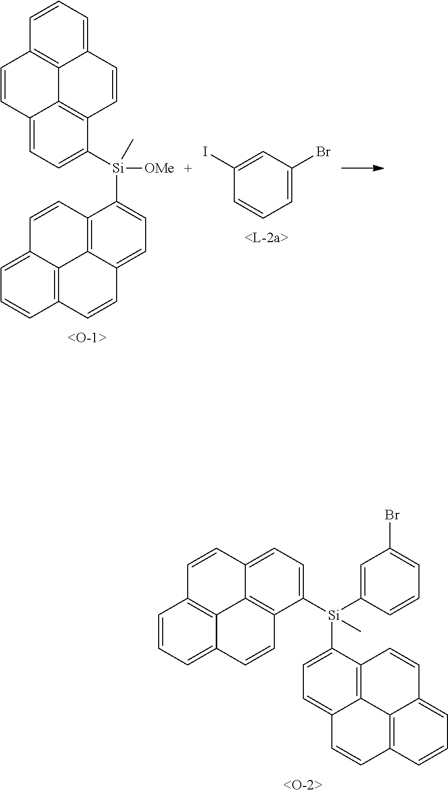 [SMILES: CO[Si](C)(c1ccc2ccc3cccc4ccc1c2c34)c1ccc2ccc3cccc4ccc1c2c34 ; Brc1cccc(I)c1 ; C[Si](c1cccc(Br)c1)(c1ccc2ccc3cccc4ccc1c2c34)c1ccc2ccc3cccc4ccc1c2c34]

<0-2> was obtained by performing a synthesis in the same manner as in Synthesis Example 1-2, except that <0-1> was used instead of <A-1>, and <L-2a> was used instead of <A-2a>. (Yield 75%)

### Synthesis Example 16-3: Synthesis of 0-3

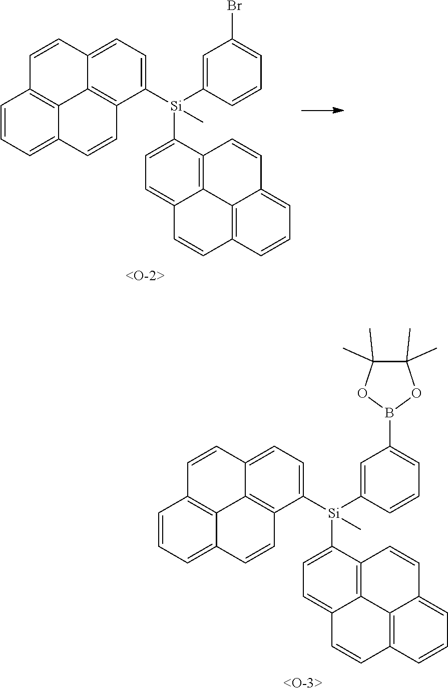 [SMILES: C[Si](c1cccc(Br)c1)(c1ccc2ccc3cccc4ccc1c2c34)c1ccc2ccc3cccc4ccc1c2c34 ; CC1(C)OB(c2cccc([Si](C)(c3ccc4ccc5cccc6ccc3c4c56)c3ccc4ccc5cccc6ccc3c4c56)c2)OC1(C)C]

<0-3> was obtained by performing a synthesis in the same manner as in Synthesis Example 6-1, except that <0-2> was used instead of <F-1a>. (Yield 82%)

### Synthesis Example 16-4: Synthesis of [Compound 1-64]

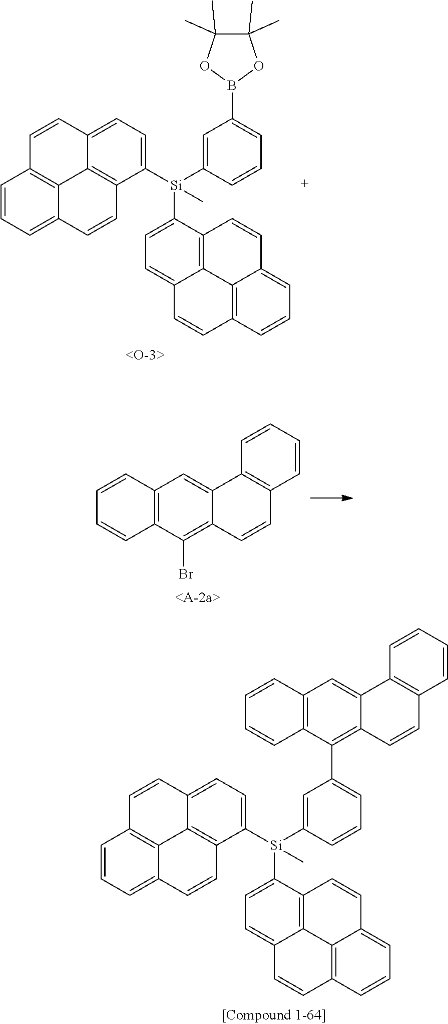 [SMILES: CC1(C)OB(c2cccc([Si](C)(c3ccc4ccc5cccc6ccc3c4c56)c3ccc4ccc5cccc6ccc3c4c56)c2)OC1(C)C ; Brc1c2ccccc2cc2c1ccc1ccccc12 ; C[Si](c1cccc(-c2c3ccccc3cc3c2ccc2ccccc23)c1)(c1ccc2ccc3cccc4ccc1c2c34)c1ccc2ccc3cccc4ccc1c2c34]

[Compound 1-64] was obtained by performing a synthesis in the same manner as in Synthesis Example 6-2, except that <0-3> was used instead of <F-1>, and <A-2a> was used instead of <F-2a>. (Yield 56%)

MS (MALDI-TOF): m/z 748.26 [M⁺]

### Synthesis Example 17: Synthesis of [Compound 1-65]

### Synthesis Example 17-1: Synthesis of P-1

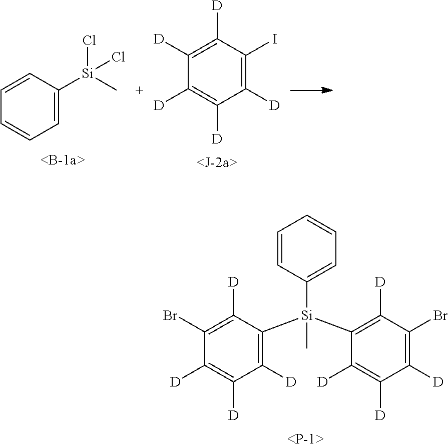

<P-1> was obtained by performing a synthesis in the same manner as in Synthesis Example 2-1, except that <J-2a> was used instead of <B-1b>. (Yield 76%)

### Synthesis Example 17-2: Synthesis of P-2

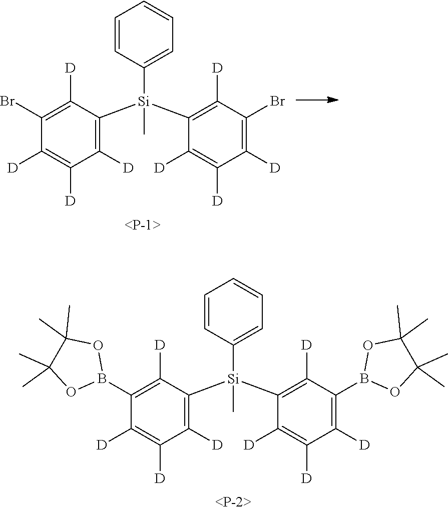

<P-2> was obtained by performing a synthesis in the same manner as in Synthesis Example 6-1, except that <P-1> was used instead of <F-1a>. (Yield 70%)

### Synthesis Example 17-3: Synthesis of [Compound 1-65]

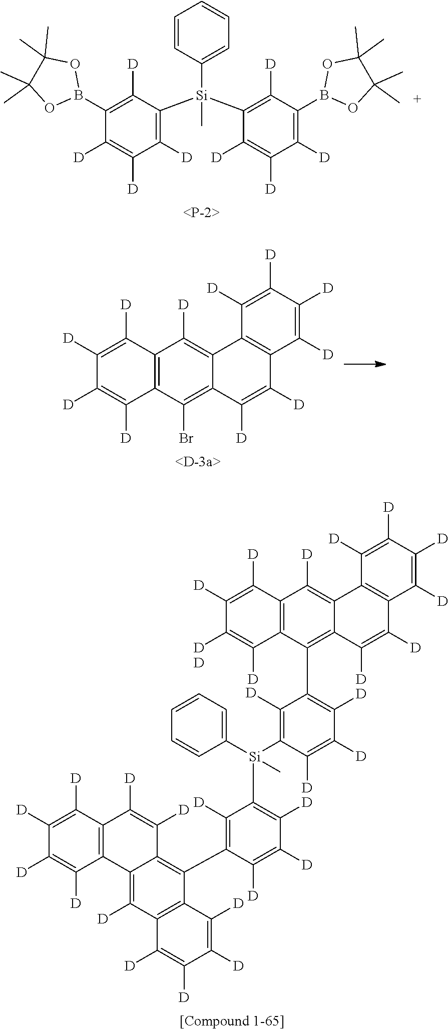

[Compound 1-65] was obtained by performing a synthesis in the same manner as in Synthesis Example 6-2, except that <P-2> was used instead of <F-1>, and <D-3a> was used instead of <F-2a>. (Yield 55%)

MS (MALDI-TOF): m/z 756.46 [M⁺]

### Synthesis Example 18: Synthesis of [Compound 1-72]

### Synthesis Example 18-1: Synthesis of Q-1

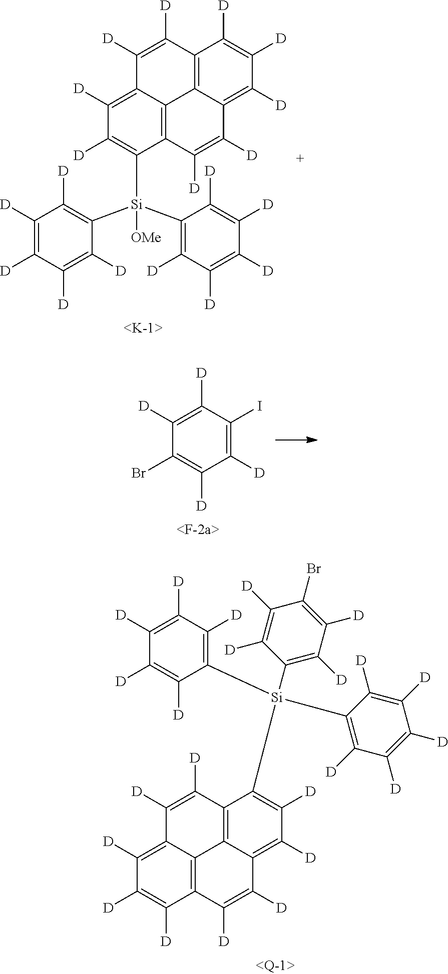 [SMILES: [2H]c1c([2H])c([2H])c([Si](OC)(c2c([2H])c([2H])c([2H])c([2H])c2[2H])c2c([2H])c([2H])c3c([2H])c([2H])c4c([2H])c([2H])c([2H])c5c([2H])c([2H])c2c3c45)c([2H])c1[2H] ; [2H]c1c([2H])c(I)c([2H])c([2H])c1Br ; [2H]c1c([2H])c([2H])c([Si](c2c([2H])c([2H])c([2H])c([2H])c2[2H])(c2c([2H])c([2H])c(Br)c([2H])c2[2H])c2c([2H])c([2H])c3c([2H])c([2H])c4c([2H])c([2H])c([2H])c5c([2H])c([2H])c2c3c45)c([2H])c1[2H]]

<Q-1> was obtained by performing a synthesis in the same manner as in Synthesis Example 1-2, except that <K-1> was used instead of <A-1>, and <F-2a> was used instead of <A-2a>. (Yield 78%)

### Synthesis Example 18-2: Synthesis of Q-2

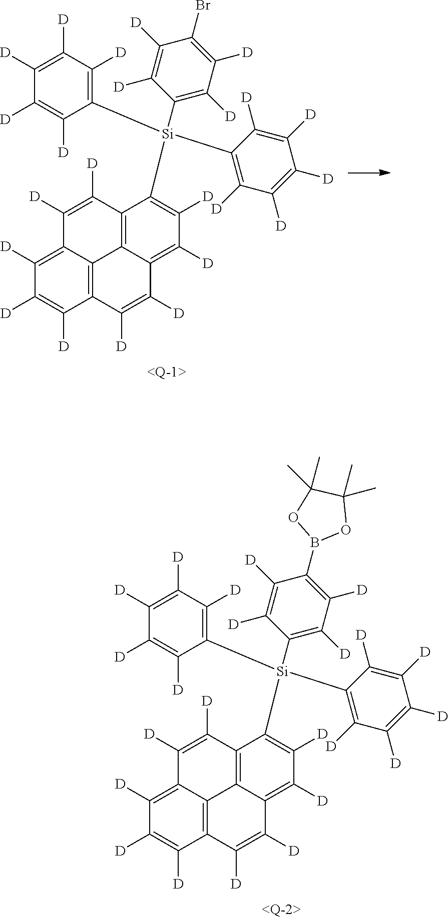 [SMILES: [2H]c1c([2H])c([2H])c([Si](c2c([2H])c([2H])c([2H])c([2H])c2[2H])(c2c([2H])c([2H])c(Br)c([2H])c2[2H])c2c([2H])c([2H])c3c([2H])c([2H])c4c([2H])c([2H])c([2H])c5c([2H])c([2H])c2c3c45)c([2H])c1[2H] ; [2H]c1c([2H])c([2H])c([Si](c2c([2H])c([2H])c([2H])c([2H])c2[2H])(c2c([2H])c([2H])c(B3OC(C)(C)C(C)(C)O3)c([2H])c2[2H])c2c([2H])c([2H])c3c([2H])c([2H])c4c([2H])c([2H])c([2H])c5c([2H])c([2H])c2c3c45)c([2H])c1[2H]]

<Q-2> was obtained by performing a synthesis in the same manner as in Synthesis Example 6-1, except that <Q-1> was used instead of <F-1a>. (Yield 81%)

### Synthesis Example 18-3: Synthesis of [Compound 1-72]

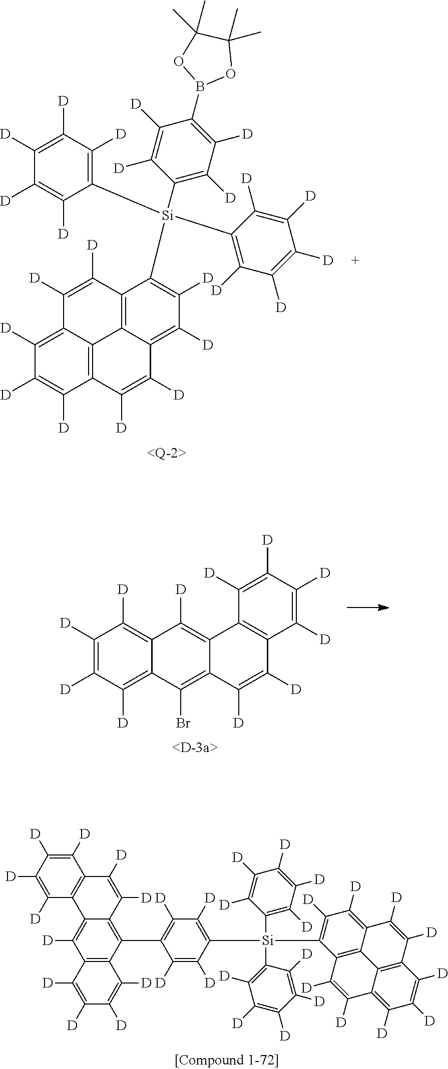

[Compound 1-72] was obtained by performing a synthesis in the same manner as in Synthesis Example 6-2, except that <Q-2> was used instead of <F-1>, and <D-3a> was used instead of <F-2a>. (Yield 59%)

MS (MALDI-TOF): m/z 720.46 [M⁺]

### Synthesis Example 19: Synthesis of [Compound 1-85]

### Synthesis Example 19-1: Synthesis of R-1

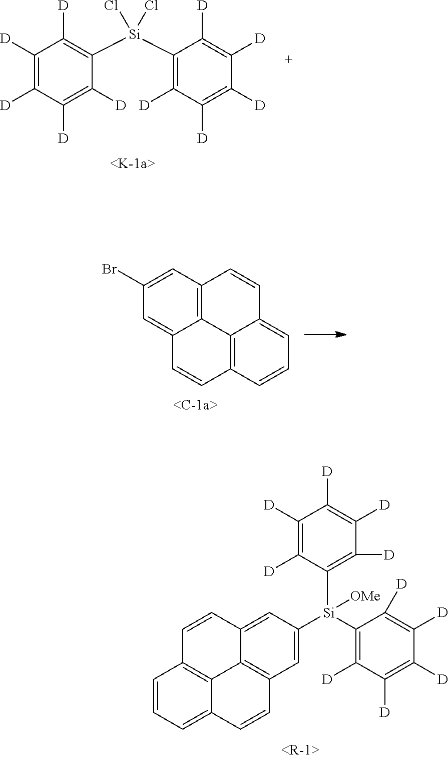 [SMILES: [2H]c1c([2H])c([2H])c([Si](Cl)(Cl)c2c([2H])c([2H])c([2H])c([2H])c2[2H])c([2H])c1[2H] ; Brc1cc2ccc3cccc4ccc(c1)c2c34 ; [2H]c1c([2H])c([2H])c([Si](OC)(c2cc3ccc4cccc5ccc(c2)c3c45)c2c([2H])c([2H])c([2H])c([2H])c2[2H])c([2H])c1[2H]]

<R-1> was obtained by performing a synthesis in the same manner as in Synthesis Example 2-1, except that <K-1a> was used instead of <B-1a>, and <C-1a> was used instead of <B-1b>. (Yield 71%)

### Synthesis Example 19-2: Synthesis of R-2

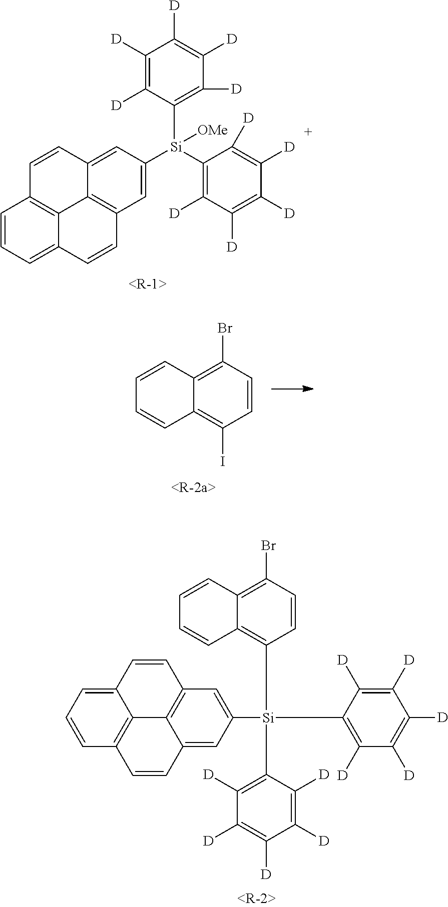 [SMILES: [2H]c1c([2H])c([2H])c([Si](OC)(c2cc3ccc4cccc5ccc(c2)c3c45)c2c([2H])c([2H])c([2H])c([2H])c2[2H])c([2H])c1[2H] ; Brc1ccc(I)c2ccccc12 ; [2H]c1c([2H])c([2H])c([Si](c2cc3ccc4cccc5ccc(c2)c3c45)(c2c([2H])c([2H])c([2H])c([2H])c2[2H])c2ccc(Br)c3ccccc23)c([2H])c1[2H]]

<R-2> was obtained by performing a synthesis in the same manner as in Synthesis Example 1-2, except that <R-1> was used instead of <A-1>, and <R-2a> was used instead of <A-2a>. (Yield 60%)

### Synthesis Example 19-3: Synthesis of R-3

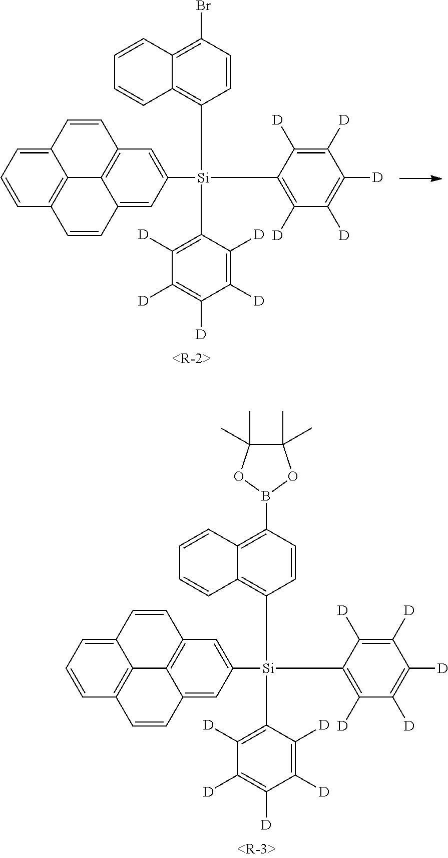 [SMILES: [2H]c1c([2H])c([2H])c([Si](c2cc3ccc4cccc5ccc(c2)c3c45)(c2c([2H])c([2H])c([2H])c([2H])c2[2H])c2ccc(Br)c3ccccc23)c([2H])c1[2H] ; [2H]c1c([2H])c([2H])c([Si](c2cc3ccc4cccc5ccc(c2)c3c45)(c2c([2H])c([2H])c([2H])c([2H])c2[2H])c2ccc(B3OC(C)(C)C(C)(C)O3)c3ccccc23)c([2H])c1[2H]]

<R-3> was obtained by performing a synthesis in the same manner as in Synthesis Example 6-1, except that <R-2> was used instead of <F-1a>. (Yield 84%)

### Synthesis Example 19-4: Synthesis of [Compound 1-85]

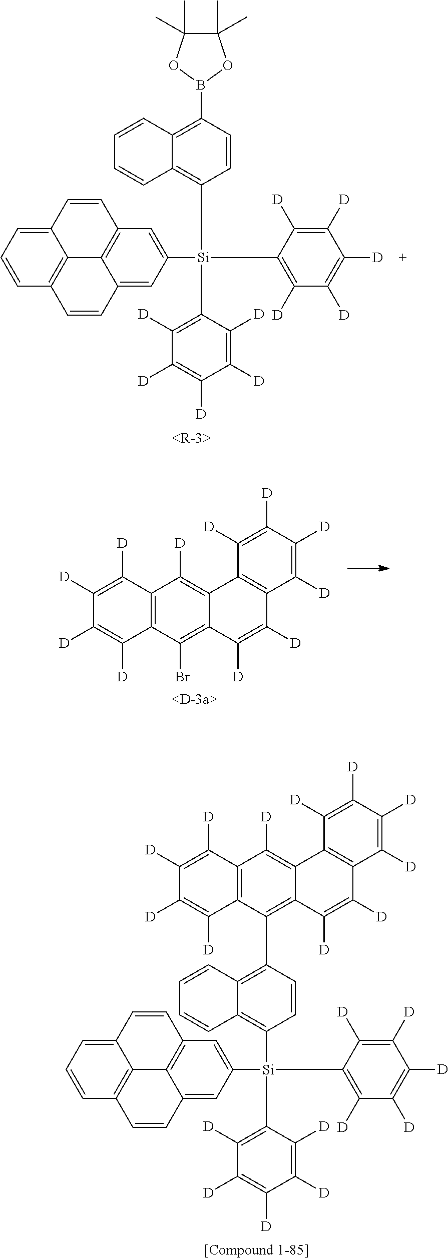 [SMILES: [2H]c1c([2H])c([2H])c([Si](c2cc3ccc4cccc5ccc(c2)c3c45)(c2c([2H])c([2H])c([2H])c([2H])c2[2H])c2ccc(B3OC(C)(C)C(C)(C)O3)c3ccccc23)c([2H])c1[2H] ; [2H]c1c([2H])c([2H])c2c([2H])c3c(c([2H])c([2H])c4c([2H])c([2H])c([2H])c([2H])c43)c(Br)c2c1[2H] ; [2H]c1c([2H])c([2H])c([Si](c2cc3ccc4cccc5ccc(c2)c3c45)(c2c([2H])c([2H])c([2H])c([2H])c2[2H])c2ccc(-c3c4c([2H])c([2H])c([2H])c([2H])c4c([2H])c4c3c([2H])c([2H])c3c([2H])c([2H])c([2H])c([2H])c34)c3ccccc23)c([2H])c1[2H]]

[Compound 1-85] was obtained by performing a synthesis in the same manner as in Synthesis Example 6-2, except that <R-3> was used instead of <F-1>, and <D-3a> was used instead of <F-2a>. (Yield 56%)

MS (MALDI-TOF): m/z 757.39 [M⁺]

### Synthesis Example 20: Synthesis of [Compound 1-89]

### Synthesis Example 20-1: Synthesis of S-1

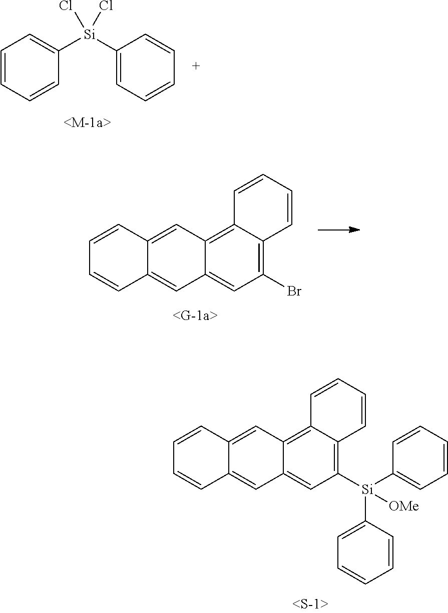 [SMILES: Cl[Si](Cl)(c1ccccc1)c1ccccc1 ; Brc1cc2cc3ccccc3cc2c2ccccc12 ; CO[Si](c1ccccc1)(c1ccccc1)c1cc2cc3ccccc3cc2c2ccccc12]

<S-1> was obtained by performing a synthesis in the same manner as in Synthesis Example 2-1, except that <M-1a> was used instead of <B-1a>, and <G-1a> was used instead of <B-1b>. (Yield 62%)

### Synthesis Example 20-2: Synthesis of S-2

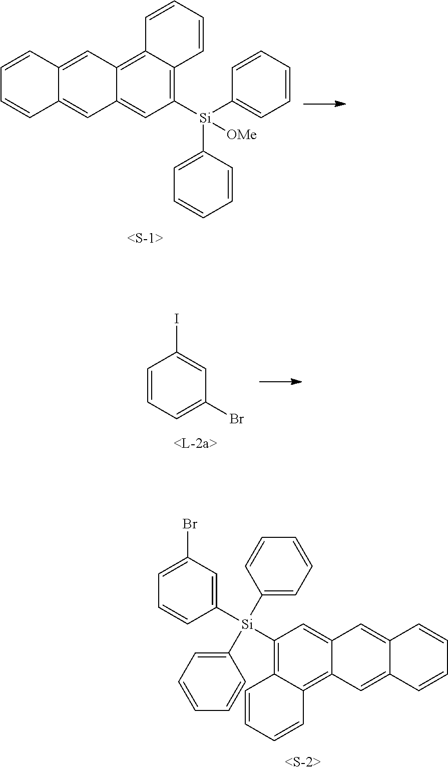 [SMILES: CO[Si](c1ccccc1)(c1ccccc1)c1cc2cc3ccccc3cc2c2ccccc12 ; Brc1cccc(I)c1 ; Brc1cccc([Si](c2ccccc2)(c2ccccc2)c2cc3cc4ccccc4cc3c3ccccc23)c1]

<S-2> was obtained by performing a synthesis in the same manner as in Synthesis Example 1-2, except that <S-1> was used instead of <A-1>, and <L-2a> was used instead of <A-2a>. (Yield 76%)

### Synthesis Example 20-3: Synthesis of S-3

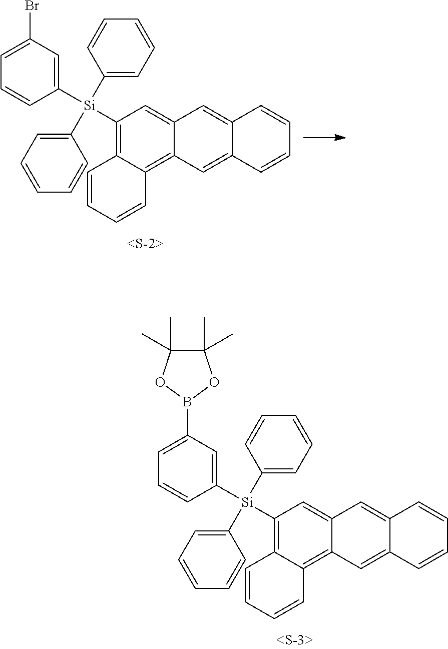 [SMILES: Brc1cccc([Si](c2ccccc2)(c2ccccc2)c2cc3cc4ccccc4cc3c3ccccc23)c1 ; CC1(C)OB(c2cccc([Si](c3ccccc3)(c3ccccc3)c3cc4cc5ccccc5cc4c4ccccc34)c2)OC1(C)C]

<S-3> was obtained by performing a synthesis in the same manner as in Synthesis Example 6-1, except that <S-2> was used instead of <F-1a>. (Yield 87%)

### Synthesis Example 20-4: Synthesis of [Compound 1-89]

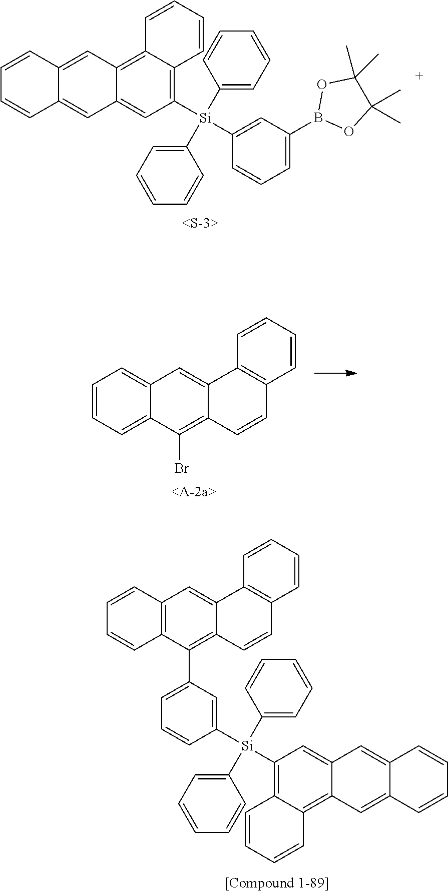 [SMILES: CC1(C)OB(c2cccc([Si](c3ccccc3)(c3ccccc3)c3cc4cc5ccccc5cc4c4ccccc34)c2)OC1(C)C ; Brc1c2ccccc2cc2c1ccc1ccccc12 ; c1ccc([Si](c2ccccc2)(c2cccc(-c3c4ccccc4cc4c3ccc3ccccc34)c2)c2cc3cc4ccccc4cc3c3ccccc23)cc1]

[Compound 1-89] was obtained by performing a synthesis in the same manner as in Synthesis Example 6-2, except that <S-3> was used instead of <F-1>, and <A-2a> was used instead of <F-2a>. (Yield 60%)

MS (MALDI-TOF): m/z 712.26 [M⁺]

### Synthesis Example 21: Synthesis of [Compound 1-92]

### Synthesis Example 21-1: Synthesis of T-1

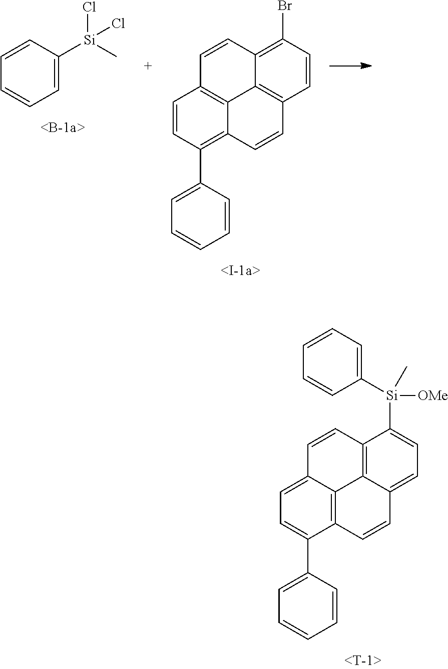

<T-1> was obtained by performing a synthesis in the same manner as in Synthesis Example 2-1, except that <I-1a> was used instead of <B-1b>. (Yield 66%)

### Synthesis Example 21-2: Synthesis of [Compound 1-92]

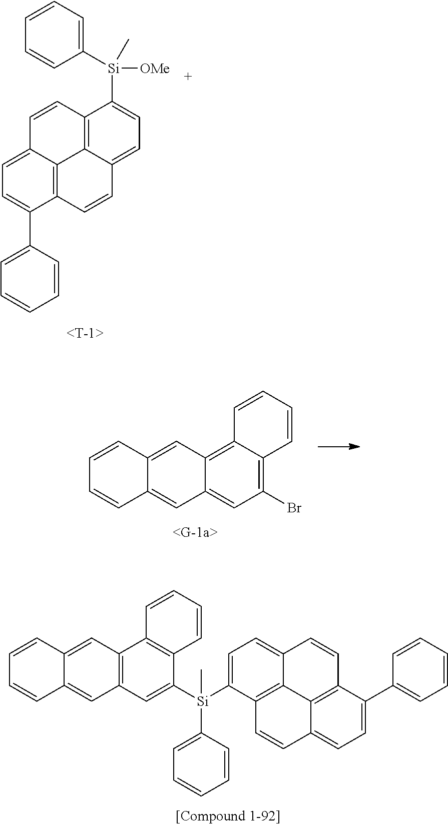 [SMILES: CO[Si](C)(c1ccccc1)c1ccc2ccc3c(-c4ccccc4)ccc4ccc1c2c43 ; Brc1cc2cc3ccccc3cc2c2ccccc12 ; C[Si](c1ccccc1)(c1cc2cc3ccccc3cc2c2ccccc12)c1ccc2ccc3c(-c4ccccc4)ccc4ccc1c2c43]

[Compound 1-92] was obtained by performing a synthesis in the same manner as in Synthesis Example 1-2, except that <T-1> was used instead of <A-1>, and <G-1a> was used instead of <A-2a>. (Yield 58%)

MS (MALDI-TOF): m/z 624.23 [M⁺]

### Synthesis Example 22: Synthesis of [Compound 1-107]

### Synthesis Example 22-1: Synthesis of U-1

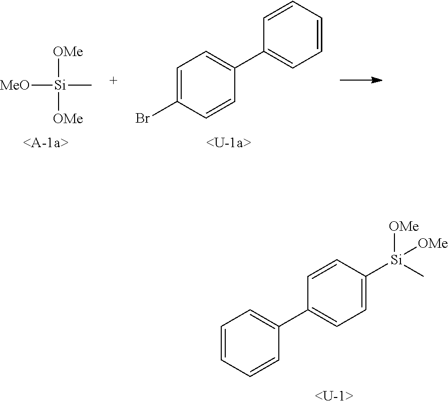

<U-1> was obtained by performing a synthesis in the same manner as in Synthesis Example 1-1, except that <U-1a> was used instead of <A-1b>. (Yield 61%)

### Synthesis Example 22-2: Synthesis of U-2

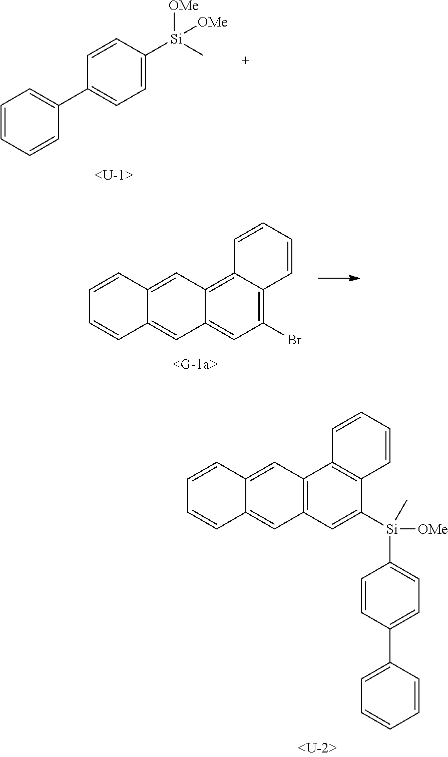 [SMILES: CO[Si](C)(OC)c1ccc(-c2ccccc2)cc1 ; Brc1cc2cc3ccccc3cc2c2ccccc12 ; CO[Si](C)(c1ccc(-c2ccccc2)cc1)c1cc2cc3ccccc3cc2c2ccccc12]

<U-2> was obtained by performing a synthesis in the same manner as in Synthesis Example 1-2, except that <U-1> was used instead of <A-1>, and <G-1a> was used instead of <A-2a>. (Yield 64%)

### Synthesis Example 22-3: Synthesis of U-3

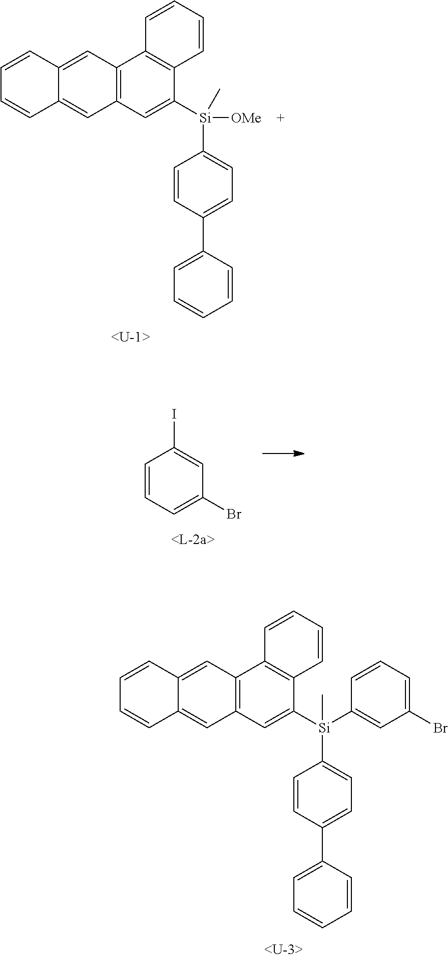 [SMILES: CO[Si](C)(c1ccc(-c2ccccc2)cc1)c1cc2cc3ccccc3cc2c2ccccc12 ; Brc1cccc(I)c1 ; C[Si](c1ccc(-c2ccccc2)cc1)(c1cccc(Br)c1)c1cc2cc3ccccc3cc2c2ccccc12]

<U-3> was obtained by performing a synthesis in the same manner as in Synthesis Example 1-2, except that <U-1> was used instead of <A-1>, and <L-2a> was used instead of <A-2a>. (Yield 77%)

### Synthesis Example 22-4: Synthesis of U-4

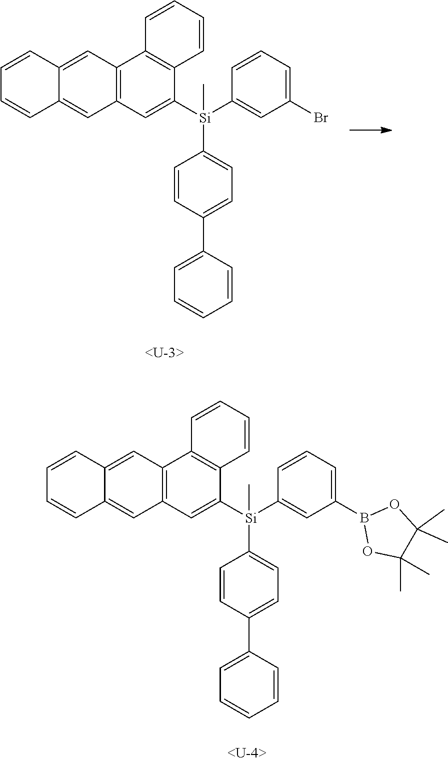 [SMILES: C[Si](c1ccc(-c2ccccc2)cc1)(c1cccc(Br)c1)c1cc2cc3ccccc3cc2c2ccccc12 ; CC1(C)OB(c2cccc([Si](C)(c3ccc(-c4ccccc4)cc3)c3cc4cc5ccccc5cc4c4ccccc34)c2)OC1(C)C]

<U-4> was obtained by performing a synthesis in the same manner as in Synthesis Example 6-1, except that <U-3> was used instead of <F-1a>. (Yield 80%)

### Synthesis Example 22-5: Synthesis of [Compound 1-107]

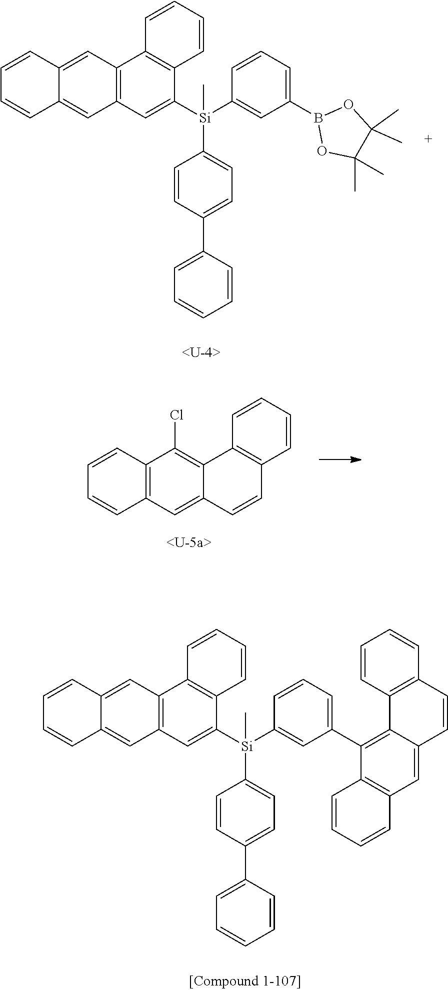 [SMILES: CC1(C)OB(c2cccc([Si](C)(c3ccc(-c4ccccc4)cc3)c3cc4cc5ccccc5cc4c4ccccc34)c2)OC1(C)C ; Clc1c2ccccc2cc2ccc3ccccc3c12 ; C[Si](c1ccc(-c2ccccc2)cc1)(c1cccc(-c2c3ccccc3cc3ccc4ccccc4c23)c1)c1cc2cc3ccccc3cc2c2ccccc12]

[Compound 1-107] was obtained by performing a synthesis in the same manner as in Synthesis Example 6-2, except that <U-4> was used instead of <F-1>, and <U-5a> was used instead of <F-2a>. (Yield 55%)

MS (MALDI-TOF): m/z 726.27 [M⁺]

### Synthesis Example 23: Synthesis of [Compound 1-109]

### Synthesis Example 23-1: Synthesis of V-1

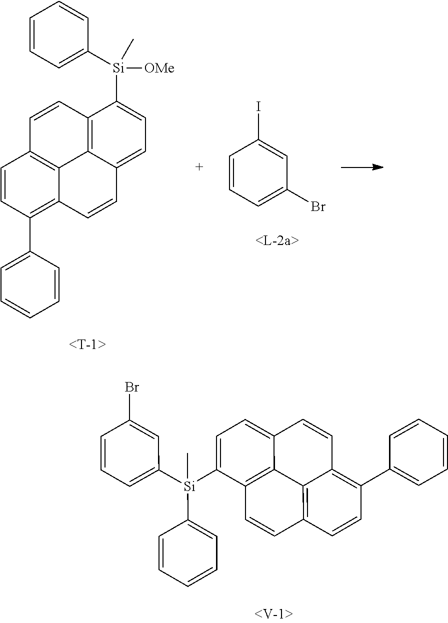 [SMILES: CO[Si](C)(c1ccccc1)c1ccc2ccc3c(-c4ccccc4)ccc4ccc1c2c43 ; Brc1cccc(I)c1 ; C[Si](c1ccccc1)(c1cccc(Br)c1)c1ccc2ccc3c(-c4ccccc4)ccc4ccc1c2c43]

<V-1> was obtained by performing a synthesis in the same manner as in Synthesis Example 1-2, except that <T-1> was used instead of <A-1>, and <L-2a> was used instead of <A-2a>. (Yield 74%)

### Synthesis Example 23-2: Synthesis of V-2

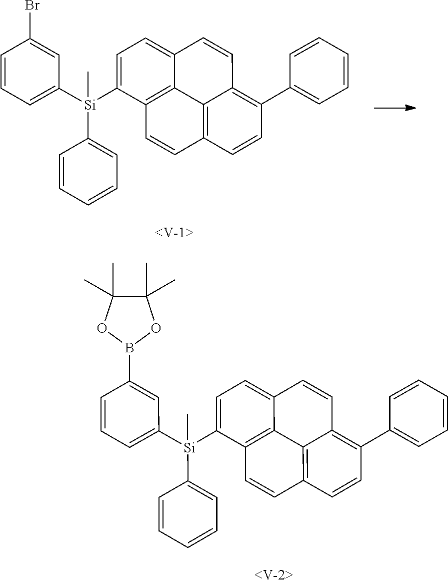 [SMILES: C[Si](c1ccccc1)(c1cccc(Br)c1)c1ccc2ccc3c(-c4ccccc4)ccc4ccc1c2c43 ; CC1(C)OB(c2cccc([Si](C)(c3ccccc3)c3ccc4ccc5c(-c6ccccc6)ccc6ccc3c4c65)c2)OC1(C)C]

<V-2> was obtained by performing a synthesis in the same manner as in Synthesis Example 6-1, except that <V-1> was used instead of <F-1a>. (Yield 83%)

### Synthesis Example 23-3: Synthesis of [Compound 1-109]

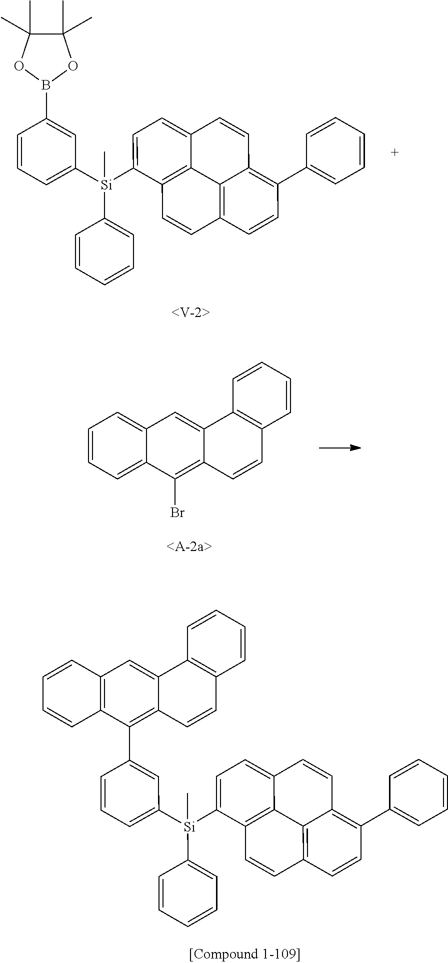 [SMILES: CC1(C)OB(c2cccc([Si](C)(c3ccccc3)c3ccc4ccc5c(-c6ccccc6)ccc6ccc3c4c65)c2)OC1(C)C ; Brc1c2ccccc2cc2c1ccc1ccccc12 ; C[Si](c1ccccc1)(c1cccc(-c2c3ccccc3cc3c2ccc2ccccc23)c1)c1ccc2ccc3c(-c4ccccc4)ccc4ccc1c2c43]

[Compound 1-109] was obtained by performing a synthesis in the same manner as in Synthesis Example 6-2, except that <V-2> was used instead of <F-1>, and <A-2a> was used instead of <F-2a>. (Yield 78%)

MS (MALDI-TOF): m/z 700.26 [M⁺]

### Synthesis Example 24: Synthesis of [Compound 1-113]

### Synthesis Example 24-1: Synthesis of W-1

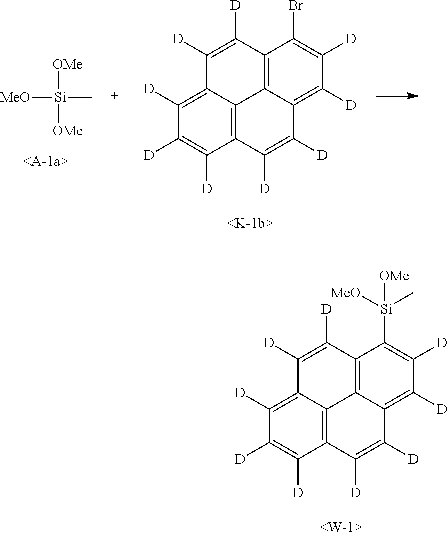

<W-1> was obtained by performing a synthesis in the same manner as in Synthesis Example 1-1, except that <K-1b> was used instead of <A-1b>. (Yield 70%)

### Synthesis Example 24-2: Synthesis of W-2

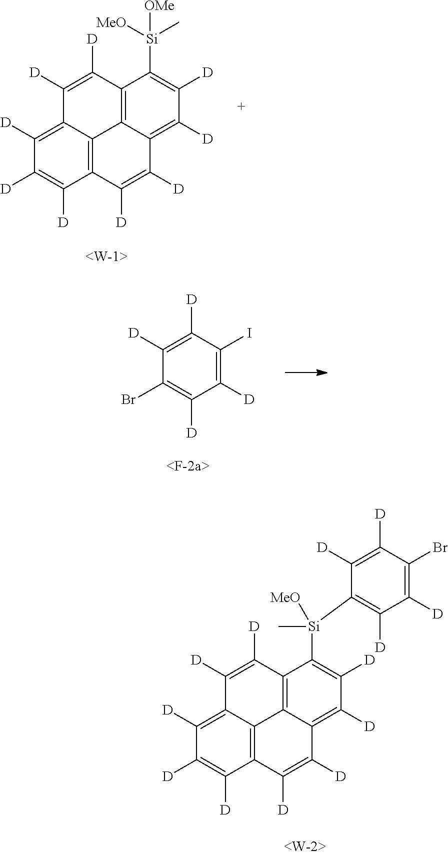 [SMILES: [2H]c1c([2H])c2c([2H])c([2H])c3c([2H])c([2H])c([Si](C)(OC)OC)c4c([2H])c([2H])c(c1[2H])c2c34 ; [2H]c1c([2H])c(I)c([2H])c([2H])c1Br ; [2H]c1c([2H])c([Si](C)(OC)c2c([2H])c([2H])c3c([2H])c([2H])c4c([2H])c([2H])c([2H])c5c([2H])c([2H])c2c3c45)c([2H])c([2H])c1Br]

<W-2> was obtained by performing a synthesis in the same manner as in Synthesis Example 1-2, except that <W-1> was used instead of <A-1>, and <F-2a> was used instead of <A-2a>. (Yield 71%)

### Synthesis Example 24-3: Synthesis of W-3

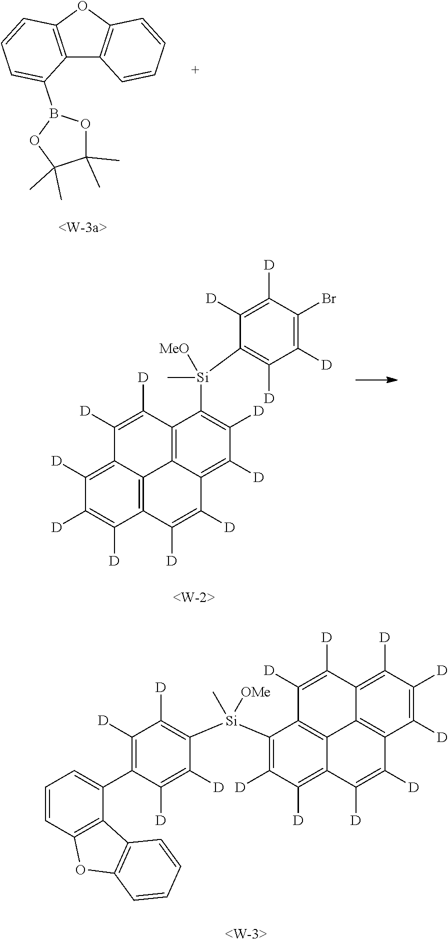 [SMILES: CC1(C)OB(c2cccc3oc4ccccc4c23)OC1(C)C ; [2H]c1c([2H])c([Si](C)(OC)c2c([2H])c([2H])c3c([2H])c([2H])c4c([2H])c([2H])c([2H])c5c([2H])c([2H])c2c3c45)c([2H])c([2H])c1Br ; [2H]c1c([2H])c([Si](C)(OC)c2c([2H])c([2H])c3c([2H])c([2H])c4c([2H])c([2H])c([2H])c5c([2H])c([2H])c2c3c45)c([2H])c([2H])c1-c1cccc2oc3ccccc3c12]

<W-3> was obtained by performing a synthesis in the same manner as in Synthesis Example 6-2, except that <W-3a> was used instead of <F-1>, and <W-2> was used instead of <F-2a>. (Yield 78%)

### Synthesis Example 24-4: Synthesis of W-4

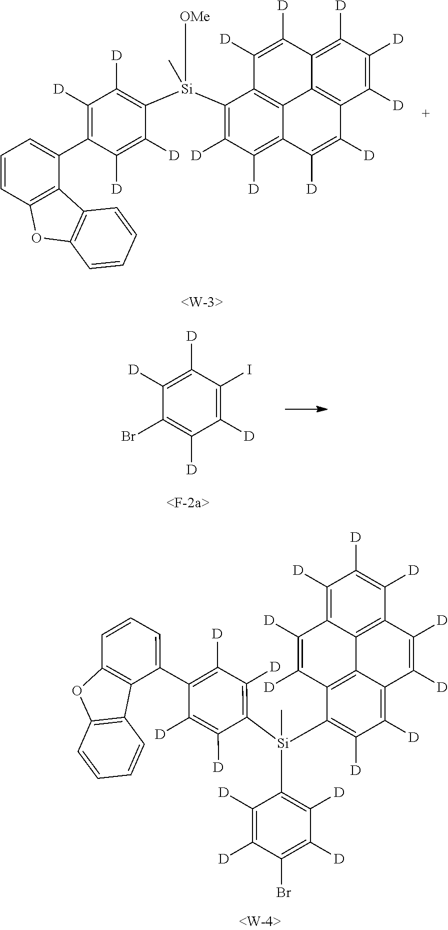 [SMILES: [2H]c1c([2H])c([Si](C)(OC)c2c([2H])c([2H])c3c([2H])c([2H])c4c([2H])c([2H])c([2H])c5c([2H])c([2H])c2c3c45)c([2H])c([2H])c1-c1cccc2oc3ccccc3c12 ; [2H]c1c([2H])c(I)c([2H])c([2H])c1Br ; [2H]c1c([2H])c([Si](C)(c2c([2H])c([2H])c(-c3cccc4oc5ccccc5c34)c([2H])c2[2H])c2c([2H])c([2H])c3c([2H])c([2H])c4c([2H])c([2H])c([2H])c5c([2H])c([2H])c2c3c45)c([2H])c([2H])c1Br]

<W-4> was obtained by performing a synthesis in the same manner as in Synthesis Example 1-2, except that <W-3> was used instead of <A-1>, and <F-2a> was used instead of <A-2a>. (Yield 70%)

### Synthesis Example 24-5: Synthesis of W-5

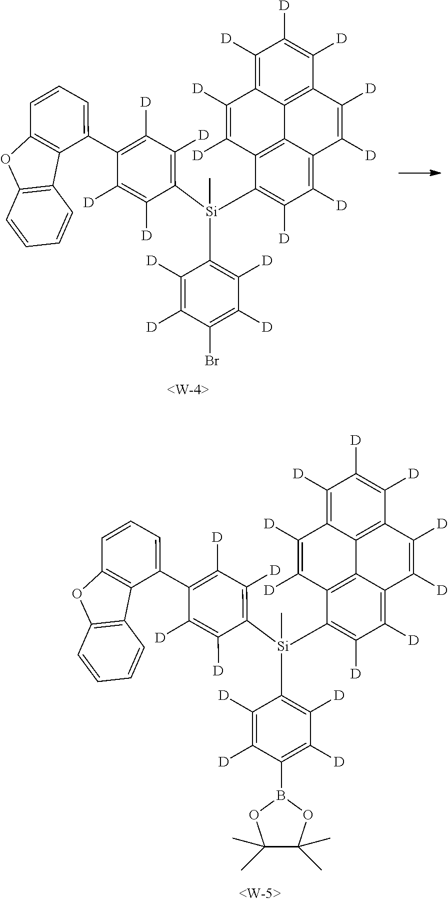 [SMILES: [2H]c1c([2H])c([Si](C)(c2c([2H])c([2H])c(-c3cccc4oc5ccccc5c34)c([2H])c2[2H])c2c([2H])c([2H])c3c([2H])c([2H])c4c([2H])c([2H])c([2H])c5c([2H])c([2H])c2c3c45)c([2H])c([2H])c1Br ; [2H]c1c([2H])c([Si](C)(c2c([2H])c([2H])c(-c3cccc4oc5ccccc5c34)c([2H])c2[2H])c2c([2H])c([2H])c3c([2H])c([2H])c4c([2H])c([2H])c([2H])c5c([2H])c([2H])c2c3c45)c([2H])c([2H])c1B1OC(C)(C)C(C)(C)O1]

<W-5> was obtained by performing a synthesis in the same manner as in Synthesis Example 6-1, except that <W-4> was used instead of <F-1a>. (Yield 84%)

### Synthesis Example 24-6: Synthesis of [Compound 1-113]

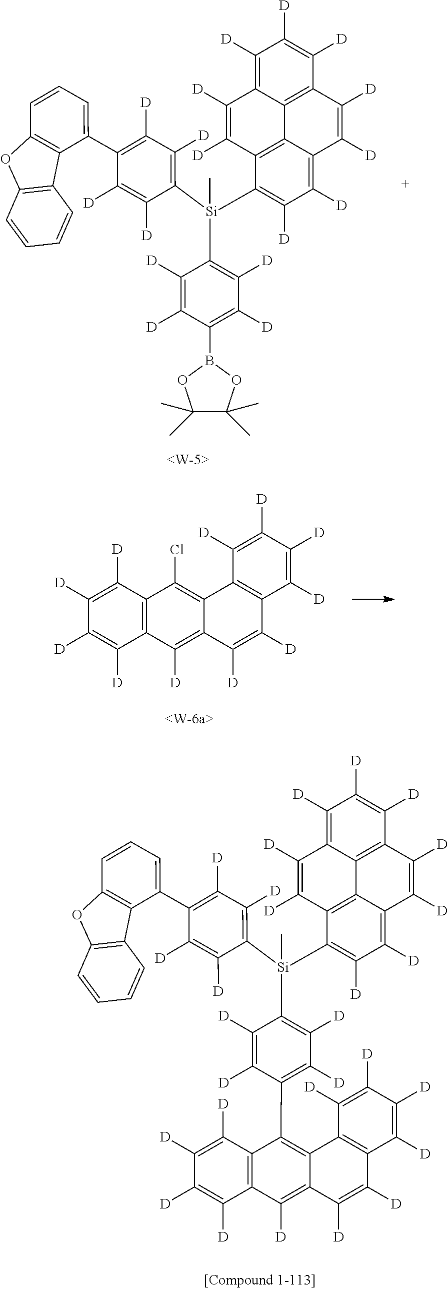

[Compound 1-113] was obtained by performing a synthesis in the same manner as in Synthesis Example 6-2, except that <W-5> was used instead of <F-1>, and <W-6a> was used instead of <F-2a>. (Yield 59%)

MS (MALDI-TOF): m/z 818.44 [M⁺]

### Synthesis Example 25: Synthesis of [Compound 1-131]

### Synthesis Example 25-1: Synthesis of X-1

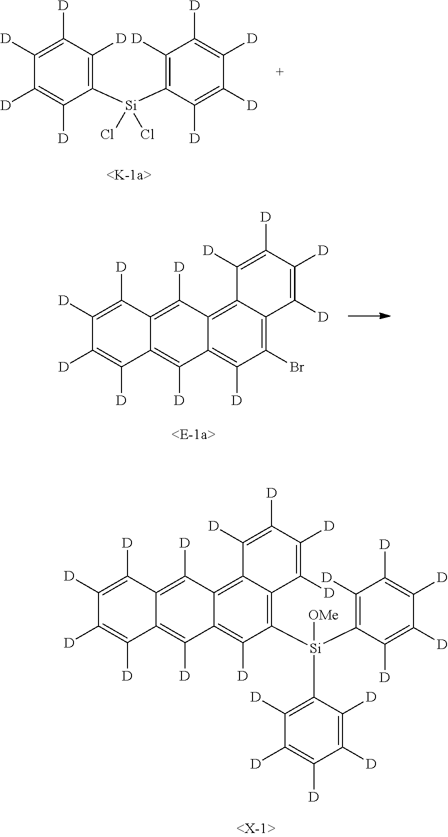 [SMILES: [2H]c1c([2H])c([2H])c([Si](Cl)(Cl)c2c([2H])c([2H])c([2H])c([2H])c2[2H])c([2H])c1[2H] ; [2H]c1c([2H])c([2H])c2c([2H])c3c(c([2H])c(Br)c4c([2H])c([2H])c([2H])c([2H])c43)c([2H])c2c1[2H] ; [2H]c1c([2H])c([2H])c([Si](OC)(c2c([2H])c([2H])c([2H])c([2H])c2[2H])c2c([2H])c3c([2H])c4c([2H])c([2H])c([2H])c([2H])c4c([2H])c3c3c([2H])c([2H])c([2H])c([2H])c23)c([2H])c1[2H]]

<X-1> was obtained by performing a synthesis in the same manner as in Synthesis Example 2-1, except that <K-1a> was used instead of <B-1a>, and <E-1a> was used instead of <B-1b>. (Yield 66%)

### Synthesis Example 25-2: Synthesis of [Compound 1-131]

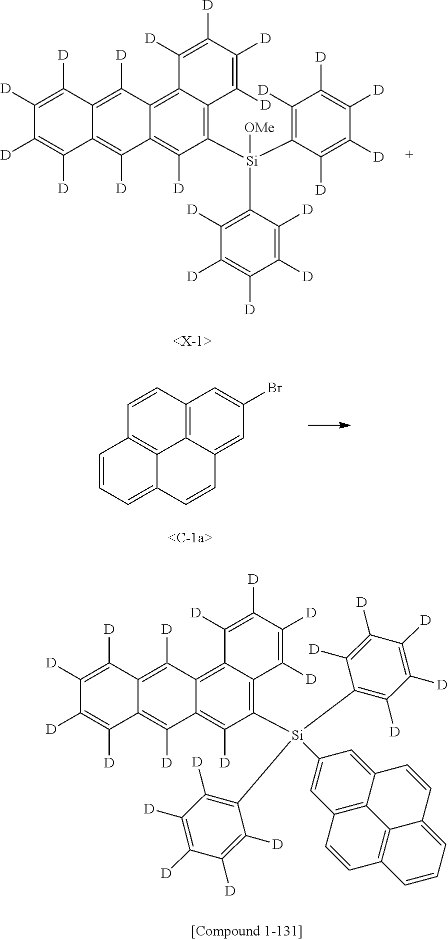 [SMILES: [2H]c1c([2H])c([2H])c([Si](OC)(c2c([2H])c([2H])c([2H])c([2H])c2[2H])c2c([2H])c3c([2H])c4c([2H])c([2H])c([2H])c([2H])c4c([2H])c3c3c([2H])c([2H])c([2H])c([2H])c23)c([2H])c1[2H] ; Brc1cc2ccc3cccc4ccc(c1)c2c34 ; [2H]c1c([2H])c([2H])c([Si](c2cc3ccc4cccc5ccc(c2)c3c45)(c2c([2H])c([2H])c([2H])c([2H])c2[2H])c2c([2H])c3c([2H])c4c([2H])c([2H])c([2H])c([2H])c4c([2H])c3c3c([2H])c([2H])c([2H])c([2H])c23)c([2H])c1[2H]]

[Compound 1-131] was obtained by performing a synthesis in the same manner as in Synthesis Example 1-2, except that <X-1> was used instead of <A-1>, and <C-1a> was used instead of <A-2a>. (Yield 45%)

MS (MALDI-TOF): m/z 631.34 [M⁺]

### Synthesis Example 26: Synthesis of [Compound 1-139]

### Synthesis Example 26-1: Synthesis of Y-1

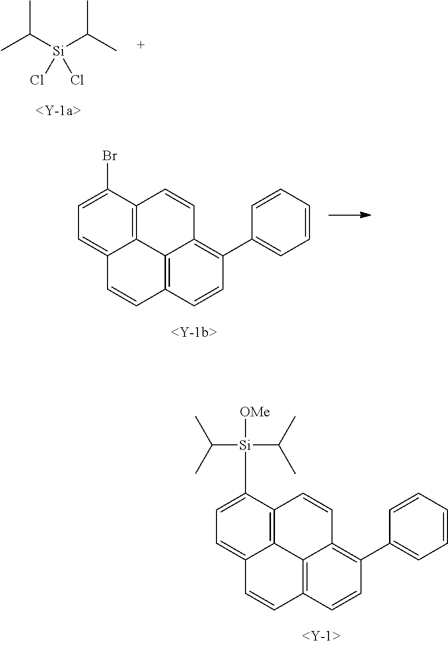

<Y-1> was obtained by performing a synthesis in the same manner as in Synthesis Example 2-1, except that <Y-1a> was used instead of <B-1a>, and <Y-1b> was used instead of <B-1b>. (Yield 57%)

### Synthesis Example 26-2: Synthesis of Y-2

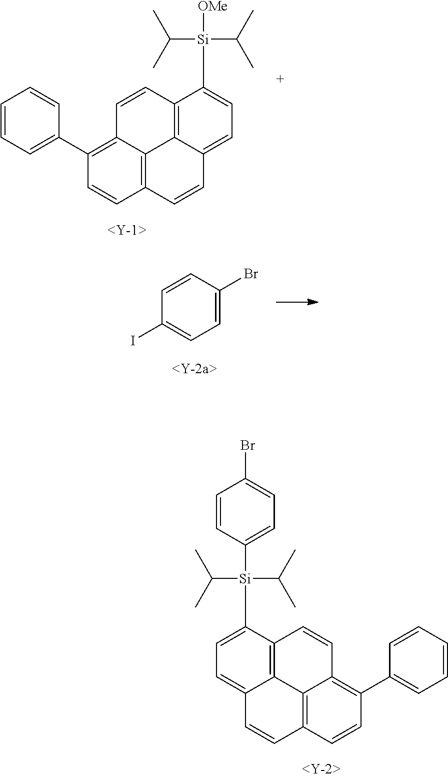 [SMILES: CO[Si](c1ccc2ccc3ccc(-c4ccccc4)c4ccc1c2c34)(C(C)C)C(C)C ; Brc1ccc(I)cc1 ; CC(C)[Si](c1ccc(Br)cc1)(c1ccc2ccc3ccc(-c4ccccc4)c4ccc1c2c34)C(C)C]

<Y-2> was obtained by performing a synthesis in the same manner as in Synthesis Example 1-2, except that <Y-1> was used instead of <A-1>, and <Y-2a> was used instead of <A-2a>. (Yield 68%)

### Synthesis Example 26-3: Synthesis of Y-3

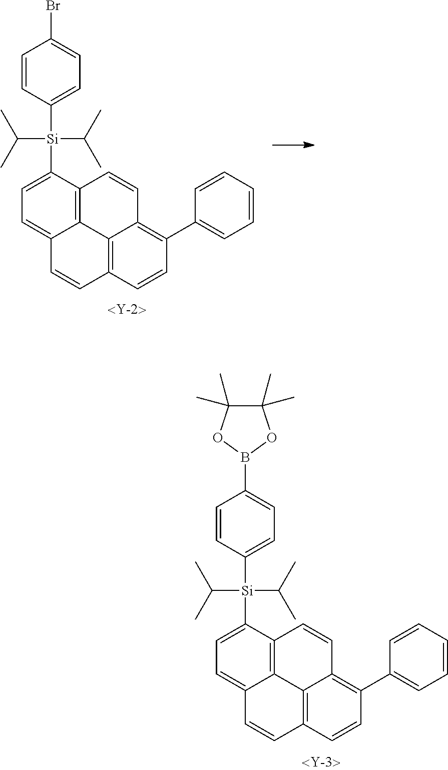 [SMILES: CC(C)[Si](c1ccc(Br)cc1)(c1ccc2ccc3ccc(-c4ccccc4)c4ccc1c2c34)C(C)C ; CC(C)[Si](c1ccc(B2OC(C)(C)C(C)(C)O2)cc1)(c1ccc2ccc3ccc(-c4ccccc4)c4ccc1c2c34)C(C)C]

<Y-3> was obtained by performing a synthesis in the same manner as in Synthesis Example 6-1, except that <Y-2> was used instead of <F-1a>. (Yield 85%)

### Synthesis Example 26-4: Synthesis of [Compound 1-139]

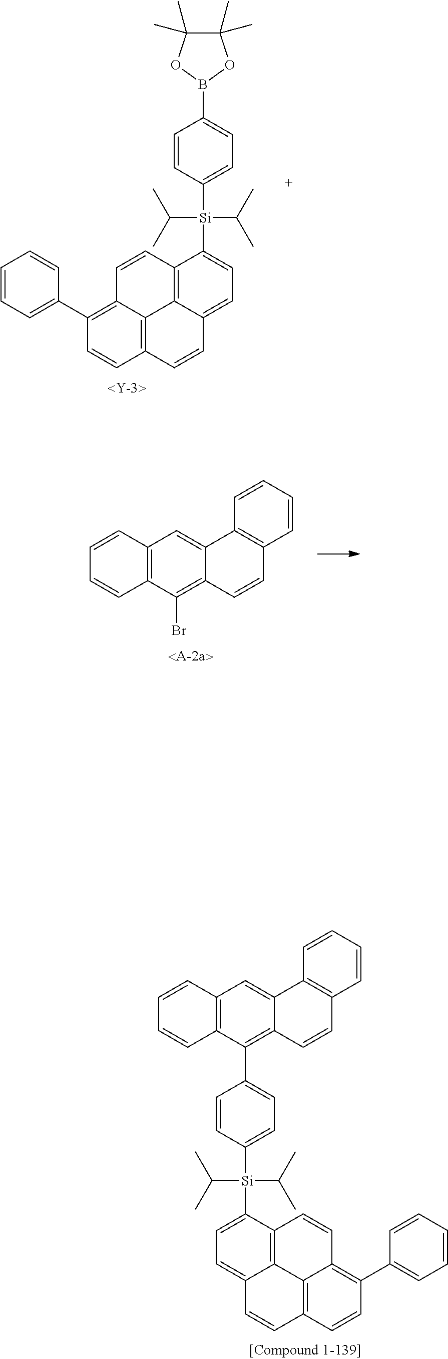 [SMILES: CC(C)[Si](c1ccc(B2OC(C)(C)C(C)(C)O2)cc1)(c1ccc2ccc3ccc(-c4ccccc4)c4ccc1c2c34)C(C)C ; Brc1c2ccccc2cc2c1ccc1ccccc12 ; CC(C)[Si](c1ccc(-c2c3ccccc3cc3c2ccc2ccccc23)cc1)(c1ccc2ccc3ccc(-c4ccccc4)c4ccc1c2c34)C(C)C]

[Compound 1-139] was obtained by performing a synthesis in the same manner as in Synthesis Example 6-2, except that <Y-3> was used instead of <F-1>, and <A-2a> was used instead of <F-2a>. (Yield 59%)

MS (MALDI-TOF): m/z 694.31 [M⁺]

### Synthesis Example 27: Synthesis of [Compound 1-140]

### Synthesis Example 27-1: Synthesis of Z-1

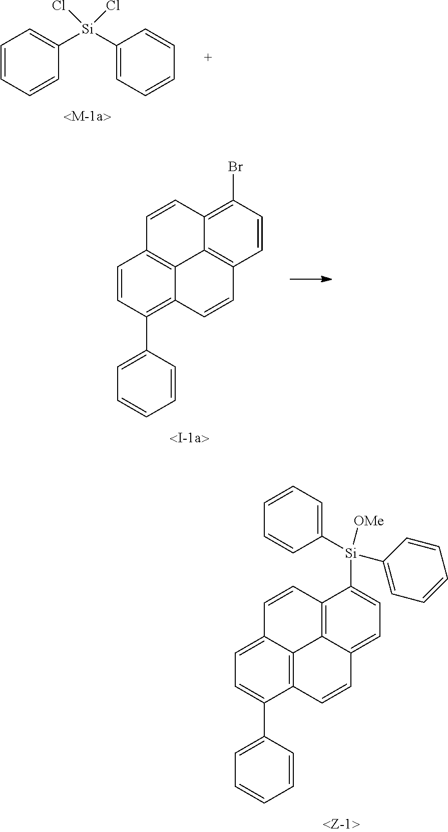 [SMILES: Cl[Si](Cl)(c1ccccc1)c1ccccc1 ; Brc1ccc2ccc3c(-c4ccccc4)ccc4ccc1c2c43 ; CO[Si](c1ccccc1)(c1ccccc1)c1ccc2ccc3c(-c4ccccc4)ccc4ccc1c2c43]

<Z-1> was obtained by performing a synthesis in the same manner as in Synthesis Example 2-1, except that <M-1a> was used instead of <B-1a>, and <I-1a> was used instead of <B-1b>. (Yield 63%)

### Synthesis Example 27-2: Synthesis of Z-2

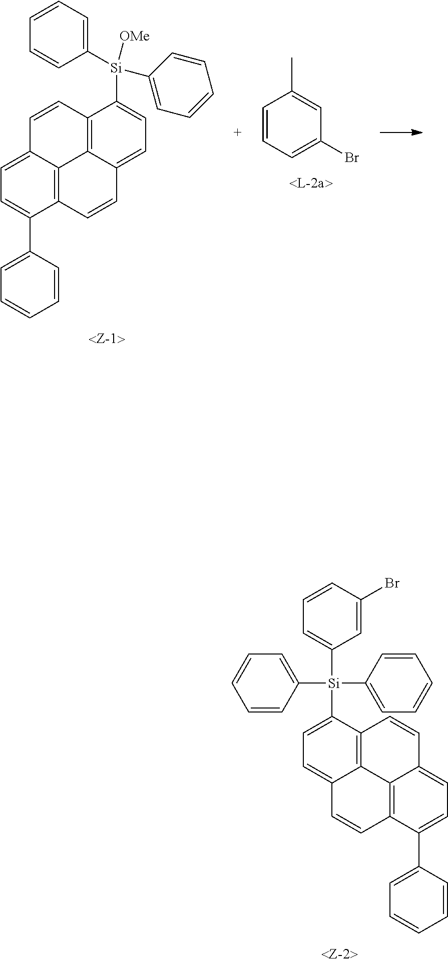

<Z-2> was obtained by performing a synthesis in the same manner as in Synthesis Example 1-2, except that <Z-1> was used instead of <A-1>, and <L-2a> was used instead of <A-2a>. (Yield 77%)

### Synthesis Example 27-3: Synthesis of Z-3

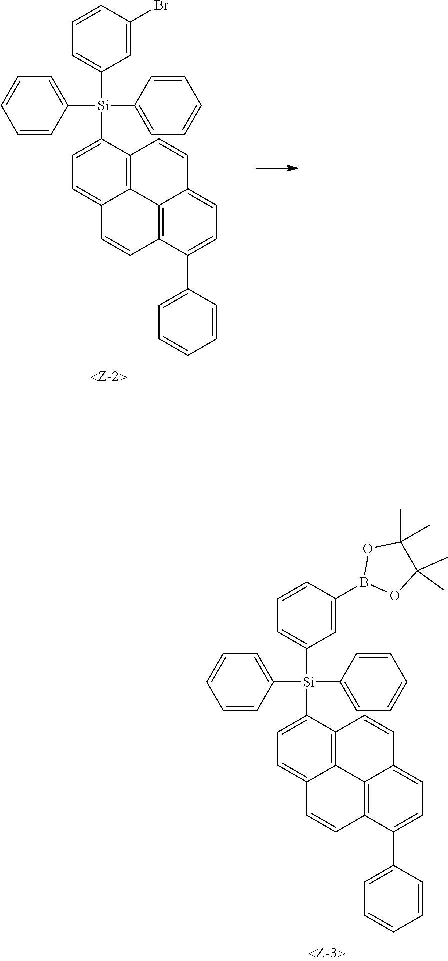 [SMILES: Brc1cccc([Si](c2ccccc2)(c2ccccc2)c2ccc3ccc4c(-c5ccccc5)ccc5ccc2c3c54)c1 ; CC1(C)OB(c2cccc([Si](c3ccccc3)(c3ccccc3)c3ccc4ccc5c(-c6ccccc6)ccc6ccc3c4c65)c2)OC1(C)C]

<Z-3> was obtained by performing a synthesis in the same manner as in Synthesis Example 6-1, except that <Z-2> was used instead of <F-1a>. (Yield 86%)

### Synthesis Example 27-4: Synthesis of [Compound 1-140]

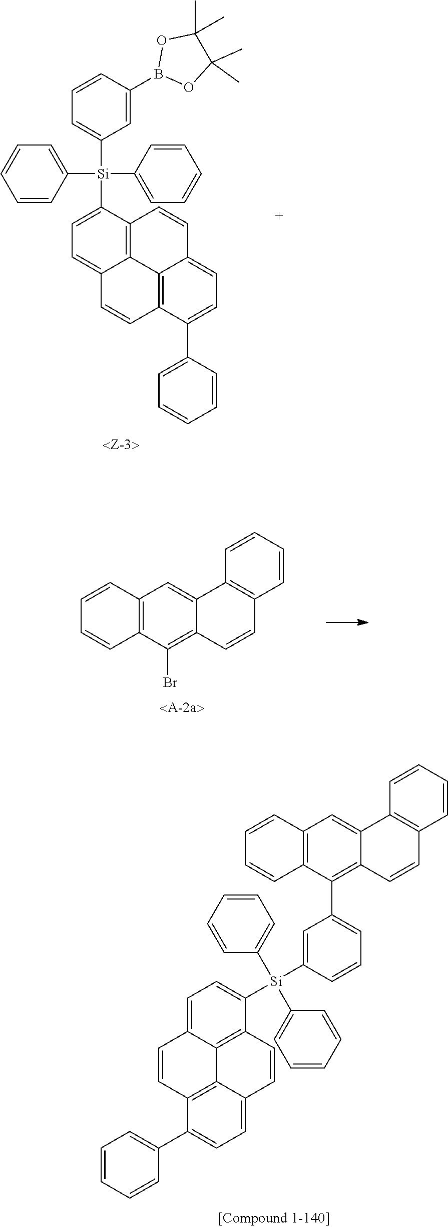 [SMILES: CC1(C)OB(c2cccc([Si](c3ccccc3)(c3ccccc3)c3ccc4ccc5c(-c6ccccc6)ccc6ccc3c4c65)c2)OC1(C)C ; Brc1c2ccccc2cc2c1ccc1ccccc12 ; c1ccc(-c2ccc3ccc4c([Si](c5ccccc5)(c5ccccc5)c5cccc(-c6c7ccccc7cc7c6ccc6ccccc67)c5)ccc5ccc2c3c54)cc1]

[Compound 1-140] was obtained by performing a synthesis in the same manner as in Synthesis Example 6-2, except that <Z-3> was used instead of <F-1>, and <A-2a> was used instead of <F-2a>. (Yield 59%)

MS (MALDI-TOF): m/z 762.27 [M⁺]

### Examples 1 to 83: Manufacture of Organic Light-Emitting Device

ITO glass was patterned to have a light-emitting area of 2 mm×2 mm, and then cleaned. The ITO glass was installed in a vacuum chamber, and the base pressure was set at 1×10−7 torr. Then, on the ITO, an electron acceptor having the following Structural Formula [Acceptor-1] and [Chemical Formula F] were deposited (100 Å) at a deposition ratio of 2:98 ([Acceptor-1]: [Chemical Formula F]) as a hole injection layer. [Chemical Formula F] was deposited (550 Å) as a hole transport layer, and then [Chemical Formula G] was deposited (50 Å) as an electron blocking layer. As a light-emitting layer, a first light-emitting layer and a second light-emitting layer were sequentially formed, wherein a fused cyclic compound represented by [Chemical Formula 1] according to the present invention and one of [BD-1] to [BD-3] (1 wt %), which are polycyclic compounds represented by [Chemical Formula 3], were mixed and deposited (50 Å) as the first light-emitting layer, and an anthracene compound [BH-1] or [BH-2] represented by [Chemical Formula 2] according to the present invention and one of [BD-1] to [BD-3] (1 wt %), which are polycyclic compounds represented by [Chemical Formula 3], were mixed and deposited (150 Å) as the second light-emitting layer. Then, [Chemical Formula H] was deposited (50 Å) as a hole blocking layer, [Chemical Formula E-1] and [Chemical Formula E-2] were deposited (250 Å) at a ratio of 1:1 as an electron transport layer, [Chemical Formula E-2] was deposited (10 Å) as an electron injection layer, and A₁ was deposited (1000 Å) in this order to manufacture an organic light-emitting device. Light-emitting characteristics of the organic light-emitting devices were measured at 0.4 mA.

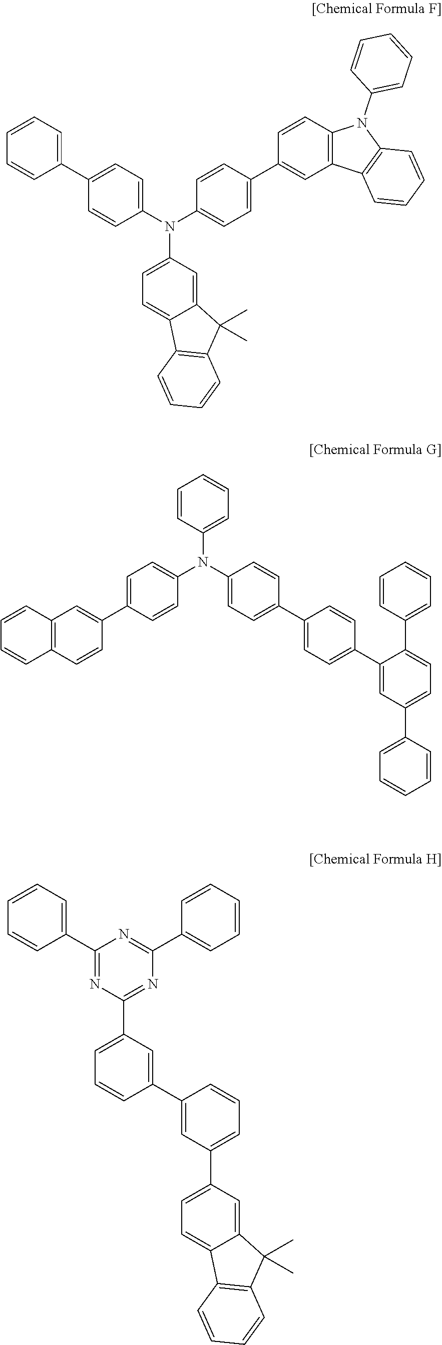 [SMILES: CC1(C)c2ccccc2-c2ccc(N(c3ccc(-c4ccccc4)cc3)c3ccc(-c4ccc5c(c4)c4ccccc4n5-c4ccccc4)cc3)cc21 ; c1ccc(-c2ccc(-c3ccccc3)c(-c3ccc(-c4ccc(N(c5ccccc5)c5ccc(-c6ccc7ccccc7c6)cc5)cc4)cc3)c2)cc1 ; CC1(C)c2ccccc2-c2ccc(-c3cccc(-c4cccc(-c5nc(-c6ccccc6)nc(-c6ccccc6)n5)c4)c3)cc21]

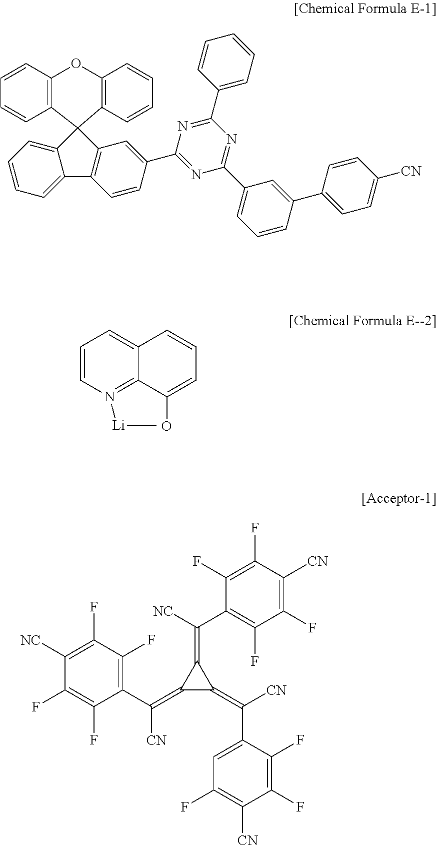

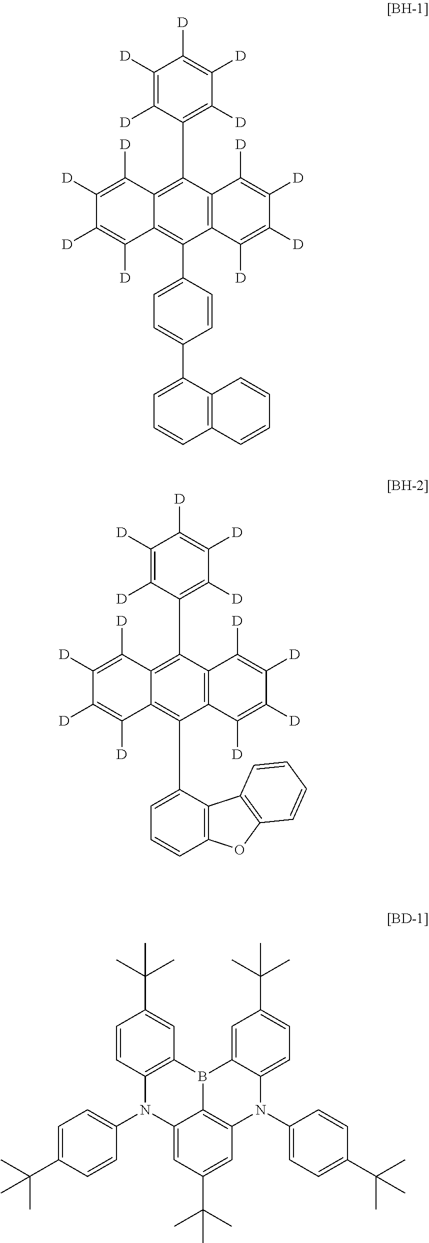 [SMILES: [2H]c1c([2H])c([2H])c(-c2c3c([2H])c([2H])c([2H])c([2H])c3c(-c3ccc(-c4cccc5ccccc45)cc3)c3c([2H])c([2H])c([2H])c([2H])c23)c([2H])c1[2H] ; [2H]c1c([2H])c([2H])c(-c2c3c([2H])c([2H])c([2H])c([2H])c3c(-c3cccc4oc5ccccc5c34)c3c([2H])c([2H])c([2H])c([2H])c23)c([2H])c1[2H] ; CC(C)(C)c1ccc(N2c3ccc(C(C)(C)C)cc3B3c4cc(C(C)(C)C)ccc4N(c4ccc(C(C)(C)C)cc4)c4cc(C(C)(C)C)cc2c43)cc1]

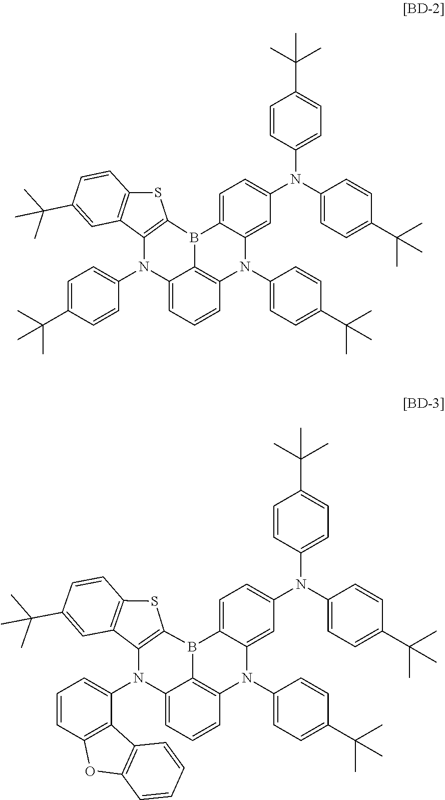

### Comparative Examples 1 to 28

Organic light-emitting devices for Comparative Examples were manufactured in the same manner as in the Examples, except that the following [RH-1] to [RH-5] were used instead of the compounds according to the present invention in the device structures of the Examples as the host compound in the first light-emitting layer and the second light-emitting layer. Light-emitting characteristics of the organic light-emitting devices were measured at 0.4 mA. The structures of [RH-1] to [RH-5] are as follows.

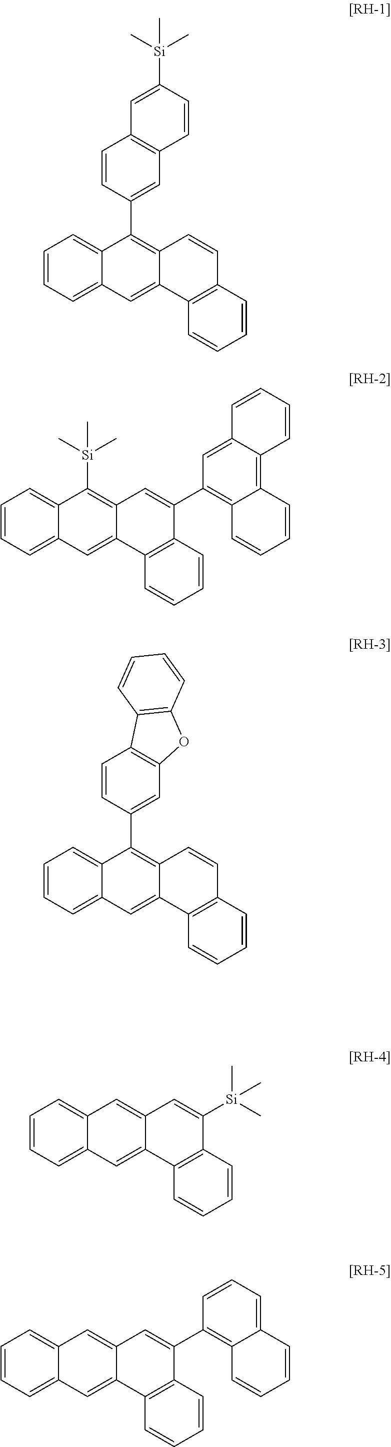

TABLE 1

| | | | | | | External | |
|---|---|---|---|---|---|---|---|
| | First Light- | | Second Light- | | Driving | Quantum | Lifespan |
| | Emitting Layer | | Emitting Layer | | Voltage | Efficiency | (LT97, |
| Classification | Host | Dopant | Host | Dopant | (V) | (EQE, %) | hr) |
| Example 1 | 1-7 | BD-1 | BH-1 | BD-1 | 3.1 | 10.0 | 184 |
| Example 2 | 1-11 | BD-1 | BH-1 | BD-1 | 3.3 | 10.1 | 192 |
| Example 3 | 1-14 | BD-1 | BH-1 | BD-1 | 3.4 | 10.3 | 209 |
| Example 4 | 1-19 | BD-1 | BH-1 | BD-1 | 3.5 | 10.5 | 225 |
| Example 5 | 1-32 | BD-1 | BH-1 | BD-1 | 3.4 | 10.7 | 243 |
| Example 6 | 1-34 | BD-1 | BH-1 | BD-1 | 3.4 | 10.7 | 258 |
| Example 7 | 1-36 | BD-1 | BH-1 | BD-1 | 3.4 | 10.6 | 255 |
| Example 8 | 1-39 | BD-1 | BH-1 | BD-1 | 3.5 | 10.8 | 221 |
| Example 9 | 1-41 | BD-1 | BH-1 | BD-1 | 3.4 | 10.9 | 229 |
| Example 10 | 1-47 | BD-1 | BH-1 | BD-1 | 3.5 | 10.8 | 220 |
| Example 11 | 1-54 | BD-1 | BH-1 | BD-1 | 3.3 | 10.5 | 214 |
| Example 12 | 1-58 | BD-1 | BH-1 | BD-1 | 3.4 | 11.0 | 234 |
| Example 13 | 1-61 | BD-1 | BH-1 | BD-1 | 3.6 | 10.7 | 226 |
| Example 14 | 1-62 | BD-1 | BH-1 | BD-1 | 3.5 | 10.6 | 225 |
| Example 15 | 1-63 | BD-1 | BH-1 | BD-1 | 3.4 | 10.9 | 250 |
| Example 16 | 1-64 | BD-1 | BH-1 | BD-1 | 3.4 | 10.9 | 223 |
| Example 17 | 1-65 | BD-1 | BH-1 | BD-1 | 3.4 | 10.8 | 231 |
| Example 18 | 1-72 | BD-1 | BH-1 | BD-1 | 3.5 | 10.9 | 224 |
| Example 19 | 1-85 | BD-1 | BH-1 | BD-1 | 3.6 | 11.0 | 216 |
| Example 20 | 1-89 | BD-1 | BH-1 | BD-1 | 3.4 | 11.0 | 229 |
| Example 21 | 1-92 | BD-1 | BH-1 | BD-1 | 3.3 | 10.9 | 240 |
| Example 22 | 1-107 | BD-1 | BH-1 | BD-1 | 3.4 | 10.8 | 241 |
| Example 23 | 1-109 | BD-1 | BH-1 | BD-1 | 3.5 | 11.1 | 244 |
| Example 24 | 1-113 | BD-1 | BH-1 | BD-1 | 3.4 | 11.2 | 266 |
| Example 25 | 1-131 | BD-1 | BH-1 | BD-1 | 3.4 | 10.7 | 226 |
| Example 26 | 1-139 | BD-1 | BH-1 | BD-1 | 3.3 | 10.5 | 195 |
| Example 27 | 1-140 | BD-1 | BH-1 | BD-1 | 3.5 | 11.1 | 248 |
| Example 28 | 1-34 | BD-1 | BH-2 | BD-1 | 3.2 | 11.0 | 268 |
| Example 29 | 1-41 | BD-1 | BH-2 | BD-1 | 3.2 | 11.2 | 239 |
| Example 30 | 1-47 | BD-1 | BH-2 | BD-1 | 3.3 | 11.1 | 230 |
| Example 31 | 1-58 | BD-1 | BH-2 | BD-1 | 3.2 | 11.3 | 244 |
| Example 32 | 1-62 | BD-1 | BH-2 | BD-1 | 3.3 | 10.9 | 235 |
| Example 33 | 1-63 | BD-1 | BH-2 | BD-1 | 3.2 | 11.2 | 260 |
| Example 34 | 1-64 | BD-1 | BH-2 | BD-1 | 3.2 | 11.2 | 233 |
| Example 35 | 1-65 | BD-1 | BH-2 | BD-1 | 3.2 | 11.1 | 261 |
| Example 36 | 1-89 | BD-1 | BH-2 | BD-1 | 3.2 | 11.3 | 239 |
| Example 37 | 1-92 | BD-1 | BH-2 | BD-1 | 3.1 | 11.2 | 250 |
| Example 38 | 1-107 | BD-1 | BH-2 | BD-1 | 3.2 | 11.1 | 251 |
| Example 39 | 1-109 | BD-1 | BH-2 | BD-1 | 3.3 | 11.4 | 254 |
| Example 40 | 1-113 | BD-1 | BH-2 | BD-1 | 3.2 | 11.5 | 276 |
| Example 41 | 1-140 | BD-1 | BH-2 | BD-1 | 3.3 | 11.4 | 258 |
| Example 42 | 1-28 | BD-2 | BH-1 | BD-2 | 3.4 | 12.9 | 281 |
| Example 43 | 1-34 | BD-2 | BH-1 | BD-2 | 3.5 | 12.5 | 318 |
| Example 44 | 1-41 | BD-2 | BH-1 | BD-2 | 3.5 | 12.7 | 289 |
| Example 45 | 1-47 | BD-2 | BH-1 | BD-2 | 3.6 | 12.6 | 280 |
| Example 46 | 1-58 | BD-2 | BH-1 | BD-2 | 3.5 | 12.8 | 294 |
| Example 47 | 1-62 | BD-2 | BH-1 | BD-2 | 3.6 | 12.4 | 285 |
| Example 48 | 1-63 | BD-2 | BH-1 | BD-2 | 3.3 | 12.7 | 310 |
| Example 49 | 1-64 | BD-2 | BH-1 | BD-2 | 3.3 | 12.7 | 283 |
| Example 50 | 1-65 | BD-2 | BH-1 | BD-2 | 3.3 | 12.6 | 291 |
| Example 51 | 1-89 | BD-2 | BH-1 | BD-2 | 3.3 | 12.8 | 289 |
| Example 52 | 1-92 | BD-2 | BH-1 | BD-2 | 3.2 | 12.7 | 300 |
| Example 53 | 1-107 | BD-2 | BH-1 | BD-2 | 3.3 | 12.6 | 301 |
| Example 54 | 1-109 | BD-2 | BH-1 | BD-2 | 3.4 | 12.9 | 304 |
| Example 55 | 1-113 | BD-2 | BH-1 | BD-2 | 3.3 | 13.0 | 326 |
| Example 56 | 1-140 | BD-2 | BH-1 | BD-2 | 3.4 | 12.9 | 308 |
| Example 57 | 1-28 | BD-2 | BH-2 | BD-2 | 3.2 | 13.0 | 291 |
| Example 58 | 1-34 | BD-2 | BH-2 | BD-2 | 3.3 | 12.6 | 328 |
| Example 59 | 1-41 | BD-2 | BH-2 | BD-2 | 3.3 | 12.8 | 299 |
| Example 60 | 1-47 | BD-2 | BH-2 | BD-2 | 3.4 | 12.7 | 290 |
| Example 61 | 1-58 | BD-2 | BH-2 | BD-2 | 3.3 | 12.9 | 304 |
| Example 62 | 1-62 | BD-2 | BH-2 | BD-2 | 3.4 | 12.5 | 295 |
| Example 63 | 1-63 | BD-2 | BH-2 | BD-2 | 3.1 | 12.8 | 320 |
| Example 64 | 1-64 | BD-2 | BH-2 | BD-2 | 3.1 | 12.8 | 293 |
| Example 65 | 1-65 | BD-2 | BH-2 | BD-2 | 3.1 | 12.7 | 301 |
| Example 66 | 1-89 | BD-2 | BH-2 | BD-2 | 3.1 | 12.9 | 299 |
| Example 67 | 1-92 | BD-2 | BH-2 | BD-2 | 3.0 | 12.8 | 310 |
| Example 68 | 1-107 | BD-2 | BH-2 | BD-2 | 3.1 | 12.7 | 311 |
| Example 69 | 1-109 | BD-2 | BH-2 | BD-2 | 3.2 | 13.0 | 314 |
| Example 70 | 1-113 | BD-2 | BH-2 | BD-2 | 3.1 | 13.1 | 336 |
| Example 71 | 1-140 | BD-2 | BH-2 | BD-2 | 3.2 | 13.0 | 318 |
| Example 72 | 1-28 | BD-3 | BH-1 | BD-3 | 3.4 | 13.3 | 301 |
| Example 73 | 1-92 | BD-3 | BH-1 | BD-3 | 3.4 | 13.0 | 310 |
| Example 74 | 1-107 | BD-3 | BH-1 | BD-3 | 3.5 | 13.0 | 311 |
| Example 75 | 1-109 | BD-3 | BH-1 | BD-3 | 3.6 | 13.2 | 314 |
| Example 76 | 1-113 | BD-3 | BH-1 | BD-3 | 3.5 | 13.3 | 336 |
| Example 77 | 1-140 | BD-3 | BH-1 | BD-3 | 3.6 | 13.2 | 318 |
| Example 78 | 1-28 | BD-3 | BH-2 | BD-3 | 3.2 | 13.2 | 311 |
| Example 79 | 1-92 | BD-3 | BH-2 | BD-3 | 3.2 | 13.1 | 320 |
| Example 80 | 1-107 | BD-3 | BH-2 | BD-3 | 3.3 | 13.1 | 321 |
| Example 81 | 1-109 | BD-3 | BH-2 | BD-3 | 3.4 | 13.3 | 324 |
| Example 82 | 1-113 | BD-3 | BH-2 | BD-3 | 3.3 | 13.4 | 346 |
| Example 83 | 1-140 | BD-3 | BH-2 | BD-3 | 3.4 | 13.3 | 328 |
| Comparative | RH-1 | BD-1 | BH-1 | BD-1 | 4.0 | 7.6 | 75 |
| Example 1 | | | | | | | |
| Comparative | RH-2 | BD-1 | BH-1 | BD-1 | 4.2 | 7.7 | 78 |
| Example 2 | | | | | | | |
| Comparative | RH-3 | BD-1 | BH-1 | BD-1 | 3.8 | 8.4 | 85 |
| Example 3 | | | | | | | |
| Comparative | RH-4 | BD-1 | BH-1 | BD-1 | 3.9 | 7.2 | 40 |
| Example 4 | | | | | | | |
| Comparative | RH-5 | BD-1 | BH-1 | BD-1 | 4.2 | 7.3 | 79 |
| Example 5 | | | | | | | |
| Comparative | RH-1 | BD-1 | BH-2 | BD-1 | 3.8 | 7.7 | 85 |
| Example 6 | | | | | | | |
| Comparative | RH-2 | BD-1 | BH-2 | BD-1 | 4.0 | 7.8 | 88 |
| Example 7 | | | | | | | |
| Comparative | RH-3 | BD-1 | BH-2 | BD-1 | 3.6 | 8.5 | 95 |
| Example 8 | | | | | | | |
| Comparative | RH-1 | BD-2 | BH-1 | BD-2 | 4.1 | 9.6 | 95 |
| Example 9 | | | | | | | |
| Comparative | RH-2 | BD-2 | BH-1 | BD-2 | 4.3 | 9.7 | 98 |
| Example 10 | | | | | | | |
| Comparative | RH-3 | BD-2 | BH-1 | BD-2 | 3.9 | 10.4 | 105 |
| Example 11 | | | | | | | |
| Comparative | RH-1 | BD-2 | BH-2 | BD-2 | 3.9 | 9.7 | 105 |
| Example 12 | | | | | | | |
| Comparative | RH-2 | BD-2 | BH-2 | BD-2 | 4.1 | 9.8 | 108 |
| Example 13 | | | | | | | |
| Comparative | RH-3 | BD-2 | BH-2 | BD-2 | 3.7 | 10.5 | 115 |
| Example 14 | | | | | | | |
| Comparative | RH-1 | BD-3 | BH-1 | BD-3 | 4.1 | 9.9 | 107 |
| Example 15 | | | | | | | |
| Comparative | RH-2 | BD-3 | BH-1 | BD-3 | 4.3 | 10.0 | 109 |
| Example 16 | | | | | | | |
| Comparative | RH-3 | BD-3 | BH-1 | BD-3 | 3.9 | 10.7 | 117 |
| Example 17 | | | | | | | |
| Comparative | RH-1 | BD-3 | BH-2 | BD-3 | 3.9 | 10.0 | 115 |
| Example 18 | | | | | | | |
| Comparative | RH-2 | BD-3 | BH-2 | BD-3 | 4.1 | 10.1 | 118 |
| Example 19 | | | | | | | |
| Comparative | RH-3 | BD-3 | BH-2 | BD-3 | 3.7 | 10.8 | 125 |
| Example 20 | | | | | | | |
| Comparative | RH-4 | BD-3 | BH-2 | BD-3 | 3.8 | 9.9 | 80 |
| Example 21 | | | | | | | |
| Comparative | RH-5 | BD-3 | BH-2 | BD-3 | 4.1 | 9.8 | 119 |
| Example 22 | | | | | | | |
| Comparative | 1-32 | BD-1 | | | 4.2 | 7.1 | 5 |
| Example 23 | | | | | | | |
| Comparative | 1-58 | BD-1 | | | 4.2 | 7.3 | 5 |
| Example 24 | | | | | | | |
| Comparative | 1-65 | BD-2 | | | 4.3 | 7.2 | 4 |
| Example 25 | | | | | | | |
| Comparative | 1-92 | BD-2 | | | 4.2 | 7.3 | 5 |
| Example 26 | | | | | | | |
| Comparative | 1-113 | BD-3 | | | 4.2 | 7.2 | 6 |
| Example 27 | | | | | | | |
| Comparative | 1-140 | BD-3 | | | 4.3 | 7.1 | 8 |
| Example 28 | | | | | | | |

As shown in [Table 1], it may be confirmed that the device employing the compound according to the present invention in the first light-emitting layer and the second light-emitting layer in the organic light-emitting device according to the present invention realizes a high-efficiency and long-lifespan organic light-emitting device having excellent light-emitting efficiency and lifespan properties at a low driving voltage compared with the organic light-emitting devices (Comparative Examples 1 to 22) using the comparative example compounds of the related art.

In addition, compared with the organic light-emitting devices (Comparative Examples 23 to 28) employing the compounds of the Examples according to the present invention in a single light-emitting layer having a thickness equal to the sum of the thicknesses of the first light-emitting layer and the second light-emitting layer of the light-emitting layer in the organic light-emitting device according to the present invention, rather than in a two-layered light-emitting layer, it may be confirmed that the devices of the Examples had significantly superior light-emitting efficiency and lifespan properties in all measured numerical parameters. This is presumed to be due to the fact that, in the case of the devices employing a multi-layered light-emitting layer according to the present invention, excitons are formed in the first light-emitting layer, and after the excitons are transferred to the second light-emitting layer, triplet-triplet fusion occurs, enabling efficient energy transfer, and as a result, properties of high efficiency and long lifespan may be exhibited.

On the other hand, in the case of the devices employing a single light-emitting layer as in the Comparative Examples, it is presumed that all processes of organic light emission need to occur in one layer, lowering probability of triplet-triplet fusion occurrences, and device degradation may consequently occur, resulting in reduced efficiency and lifespan. For these reasons, it may be confirmed that the device employing the first light-emitting layer and the second light-emitting layer is more advantageous in manufacturing a high-efficiency and long-lifespan organic light-emitting device compared with the device employing a single light-emitting layer.

### Examples 84 to 111: Manufacture of Organic Light-Emitting Device

Organic light-emitting devices were manufactured in the same manner as the organic light-emitting devices of Examples 1 to 83, except that, in manufacturing the organic light-emitting device including the first light-emitting layer and the second light-emitting layer, two compounds among the following [BH-3] to [BH-7] were used as the host in at least one of the first light-emitting layer and the second light-emitting layer or in both the light-emitting layers, and the following [BD-4] was used as the dopant in each of the light-emitting layers. Herein, the structure of [BD-4] is as follows, and light-emitting characteristics of the organic light-emitting devices were measured at 0.4 mA.

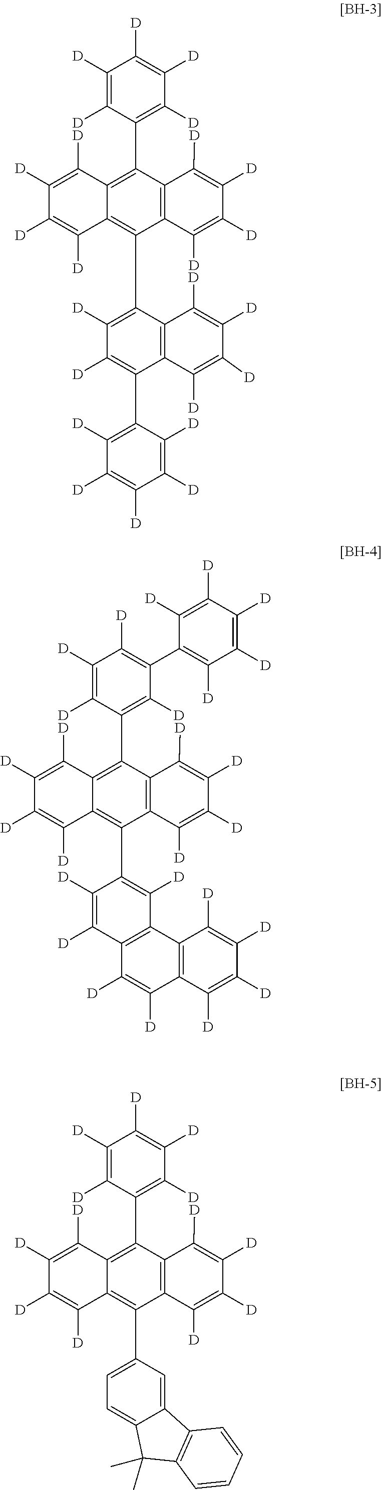

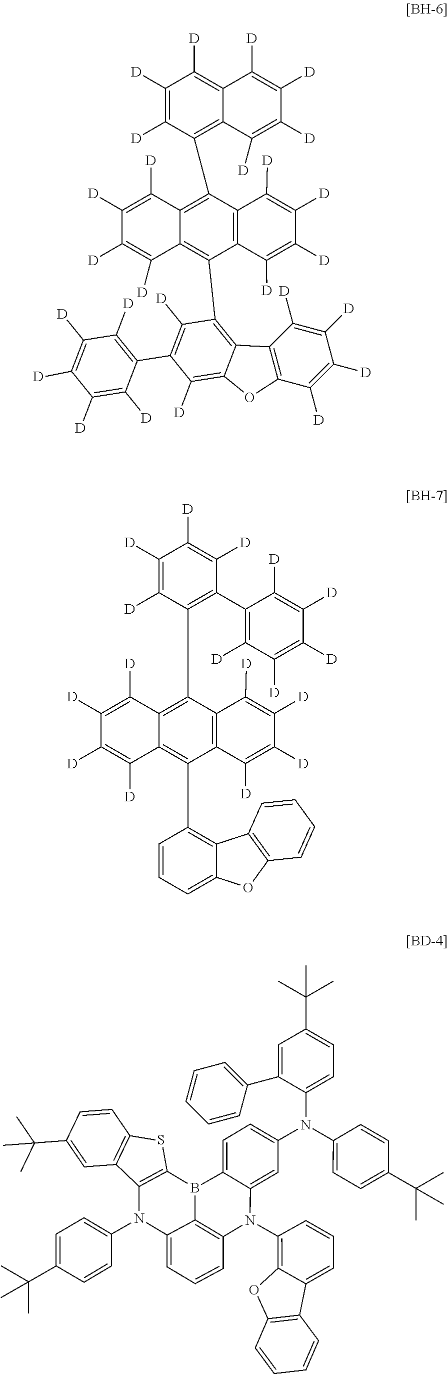

TABLE 2

| | | | | | | External | |
|---|---|---|---|---|---|---|---|
| | First Light- | | Second Light- | | Driving | Quantum | Lifespan |
| | Emitting Layer | | Emitting Layer | | Voltage | Efficiency | (LT97, |
| Classification | Host | | Host | | (V) | (EQE, %) | hr) |
| Example 84 | 1-34 | | BH-3 | BH-6 | 3.5 | 13.0 | 331 |
| Example 85 | 1-36 | | BH-3 | BH-6 | 3.4 | 13.0 | 334 |
| Example 86 | 1-58 | | BH-3 | BH-6 | 3.5 | 13.2 | 327 |
| Example 87 | 1-92 | | BH-3 | BH-6 | 3.4 | 12.9 | 320 |
| Example 88 | 1-107 | | BH-3 | BH-6 | 3.6 | 13.0 | 319 |
| Example 89 | 1-140 | | BH-3 | BH-6 | 3.5 | 13.1 | 325 |
| Example 90 | 1-34 | | BH-4 | BH-6 | 3.5 | 12.9 | 321 |
| Example 91 | 1-36 | | BH-4 | BH-6 | 3.4 | 12.9 | 324 |
| Example 92 | 1-58 | | BH-5 | BH-6 | 3.5 | 13.4 | 317 |
| Example 93 | 1-92 | | BH-5 | BH-6 | 3.4 | 13.1 | 310 |
| Example 94 | 1-107 | | BH-3 | BH-4 | 3.6 | 13.0 | 307 |
| Example 95 | 1-140 | | BH-3 | BH-5 | 3.6 | 13.2 | 308 |
| Example 96 | 1-58 | | BH-3 | BH-7 | 3.4 | 13.3 | 337 |
| Example 97 | 1-92 | | BH-4 | BH-7 | 3.4 | 12.9 | 325 |
| Example 98 | 1-107 | | BH-5 | BH-7 | 3.6 | 13.2 | 306 |
| Example 99 | 1-140 | | BH-6 | BH-7 | 3.3 | 13.2 | 345 |
| Example 100 | 1-34 | 1-36 | BH-3 | | 3.5 | 12.8 | 287 |
| Example 101 | 1-36 | 1-58 | BH-4 | | 3.5 | 13.0 | 300 |
| Example 102 | 1-58 | 1-92 | BH-5 | | 3.5 | 13.1 | 302 |
| Example 103 | 1-92 | 1-107 | BH-6 | | 3.3 | 12.9 | 321 |
| Example 104 | 1-107 | 1-140 | BH-7 | | 3.2 | 12.8 | 343 |
| Example 105 | 1-34 | 1-58 | BH-3 | BH-4 | 3.6 | 13.2 | 323 |
| Example 106 | 1-36 | 1-92 | BH-3 | BH-5 | 3.5 | 13.3 | 275 |
| Example 107 | 1-58 | 1-107 | BH-4 | BH-6 | 3.5 | 13.1 | 286 |
| Example 108 | 1-92 | 1-140 | BH-5 | BH-7 | 3.5 | 13.3 | 301 |
| Example 109 | 1-58 | 1-107 | BH-3 | BH-6 | 3.6 | 13.3 | 285 |
| Example 110 | 1-58 | 1-140 | BH-5 | BH-6 | 3.5 | 13.5 | 312 |
| Example 111 | 1-36 | 1-107 | BH-6 | BH-7 | 3.3 | 13.0 | 328 |

As shown in [Table 2], it may be confirmed that the device employing two or more compounds having different structural formulae as the host in at least one of the first light-emitting layer and the second light-emitting layer in the organic light-emitting device according to the present invention realizes a high-efficiency and long-lifespan organic light-emitting device having excellent light-emitting efficiency and lifespan properties at a low driving voltage.

1. A fused cyclic compound represented by the following [Chemical Formula 1]: 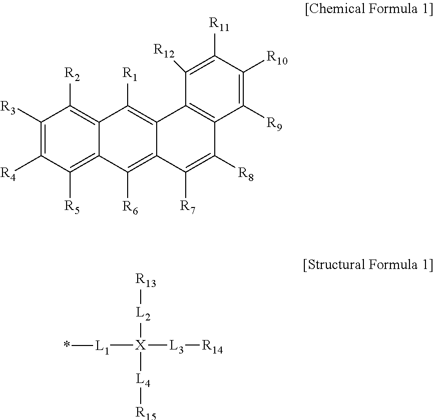
wherein, in [Chemical Formula 1],
one of R₁ to R₁₂ is linked to L₁ in [Structural Formula 1] via a single bond (′*′ represents a linking site);
the remainders of R₁ to R₁₂ excluding the one linked to L₁ via a single bond are the same as or different from each other, and each independently any one selected from hydrogen, deuterium, tritium, a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted alkenyl a substituted or unsubstituted C₂-C₃₀ group, or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group;
X is Si or Ge;
L₁ to La are the same as or different from each other, and each independently a single bond, or any one selected from a substituted or unsubstituted C₆-C₃₀ arylene group, a substituted or unsubstituted C₂-C₃₀ heteroarylene group, and a substituted or unsubstituted arylene group fused with a C₈-C₃₀ aliphatic hydrocarbon ring;
R₁₃ is any one selected from a substituted or unsubstituted C₆-C₅₀ aryl group, a substituted or unsubstituted C₂-C₅₀ heteroaryl group, a substituted or unsubstituted C₃-C₅₀ cycloalkyl group, a substituted or unsubstituted C₂-C₅₀ heterocycloalkyl group, and a substituted or unsubstituted cyclic group in which a C₃-C₃₀ aliphatic ring and a C₅-C₃₀ aromatic ring are fused;
R₁₄ and R₁₅ are the same as or different from each other, and each independently any one selected from a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted or unsubstituted C₂-C₃₀ alkenyl group, a substituted or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group; and
the ‘substituted’ in the ‘substituted or unsubstituted’ in [Chemical Formula 1] and [Structural Formula 1] means being substituted with one or more substituents selected from the group consisting of deuterium, tritium, a C₁-C₂₄ alkyl group, a C₁-C₂₄ halogenated alkyl group, a C₂-C₂₄ alkenyl group, a C₂-C₂₄ alkynyl group, a C₃-C₃₀ cycloalkyl group, a C₁-C₂₄ heteroalkyl group, a C₆-C₃₀ aryl group, a C₇-C₃₀ arylalkyl group, a C₇-C₃₀ alkylaryl group, a C₂-C₃₀ heteroaryl group, a C₂-C₃₀ heteroarylalkyl group, a cyclic group in which a C₃-C₂₄ aliphatic ring and a C₅-C₂₄ aromatic ring are fused, a C₁-C₃₀ amine group, a C₁-C₃₀ silyl group, a C₁-C₃₀ germanium group, a C₁-C₃₀ oxy group, a C₁-C₃₀ thioxy group, a C₁-C₃₀ thionyl group, a cyano group, a halogen group, a thiol group, a hydroxyl group and a nitro group, and when there are two or more substituents, they are the same as or different from each other, and at least one hydrogen atom in the compound formed from [Chemical Formula 1] is optionally substituted with deuterium or tritium.

2. The fused cyclic compound of claim 1, wherein R₆ in [Chemical Formula 1] is linked to L₁ in [Structural Formula 1] via a single bond.

3. The fused cyclic compound of claim 1, wherein R₈ in [Chemical Formula 1] is linked to L₁ in [Structural Formula 1] via a single bond.

4. The fused cyclic compound of claim 1, wherein L₁ is a single bond, or a substituted or unsubstituted C₆-C₂₀ arylene group.

5. The fused cyclic compound of claim 4, wherein L₁ is a single bond.

6. The fused cyclic compound of claim 1, wherein R₁₃ is a substituted or unsubstituted C₆-C₂₀ aryl group.

7. The fused cyclic compound of claim 1, wherein R₁₄ and R₁₅ are t same as or different from each other, and each independently any one selected from a substituted or unsubstituted C₁-C₁₀ alkyl group, a substituted or unsubstituted C₆-C₂₀ aryl group, a substituted or unsubstituted C₂-C₂₀ heteroaryl group, and a substituted or unsubstituted cyclic group in which a C₃-C₂₀ aliphatic ring and a C₅-C₂₀ aromatic ring are fused.

8. The fused cyclic compound of claim 1, wherein the remainders of R₁ to R₁₂ excluding the one linked to L₁ in [Structural Formula 1] via a single bond are each hydrogen or deuterium.

9. The fused cyclic compound of claim 1, wherein the compound represented by [Chemical Formula 1] is any one selected from the group consisting of the following Chemical Formulae 1-1 to 1-168:

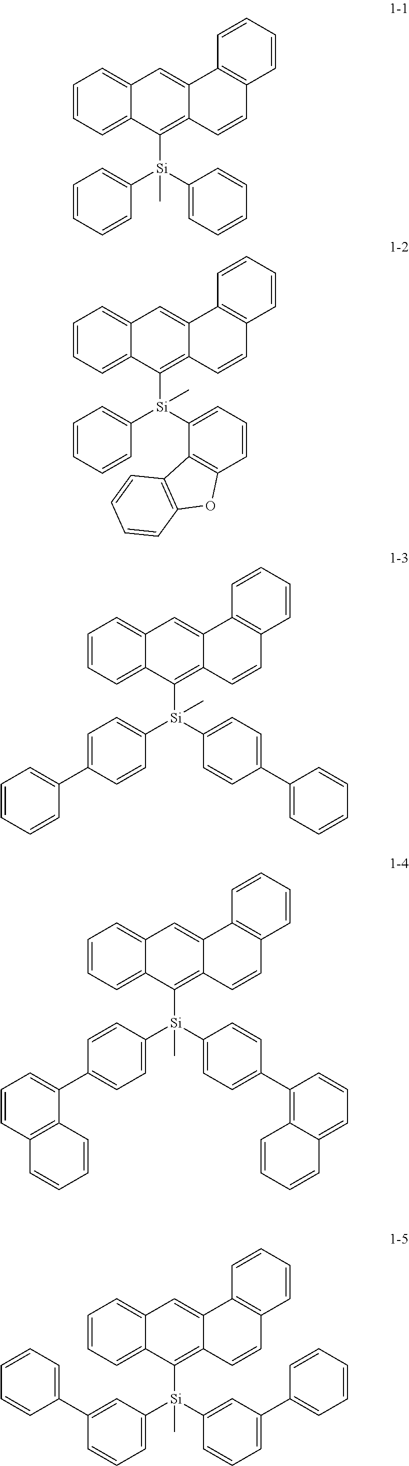

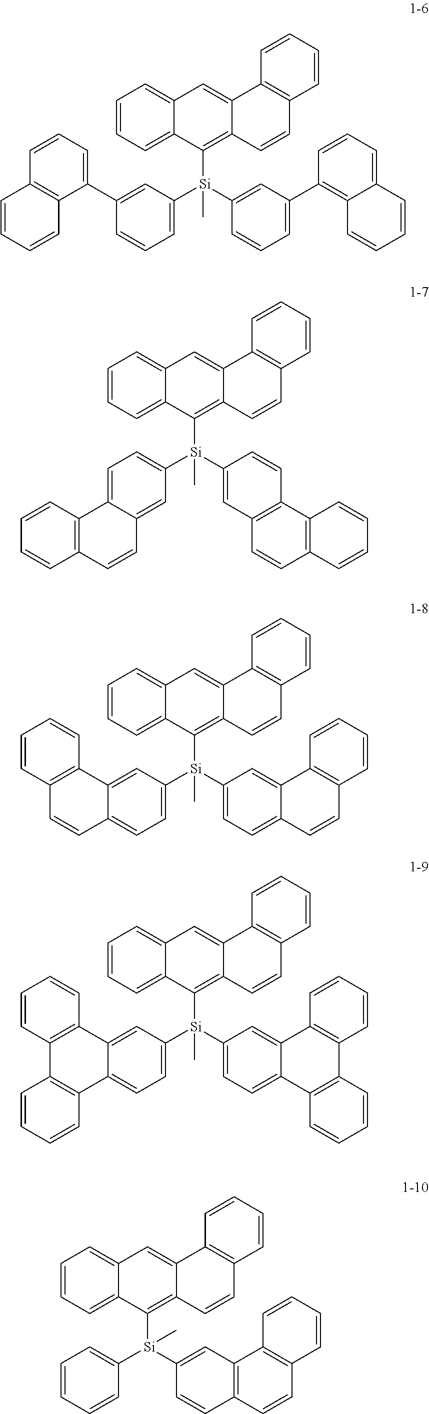 [SMILES: C[Si](c1cccc(-c2cccc3ccccc23)c1)(c1cccc(-c2cccc3ccccc23)c1)c1c2ccccc2cc2c1ccc1ccccc12 ; C[Si](c1ccc2c(ccc3ccccc32)c1)(c1ccc2c(ccc3ccccc32)c1)c1c2ccccc2cc2c1ccc1ccccc12 ; C[Si](c1ccc2ccc3ccccc3c2c1)(c1ccc2ccc3ccccc3c2c1)c1c2ccccc2cc2c1ccc1ccccc12 ; C[Si](c1ccc2c3ccccc3c3ccccc3c2c1)(c1ccc2c3ccccc3c3ccccc3c2c1)c1c2ccccc2cc2c1ccc1ccccc12 ; C[Si](c1ccccc1)(c1ccc2ccc3ccccc3c2c1)c1c2ccccc2cc2c1ccc1ccccc12]

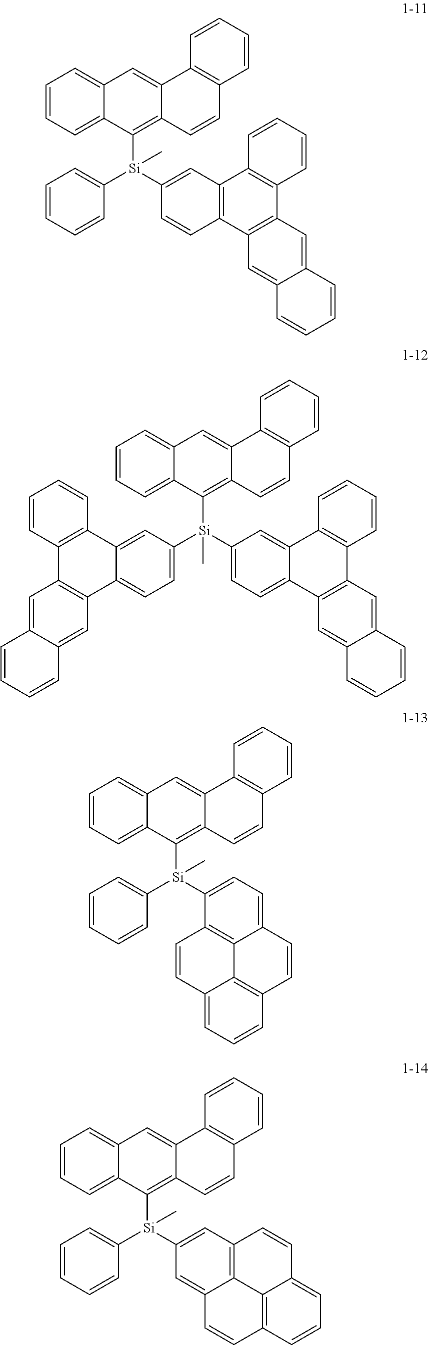

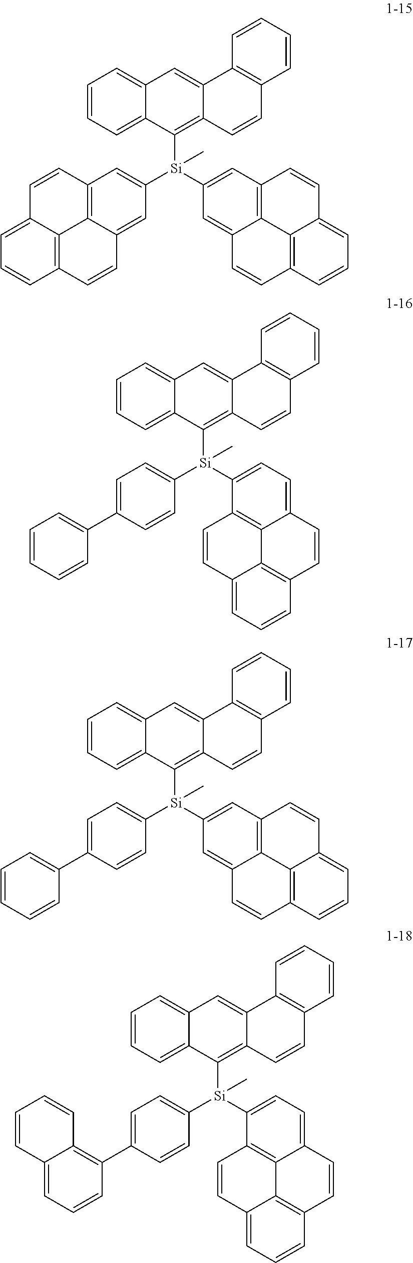

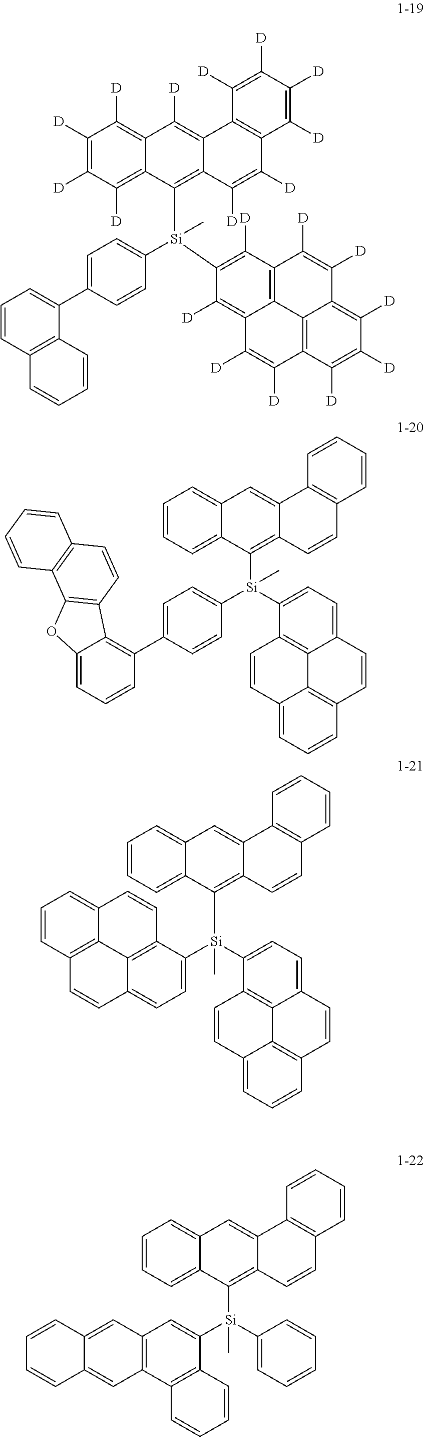

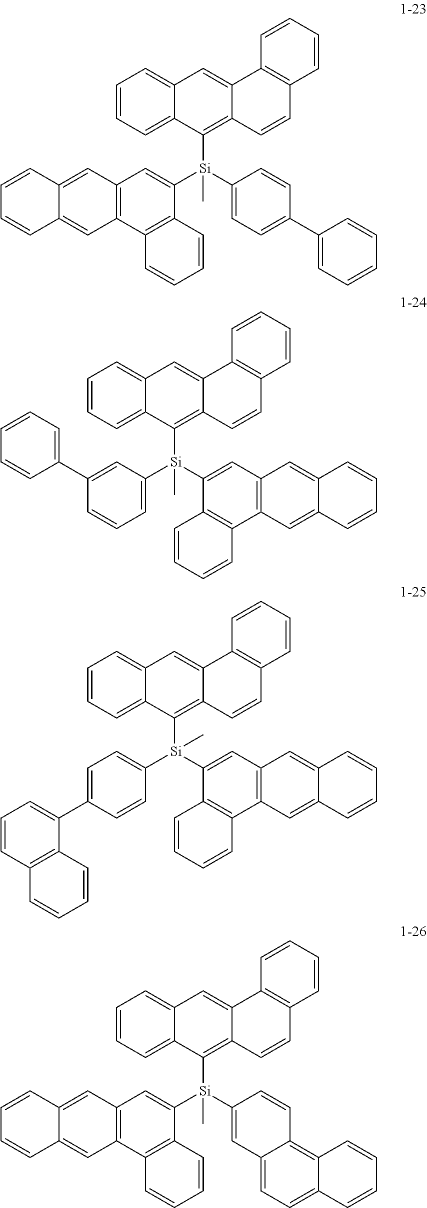 [SMILES: C[Si](c1ccc(-c2ccccc2)cc1)(c1cc2cc3ccccc3cc2c2ccccc12)c1c2ccccc2cc2c1ccc1ccccc12 ; C[Si](c1cccc(-c2ccccc2)c1)(c1cc2cc3ccccc3cc2c2ccccc12)c1c2ccccc2cc2c1ccc1ccccc12 ; C[Si](c1ccc(-c2cccc3ccccc23)cc1)(c1cc2cc3ccccc3cc2c2ccccc12)c1c2ccccc2cc2c1ccc1ccccc12 ; C[Si](c1ccc2c(ccc3ccccc32)c1)(c1cc2cc3ccccc3cc2c2ccccc12)c1c2ccccc2cc2c1ccc1ccccc12]

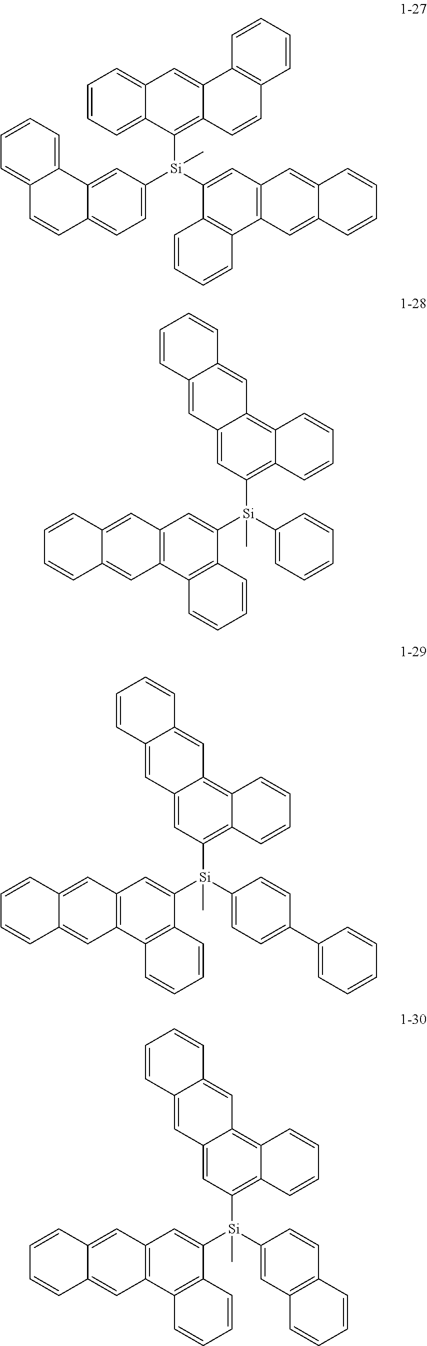

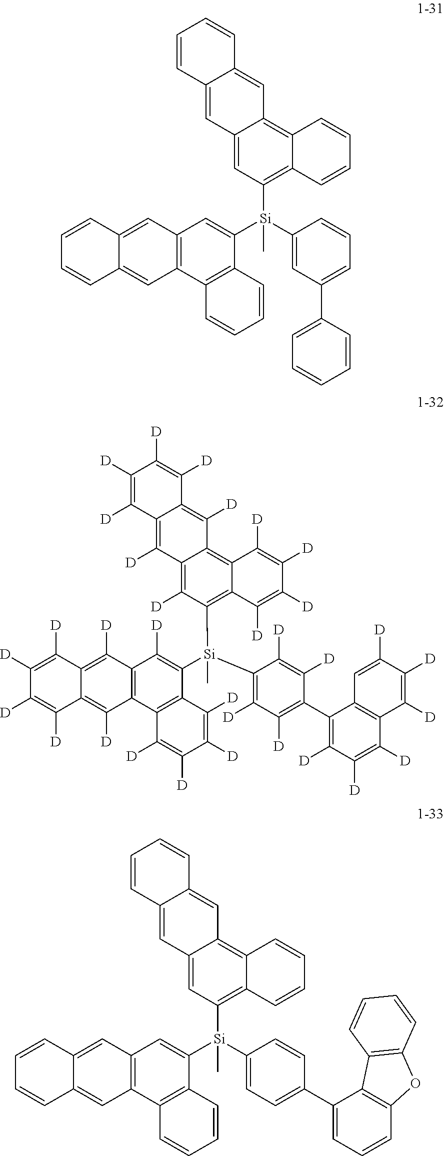 [SMILES: C[Si](c1cccc(-c2ccccc2)c1)(c1cc2cc3ccccc3cc2c2ccccc12)c1cc2cc3ccccc3cc2c2ccccc12 ; [2H]c1cc2c(-c3c([2H])c([2H])c([Si](C)(c4c([2H])c5c([2H])c6c([2H])c([2H])c([2H])c([2H])c6c([2H])c5c5c([2H])c([2H])c([2H])c([2H])c45)c4c([2H])c5c([2H])c6c([2H])c([2H])c([2H])c([2H])c6c([2H])c5c5c([2H])c([2H])c([2H])c([2H])c45)c([2H])c3[2H])c([2H])c([2H])c([2H])c2c([2H])c1[2H] ; C[Si](c1ccc(-c2cccc3oc4ccccc4c23)cc1)(c1cc2cc3ccccc3cc2c2ccccc12)c1cc2cc3ccccc3cc2c2ccccc12]

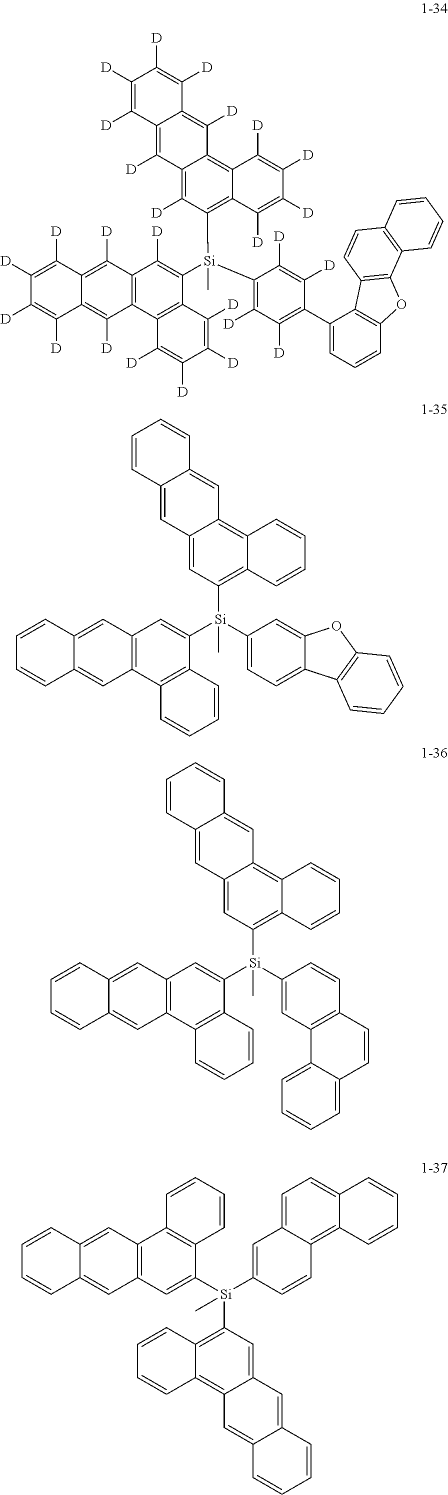

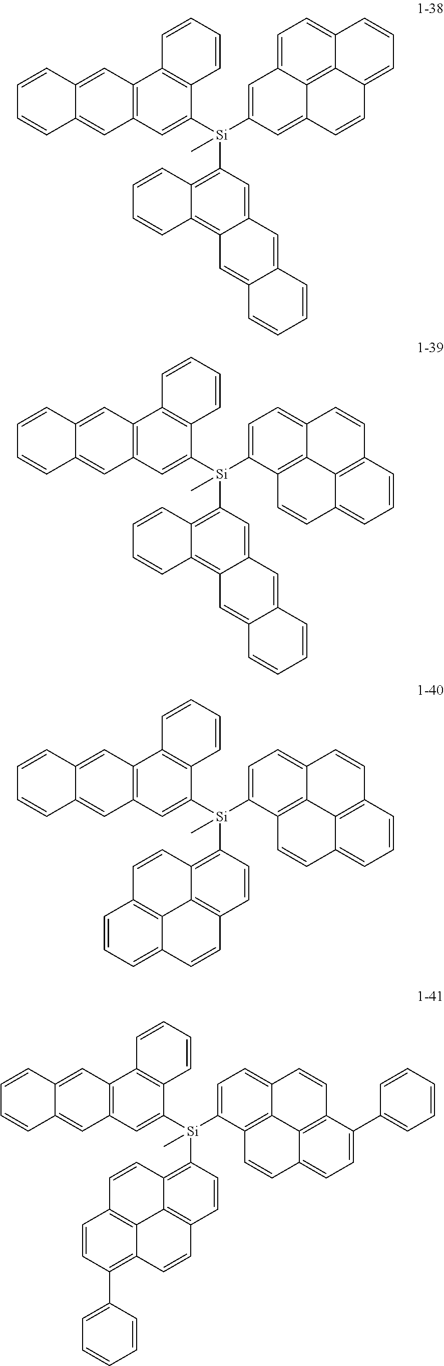 [SMILES: C[Si](c1cc2ccc3cccc4ccc(c1)c2c34)(c1cc2cc3ccccc3cc2c2ccccc12)c1cc2cc3ccccc3cc2c2ccccc12 ; C[Si](c1cc2cc3ccccc3cc2c2ccccc12)(c1cc2cc3ccccc3cc2c2ccccc12)c1ccc2ccc3cccc4ccc1c2c34 ; C[Si](c1cc2cc3ccccc3cc2c2ccccc12)(c1ccc2ccc3cccc4ccc1c2c34)c1ccc2ccc3cccc4ccc1c2c34 ; C[Si](c1cc2cc3ccccc3cc2c2ccccc12)(c1ccc2ccc3c(-c4ccccc4)ccc4ccc1c2c43)c1ccc2ccc3c(-c4ccccc4)ccc4ccc1c2c43]

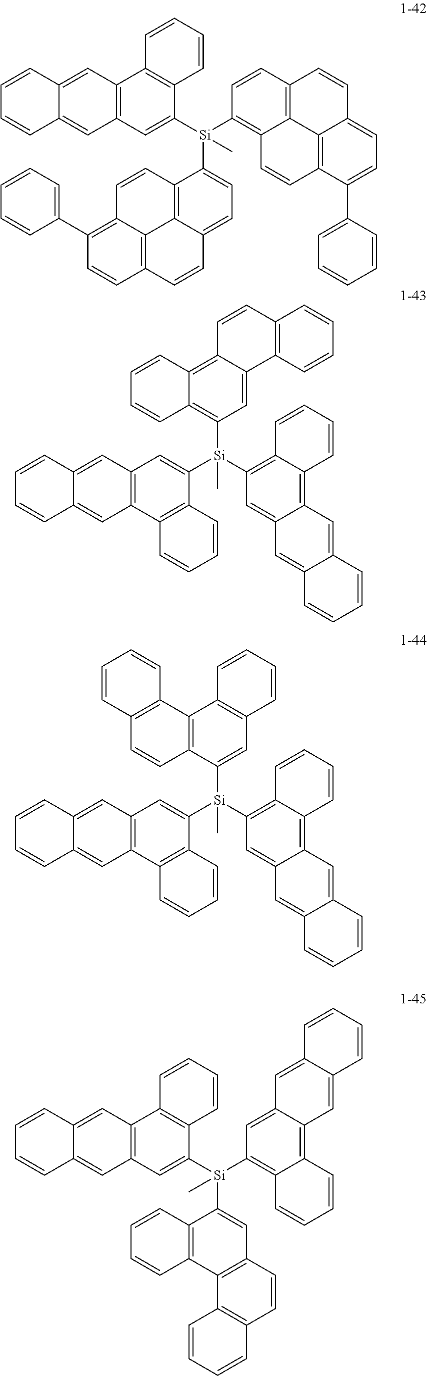

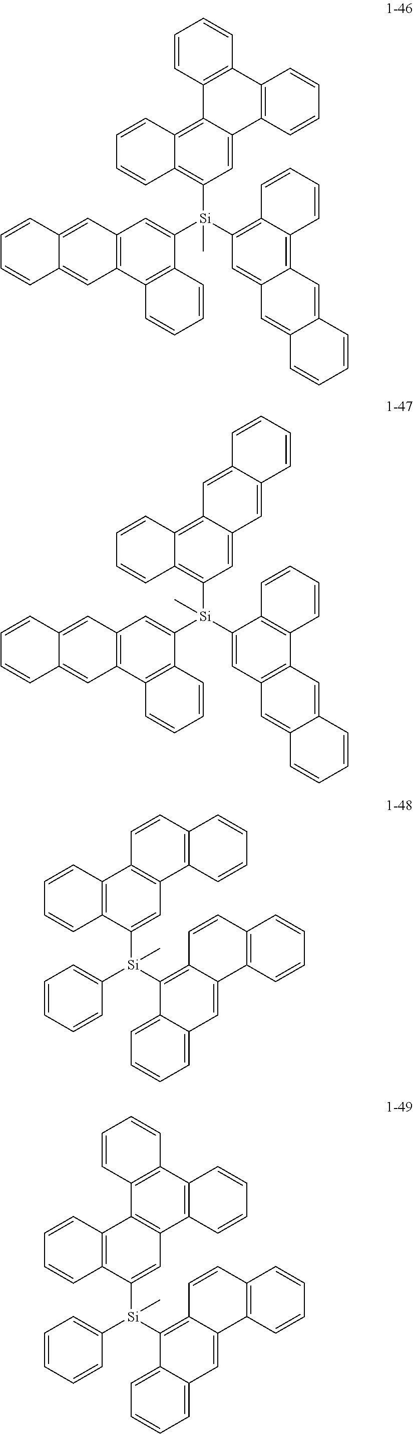

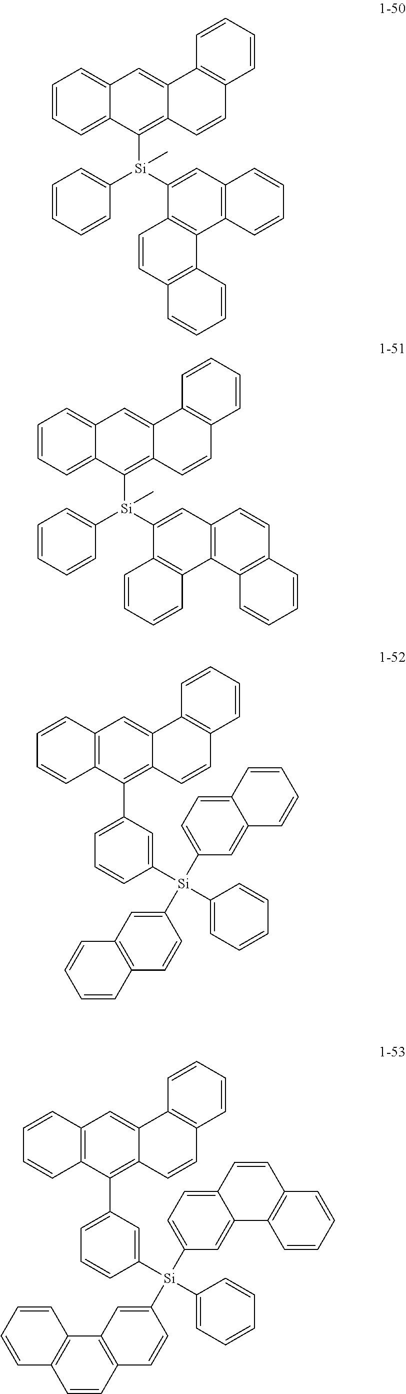

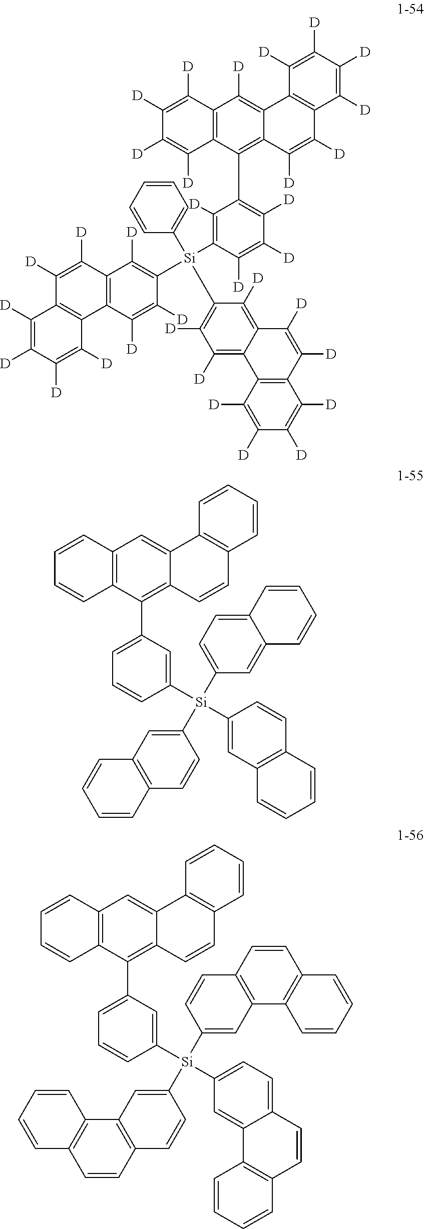

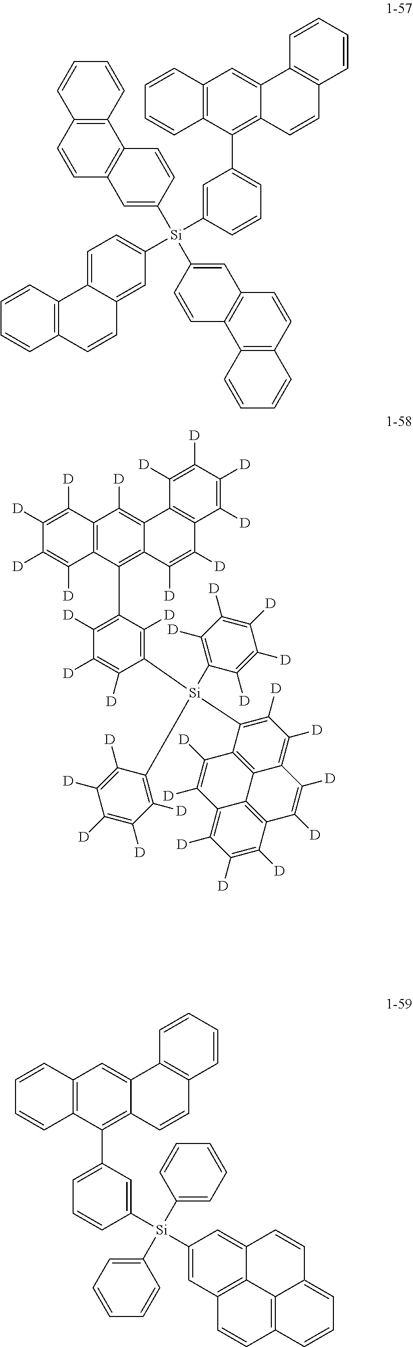 [SMILES: c1cc(-c2c3ccccc3cc3c2ccc2ccccc23)cc([Si](c2ccc3c(ccc4ccccc43)c2)(c2ccc3c(ccc4ccccc43)c2)c2ccc3c(ccc4ccccc43)c2)c1 ; [2H]c1c([2H])c([2H])c([Si](c2c([2H])c([2H])c([2H])c([2H])c2[2H])(c2c([2H])c([2H])c([2H])c(-c3c4c([2H])c([2H])c([2H])c([2H])c4c([2H])c4c3c([2H])c([2H])c3c([2H])c([2H])c([2H])c([2H])c34)c2[2H])c2c([2H])c([2H])c3c([2H])c([2H])c4c([2H])c([2H])c([2H])c5c([2H])c([2H])c2c3c45)c([2H])c1[2H] ; c1ccc([Si](c2ccccc2)(c2cccc(-c3c4ccccc4cc4c3ccc3ccccc34)c2)c2cc3ccc4cccc5ccc(c2)c3c45)cc1]

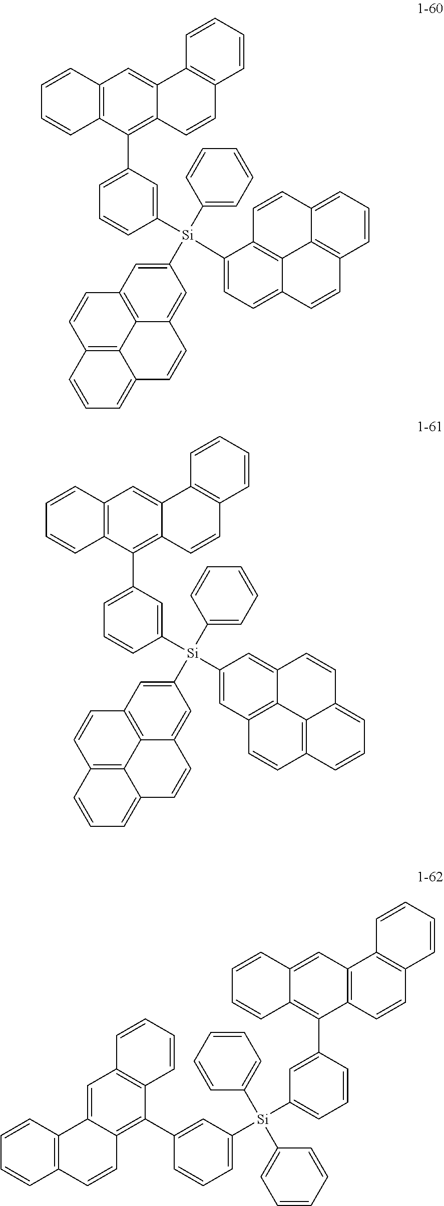 [SMILES: c1ccc([Si](c2cccc(-c3c4ccccc4cc4c3ccc3ccccc34)c2)(c2cc3ccc4cccc5ccc(c2)c3c45)c2ccc3ccc4cccc5ccc2c3c45)cc1 ; c1ccc([Si](c2cccc(-c3c4ccccc4cc4c3ccc3ccccc34)c2)(c2cc3ccc4cccc5ccc(c2)c3c45)c2cc3ccc4cccc5ccc(c2)c3c45)cc1 ; c1ccc([Si](c2ccccc2)(c2cccc(-c3c4ccccc4cc4c3ccc3ccccc34)c2)c2cccc(-c3c4ccccc4cc4c3ccc3ccccc34)c2)cc1]

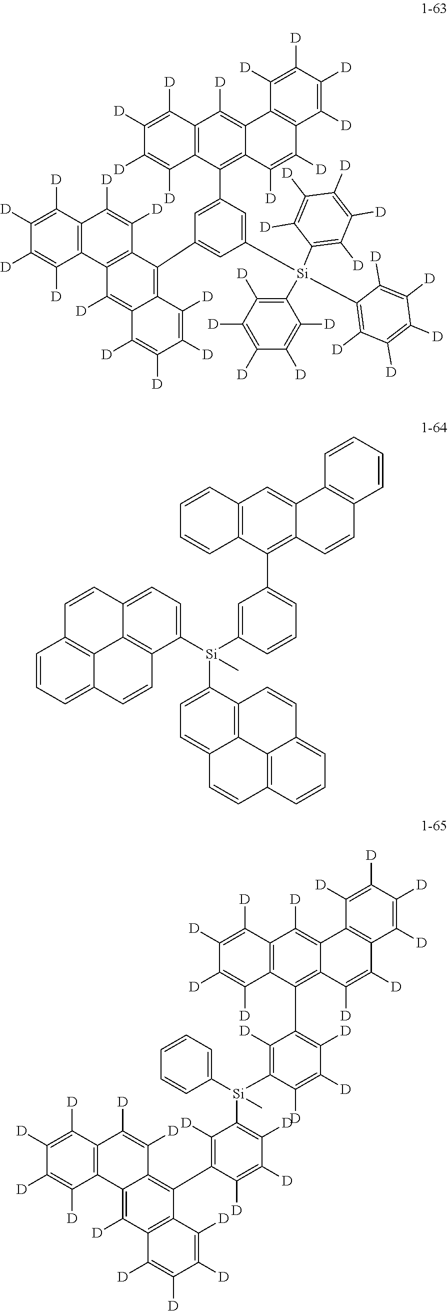

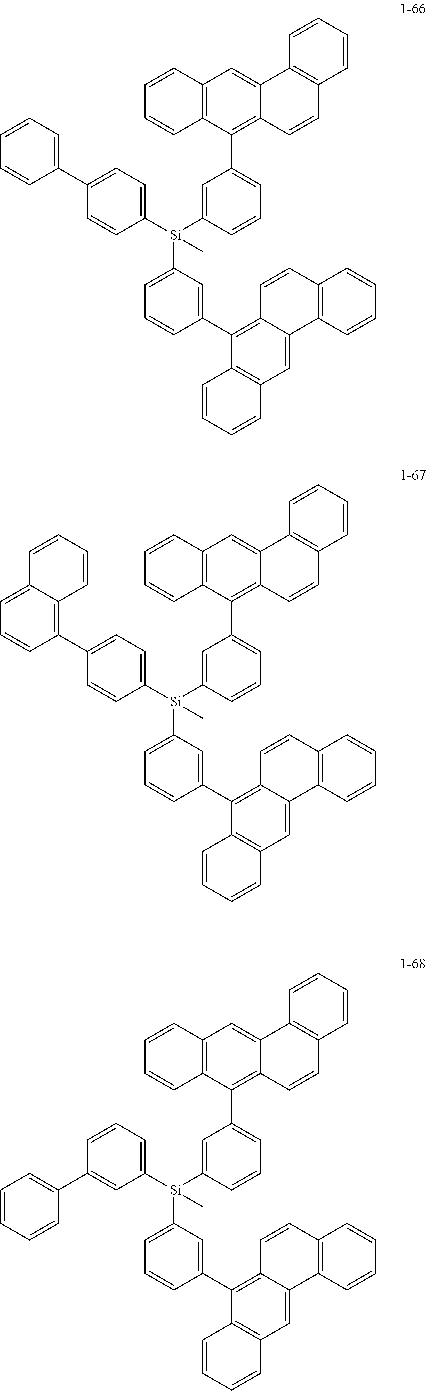 [SMILES: C[Si](c1ccc(-c2ccccc2)cc1)(c1cccc(-c2c3ccccc3cc3c2ccc2ccccc23)c1)c1cccc(-c2c3ccccc3cc3c2ccc2ccccc23)c1 ; C[Si](c1ccc(-c2cccc3ccccc23)cc1)(c1cccc(-c2c3ccccc3cc3c2ccc2ccccc23)c1)c1cccc(-c2c3ccccc3cc3c2ccc2ccccc23)c1 ; C[Si](c1cccc(-c2ccccc2)c1)(c1cccc(-c2c3ccccc3cc3c2ccc2ccccc23)c1)c1cccc(-c2c3ccccc3cc3c2ccc2ccccc23)c1]

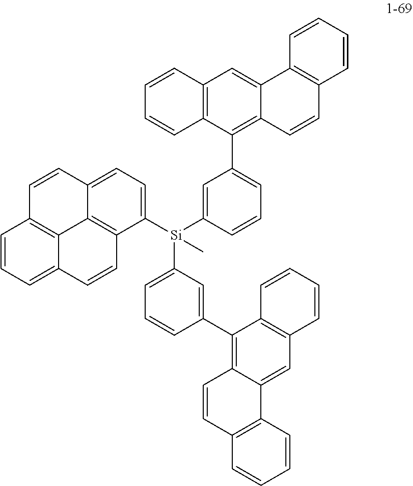 [SMILES: C[Si](c1cccc(-c2c3ccccc3cc3c2ccc2ccccc23)c1)(c1cccc(-c2c3ccccc3cc3c2ccc2ccccc23)c1)c1ccc2ccc3cccc4ccc1c2c34]

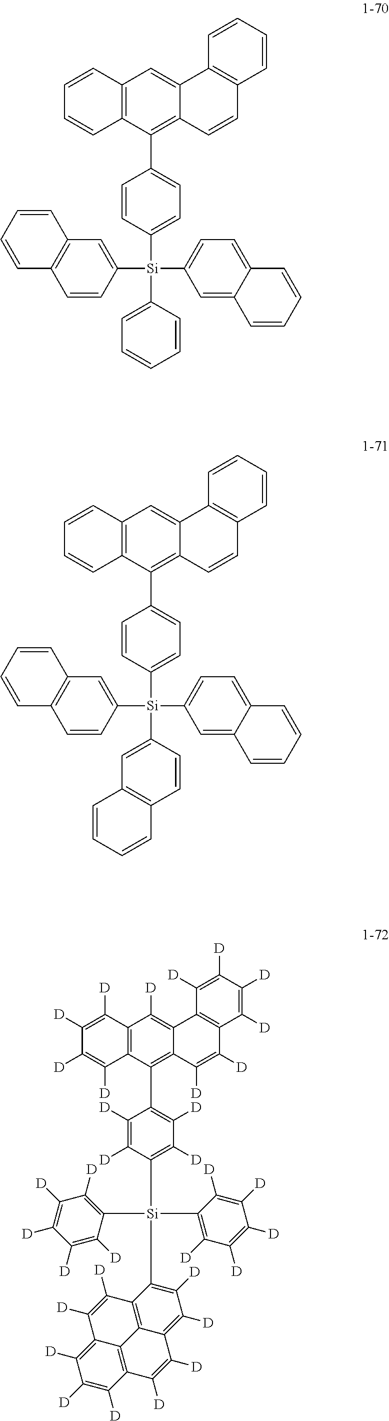 [SMILES: c1ccc([Si](c2ccc(-c3c4ccccc4cc4c3ccc3ccccc34)cc2)(c2ccc3ccccc3c2)c2ccc3ccccc3c2)cc1 ; c1ccc2cc([Si](c3ccc(-c4c5ccccc5cc5c4ccc4ccccc45)cc3)(c3ccc4ccccc4c3)c3ccc4ccccc4c3)ccc2c1 ; [2H]c1c([2H])c([2H])c([Si](c2c([2H])c([2H])c([2H])c([2H])c2[2H])(c2c([2H])c([2H])c(-c3c4c([2H])c([2H])c([2H])c([2H])c4c([2H])c4c3c([2H])c([2H])c3c([2H])c([2H])c([2H])c([2H])c34)c([2H])c2[2H])c2c([2H])c([2H])c3c([2H])c([2H])c4c([2H])c([2H])c([2H])c5c([2H])c([2H])c2c3c45)c([2H])c1[2H]]

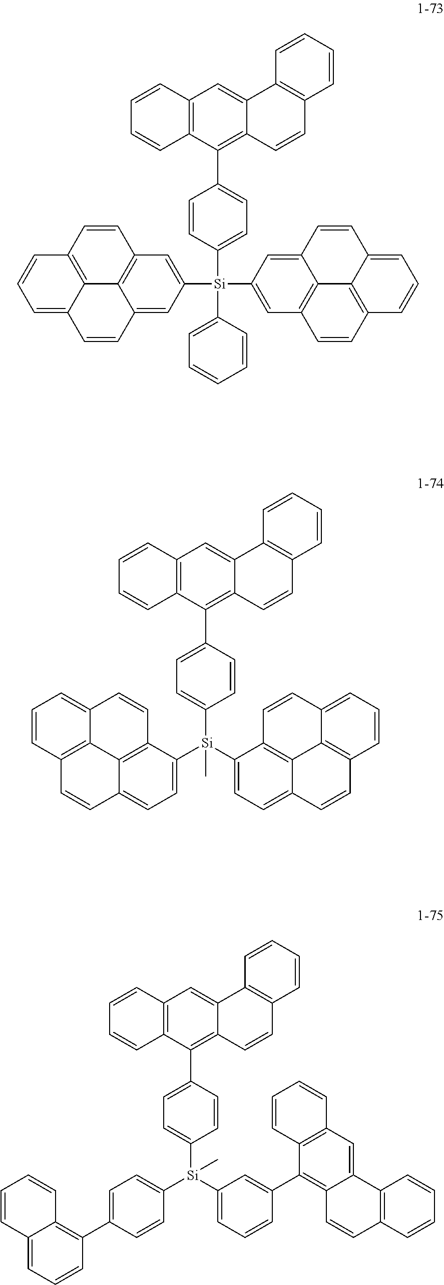 [SMILES: c1ccc([Si](c2ccc(-c3c4ccccc4cc4c3ccc3ccccc34)cc2)(c2cc3ccc4cccc5ccc(c2)c3c45)c2cc3ccc4cccc5ccc(c2)c3c45)cc1 ; C[Si](c1ccc(-c2c3ccccc3cc3c2ccc2ccccc23)cc1)(c1ccc2ccc3cccc4ccc1c2c34)c1ccc2ccc3cccc4ccc1c2c34 ; C[Si](c1ccc(-c2cccc3ccccc23)cc1)(c1ccc(-c2c3ccccc3cc3c2ccc2ccccc23)cc1)c1cccc(-c2c3ccccc3cc3c2ccc2ccccc23)c1]

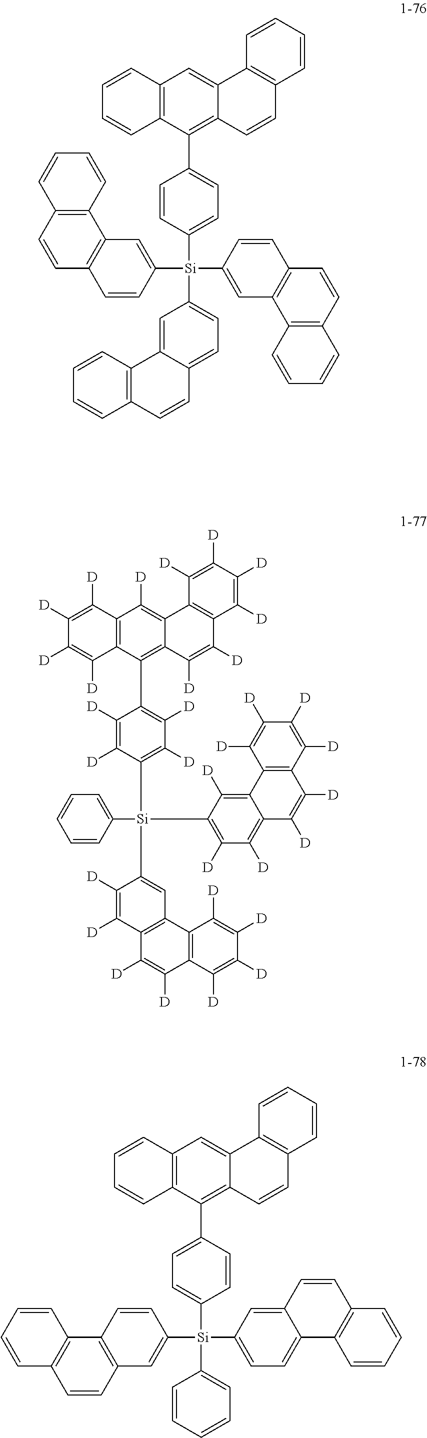 [SMILES: c1ccc2c(-c3ccc([Si](c4ccc5ccc6ccccc6c5c4)(c4ccc5ccc6ccccc6c5c4)c4ccc5ccc6ccccc6c5c4)cc3)c3ccc4ccccc4c3cc2c1 ; [2H]c1c([2H])c([Si](c2ccccc2)(c2cc3c(c([2H])c2[2H])c([2H])c([2H])c2c([2H])c([2H])c([2H])c([2H])c23)c2c([2H])c([2H])c3c([2H])c([2H])c4c([2H])c([2H])c([2H])c([2H])c4c3c2[2H])c([2H])c([2H])c1-c1c2c([2H])c([2H])c([2H])c([2H])c2c([2H])c2c1c([2H])c([2H])c1c([2H])c([2H])c([2H])c([2H])c12 ; c1ccc([Si](c2ccc(-c3c4ccccc4cc4c3ccc3ccccc34)cc2)(c2ccc3c(ccc4ccccc43)c2)c2ccc3c(ccc4ccccc43)c2)cc1]

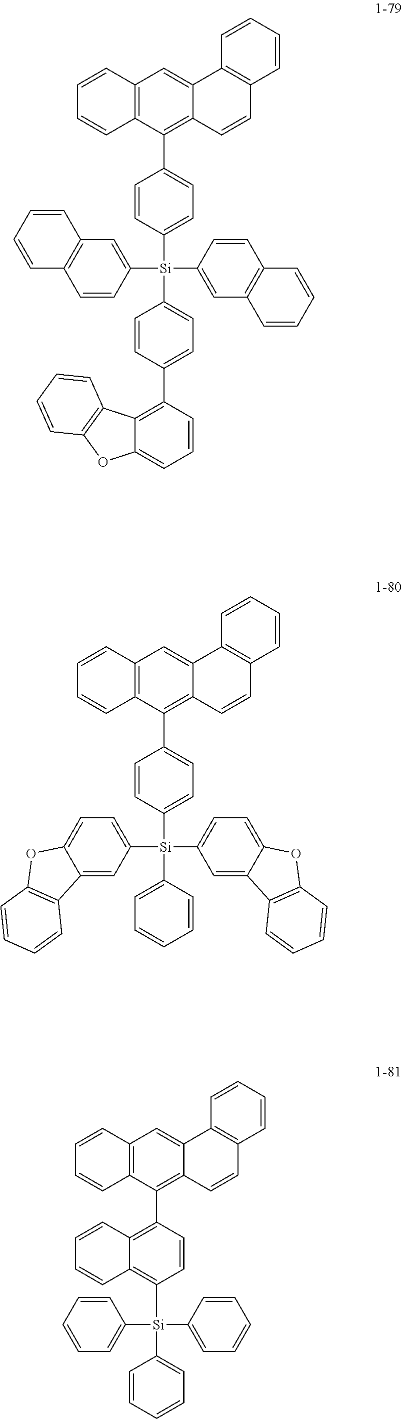 [SMILES: c1ccc2cc([Si](c3ccc(-c4c5ccccc5cc5c4ccc4ccccc45)cc3)(c3ccc(-c4cccc5oc6ccccc6c45)cc3)c3ccc4ccccc4c3)ccc2c1 ; c1ccc([Si](c2ccc(-c3c4ccccc4cc4c3ccc3ccccc34)cc2)(c2ccc3oc4ccccc4c3c2)c2ccc3oc4ccccc4c3c2)cc1 ; c1ccc([Si](c2ccccc2)(c2ccccc2)c2ccc(-c3c4ccccc4cc4c3ccc3ccccc34)c3ccccc23)cc1]

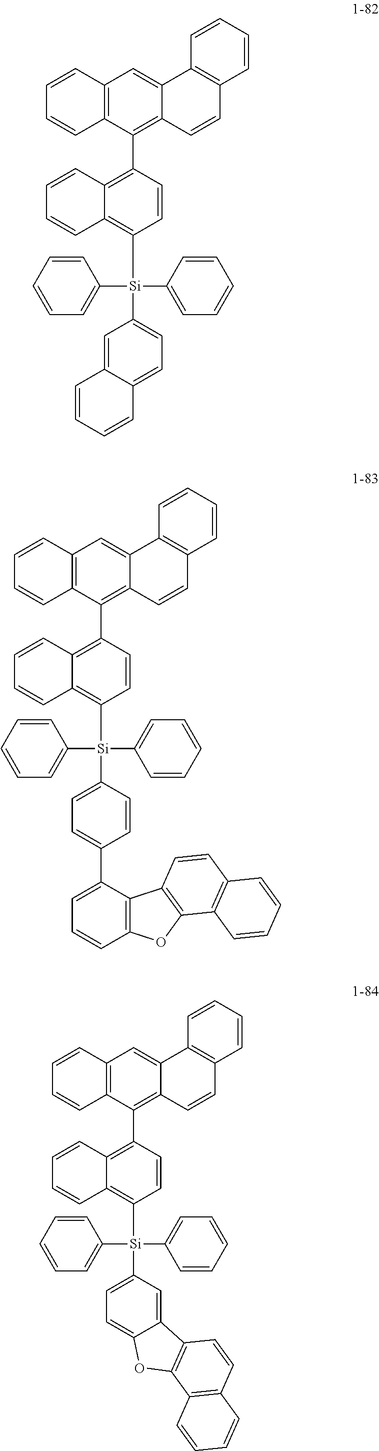 [SMILES: c1ccc([Si](c2ccccc2)(c2ccc3ccccc3c2)c2ccc(-c3c4ccccc4cc4c3ccc3ccccc34)c3ccccc23)cc1 ; c1ccc([Si](c2ccccc2)(c2ccc(-c3cccc4oc5c6ccccc6ccc5c34)cc2)c2ccc(-c3c4ccccc4cc4c3ccc3ccccc34)c3ccccc23)cc1 ; c1ccc([Si](c2ccccc2)(c2ccc3oc4c5ccccc5ccc4c3c2)c2ccc(-c3c4ccccc4cc4c3ccc3ccccc34)c3ccccc23)cc1]

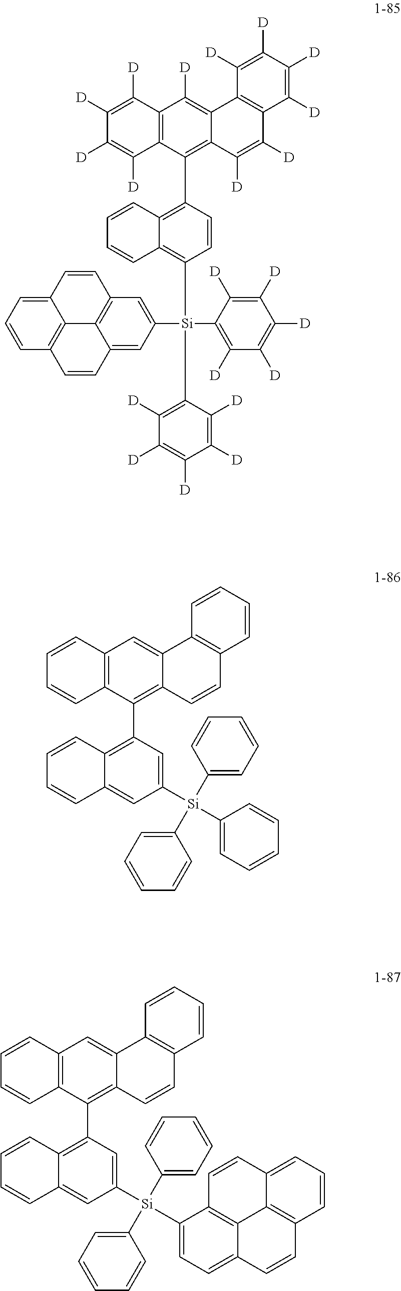 [SMILES: [2H]c1c([2H])c([2H])c([Si](c2cc3ccc4cccc5ccc(c2)c3c45)(c2c([2H])c([2H])c([2H])c([2H])c2[2H])c2ccc(-c3c4c([2H])c([2H])c([2H])c([2H])c4c([2H])c4c3c([2H])c([2H])c3c([2H])c([2H])c([2H])c([2H])c34)c3ccccc23)c([2H])c1[2H] ; c1ccc([Si](c2ccccc2)(c2ccccc2)c2cc(-c3c4ccccc4cc4c3ccc3ccccc34)c3ccccc3c2)cc1 ; c1ccc([Si](c2ccccc2)(c2cc(-c3c4ccccc4cc4c3ccc3ccccc34)c3ccccc3c2)c2ccc3ccc4cccc5ccc2c3c45)cc1]

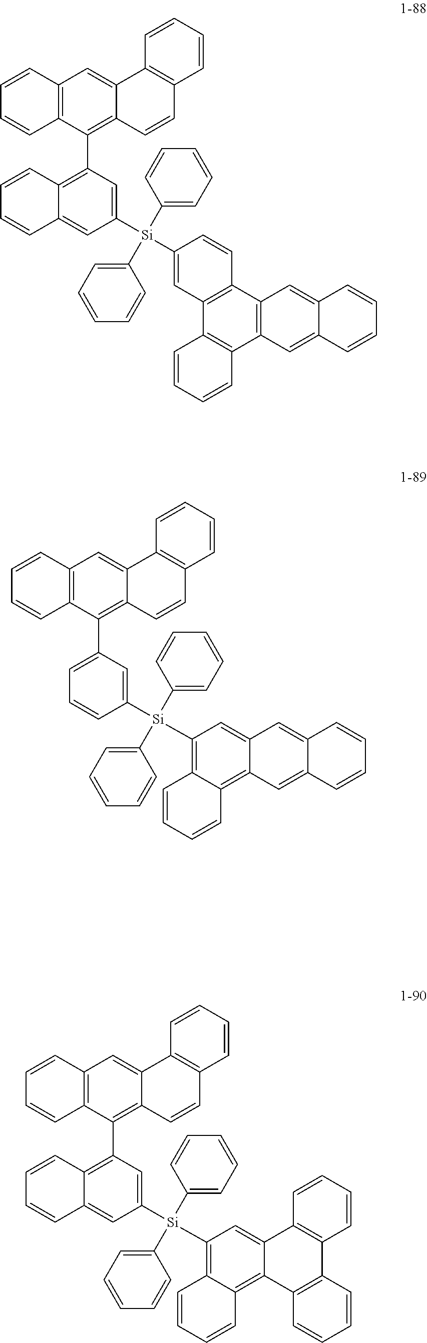 [SMILES: c1ccc([Si](c2ccccc2)(c2cc(-c3c4ccccc4cc4c3ccc3ccccc34)c3ccccc3c2)c2ccc3c(c2)c2ccccc2c2cc4ccccc4cc32)cc1 ; c1ccc([Si](c2ccccc2)(c2cccc(-c3c4ccccc4cc4c3ccc3ccccc34)c2)c2cc3cc4ccccc4cc3c3ccccc23)cc1 ; c1ccc([Si](c2ccccc2)(c2cc(-c3c4ccccc4cc4c3ccc3ccccc34)c3ccccc3c2)c2cc3c4ccccc4c4ccccc4c3c3ccccc23)cc1]

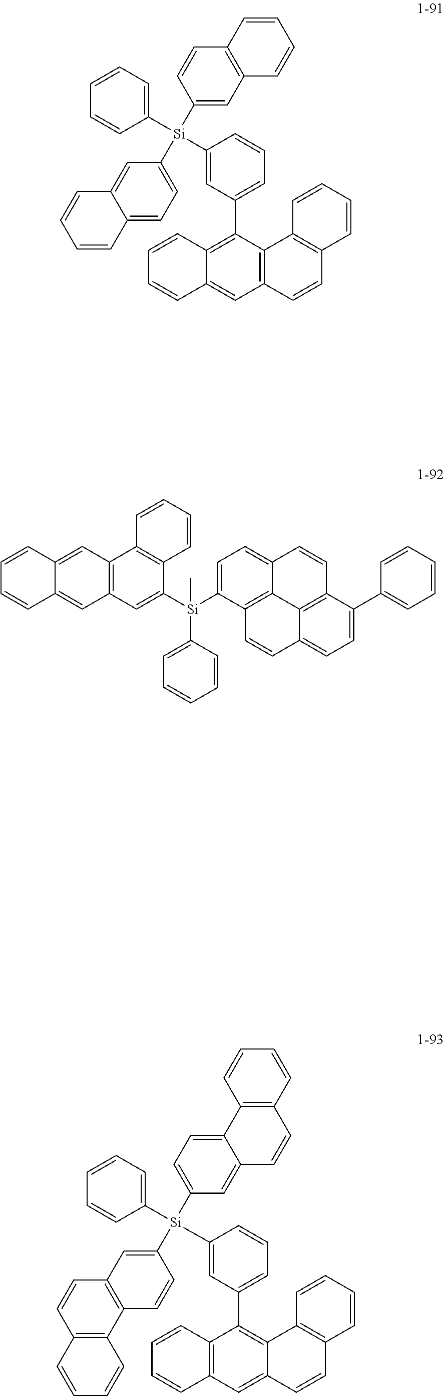 [SMILES: c1ccc([Si](c2cccc(-c3c4ccccc4cc4ccc5ccccc5c34)c2)(c2ccc3ccccc3c2)c2ccc3ccccc3c2)cc1 ; C[Si](c1ccccc1)(c1cc2cc3ccccc3cc2c2ccccc12)c1ccc2ccc3c(-c4ccccc4)ccc4ccc1c2c43 ; c1ccc([Si](c2cccc(-c3c4ccccc4cc4ccc5ccccc5c34)c2)(c2ccc3c(ccc4ccccc43)c2)c2ccc3c(ccc4ccccc43)c2)cc1]

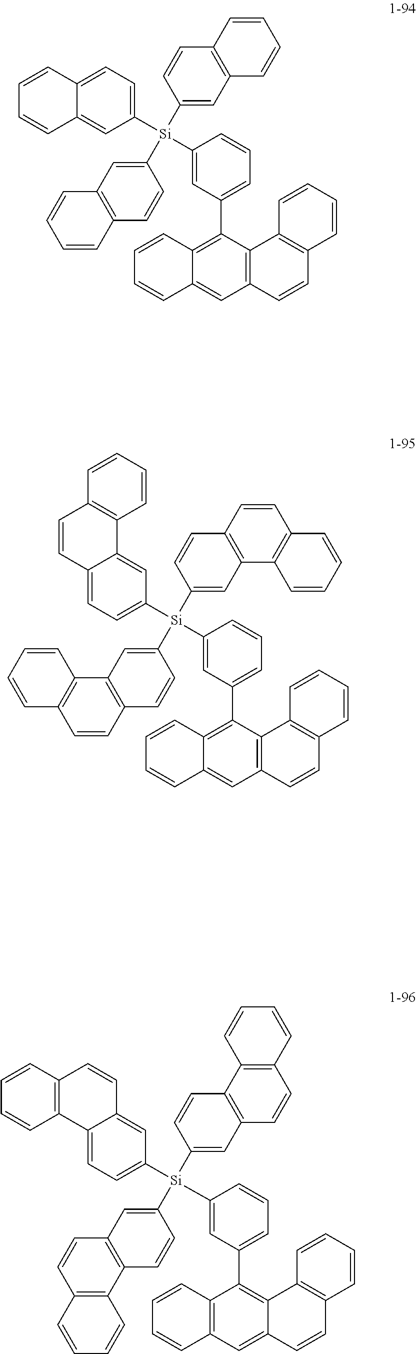 [SMILES: c1cc(-c2c3ccccc3cc3ccc4ccccc4c23)cc([Si](c2ccc3ccccc3c2)(c2ccc3ccccc3c2)c2ccc3ccccc3c2)c1 ; c1cc(-c2c3ccccc3cc3ccc4ccccc4c23)cc([Si](c2ccc3ccc4ccccc4c3c2)(c2ccc3ccc4ccccc4c3c2)c2ccc3ccc4ccccc4c3c2)c1 ; c1cc(-c2c3ccccc3cc3ccc4ccccc4c23)cc([Si](c2ccc3c(ccc4ccccc43)c2)(c2ccc3c(ccc4ccccc43)c2)c2ccc3c(ccc4ccccc43)c2)c1]

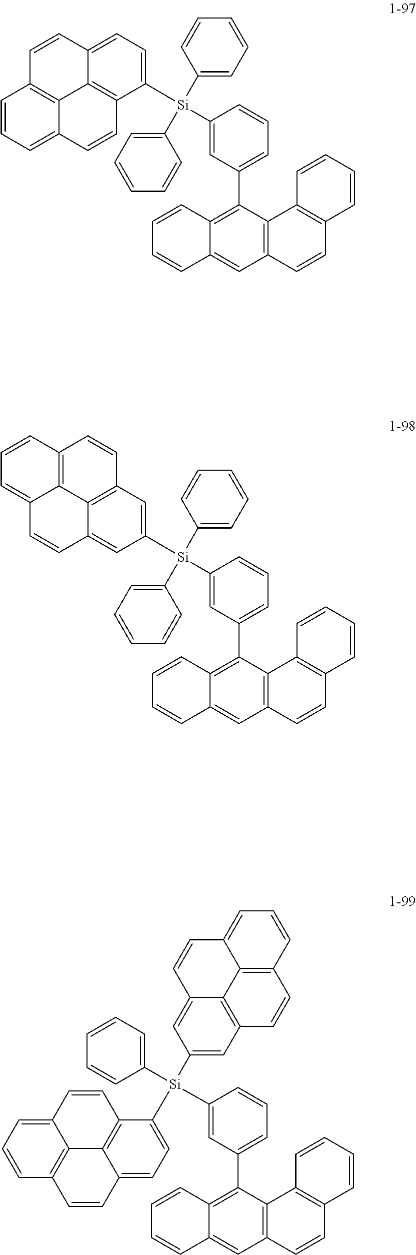 [SMILES: c1ccc([Si](c2ccccc2)(c2cccc(-c3c4ccccc4cc4ccc5ccccc5c34)c2)c2ccc3ccc4cccc5ccc2c3c45)cc1 ; c1ccc([Si](c2ccccc2)(c2cccc(-c3c4ccccc4cc4ccc5ccccc5c34)c2)c2cc3ccc4cccc5ccc(c2)c3c45)cc1 ; c1ccc([Si](c2cccc(-c3c4ccccc4cc4ccc5ccccc5c34)c2)(c2cc3ccc4cccc5ccc(c2)c3c45)c2ccc3ccc4cccc5ccc2c3c45)cc1]

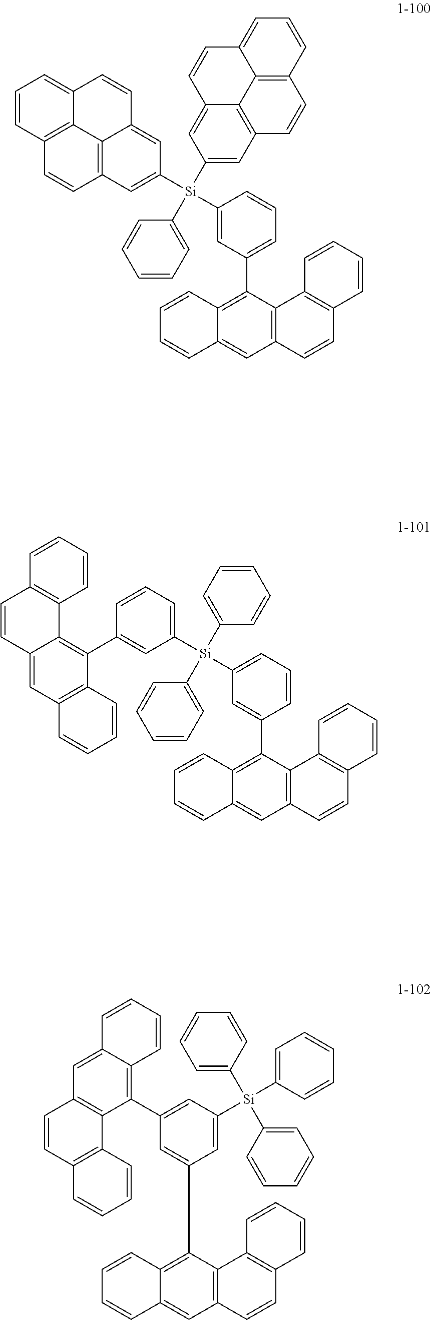 [SMILES: c1ccc([Si](c2cccc(-c3c4ccccc4cc4ccc5ccccc5c34)c2)(c2cc3ccc4cccc5ccc(c2)c3c45)c2cc3ccc4cccc5ccc(c2)c3c45)cc1 ; c1ccc([Si](c2ccccc2)(c2cccc(-c3c4ccccc4cc4ccc5ccccc5c34)c2)c2cccc(-c3c4ccccc4cc4ccc5ccccc5c34)c2)cc1 ; c1ccc([Si](c2ccccc2)(c2ccccc2)c2cc(-c3c4ccccc4cc4ccc5ccccc5c34)cc(-c3c4ccccc4cc4ccc5ccccc5c34)c2)cc1]

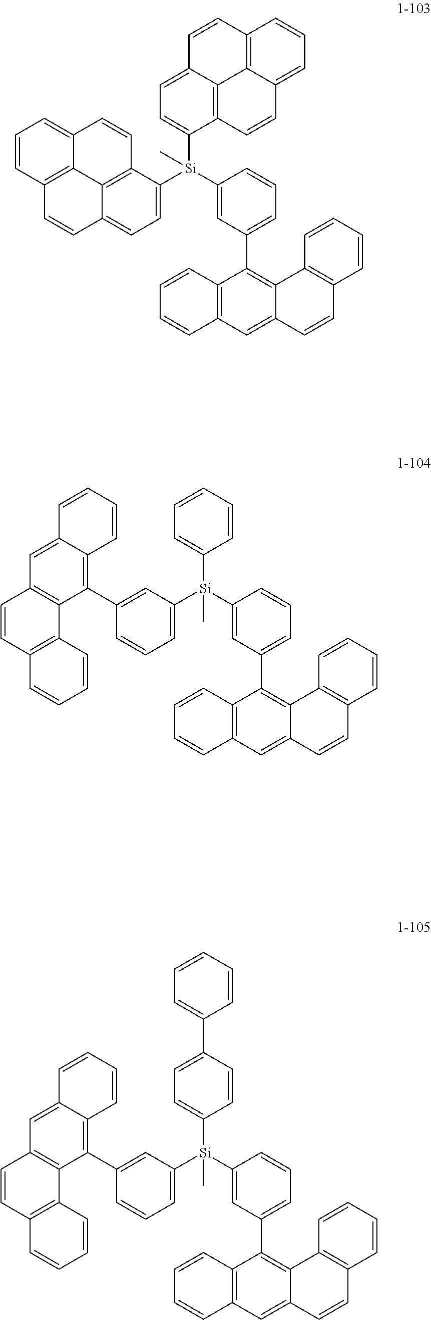 [SMILES: C[Si](c1cccc(-c2c3ccccc3cc3ccc4ccccc4c23)c1)(c1ccc2ccc3cccc4ccc1c2c34)c1ccc2ccc3cccc4ccc1c2c34 ; C[Si](c1ccccc1)(c1cccc(-c2c3ccccc3cc3ccc4ccccc4c23)c1)c1cccc(-c2c3ccccc3cc3ccc4ccccc4c23)c1 ; C[Si](c1ccc(-c2ccccc2)cc1)(c1cccc(-c2c3ccccc3cc3ccc4ccccc4c23)c1)c1cccc(-c2c3ccccc3cc3ccc4ccccc4c23)c1]

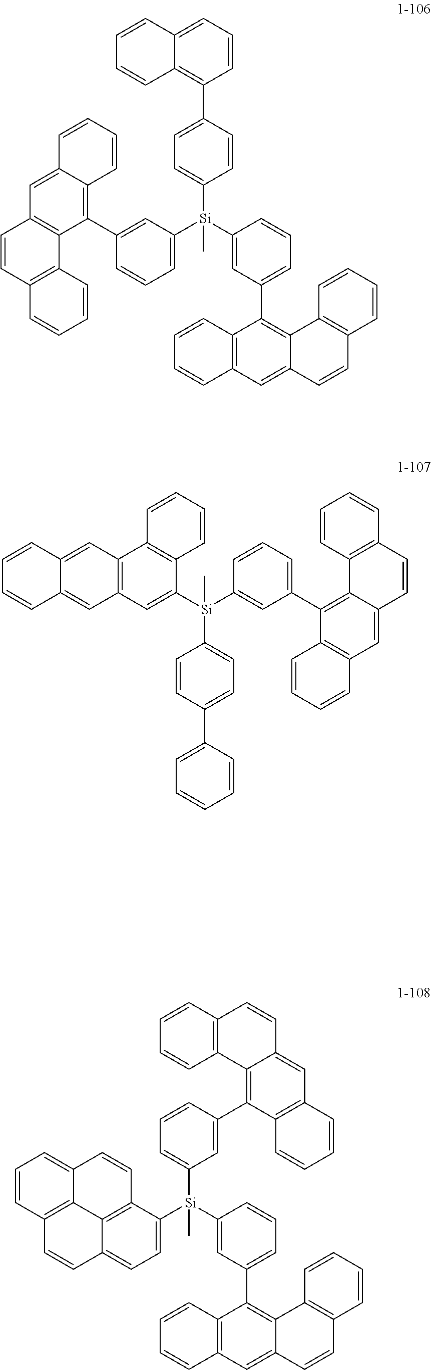 [SMILES: C[Si](c1ccc(-c2cccc3ccccc23)cc1)(c1cccc(-c2c3ccccc3cc3ccc4ccccc4c23)c1)c1cccc(-c2c3ccccc3cc3ccc4ccccc4c23)c1 ; C[Si](c1ccc(-c2ccccc2)cc1)(c1cccc(-c2c3ccccc3cc3ccc4ccccc4c23)c1)c1cc2cc3ccccc3cc2c2ccccc12 ; C[Si](c1cccc(-c2c3ccccc3cc3ccc4ccccc4c23)c1)(c1cccc(-c2c3ccccc3cc3ccc4ccccc4c23)c1)c1ccc2ccc3cccc4ccc1c2c34]

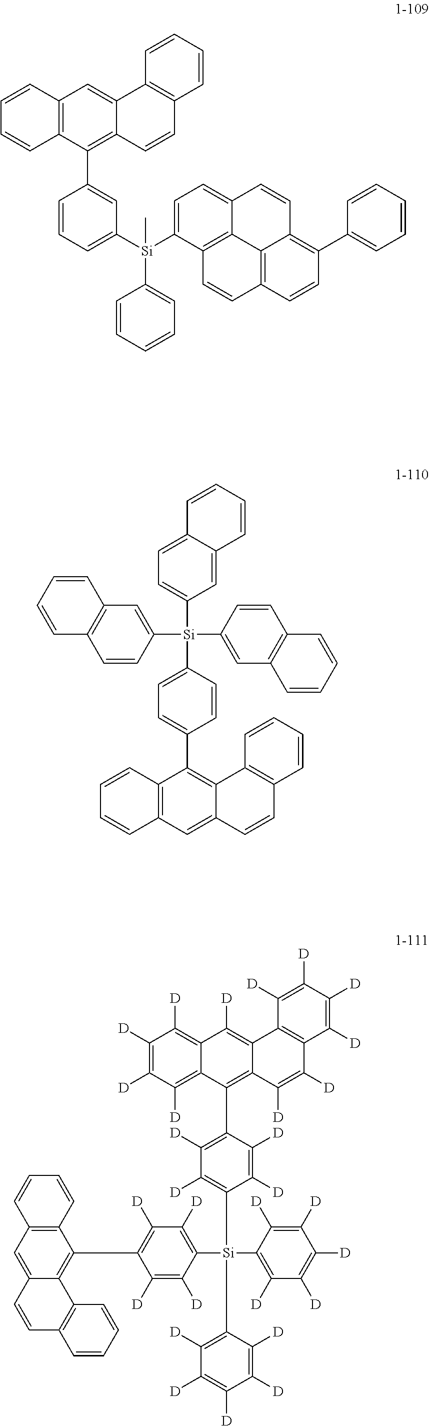 [SMILES: C[Si](c1ccccc1)(c1cccc(-c2c3ccccc3cc3c2ccc2ccccc23)c1)c1ccc2ccc3c(-c4ccccc4)ccc4ccc1c2c43 ; c1ccc2cc([Si](c3ccc(-c4c5ccccc5cc5ccc6ccccc6c45)cc3)(c3ccc4ccccc4c3)c3ccc4ccccc4c3)ccc2c1 ; [2H]c1c([2H])c([2H])c([Si](c2c([2H])c([2H])c([2H])c([2H])c2[2H])(c2c([2H])c([2H])c(-c3c4c([2H])c([2H])c([2H])c([2H])c4c([2H])c4c3c([2H])c([2H])c3c([2H])c([2H])c([2H])c([2H])c34)c([2H])c2[2H])c2c([2H])c([2H])c(-c3c4ccccc4cc4ccc5ccccc5c34)c([2H])c2[2H])c([2H])c1[2H]]

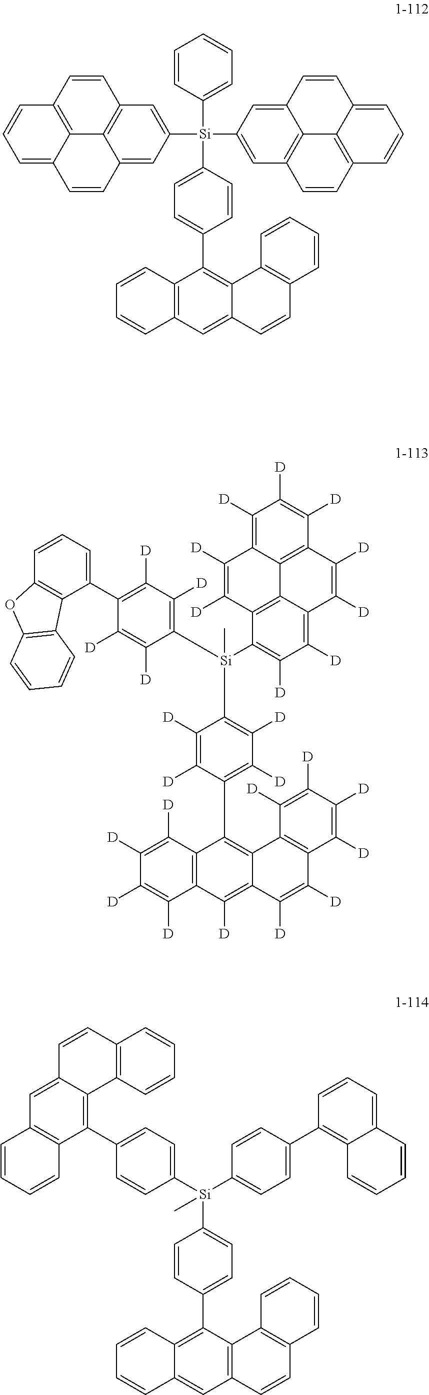 [SMILES: c1ccc([Si](c2ccc(-c3c4ccccc4cc4ccc5ccccc5c34)cc2)(c2cc3ccc4cccc5ccc(c2)c3c45)c2cc3ccc4cccc5ccc(c2)c3c45)cc1 ; [2H]c1c([2H])c([Si](C)(c2c([2H])c([2H])c(-c3c4c([2H])c([2H])c([2H])c([2H])c4c([2H])c4c([2H])c([2H])c5c([2H])c([2H])c([2H])c([2H])c5c34)c([2H])c2[2H])c2c([2H])c([2H])c3c([2H])c([2H])c4c([2H])c([2H])c([2H])c5c([2H])c([2H])c2c3c45)c([2H])c([2H])c1-c1cccc2oc3ccccc3c12 ; C[Si](c1ccc(-c2cccc3ccccc23)cc1)(c1ccc(-c2c3ccccc3cc3ccc4ccccc4c23)cc1)c1ccc(-c2c3ccccc3cc3ccc4ccccc4c23)cc1]

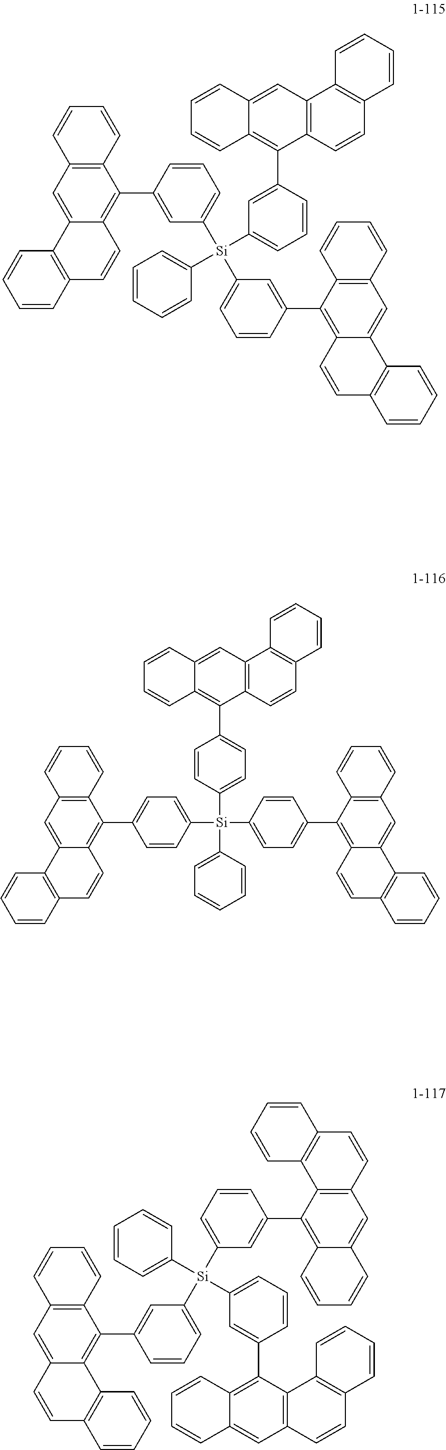 [SMILES: c1ccc([Si](c2cccc(-c3c4ccccc4cc4c3ccc3ccccc34)c2)(c2cccc(-c3c4ccccc4cc4c3ccc3ccccc34)c2)c2cccc(-c3c4ccccc4cc4c3ccc3ccccc34)c2)cc1 ; c1ccc([Si](c2ccc(-c3c4ccccc4cc4c3ccc3ccccc34)cc2)(c2ccc(-c3c4ccccc4cc4c3ccc3ccccc34)cc2)c2ccc(-c3c4ccccc4cc4c3ccc3ccccc34)cc2)cc1 ; c1ccc([Si](c2cccc(-c3c4ccccc4cc4ccc5ccccc5c34)c2)(c2cccc(-c3c4ccccc4cc4ccc5ccccc5c34)c2)c2cccc(-c3c4ccccc4cc4ccc5ccccc5c34)c2)cc1]

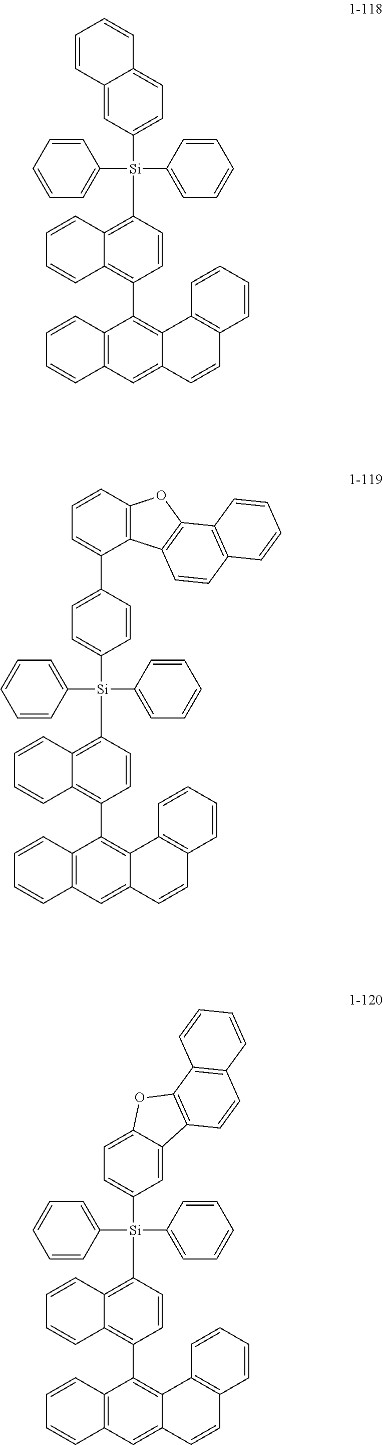 [SMILES: c1ccc([Si](c2ccccc2)(c2ccc3ccccc3c2)c2ccc(-c3c4ccccc4cc4ccc5ccccc5c34)c3ccccc23)cc1 ; c1ccc([Si](c2ccccc2)(c2ccc(-c3cccc4oc5c6ccccc6ccc5c34)cc2)c2ccc(-c3c4ccccc4cc4ccc5ccccc5c34)c3ccccc23)cc1 ; c1ccc([Si](c2ccccc2)(c2ccc3oc4c5ccccc5ccc4c3c2)c2ccc(-c3c4ccccc4cc4ccc5ccccc5c34)c3ccccc23)cc1]

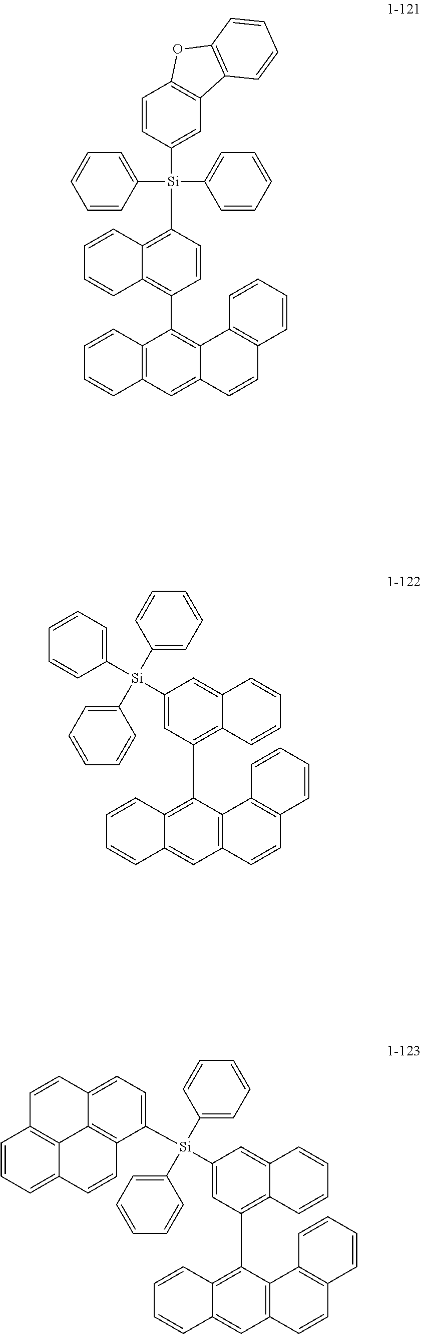 [SMILES: c1ccc([Si](c2ccccc2)(c2ccc3oc4ccccc4c3c2)c2ccc(-c3c4ccccc4cc4ccc5ccccc5c34)c3ccccc23)cc1 ; c1ccc([Si](c2ccccc2)(c2ccccc2)c2cc(-c3c4ccccc4cc4ccc5ccccc5c34)c3ccccc3c2)cc1 ; c1ccc([Si](c2ccccc2)(c2cc(-c3c4ccccc4cc4ccc5ccccc5c34)c3ccccc3c2)c2ccc3ccc4cccc5ccc2c3c45)cc1]

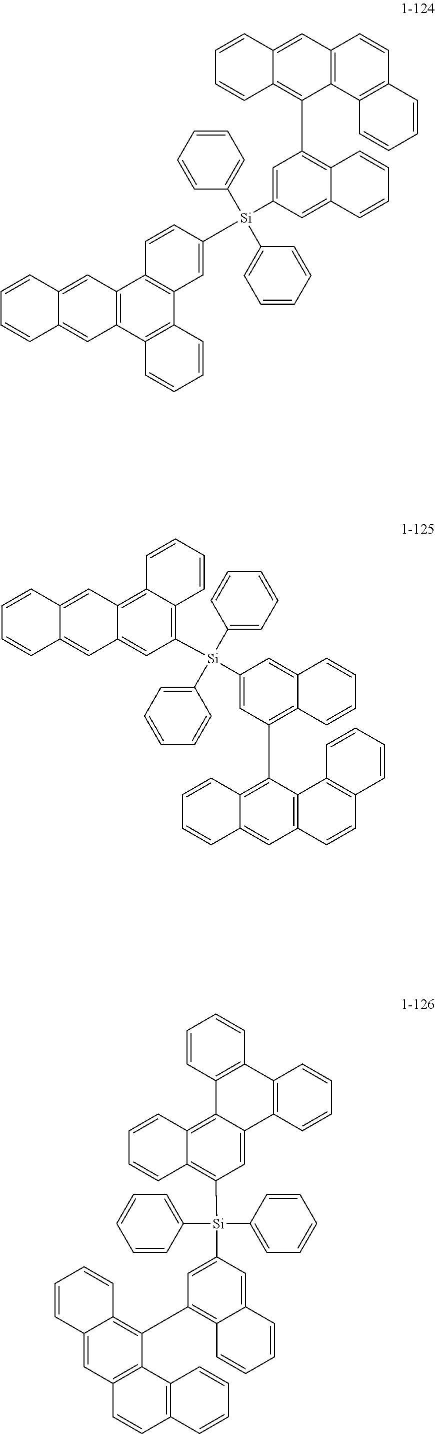 [SMILES: c1ccc([Si](c2ccccc2)(c2cc(-c3c4ccccc4cc4ccc5ccccc5c34)c3ccccc3c2)c2ccc3c(c2)c2ccccc2c2cc4ccccc4cc32)cc1 ; c1ccc([Si](c2ccccc2)(c2cc(-c3c4ccccc4cc4ccc5ccccc5c34)c3ccccc3c2)c2cc3cc4ccccc4cc3c3ccccc23)cc1 ; c1ccc([Si](c2ccccc2)(c2cc(-c3c4ccccc4cc4ccc5ccccc5c34)c3ccccc3c2)c2cc3c4ccccc4c4ccccc4c3c3ccccc23)cc1]

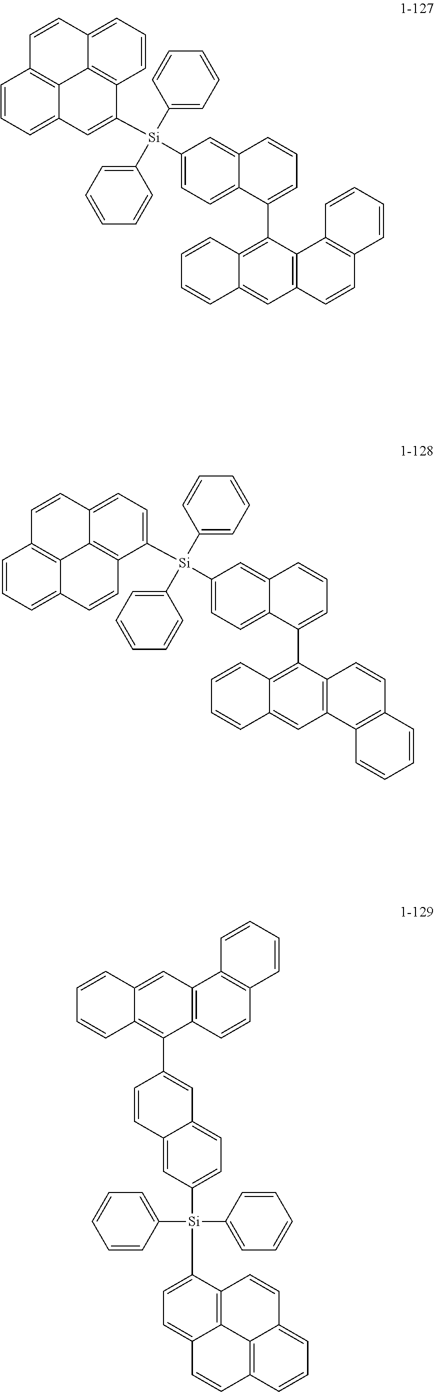 [SMILES: c1ccc([Si](c2ccccc2)(c2ccc3c(-c4c5ccccc5cc5ccc6ccccc6c45)cccc3c2)c2cc3cccc4ccc5cccc2c5c43)cc1 ; c1ccc([Si](c2ccccc2)(c2ccc3c(-c4c5ccccc5cc5c4ccc4ccccc45)cccc3c2)c2ccc3ccc4cccc5ccc2c3c45)cc1 ; c1ccc([Si](c2ccccc2)(c2ccc3cc(-c4c5ccccc5cc5c4ccc4ccccc45)ccc3c2)c2ccc3ccc4cccc5ccc2c3c45)cc1]

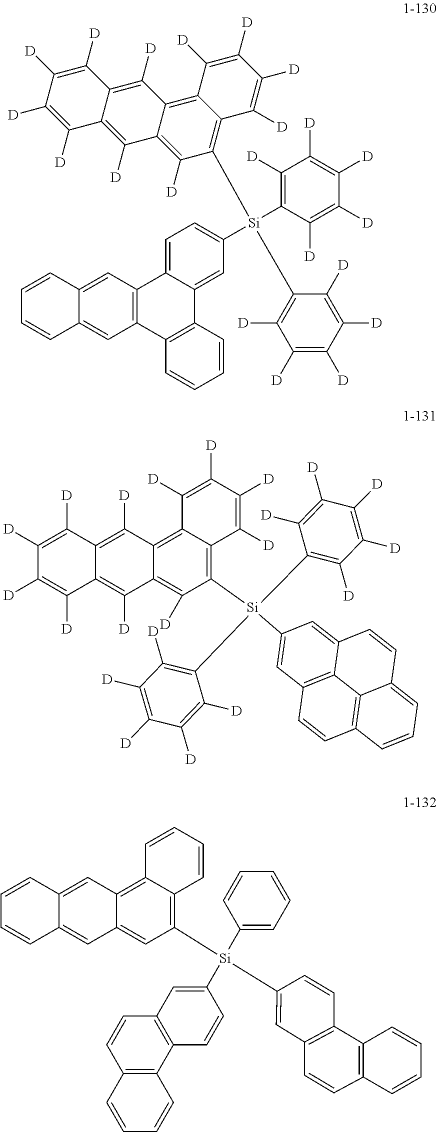 [SMILES: [2H]c1c([2H])c([2H])c([Si](c2ccc3c(c2)c2ccccc2c2cc4ccccc4cc32)(c2c([2H])c([2H])c([2H])c([2H])c2[2H])c2c([2H])c3c([2H])c4c([2H])c([2H])c([2H])c([2H])c4c([2H])c3c3c([2H])c([2H])c([2H])c([2H])c23)c([2H])c1[2H] ; [2H]c1c([2H])c([2H])c([Si](c2cc3ccc4cccc5ccc(c2)c3c45)(c2c([2H])c([2H])c([2H])c([2H])c2[2H])c2c([2H])c3c([2H])c4c([2H])c([2H])c([2H])c([2H])c4c([2H])c3c3c([2H])c([2H])c([2H])c([2H])c23)c([2H])c1[2H] ; c1ccc([Si](c2ccc3c(ccc4ccccc43)c2)(c2ccc3c(ccc4ccccc43)c2)c2cc3cc4ccccc4cc3c3ccccc23)cc1]

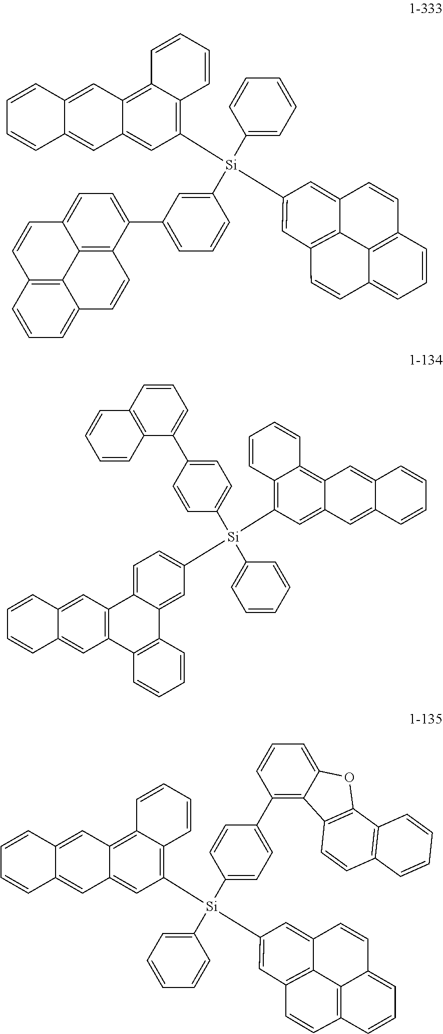 [SMILES: c1ccc([Si](c2cccc(-c3ccc4ccc5cccc6ccc3c4c56)c2)(c2cc3ccc4cccc5ccc(c2)c3c45)c2cc3cc4ccccc4cc3c3ccccc23)cc1 ; c1ccc([Si](c2ccc(-c3cccc4ccccc34)cc2)(c2ccc3c(c2)c2ccccc2c2cc4ccccc4cc32)c2cc3cc4ccccc4cc3c3ccccc23)cc1 ; c1ccc([Si](c2ccc(-c3cccc4oc5c6ccccc6ccc5c34)cc2)(c2cc3ccc4cccc5ccc(c2)c3c45)c2cc3cc4ccccc4cc3c3ccccc23)cc1]

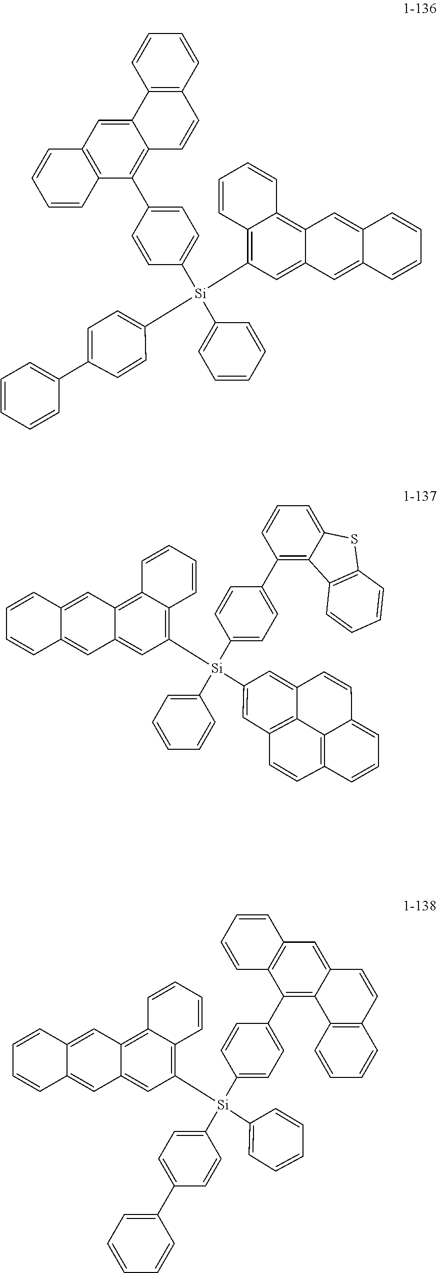 [SMILES: c1ccc(-c2ccc([Si](c3ccccc3)(c3ccc(-c4c5ccccc5cc5c4ccc4ccccc45)cc3)c3cc4cc5ccccc5cc4c4ccccc34)cc2)cc1 ; c1ccc([Si](c2ccc(-c3cccc4sc5ccccc5c34)cc2)(c2cc3ccc4cccc5ccc(c2)c3c45)c2cc3cc4ccccc4cc3c3ccccc23)cc1 ; c1ccc(-c2ccc([Si](c3ccccc3)(c3ccc(-c4c5ccccc5cc5ccc6ccccc6c45)cc3)c3cc4cc5ccccc5cc4c4ccccc34)cc2)cc1]

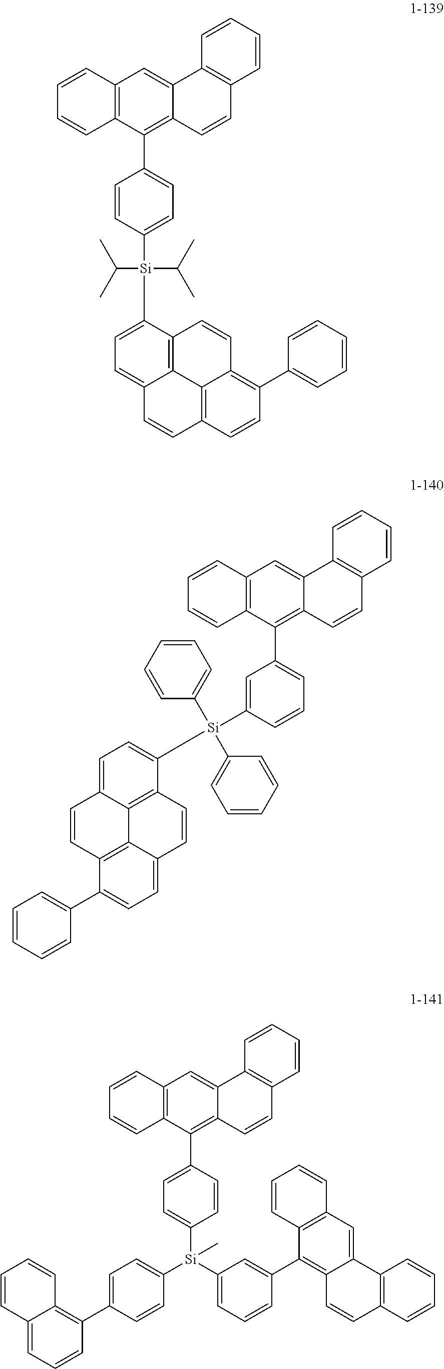 [SMILES: CC(C)[Si](c1ccc(-c2c3ccccc3cc3c2ccc2ccccc23)cc1)(c1ccc2ccc3ccc(-c4ccccc4)c4ccc1c2c34)C(C)C ; c1ccc(-c2ccc3ccc4c([Si](c5ccccc5)(c5ccccc5)c5cccc(-c6c7ccccc7cc7c6ccc6ccccc67)c5)ccc5ccc2c3c54)cc1 ; C[Si](c1ccc(-c2cccc3ccccc23)cc1)(c1ccc(-c2c3ccccc3cc3c2ccc2ccccc23)cc1)c1cccc(-c2c3ccccc3cc3c2ccc2ccccc23)c1]

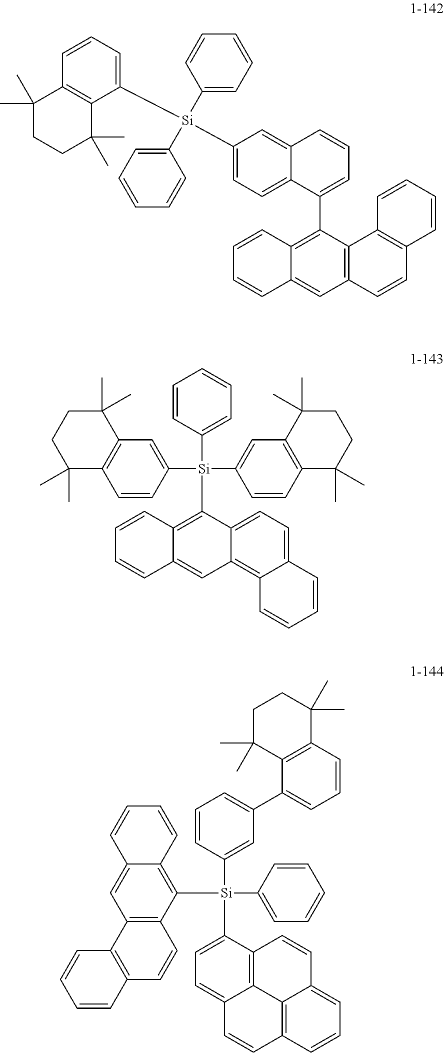

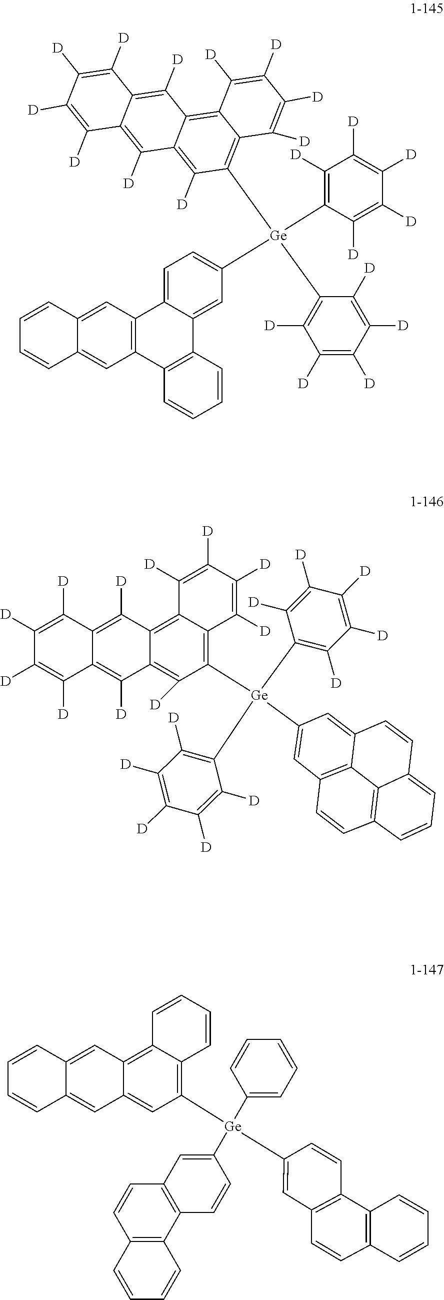

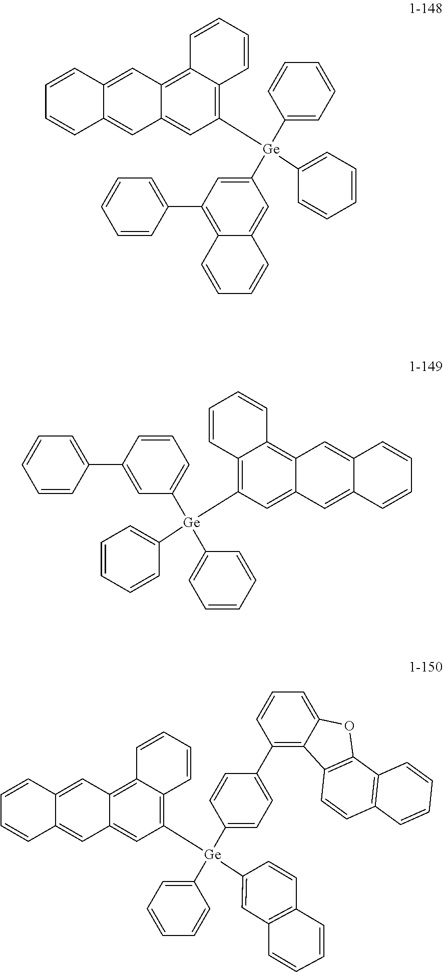

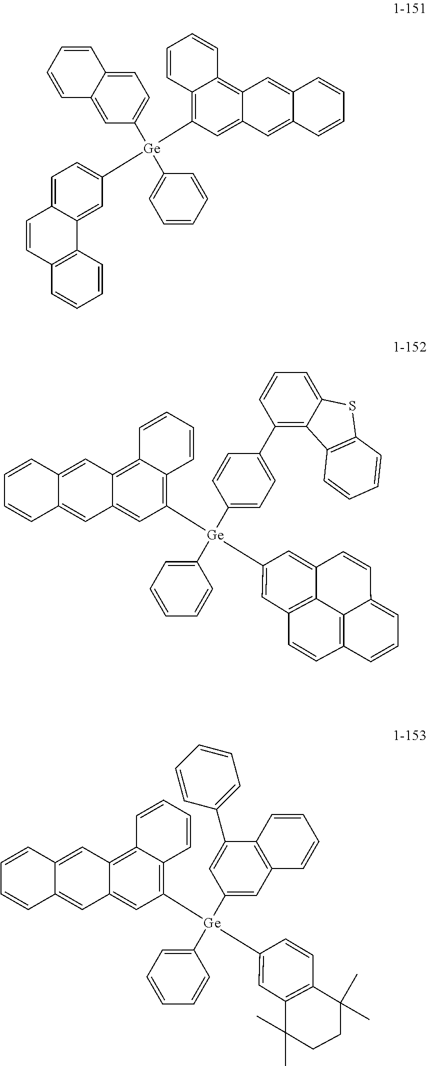

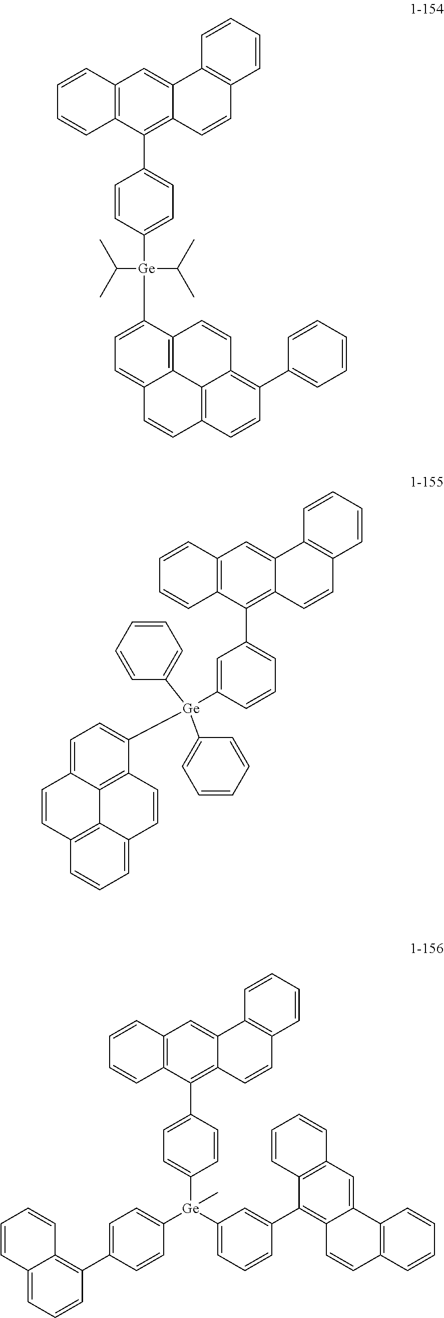

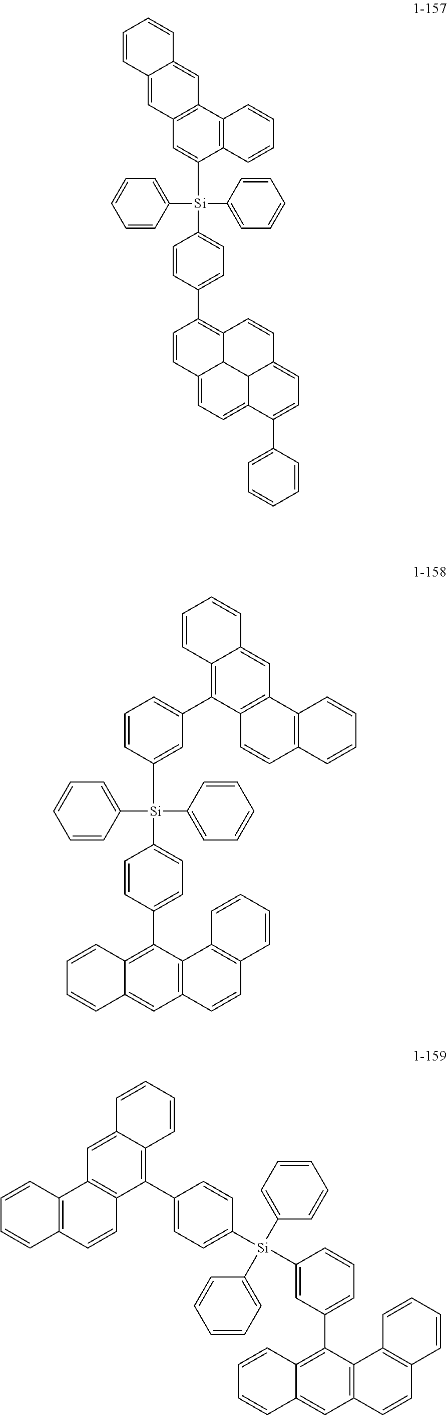 [SMILES: C1=CC2=C(c3ccc([Si](c4ccccc4)(c4ccccc4)c4cc5cc6ccccc6cc5c5ccccc45)cc3)C=CC3=CC=C4C(c5ccccc5)=CC=C1C4C32 ; c1ccc([Si](c2ccccc2)(c2ccc(-c3c4ccccc4cc4ccc5ccccc5c34)cc2)c2cccc(-c3c4ccccc4cc4c3ccc3ccccc34)c2)cc1 ; c1ccc([Si](c2ccccc2)(c2ccc(-c3c4ccccc4cc4c3ccc3ccccc34)cc2)c2cccc(-c3c4ccccc4cc4ccc5ccccc5c34)c2)cc1]

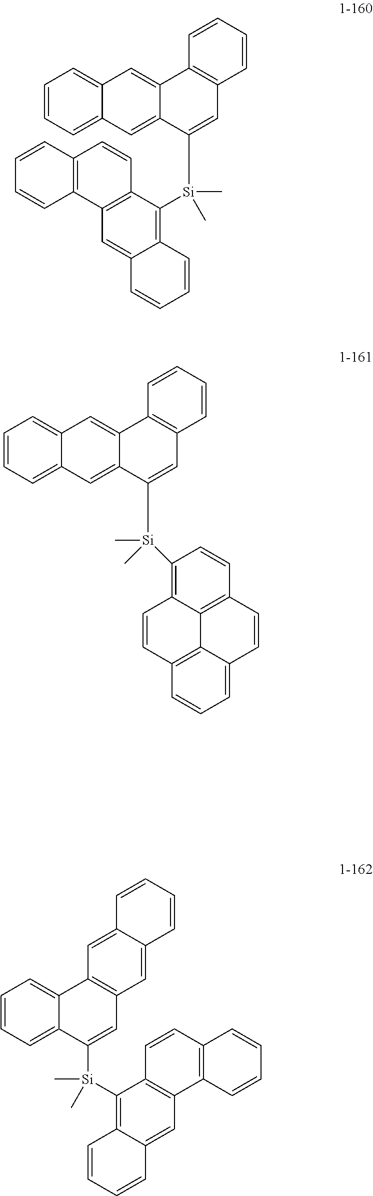 [SMILES: C[Si](C)(c1cc2ccccc2c2cc3ccccc3cc12)c1c2ccccc2cc2c1ccc1ccccc12 ; C[Si](C)(c1cc2ccccc2c2cc3ccccc3cc12)c1ccc2ccc3cccc4ccc1c2c34 ; C[Si](C)(c1cc2cc3ccccc3cc2c2ccccc12)c1c2ccccc2cc2c1ccc1ccccc12]

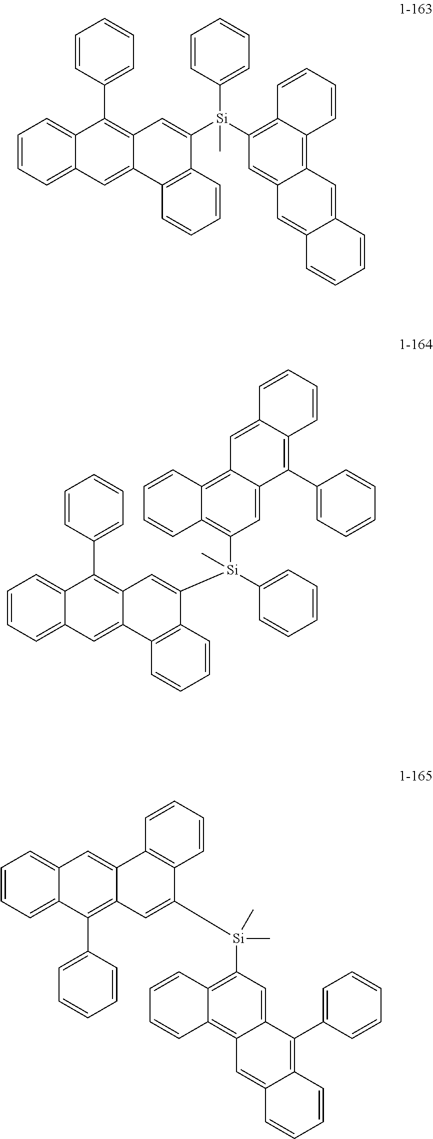 [SMILES: C[Si](c1ccccc1)(c1cc2cc3ccccc3cc2c2ccccc12)c1cc2c(-c3ccccc3)c3ccccc3cc2c2ccccc12 ; C[Si](c1ccccc1)(c1cc2c(-c3ccccc3)c3ccccc3cc2c2ccccc12)c1cc2c(-c3ccccc3)c3ccccc3cc2c2ccccc12 ; C[Si](C)(c1cc2c(-c3ccccc3)c3ccccc3cc2c2ccccc12)c1cc2c(-c3ccccc3)c3ccccc3cc2c2ccccc12]

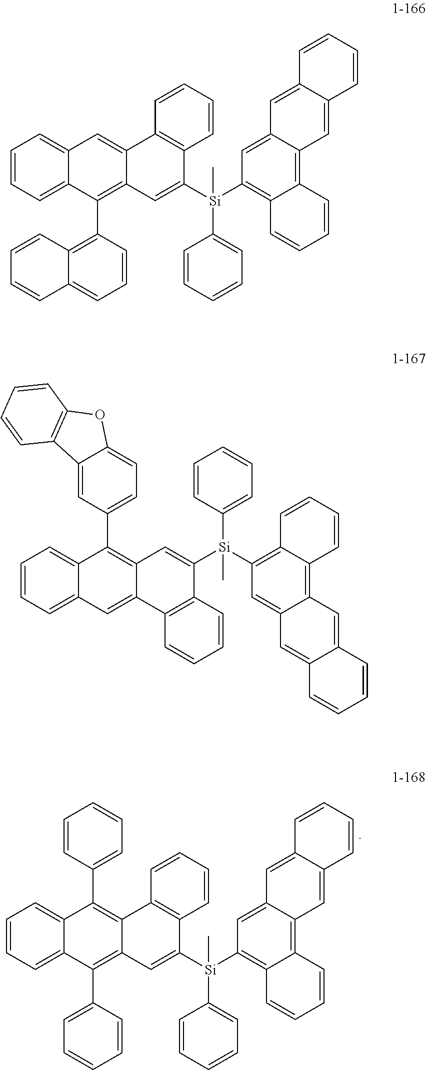 [SMILES: C[Si](c1ccccc1)(c1cc2cc3ccccc3cc2c2ccccc12)c1cc2c(-c3cccc4ccccc34)c3ccccc3cc2c2ccccc12 ; C[Si](c1ccccc1)(c1cc2cc3ccccc3cc2c2ccccc12)c1cc2c(-c3ccc4oc5ccccc5c4c3)c3ccccc3cc2c2ccccc12 ; C[Si](c1ccccc1)(c1cc2cc3ccccc3cc2c2ccccc12)c1cc2c(-c3ccccc3)c3ccccc3c(-c3ccccc3)c2c2ccccc12]

10. An organic light-emitting device comprising:
a first electrode;
a second electrode provided opposite to the first electrode; and
a first light-emitting layer including a first host and a first dopant, and a second light-emitting layer including a second host and a second dopant, the first light-emitting layer and the second light-emitting layers being interposed between the first electrode and the second electrode,
wherein the first host and the second host each include one or more compounds, and at least one selected from the group consisting of the first host and the second host includes a compound represented by the following [Chemical Formula 1]: 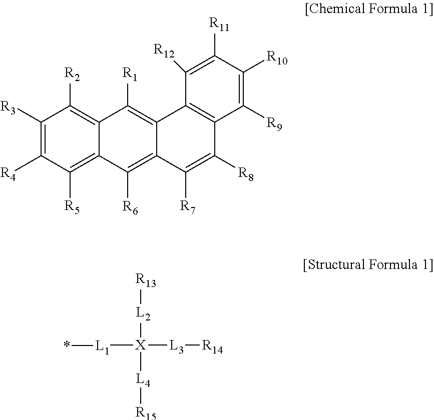
in [Chemical Formula 1],
one of R₁ to R₁₂ is linked to L₁ in [Structural Formula 1] via a single bond (‘*’ represents a linking site);
the remainders of R₁ to R₁₂ excluding the one linked to L₁ via a single bond are the same as or different from each other, and each independently any one selected from hydrogen, deuterium, tritium, a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted group, or unsubstituted C₂-C₃₀ alkenyl a substituted or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group;
X is Si or Ge;
L₁ to L₄ are the same as or different from each other, and each independently a single bond, or any one selected from a substituted or unsubstituted C₆-C₃₀ arylene group, a substituted or unsubstituted C₂-C₃₀ heteroarylene group, and a substituted or unsubstituted arylene group fused with a C₈-C₃₀ aliphatic hydrocarbon ring;
R₁₃ is any one selected from a substituted or unsubstituted C₆-C₅₀ aryl group, a substituted or unsubstituted C₂-C₅₀ heteroaryl group, a substituted or unsubstituted C₃-C₅₀ cycloalkyl group, a substituted or unsubstituted C₂-C₅₀ heterocycloalkyl group, and a substituted or unsubstituted cyclic group in which a C₃-C₃₀ aliphatic ring and a C₅-C₃₀ aromatic ring are fused;
R₁₄ and R₁₅ are the same as or different from each other, and each independently any one selected from a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted or unsubstituted C₂-C₃₀ alkenyl group, a substituted or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group; and
the ‘substituted’ in the ‘substituted or unsubstituted’ in [Chemical Formula 1] and [Structural Formula 1] means being substituted with one or more substituents selected from the group consisting of deuterium, tritium, a C₁-C₂₄ alkyl group, a C₁-C₂₄ halogenated alkyl group, a C₂-C₂₄ alkenyl group, a C₂-C₂₄ alkynyl group, a C₃-C₃₀ cycloalkyl group, a C₁-C₂₄ heteroalkyl group, a C₆-C₃₀ aryl group, a C₇-C₃₀ arylalkyl group, a C₇-C₃₀ alkylaryl group, a C₂-C₃₀ heteroaryl group, a C₂-C₃₀ heteroarylalkyl group, a cyclic group in which a C₃-C₂₄ aliphatic ring and a C₅-C₂₄ aromatic ring are fused, a C₁-C₃₀ amine group, a C₁-C₃₀ silyl group, a C₁-C₃₀ germanium group, a C₁-C₃₀ oxy group, a C₁-C₃₀ thioxy group, a C₁-C₃₀ thionyl group, a cyano group, a halogen group, a thiol group, a hydroxyl group and a nitro group, and when there are two or more substituents, they are the same as or different from each other, and at least one hydrogen atom in the compound formed from [Chemical Formula 1] is optionally substituted with deuterium or tritium.

11. The organic light-emitting device of claim 10, wherein one of the first host and the second host in the organic light-emitting device includes the compound represented by [Chemical Formula 1], and the other of the first host and the second host includes an anthracene compound represented by the following [Chemical Formula 2]: 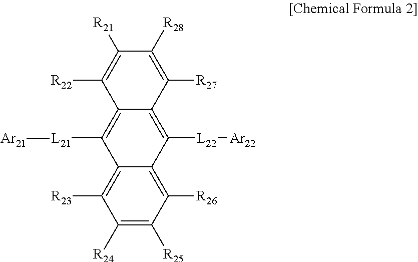
in [Chemical Formula 2],
R₂₁ to R₂₈ are the same as or different from each other, and each independently any one selected from hydrogen, deuterium, tritium, a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted or unsubstituted C₂-C₃₀ alkenyl group, a substituted or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group;
L₂₁ and L₂₂ are the same as or different from each other, and each independently a single bond, or any one selected from a substituted or unsubstituted C₆-C₃₀ arylene group, a substituted or unsubstituted C₂-C₃₀ heteroarylene group, and a substituted or unsubstituted arylene group fused with a C₈-C₃₀ aliphatic hydrocarbon ring;
Ar₂₁ and Ar₂₂ are the same as or different from each other, and each independently any one selected from a substituted or unsubstituted C₆-C₅₀ aryl group, a substituted or unsubstituted C₂-C₅₀ heteroaryl group, a substituted or unsubstituted C₃-C₅₀ cycloalkyl group, a substituted or unsubstituted C₂-C₅₀ heterocycloalkyl group, and a substituted or unsubstituted cyclic group in which a C₃-C₃₀ aliphatic ring and a C₅-C₃₀ aromatic ring are fused;
hydrogen atoms bonded to carbon atoms in [Chemical Formula 2] may be substituted with deuterium or tritium in a number ranging from 0 to 60; and
the ‘substituted’ in the ‘substituted or unsubstituted’ in [Chemical Formula 2] means being substituted with one or more substituents selected from the group consisting of deuterium, tritium, a C₁-C₂₄ alkyl group, a C₁-C₂₄ halogenated alkyl group, a C₂-C₂₄ alkenyl group, a C₂-C₂₄ alkynyl group, a C₃-C₃₀ cycloalkyl group, a C₁-C₂₄ heteroalkyl group, a C₆-C₃₀ aryl group, a C₇-C₃₀ arylalkyl group, a C₇-C₃₀ alkylaryl group, a C₂-C₃₀ heteroaryl group, a C₂-C₃₀ heteroarylalkyl group, a cyclic group in which a C₃-C₂₄ aliphatic ring and a C₅-C₂₄ aromatic ring are fused, a C₁-C₃₀ amine group, a C₁-C₃₀ silyl group, a C₁-C₃₀ germanium group, a C₁-C₃₀ oxy group, a C₁-C₃₀ thioxy group, a C₁-C₃₀ thionyl group, a cyano group, a halogen group, a thiol group, a hydroxyl group and a nitro group, and when there are two or more substituents, they are the same as or different from each other, and at least one hydrogen atom in the compound formed from [Chemical Formula 2] is optionally substituted with deuterium or tritium.

12. The organic light-emitting device of claim 11, wherein Ar₂₁ in the anthracene compound represented by [Chemical Formula 2] is represented by the following [Structural Formula 2]: 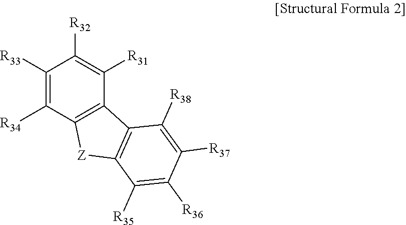
in [Structural Formula 2],
Z is O or S;
one of R₃₁ to R₃₈ is linked to L₂₁ in [Chemical Formula 2] via a single bond;
the remainders of R₃₁ to R₃₈ excluding the one linked to L₂₁ via a single bond are the same as or different from each other, and each independently any one selected from hydrogen, deuterium, tritium, a substituted or unsubstituted C₁-C₃₀ alkyl group, a substituted or unsubstituted C₁-C₃₀ halogenated alkyl group, a substituted or unsubstituted C₂-C₃₀ alkynyl group, a substituted or unsubstituted C₂-C₃₀ alkenyl group, a substituted or unsubstituted C₆-C₅₀ aryl group, a substituted or unsubstituted C₃-C₅₀ cycloalkyl group, a substituted or unsubstituted C₂-C₅₀ heterocycloalkyl group, a substituted or unsubstituted C₂-C₅₀ heteroaryl group, a substituted or unsubstituted cyclic group in which a C₃-C₃₀ aliphatic ring and a C₅-C₃₀ aromatic ring are fused, a substituted or unsubstituted C₁-C₃₀ oxy group, a substituted or unsubstituted C₁-C₃₀ thioxy group, a substituted or unsubstituted C₁-C₃₀ thionyl group, a substituted or unsubstituted amine group, a substituted or unsubstituted silyl group, a substituted or unsubstituted germanium group, a thiol group, a hydroxyl group, a nitro group, a cyano group, and a halogen group;
the adjacent R₃₁ to R₃₈ are each optionally linked to each other to further form an alicyclic or aromatic monocyclic or polycyclic ring; and
the ‘substituted’ in the ‘substituted or unsubstituted’ in [Structural Formula 2] means being substituted with one or more substituents selected from the group consisting of deuterium, tritium, a C₁-C₂₄ alkyl group, a C₁-C₂₄ halogenated alkyl group, a C₂-C₂₄ alkenyl group, a C₂-C₂₄ alkynyl group, a C₃-C₃₀ cycloalkyl group, a C₁-C₂₄ heteroalkyl group, a C₆-C₃₀ aryl group, a C₇-C₃₀ arylalkyl group, a C₇-C₃₀ alkylaryl group, a C₂-C₃₀ heteroaryl group, a C₂-C₃₀ heteroarylalkyl group, a cyclic group in which a C₃-C₂₄ aliphatic ring and a C₅-C₂₄ aromatic ring are fused, a C₁-C₃₀ amine group, a C₁-C₃₀ silyl group, a C₁-C₃₀ germanium group, a C₁-C₃₀ oxy group, a C₁-C₃₀ thioxy group, a C₁-C₃₀ thionyl group, a cyano group, a halogen group, a thiol group, a hydroxyl group and a nitro group, and when there are two or more substituents, they are the same as or different from each other, and at least one hydrogen atom in the compound formed from [Structural Formula 2] is optionally substituted with deuterium or tritium.

13. The organic light-emitting device of claim 11, wherein the anthracene compound represented by [Chemical Formula 2] includes at least one deuterium atom.

14. The organic light-emitting device of claim 11, wherein, in the organic light-emitting device, one of the first host and the second host includes two or more different anthracene compounds represented by [Chemical Formula 2].

15. The organic light-emitting device of claim 14, wherein Ar₂₁ in at least one of the anthracene compounds represented by [Chemical Formula 2] is a substituted or unsubstituted C₆-C₃₀ aryl group, and Ar₂₁ in at least one of the additionally included anthracene compounds represented by [Chemical Formula 2] is a substituted or unsubstituted C₂-C₃₀ heteroaryl group.

16. The organic light-emitting device of claim 15, wherein, when Ar₂₁ is a substituted or unsubstituted C₂-C₃₀ heteroaryl group, Ar₂₁ is the substituent represented by [Structural Formula 2].

17. The organic light-emitting device of claim 10, wherein the first light-emitting layer in the organic light-emitting device includes the compound represented by [Chemical Formula 1] and further includes a host compound different from the compound represented by [Chemical Formula 1] as the first host, and includes the compound represented by [Chemical Formula 1] and the host compound different therefrom in a ratio of 1:9 to 9:1.

18. The organic light-emitting device of claim 14, wherein the second light-emitting layer in the organic light-emitting device includes the compound represented by [Chemical Formula 2] and further includes a host compound different from the compound represented by [Chemical Formula 2] as the second host, and includes the compound represented by [Chemical Formula 2] and the host compound different therefrom in a ratio of 1:9 to 9:1.

19. The organic light-emitting device of claim 11, wherein the first host in the first light-emitting layer in the organic light-emitting device includes the compound represented by [Chemical Formula 1] and a host compound different from the compound represented by [Chemical Formula 1] in a ratio of 1:9 to 9:1, and the second host in the second light-emitting layer includes the compound represented by [Chemical Formula 2] and a host compound different from the compound represented by [Chemical Formula 2] in a ratio of 1:9 to 9:1.
